(19) United States
(12) Patent Application Publication
(10) Pub. No.: US 2025/0255183 A1
(43) Pub. Date: Aug. 7, 2025

(54) ORGANIC LIGHT-EMITTING DIODE AND DISPLAY APPARATUS

(71) Applicants: KunShan Go-Visionox Opto-Electronics Co., Ltd, Kunshan (CN); TSINGHUA UNIVERSITY, Beijing (CN)

(72) Inventors: Guomeng LI, Kunshan (CN); Lian DUAN, Kunshan (CN); Baoyu LI, Kunshan (CN); Minghan CAI, Kunshan (CN); Bin LIU, Kunshan (CN); Mengzhen LI, Kunshan (CN); Hongyu WANG, Kunshan (CN)

(73) Assignees: KunShan Go-Visionox Opto-Electronics Co., Ltd, Kunshan (CN); TSINGHUA UNIVERSITY, Beijing (CN)

(21) Appl. No.: 19/187,934

(22) Filed: Apr. 23, 2025

Related U.S. Application Data
(63) Continuation of application No. PCT/CN2023/077228, filed on Feb. 20, 2023.

(30) Foreign Application Priority Data
Nov. 14, 2022 (CN) 202211418348.3

(51) Int. Cl. H10K 85/60; C09K 11/02; C09K 11/06; H10K 50/12; H10K 85/30; H10K 85/40; H10K 101/00

(52) U.S. Cl. CPC H10K 85/658; C09K 11/02; C09K 11/06; H10K 85/342; H10K 85/346; H10K 85/40; H10K 85/622; H10K 85/654; H10K 85/6572; H10K 85/6576; C09K 2211/1007; C09K 2211/1018; H10K 50/121; H10K 2101/27

(57) ABSTRACT

The present application provides an organic light-emitting diode and a display apparatus. The organic light-emitting diode comprises at least one light-emitting layer; the at least one light-emitting layer comprises at least one phosphorescence sensitized layer; the phosphorescence sensitized layer comprises a host material, a phosphorescent sensitizer, and a narrow-spectrum fluorescent material; and the full width at half maximum of the narrow-spectrum fluorescent material is less than 45 nm. The present application can improve the properties such as efficiency and service life of the organic light-emitting diode.

### CROSS REFERENCE TO RELATED APPLICATION

The present application is a continuation application of International Application No. PCT/CN 2023/077228, filed on Feb. 20, 2023, which claims priority to Chinese Patent Application No. 202211418348.3, filed with the China National Intellectual Property Administration on Nov. 14, 2022 and entitled “ORGANIC LIGHT-EMITTING DIODE AND DISPLAY APPARATUS”, which is incorporated herein by reference in its entirety.

### FIELD

The present application relates to an organic light-emitting diode and a display apparatus, which belong to the field of organic electroluminescence.

### BACKGROUND

An organic light-emitting diode (OLED) is a device driven by electric current to achieve luminescence, the main characteristic of which is derived from the light-emitting layer therein. When an appropriate voltage is applied, electrons and holes will be combined in the light-emitting layer to generate excitons, and light of various wavelengths is emitted depending on the properties of the light-emitting layer. Currently, the light-emitting layer materials generally lead to defects such as low efficiency and short service life of devices, especially for stacked-layer devices, which usually include a plurality of light-emitting layers. The light-emitting layer essentially includes a host material and a phosphorescent material, and the phosphorescent material is prone to cause problems such as low efficiency and short service life of devices with the limitations of the structural properties thereof (such as long-wavelength 3M LCT absorption and long self-transient service life).

### SUMMARY

The present application provides an organic light-emitting diode and a display apparatus, which can improve the performance such as the efficiency and service life of the device and effectively overcome the defects in the prior art.

An aspect of the present application provides an organic light-emitting diode, including at least one light-emitting layer, which includes at least one phosphorescence sensitized layer, wherein the phosphorescence sensitized layer includes a host material, a phosphorescent sensitizer, and a narrow-spectrum fluorescent material, and the full width at half maximum of the narrow-spectrum fluorescent material is less than 45 nm.

Another aspect of the present application provides a display apparatus, which includes the organic light-emitting diode described above.

In the present application, the organic light-emitting diode has at least one light-emitting layer that is a phosphorescence sensitized layer (that is, the organic light-emitting diode at least includes one phosphorescence sensitized layer). The phosphorescence sensitized layer has a composition system including a host material, a phosphorescent sensitizer, and a narrow-spectrum fluorescent material, wherein the full width at half maximum (FWHM) of the introduced narrow-spectrum fluorescent material is less than 45 nm. With such a composition system, the phosphorescent material is used to sensitize the narrow-spectrum fluorescent material for luminescence, such that problems such as a broader full width at half maximum of the phosphorescent material itself can be mitigated, thereby improving the performance such as the efficiency and service life of the device

### BRIEF DESCRIPTION OF THE DRAWINGS

FIG. 1 shows a structural schematic diagram of an organic light-emitting diode according to an example of the present application; and

FIG. 2 shows a structural schematic diagram of an organic light-emitting diode according to another example of the present application.

List of reference signs: 10: anode; 11: first hole injection layer; 20: cathode; 21: first hole transport layer; 22: second hole transport layer; 31: first electron blocking layer; 32: second electron blocking layer; 41: first light-emitting layer; 42: second light-emitting layer; 51: first hole blocking layer; 52: second hole blocking layer; 61: first electron transport layer; 62: second electron transport layer; 71: p-type charge generation layer; 72: n-type charge generation layer; 81: first electron injection layer; 9: capping layer.

### DETAILED DESCRIPTION OF THE EMBODIMENTS

In the related art, light-emitting layer materials generally lead to defects such as low efficiency and short service life of devices, especially for stacked-layer devices that usually have at least two light-emitting layers. A light-emitting layer essentially includes a host material and a phosphorescent material (or referred to as phosphorescent dye). For example, in a red stacked-layer device, the light-emitting layers essentially have a composition system of a host material and a red phosphorescent dye. With such a composition system, the phosphorescent material always has problems of a broader width of emission peak and the resulting low efficiency and short service life of devices due to the limitation of the structural properties thereof (such as long-wavelength ³M L CT absorption and long transient service life themselves).

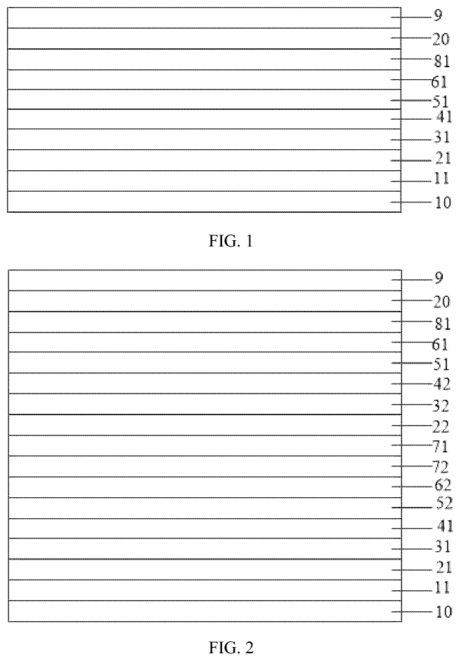

In view of this, an example of the present application provides an organic light-emitting diode. As shown in FIGS. 1 and 2, the organic light-emitting diode includes at least one light-emitting layer, which includes at least one phosphorescence sensitized layer. The phosphorescence sensitized layer includes a host material, a phosphorescent sensitizer, and a narrow-spectrum fluorescent material, wherein the full width at half maximum of the narrow-spectrum fluorescent material is less than 45 nm.

The organic light-emitting diode described above at least includes one phosphorescence sensitized layer, which has a composition system including a host material, a phosphorescent sensitizer, and a narrow-spectrum fluorescent material, wherein the full width at half maximum (FWHM) of the introduced narrow-spectrum fluorescent material is less than 45 nm. With such a composition system, the phosphorescent material is used to sensitize the narrow-spectrum fluorescent material for luminescence, such that problems such as a broader full width at half maximum of the phosphorescent material itself can be mitigated, thereby improving the performance such as efficiency and service life of the devices and realizing high-efficiency and high-stability luminescence of the devices.

In some examples, the luminescence peak of the narrow-spectrum fluorescent material may be 550 nm-680 nm, for example, 550 nm, 580 nm, 590 nm, 600 nm, 610 nm, 620 nm, 630 nm, 640 nm, 650 nm, 660 nm, 670 nm, and 680 nm. Preferably, the narrow-spectrum fluorescent material has a luminescence peak of 590-650 nm and a luminescence spectrum of red light, which enables the organic light-emitting diodes in these examples of the present application to generate red light. Furthermore, in the red light-emitting device, the light-emitting layer is formed by a three-doped system of a host material, a phosphorescent sensitizer, and a narrow-spectrum fluorescent material with an FWHM less than 45 nm, which are introduced simultaneously, so that the performance such as efficiency and service life of the red light-emitting device can be improved.

Specifically, the narrow-spectrum fluorescent material may be selected from fluorescent materials that have an FWHM<45 nm and a double-boron resonance structure. For example, in some preferred examples, the narrow-spectrum fluorescent material includes one or more of compounds having structures represented by Formula V-1, Formula V-2, and Formula V-3 below:

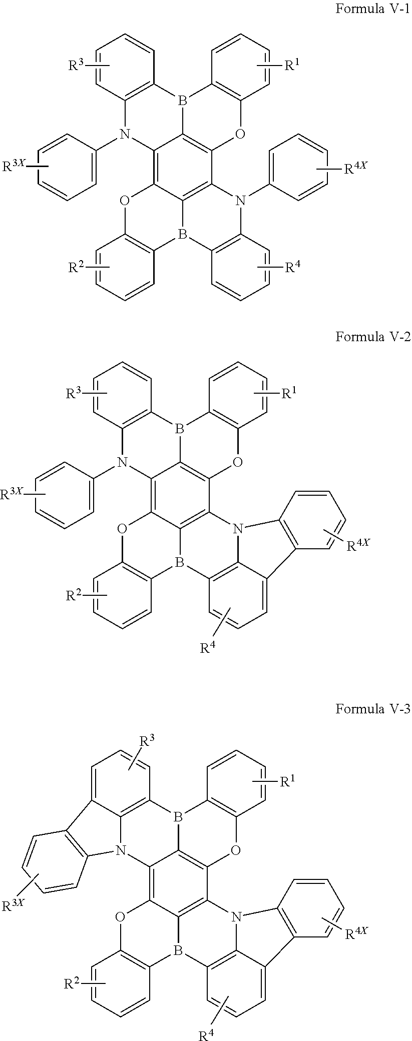

wherein R¹, R², R³, R⁴, R^{3X} and R^{4X}, each independently, represent one to the maximum permissible substituents, and R¹ and R² are each independently selected from any one of substituted or unsubstituted C1-C20 linear or branched alkyl, substituted or unsubstituted C3-C20 cycloalkyl, and substituted or unsubstituted C1-C20 alkylsilyl, and R³, R⁴, R^{3X} and R^{4X} are each independently selected from any one of substituted or unsubstituted C6-C60 aryl, and substituted or unsubstituted C3-C60 heteroaryl; or R¹ and R² are each independently selected from any one of substituted or unsubstituted C6-C60 aryl, and substituted or unsubstituted C3-C60 heteroaryl, and R³, R⁴, R^{3X} and R^{4X} are each independently selected from any one of substituted or unsubstituted C1-C20 linear or branched alkyl, substituted or unsubstituted C3-C20 cycloalkyl, and substituted or unsubstituted C1-C20 alkylsilyl.

Herein, when R¹, R², R³, R⁴, R^{3X} and R^{4X} carry a substituent (i.e., being the substituted groups mentioned above), the substituents thereof are each independently selected from at least one of halogen, C1-C20 linear or branched alkyl, C3-C20 cycloalkyl, nitro, cyano, amino, hydroxyl, C1-C20 alkylsilyl, C6-C60 aryl, or C3-C60 heteroaryl, further preferably any one or a combination of at least two of C1-C20 linear or branched alkyl, C3-C20 cycloalkyl, C1-C20 alkylsilyl, C6-C60 aryl, and C3-C60 heteroaryl; and R¹, R², R³, R⁴, R^{3X} and R^{4X} are each independently not linked to or linked to an adjacent benzene ring structure to form a ring via a chemical bond.

The compounds having structures represented by Formula V-1, Formula V-2, and Formula V-3 have a double-boron resonance structure. With the synergistic effect of the parent nucleus structure and a substituent, the compounds can achieve a high luminescence efficiency on the basis of triplet excitons and have good carrier transport efficiency. The compounds have an emission spectrum of red light, and the luminescence spectrum is narrow, with an FWHM<45 nm, which can effectively adjust and improve light color, thereby improving the light color, light purity, luminescence efficiency, service life and other performance of the device.

Specifically, in the molecular structure of the narrow-spectrum fluorescent material described above, part of the peripheral groups (R¹, R², R³, R⁴, R^{3X} and R^{4X}) are aromatic groups (i.e., the aryl or heteroaryl mentioned above), and part of the peripheral groups are non-aromatic groups (i.e., the linear or branched alkyl, cycloalkyl, and alkylsilyl mentioned above), such that the molecular structure is asymmetric, which enables the adjustment of light color, allowing the light color of the compounds to reach 620 nm or more. Furthermore, the introduction of the peripheral groups results in a higher carrier mobility, which favors voltage reduction, forms a more effective protection for the parent nucleus, and inhibits the annihilation of excitons, thereby improving efficiency and service life.

In the present application, unless otherwise stated, the expression related to chemical elements includes the concept of isotopes with the same chemical properties. For example, hydrogen (H) includes ¹H (protium), ²H (deuterium, D), ³H (tritium, T), and the like, and carbon (C) includes ¹²C, ¹³C, and the like.

In the present application, unless otherwise specified, the heteroatom of heteroaryl is an atom or atomic group selected from the group consisting of N, O, S, P, B, Si, and Se, preferably N, O, and S.

In the present application, the halogens may be fluorine, chlorine, bromine or iodine.

In the present application, the illustration where the “—” crosses a ring structure denotes that the linkage site of the ring structure with a substituent is any position on the ring structure where a bond may form. Specifically, the “substituted or unsubstituted” groups mentioned above may be substituted with one or a plurality of substituents. When there is a plurality of (at least 2) substituents, the substituents may be identical or different.

For example, the number of R¹, R², R³, R⁴, R^{3X} and R^{4X} may be 1, 2, 3, 4, etc. When there is a plurality of (≥2) R¹, R², R³, R⁴, R^{3X} and R^{4X}, the plurality of (≥2) substituents are the same or different groups.

In the present application, the expression Ca-Cb denotes that the number of carbon atoms in the group is a-b, and this number of carbon atoms does not include the number of carbon atoms in the substituent unless otherwise stated. As an example, C1-C20 mentioned above may be, for example, C1, C2, C3, C4, C5, C6, C7, C8, C9, C10, C11, C12, C13, C14, C15, C16, C17, C18, or C20; C3-C20 may be, for example, C3, C4, C5, C6, C7, C8, C9, C10, C11, C12, C13, C14, C15, C16, C17, C18, C19, or C20; C3-C60 may be, for example, C3, C4, C5, C6, C9, C10, C12, C14, C16, C18, C20, C22, C24, C26, C28, C30, C32, C34, C36, C38, C40, C42, C44, C46, C48, C50, C52, C54, C56, or C58; and C6-C60 may be, for example, C6, C9, C10, C12, C14, C16, C18, C20, C22, C24, C26, C28, C30, C32, C34, C36, C38, C40, C42, C44, C46, C48, C50, C52, C54, C56, or C58.

For example, the C1-C20 linear or branched alkyl is selected from, but is not limited to, methyl, ethyl, n-propyl, isopropyl, n-butyl, isobutyl, tert-butyl, 2-methylbutyl, n-pentyl, isopentyl, neopentyl, n-hexyl, neohexyl, 2-ethylhexyl, n-octyl, n-heptyl, n-nonyl, and n-decyl.

In some specific examples, the substituted or unsubstituted C1-C20 linear or branched alkyl is selected from one of the following groups: methyl, ethyl, n-propyl,

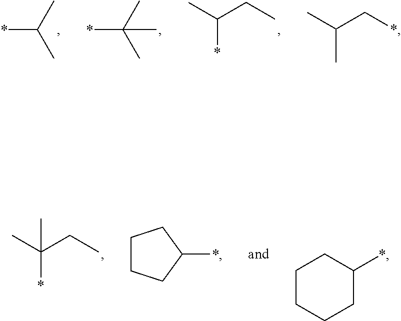

where * represents the linkage site of a group.

Specifically, the C3-C20 cycloalkyl may include monocycloalkyl or polycycloalkyl, wherein the monocycloalkyl refers to an alkyl group containing a single cyclic structure, and the polycycloalkyl refers to a structure formed by two or more cycloalkyl groups sharing one or more carbon atoms on the rings. As an example, the C3-C20 cycloalkyl is selected from, but is not limited to, cyclopropyl, cyclobutyl, cyclopentyl, cyclohexyl, adamantyl, etc.

Specifically, the C6-C60 aryl includes monocyclic aryl and polycyclic aryl, wherein the monocyclic aryl refers to a single phenyl group or a biphenyl group (i.e. the group contains at least one phenyl group, and when at least two phenyl groups are contained, the phenyl groups are linked via single bonds), including, for example, phenyl, biphenyl, and terphenyl; and the polycyclic aryl refers to a group containing at least two aromatic rings which are fused together via two adjacent carbon atoms in common, including, for example, naphthyl, anthryl, phenanthryl, indenyl, fluorenyl and derivatives thereof (9,9-dimethylfluorenyl, 9,9-diethylfluorenyl, 9,9-dipropylfluorenyl, 9,9-dibutylfluorenyl, 9,9-dipentylfluorenyl, 9,9-dihexylfluorenyl, 9,9-diphenylfluorenyl, 9,9-dinaphthylfluorenyl, spirobifluorenyl, benzofluorenyl, etc.), fluoranthryl, triphenylylene, pyrenyl, perylenyl, chrysenyl, or tetracenyl.

In some specific examples, the substituted or unsubstituted C6-C60 aryl is selected from one of the following groups:

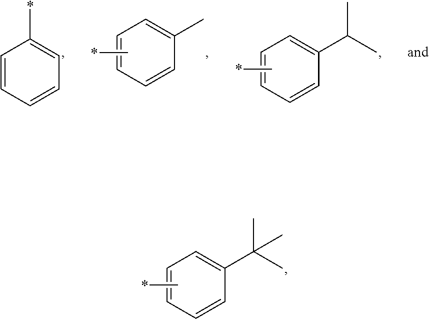

where * represents the linkage site of a group.

Specifically, C3-C60 heteroaryl includes monocyclic heteroaryl or polycyclic heteroaryl. The monocyclic heteroaryl refers to a single heteroaryl group (aromatic heterocycle) or a biaryl group formed by a single heteroaryl group linked to another aromatic group (aryl or heteroaryl) via a single bond, that is, the monocyclic heteroaryl contains at least one heteroaryl group, and when a molecule contains one heteroaryl group and an additional aromatic group, the heteroaryl group is linked to the additional aromatic group via a single bond. The monocyclic heteroaryl includes, for example, pyridinyl, pyrimidinyl, pyrazinyl, pyridazinyl, triazinyl, furanyl, thienyl, and pyrrolyl. The polycyclic heteroaryl refers to a molecule containing at least one heteroaryl group and at least one aromatic group (heteroaryl or aryl), which are fused together via two adjacent atoms in common, including, for example, quinolinyl, isoquinolinyl, quinoxalinyl, quinazolinyl, benzofuranyl, benzothienyl, isobenzofuranyl, isobenzothienyl, indolyl, dibenzofuranyl, dibenzothienyl, carbazolyl and derivatives thereof (N-phenylcarbazolyl, N-naphthylcarbazolyl, benzocarbazolyl, dibenzocarbazolyl, indolocarbazolyl, azacarbazolyl, etc.), acridinyl, phenothiazinyl, phenoxazinyl, and hydroacridinyl.

In the present application, “each independently” denotes that when there is a plurality of subjects, the subjects may be the same or different from each other.

Generally, R¹ and R² may be the same group, and R³ and R⁴ are the same group, and further preferably, R³, R⁴, R^{3X} and R^{4X} are the same group.

In addition, R¹ and R² may each independently be linked to the para or meta position of a carbon atom linked to an O atom, and preferably, R¹ and R² are each independently linked to a meta position of a carbon atom linked to an O atom, such that the performance such as efficiency and service life of the device can be further improved.

In addition, R³ and R⁴ may be linked to the para position of a carbon atom linked to a N atom.

In some specific examples, the narrow-spectrum fluorescent material includes, but is not limited to, one or more of the following compounds A 1-A 268:

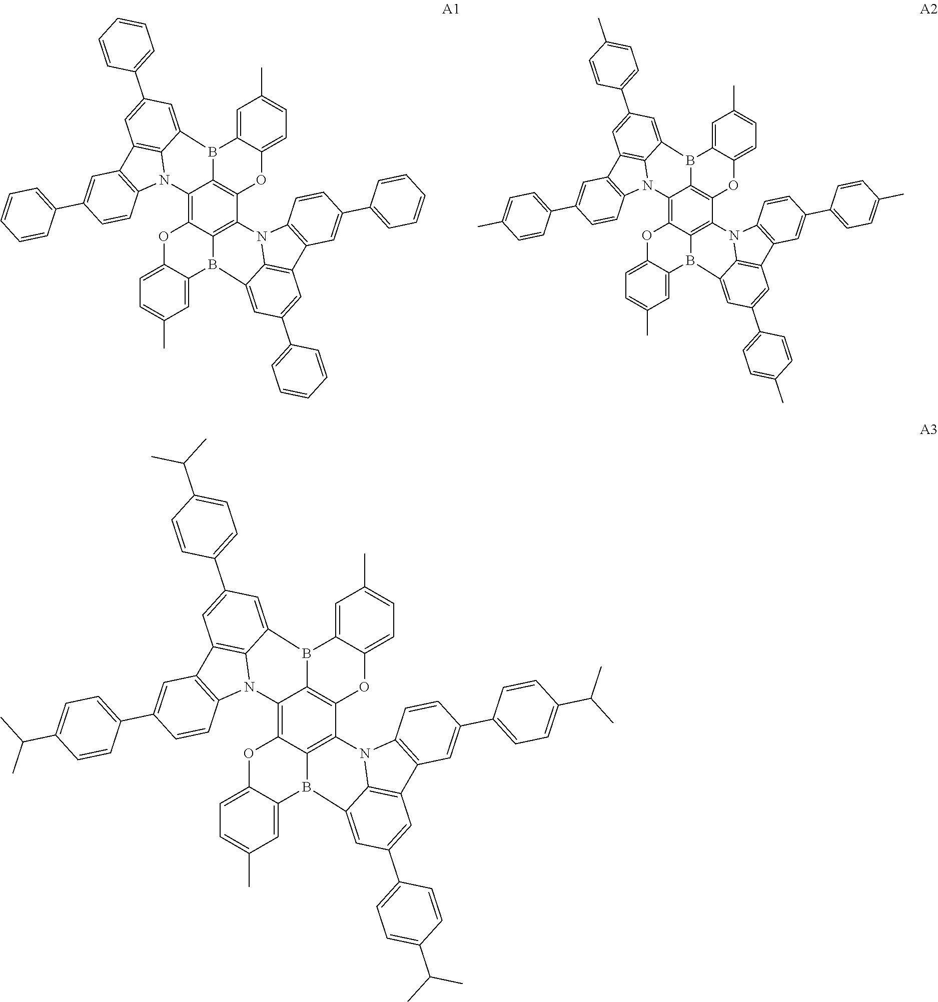

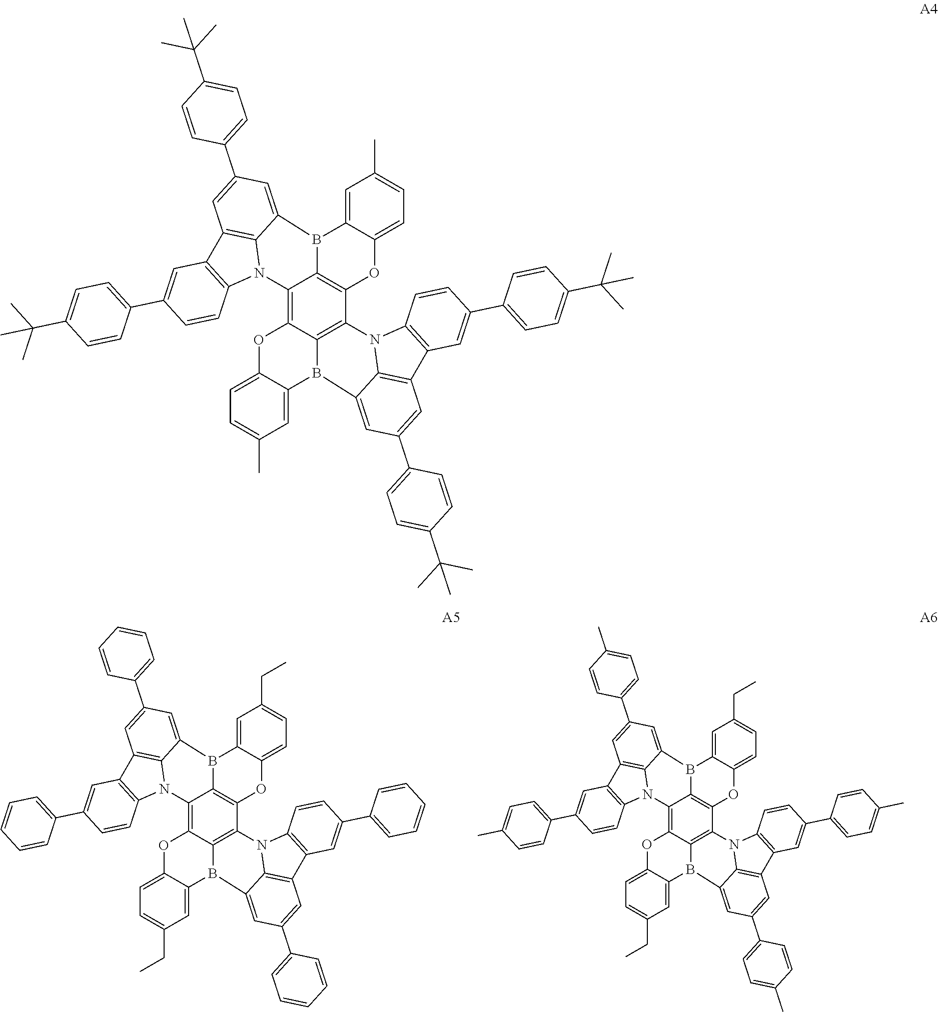

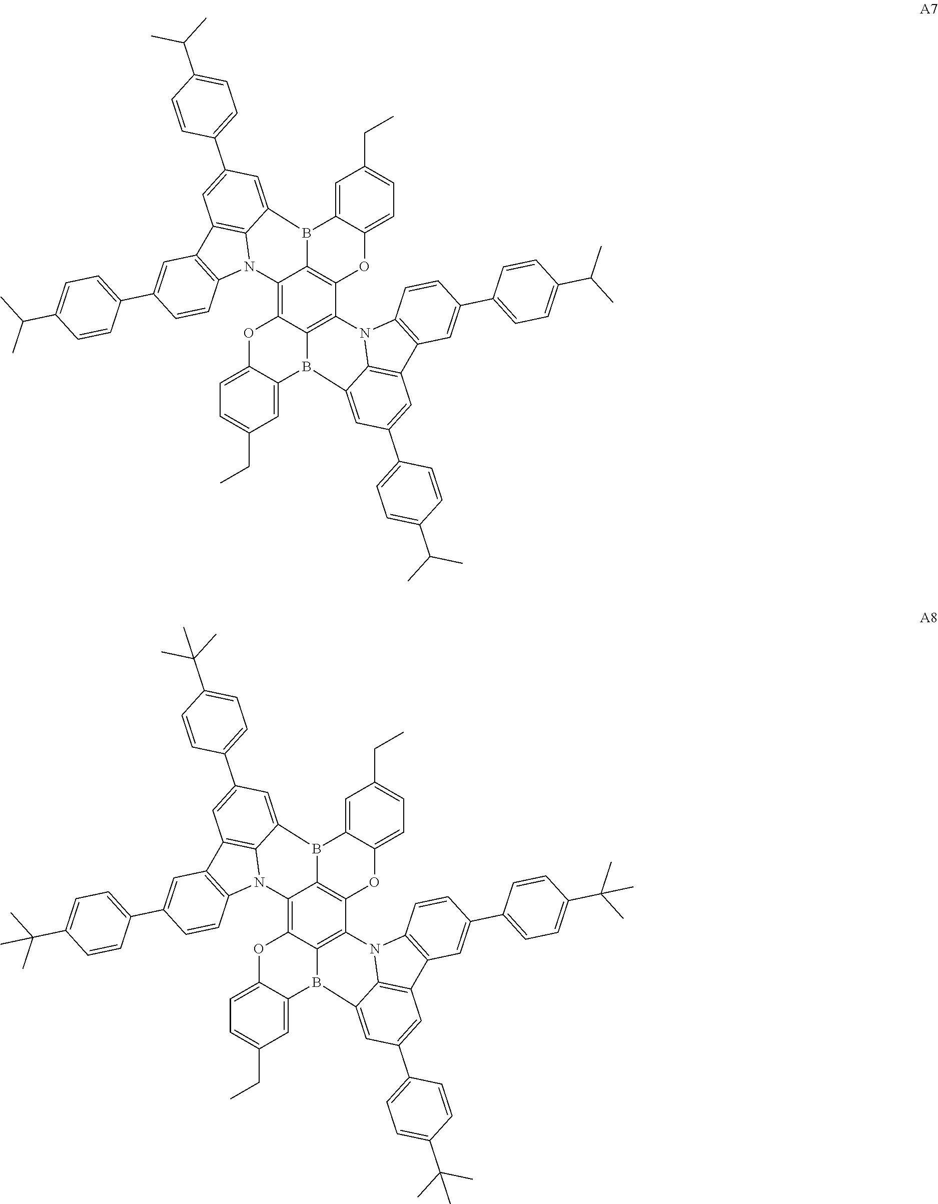

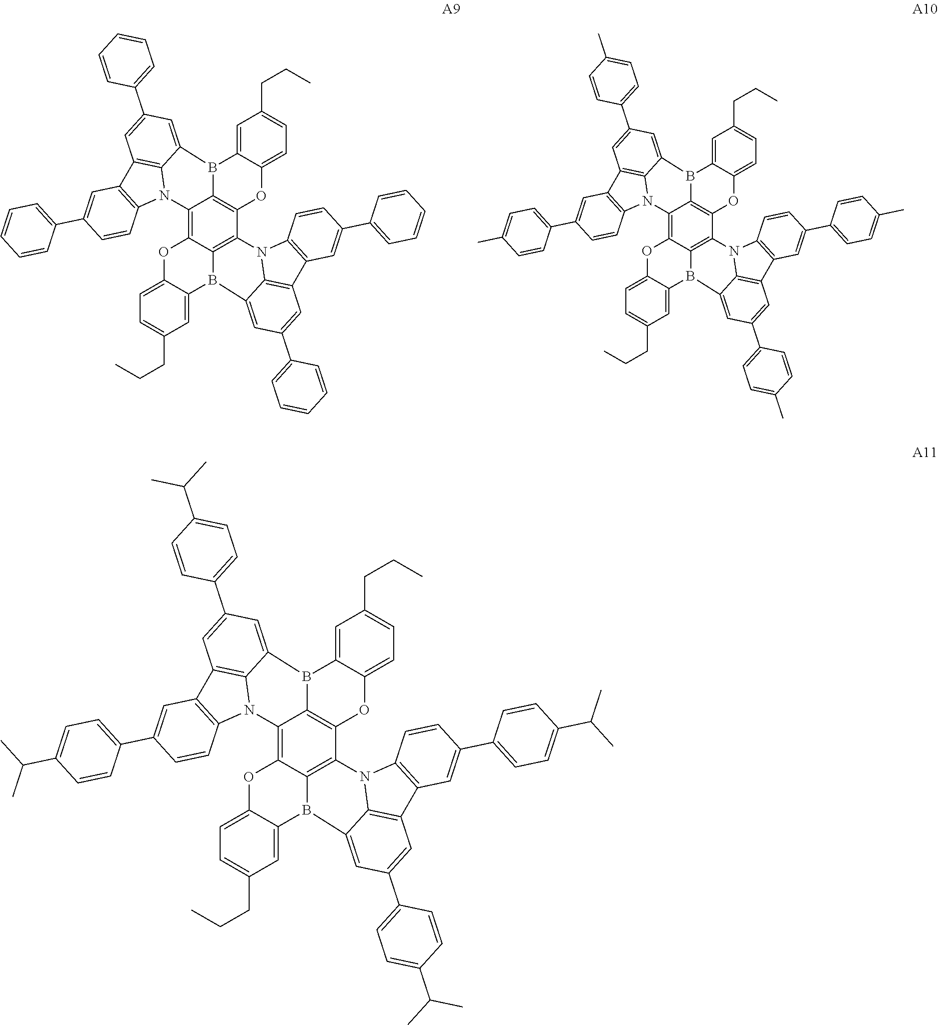

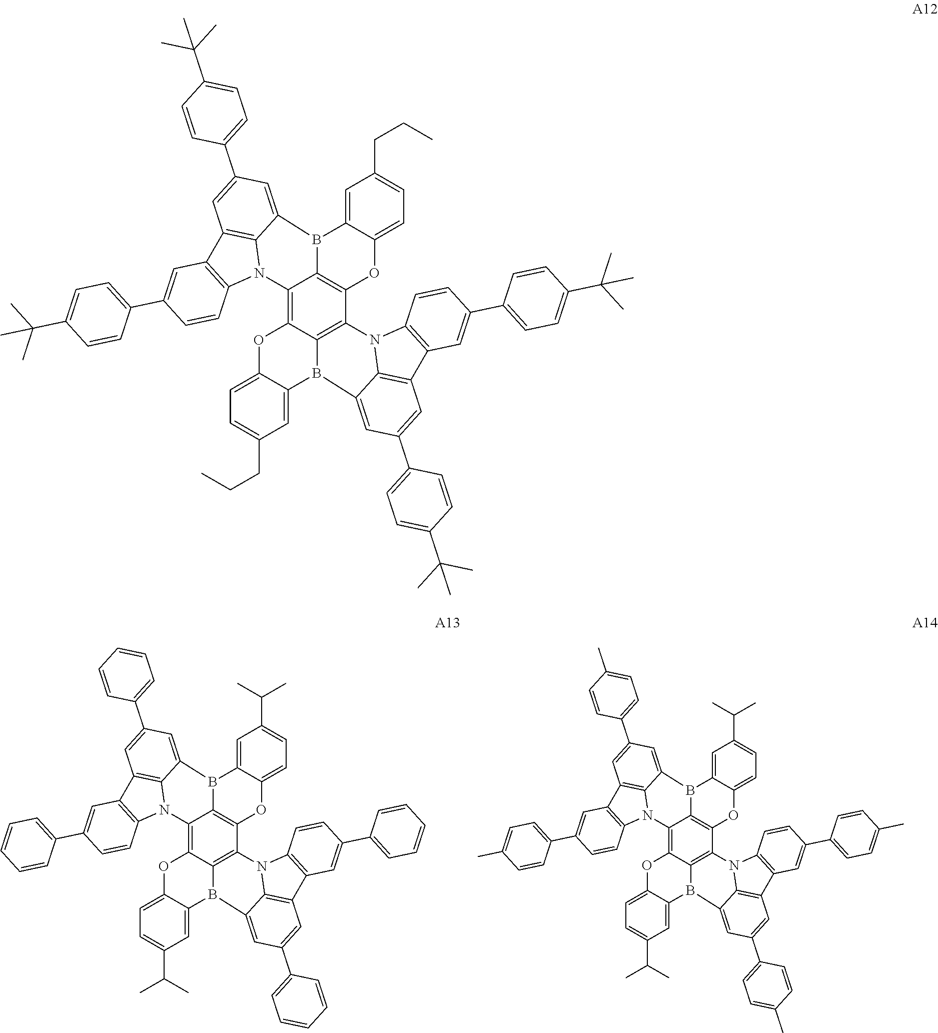

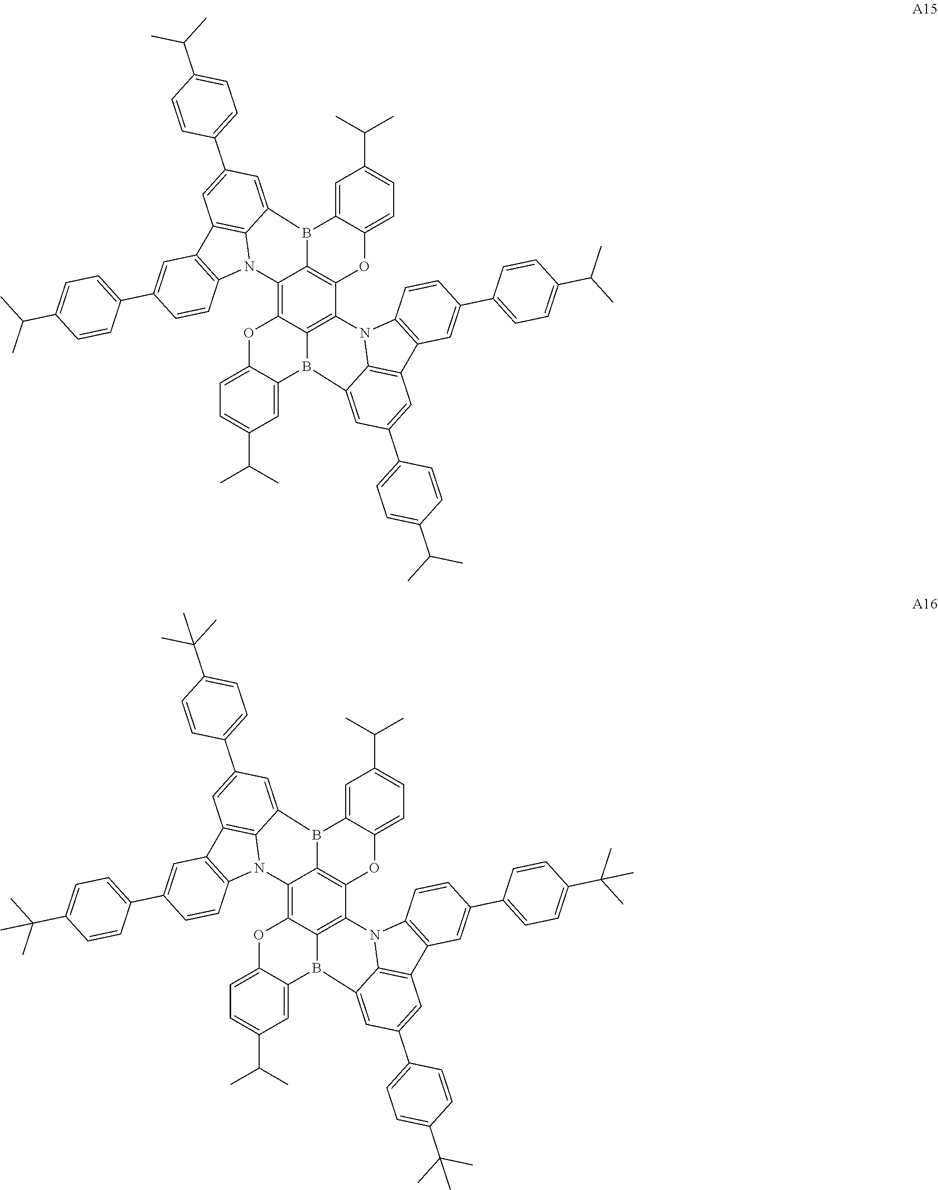

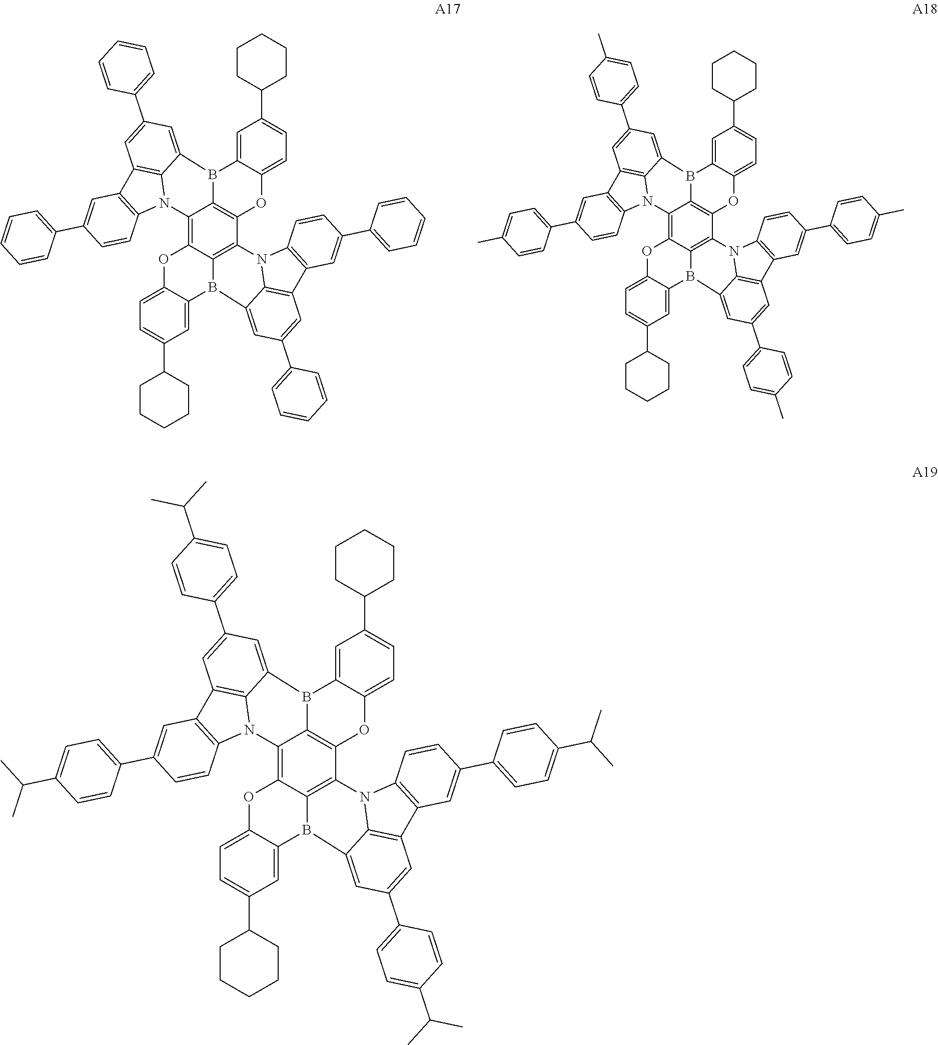

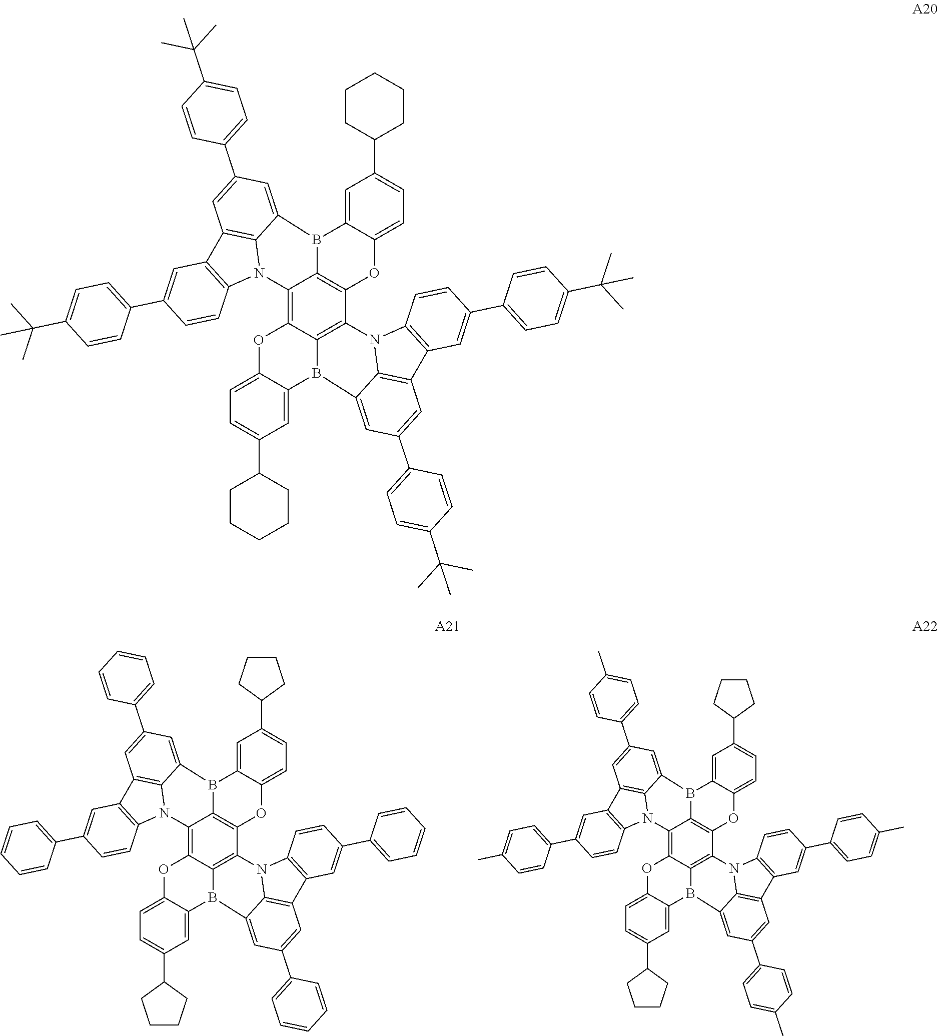

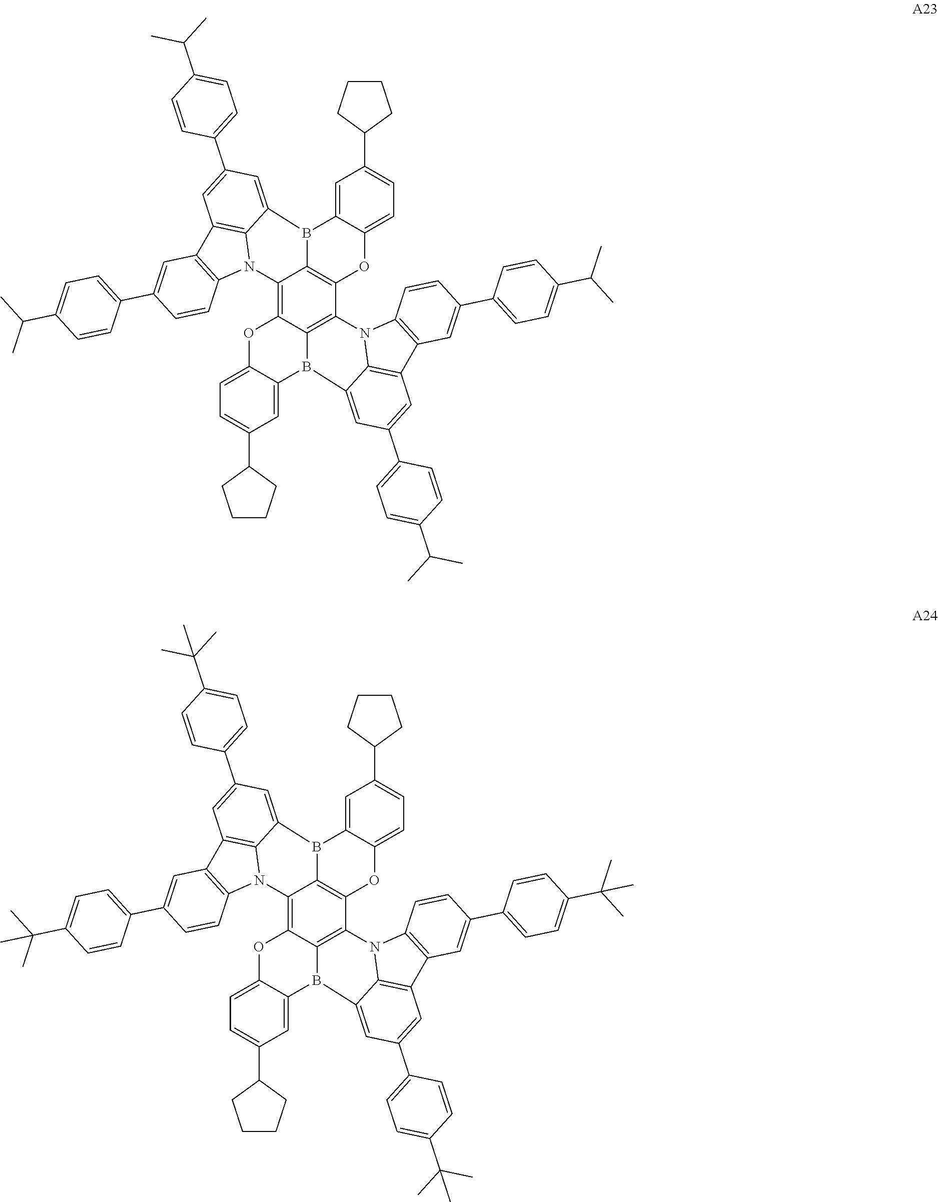

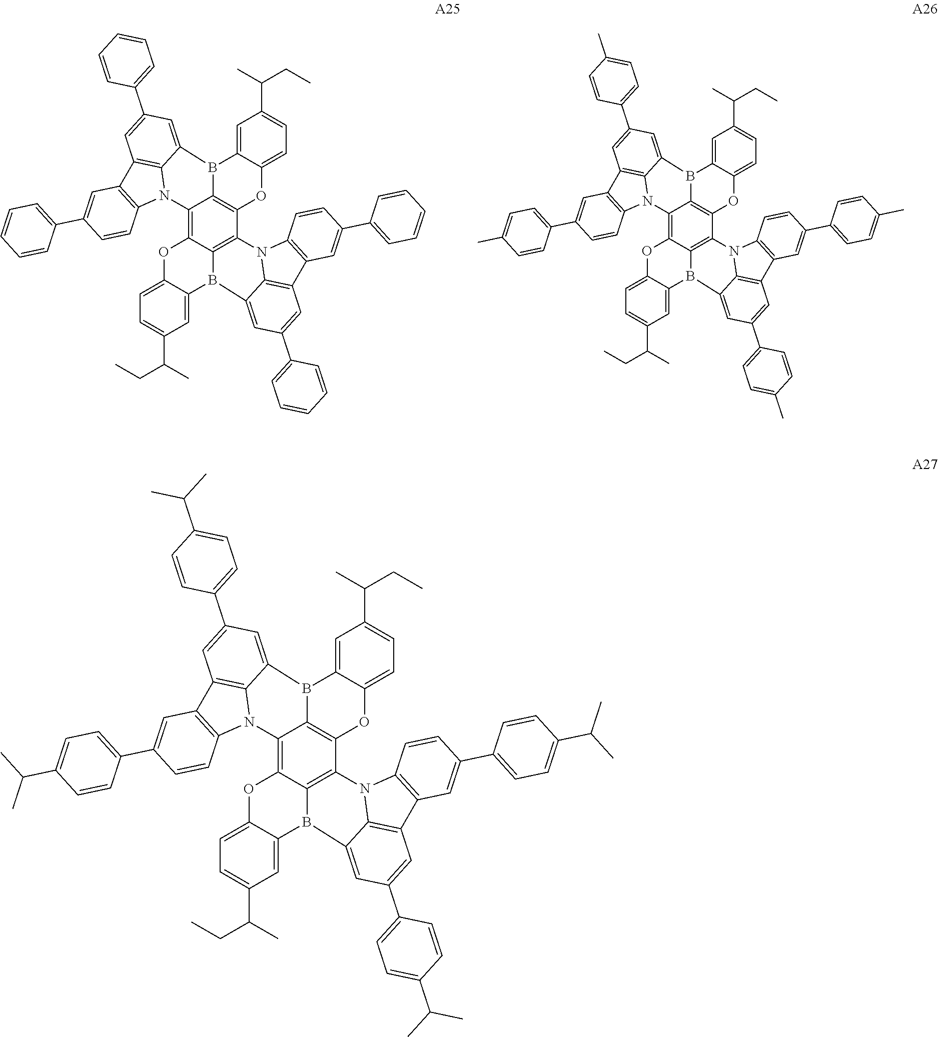

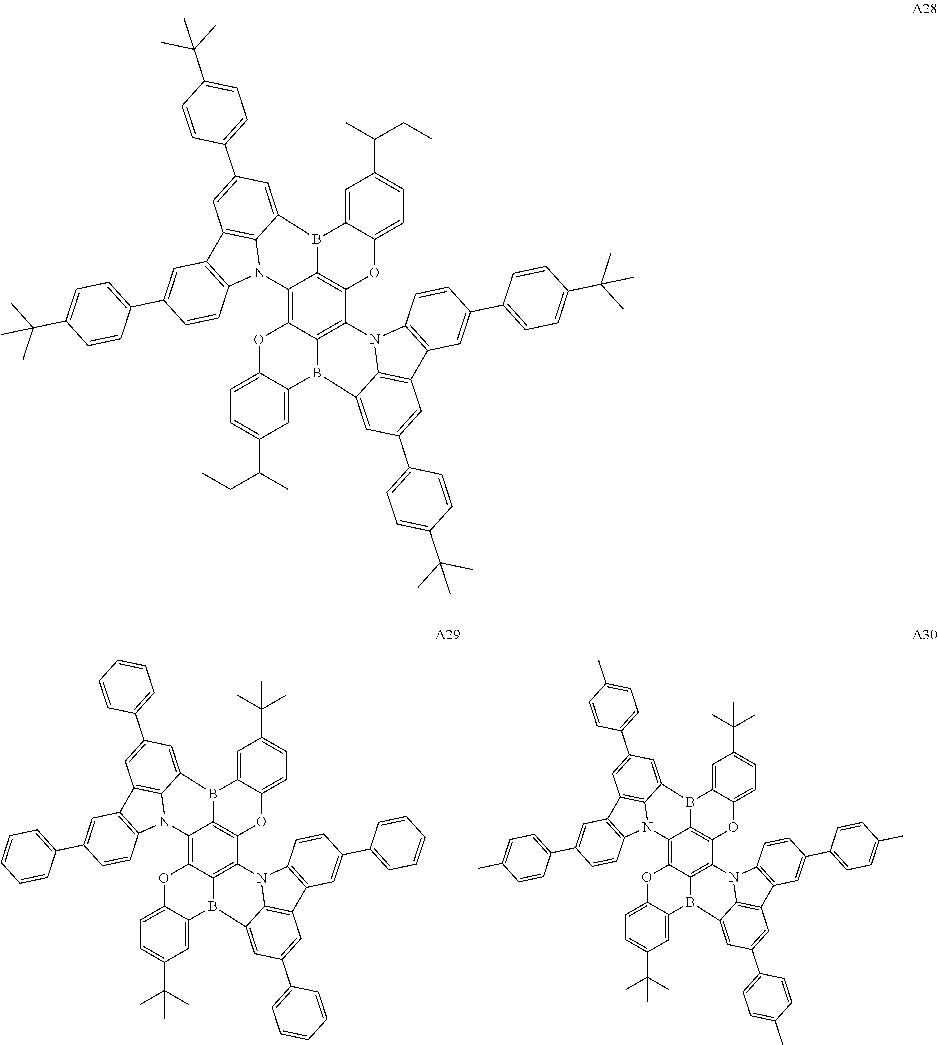

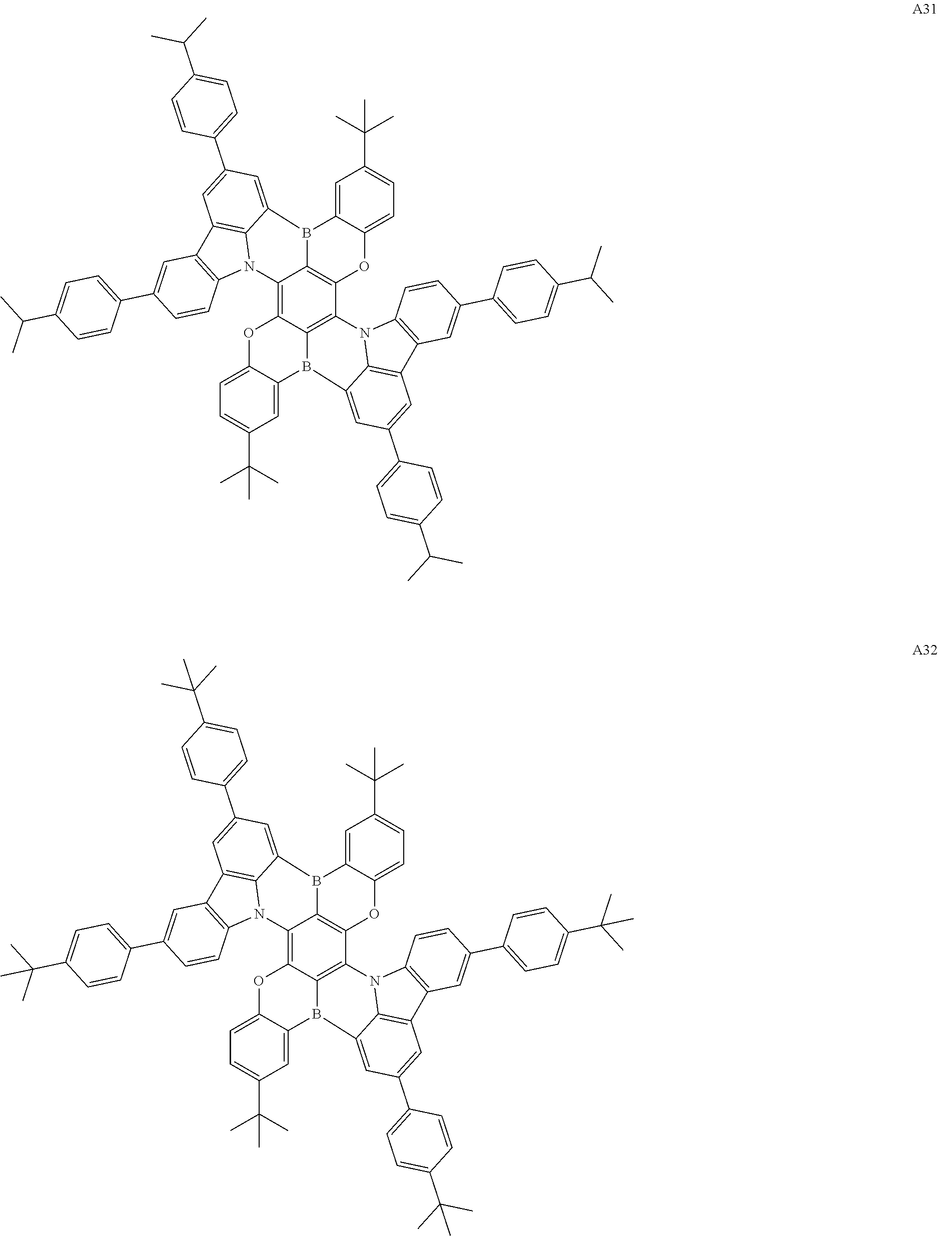

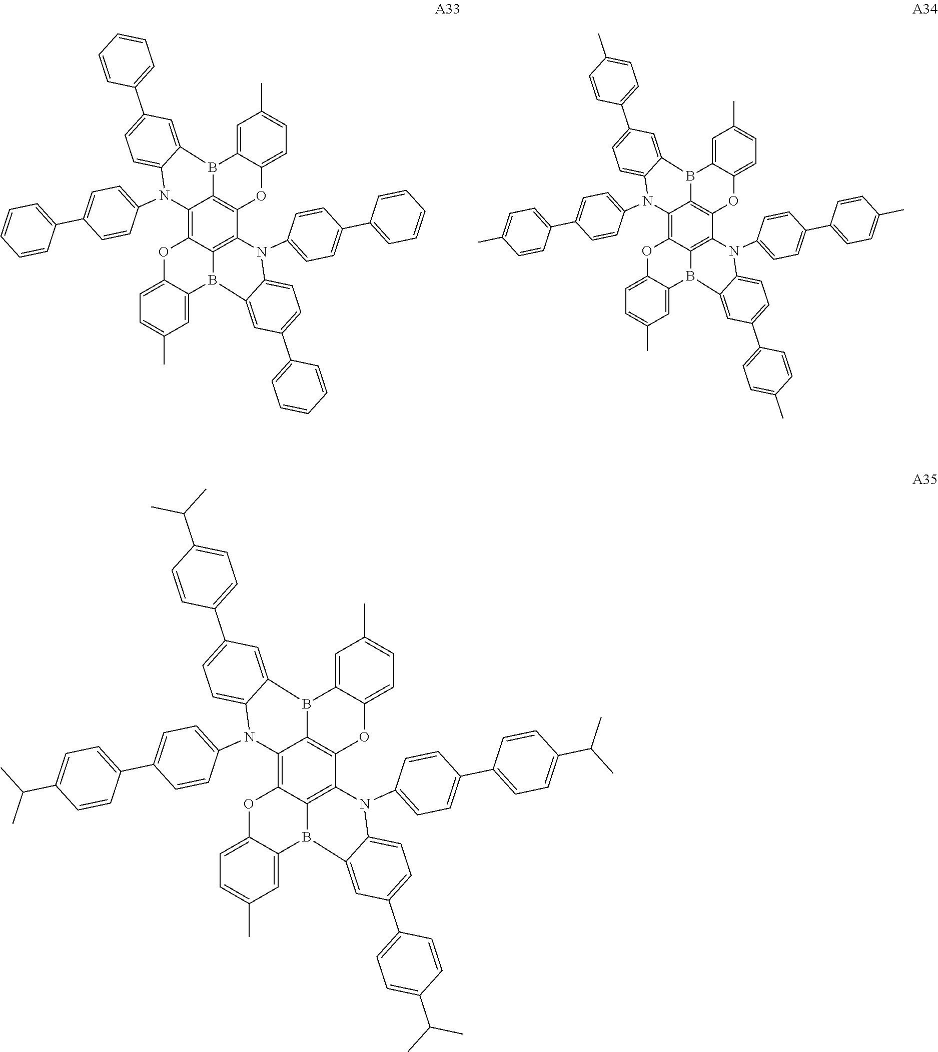

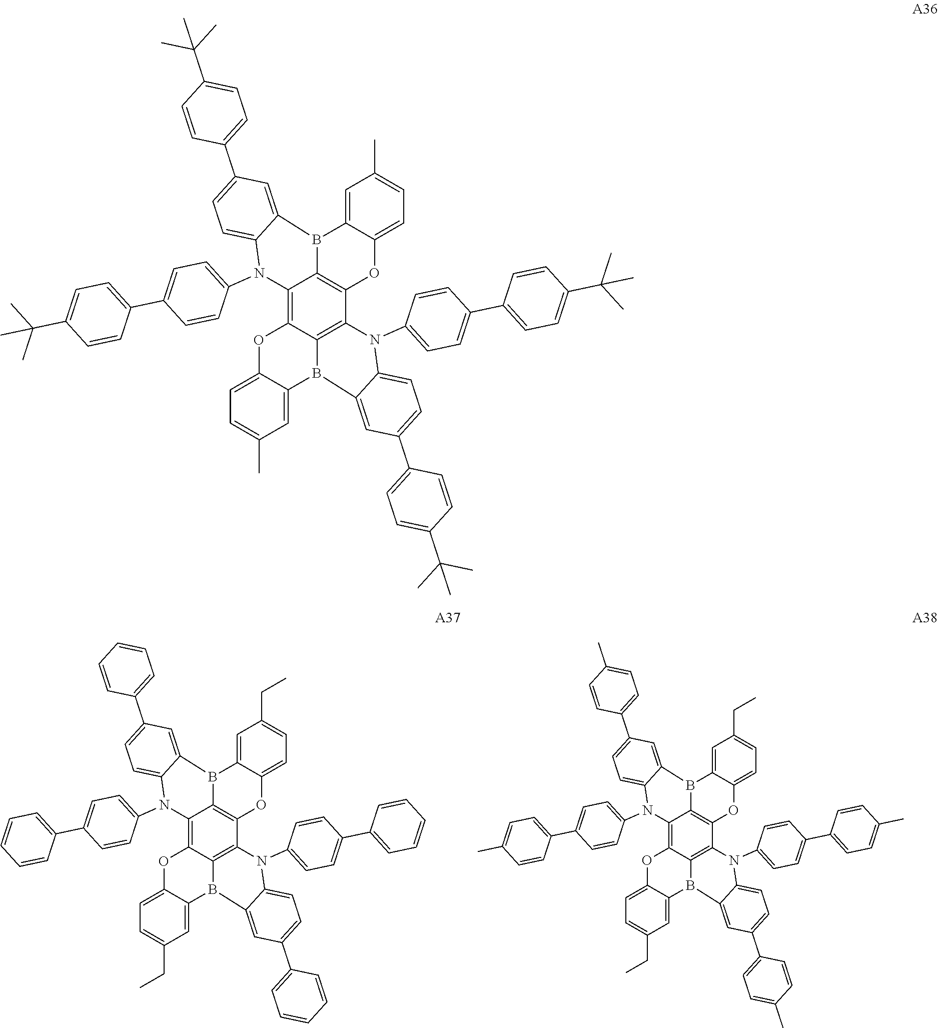

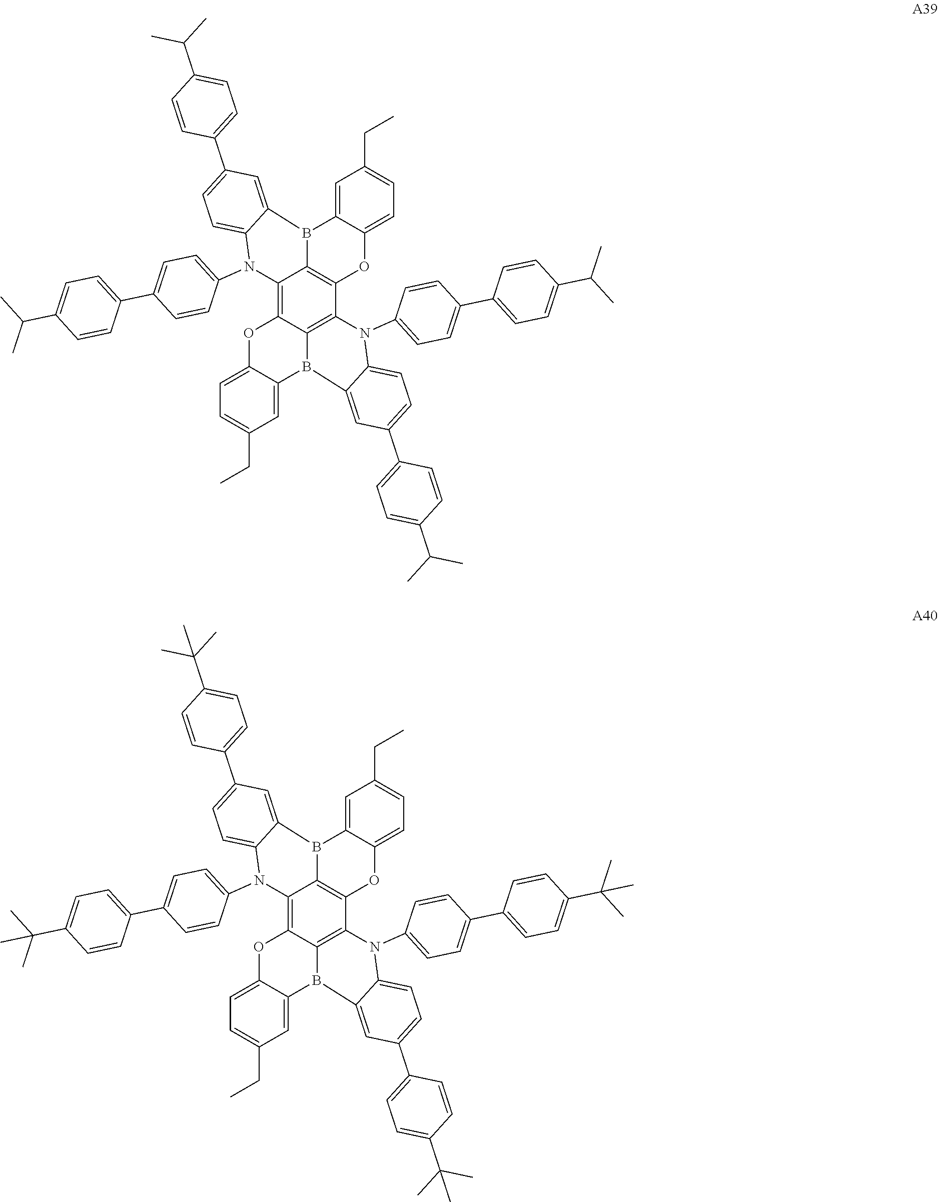

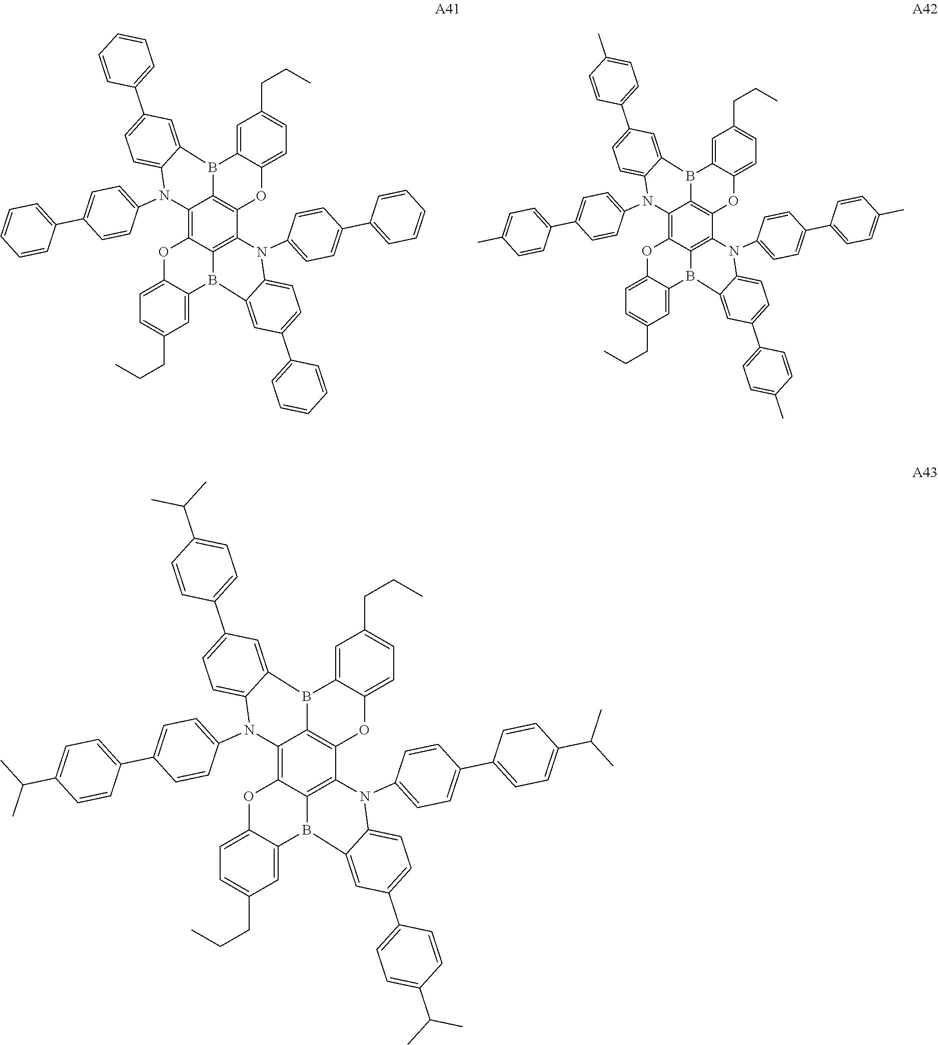

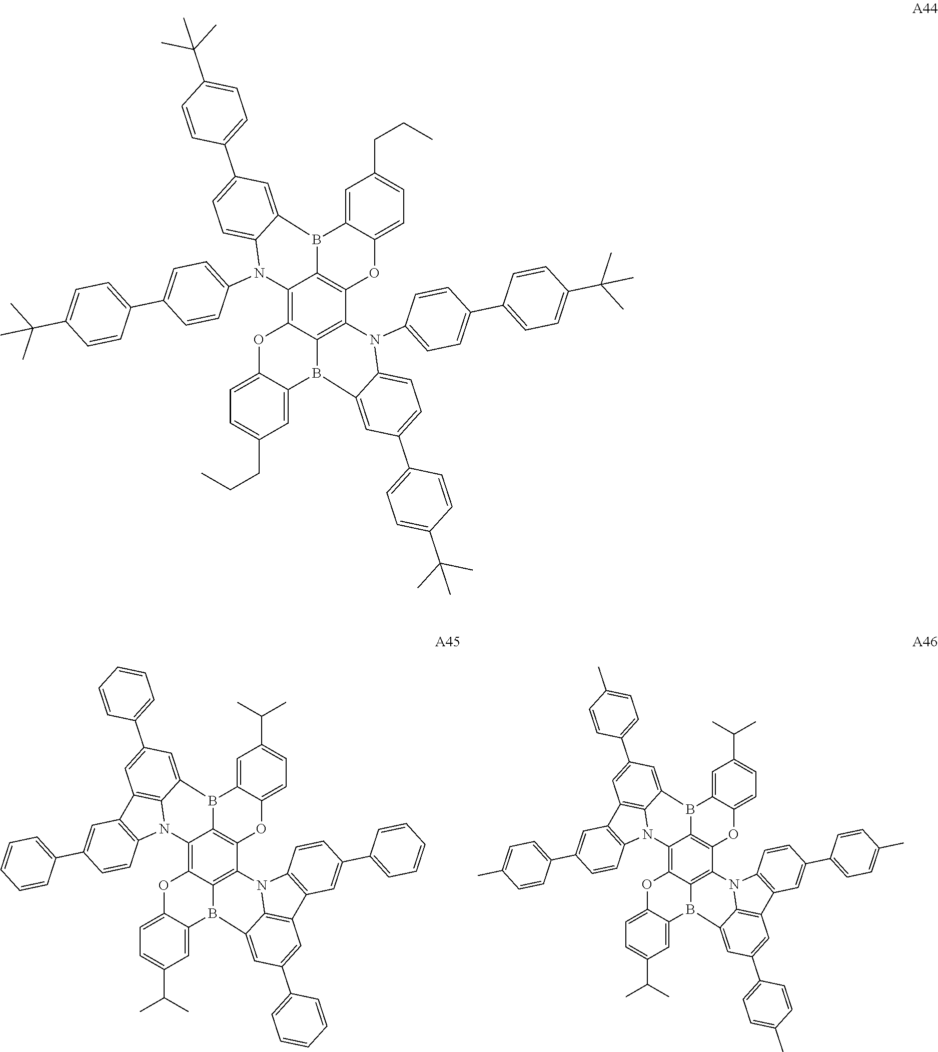

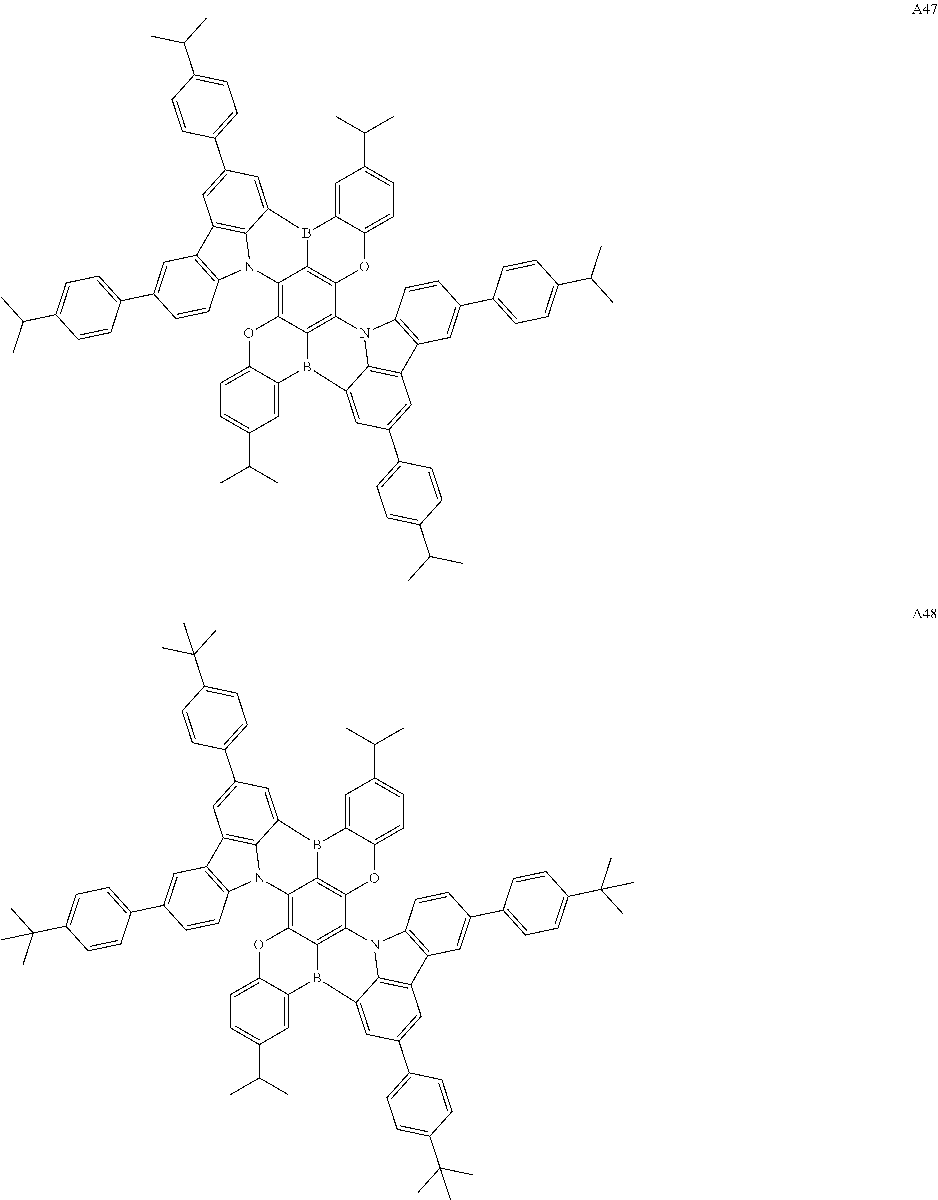

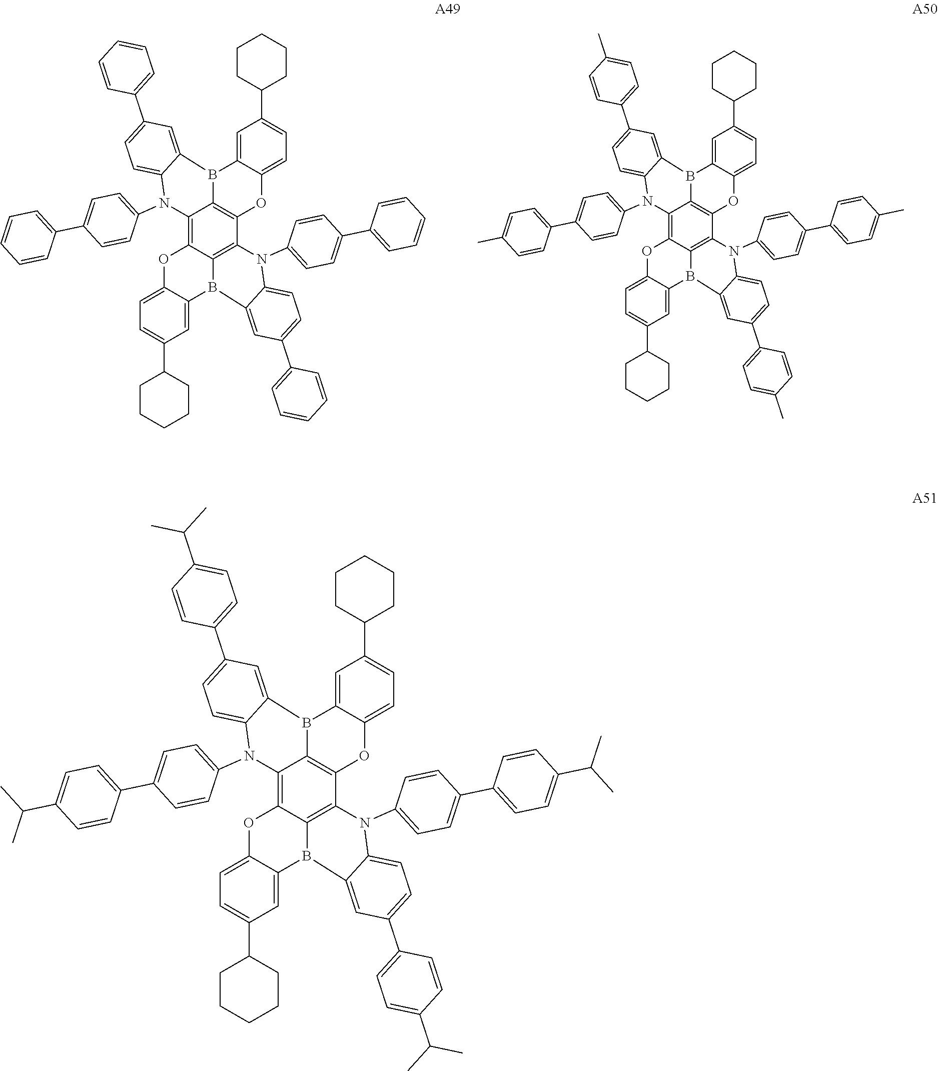

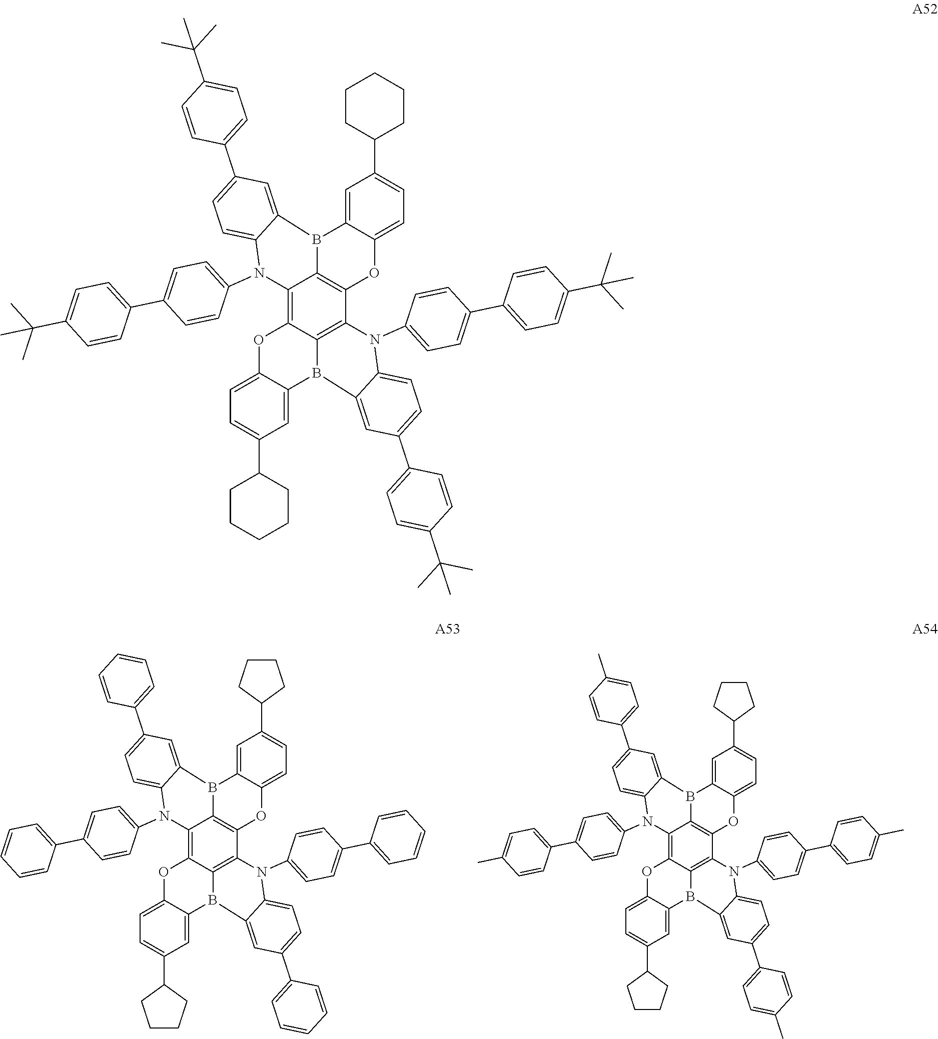

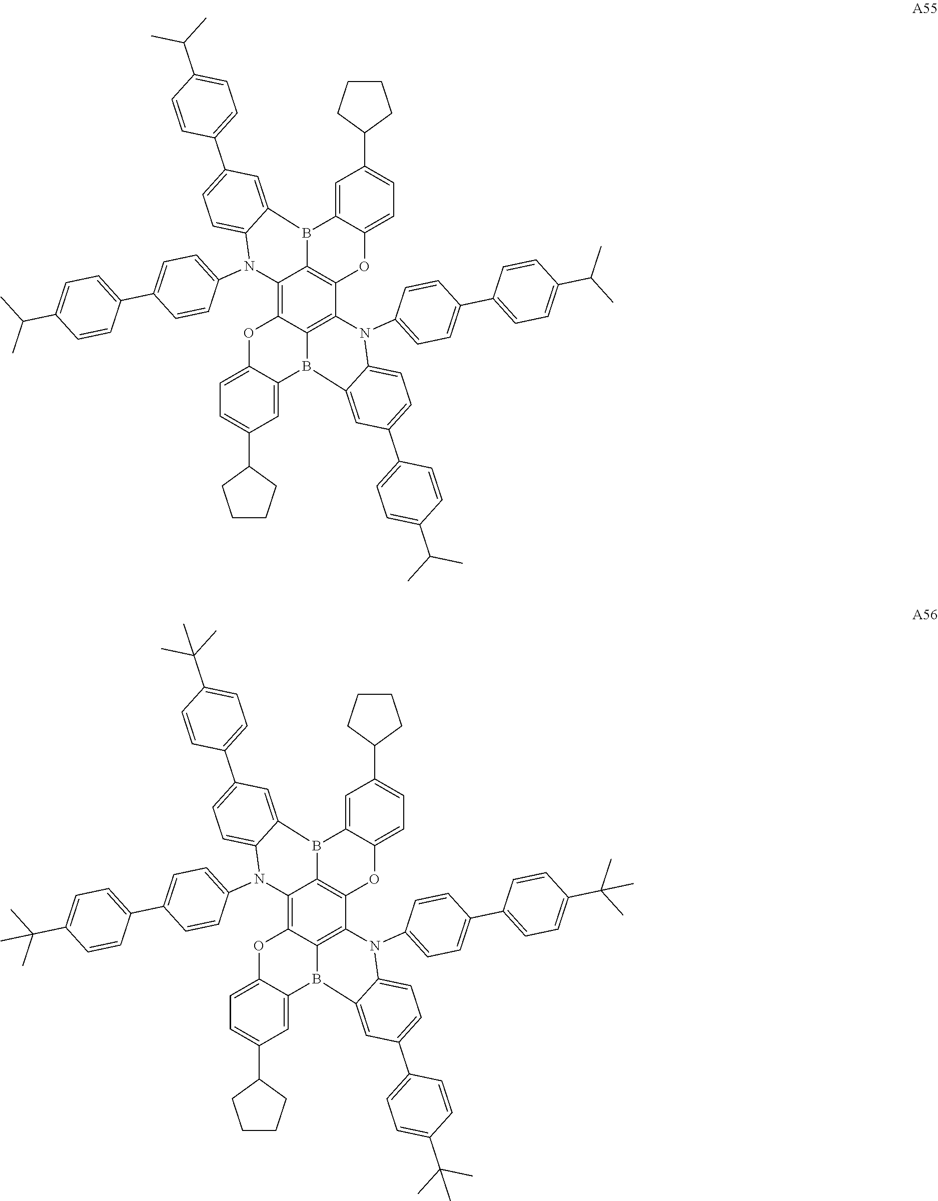

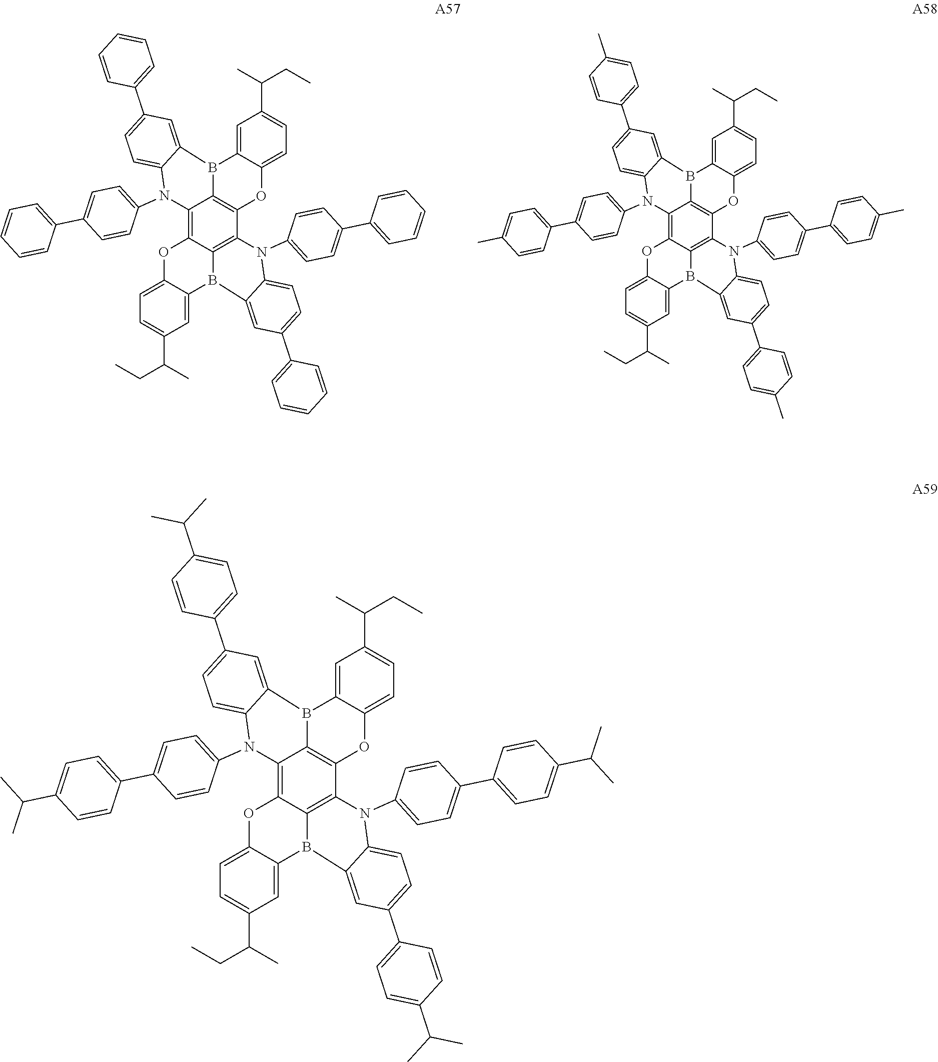

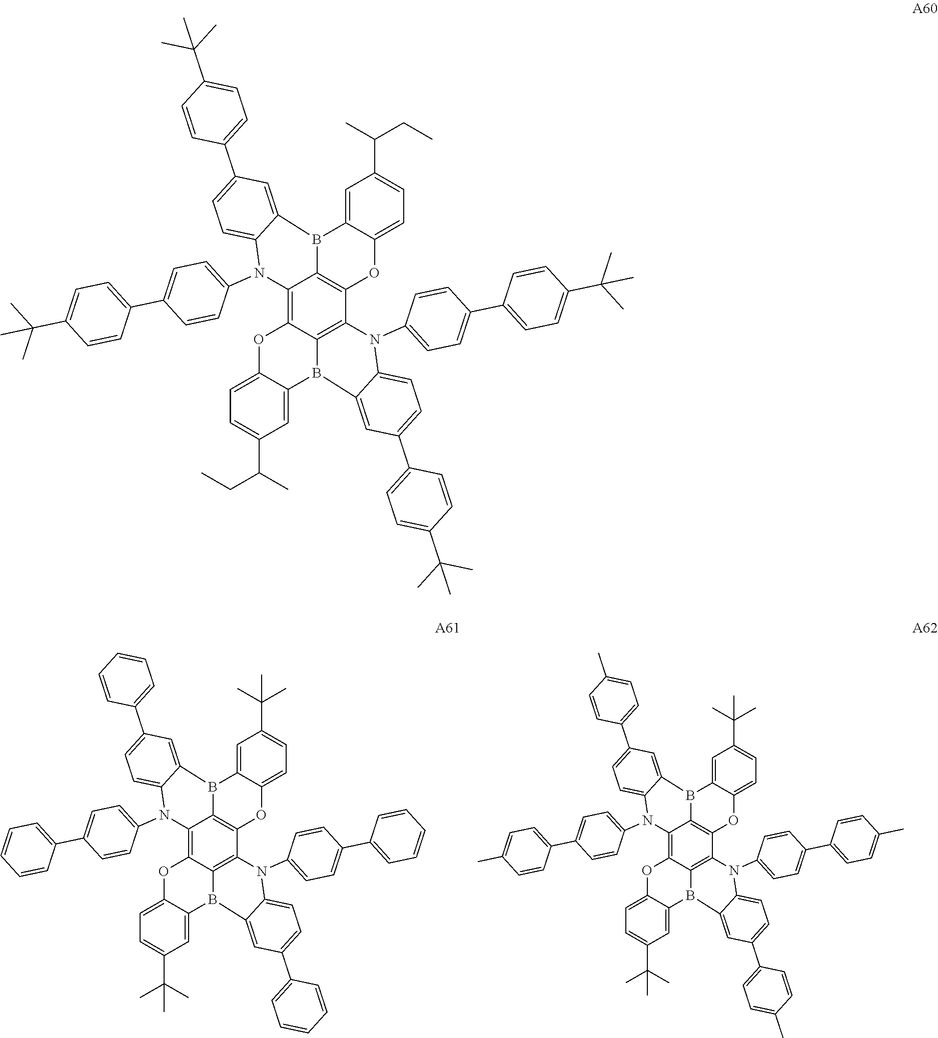

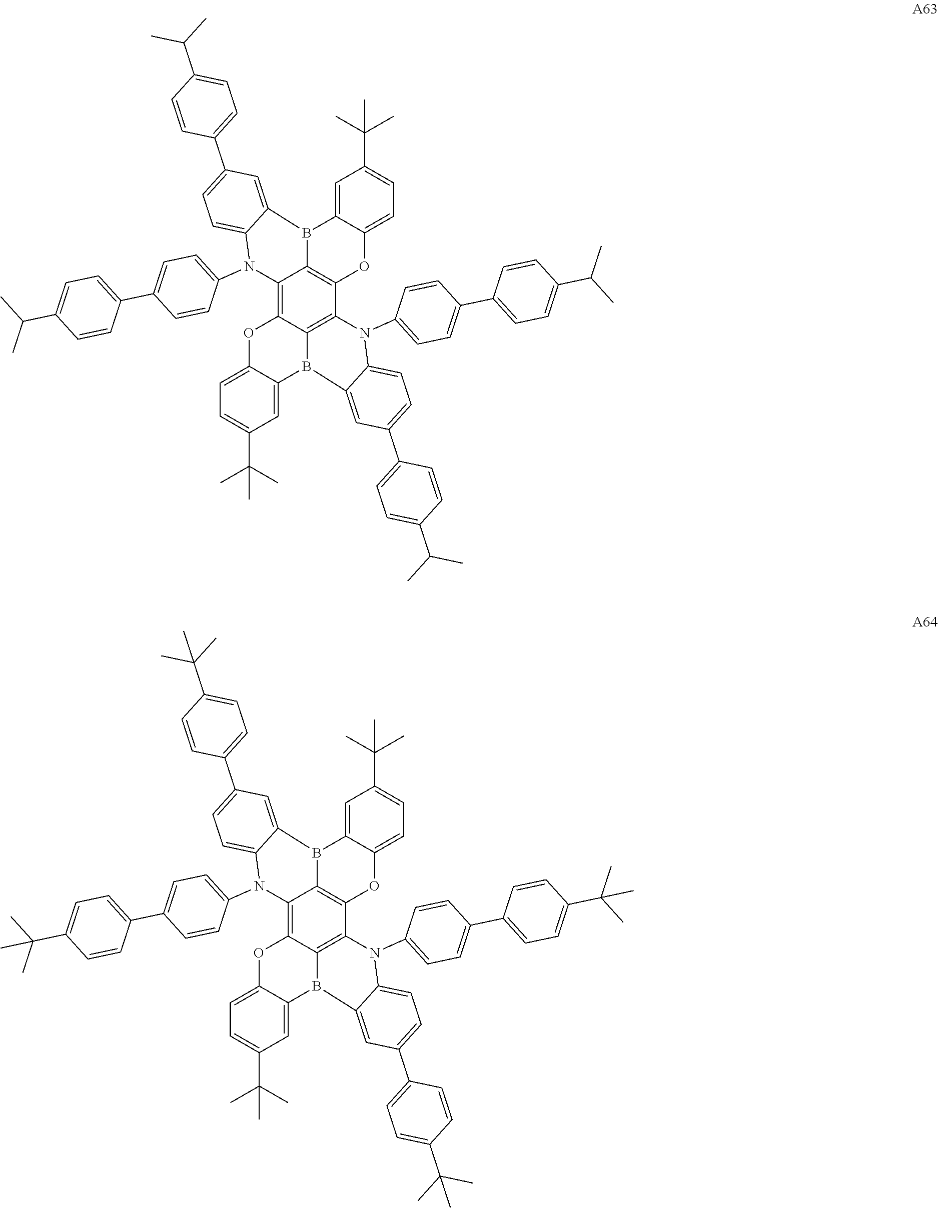

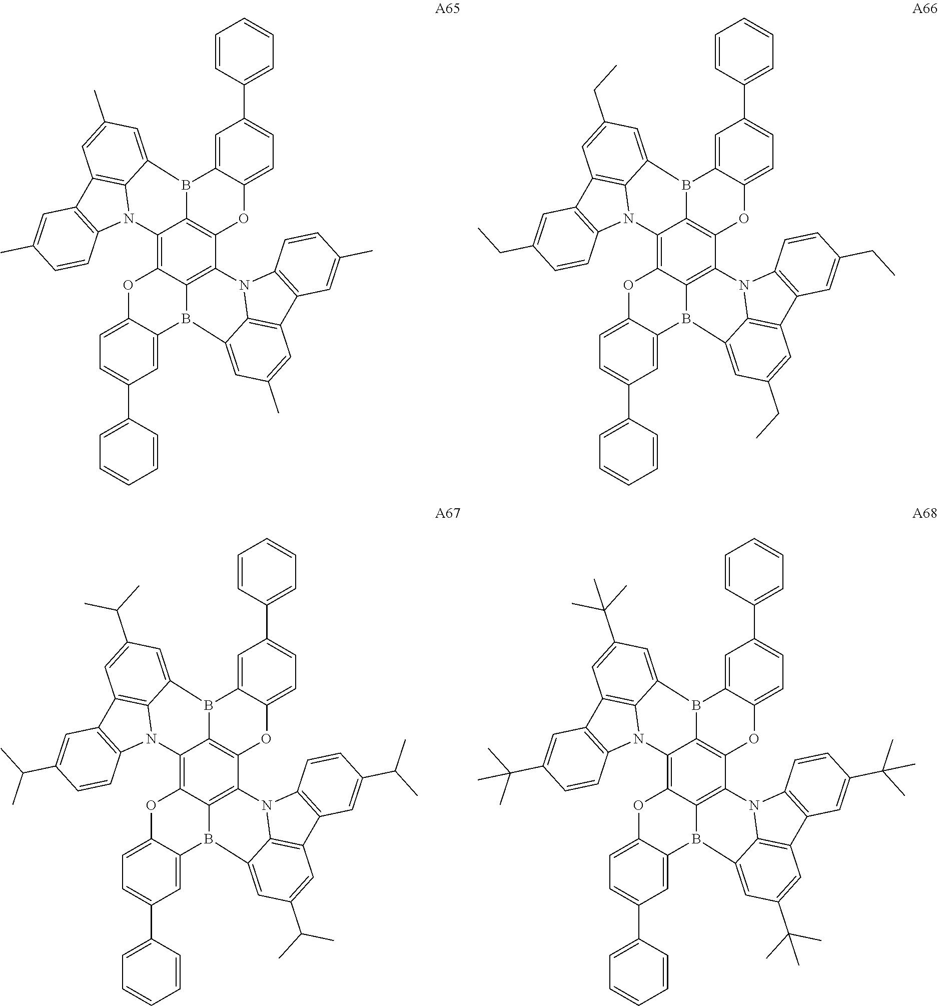

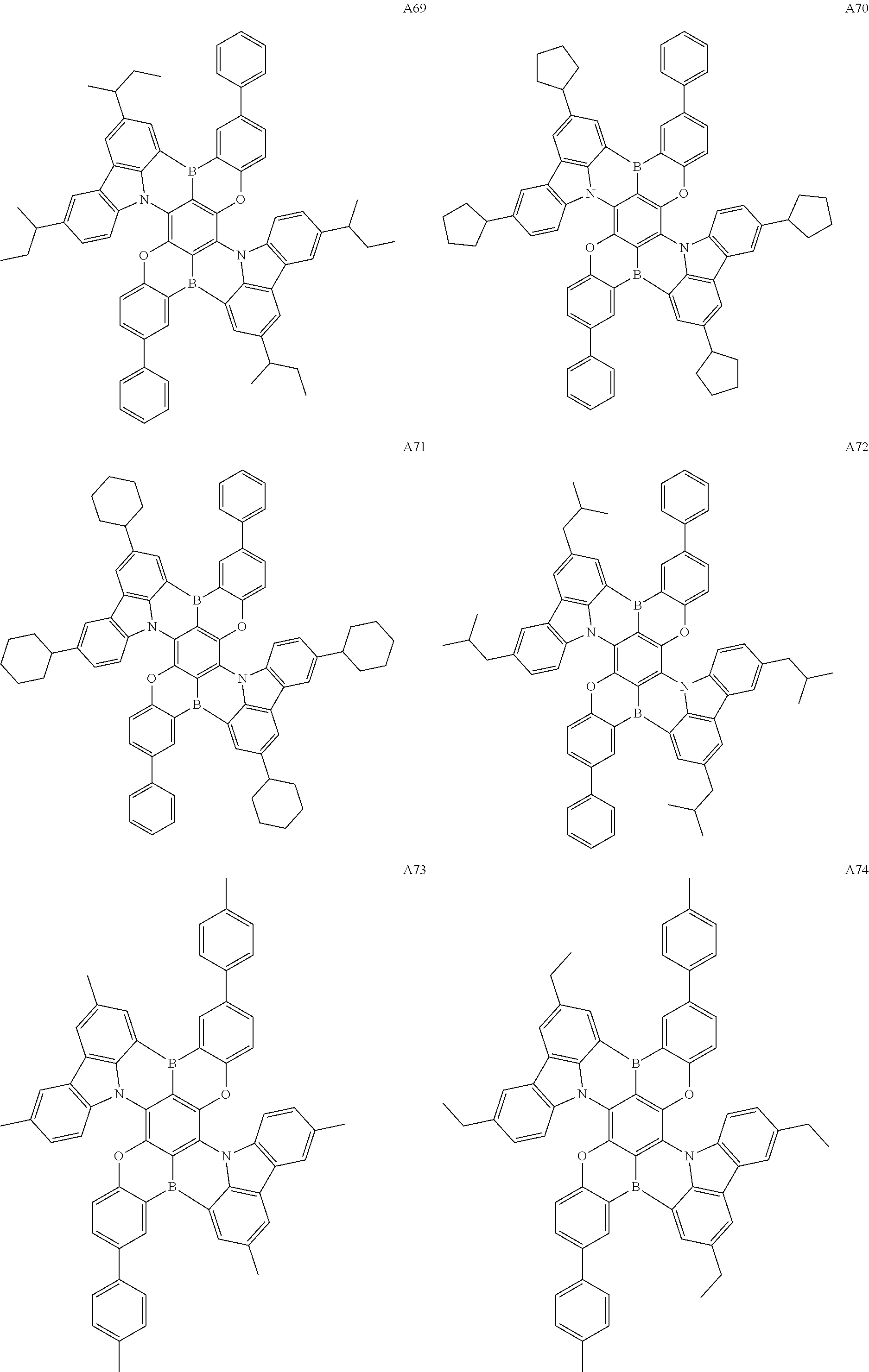

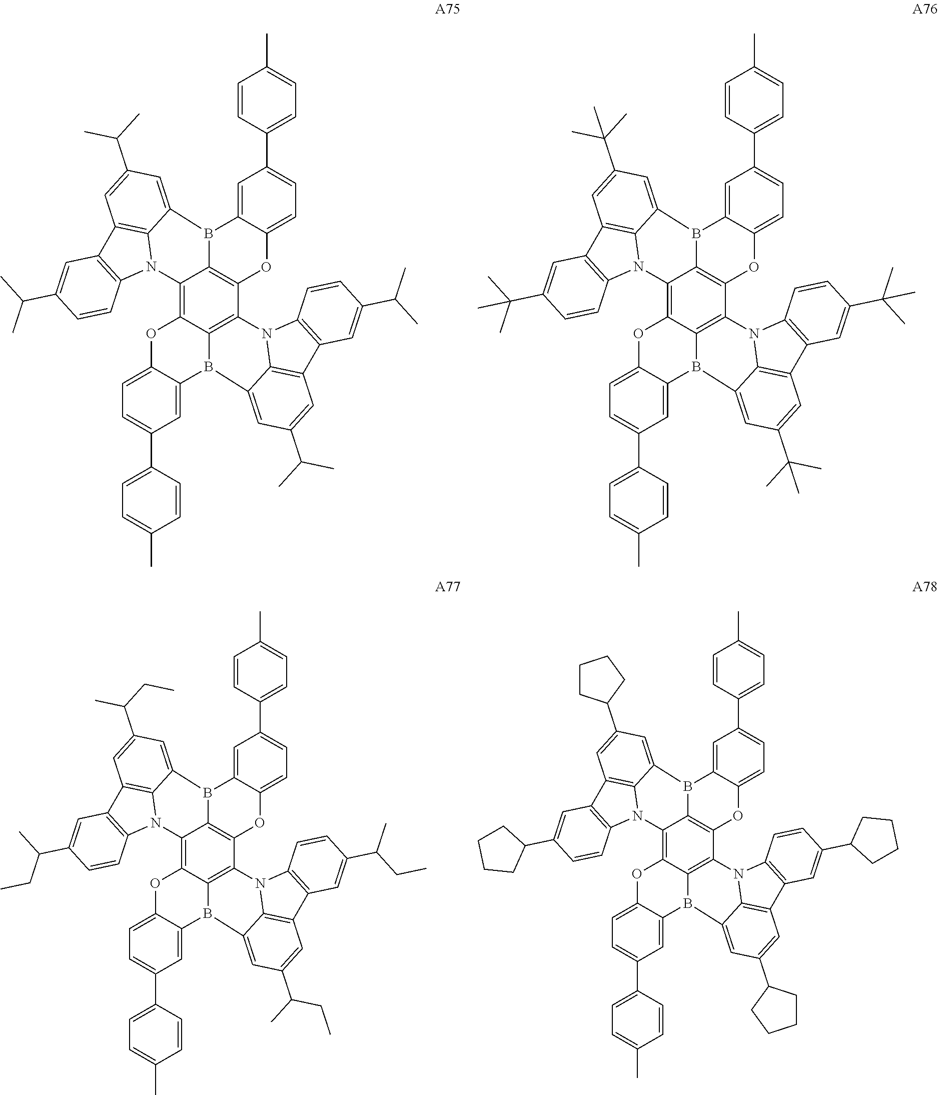

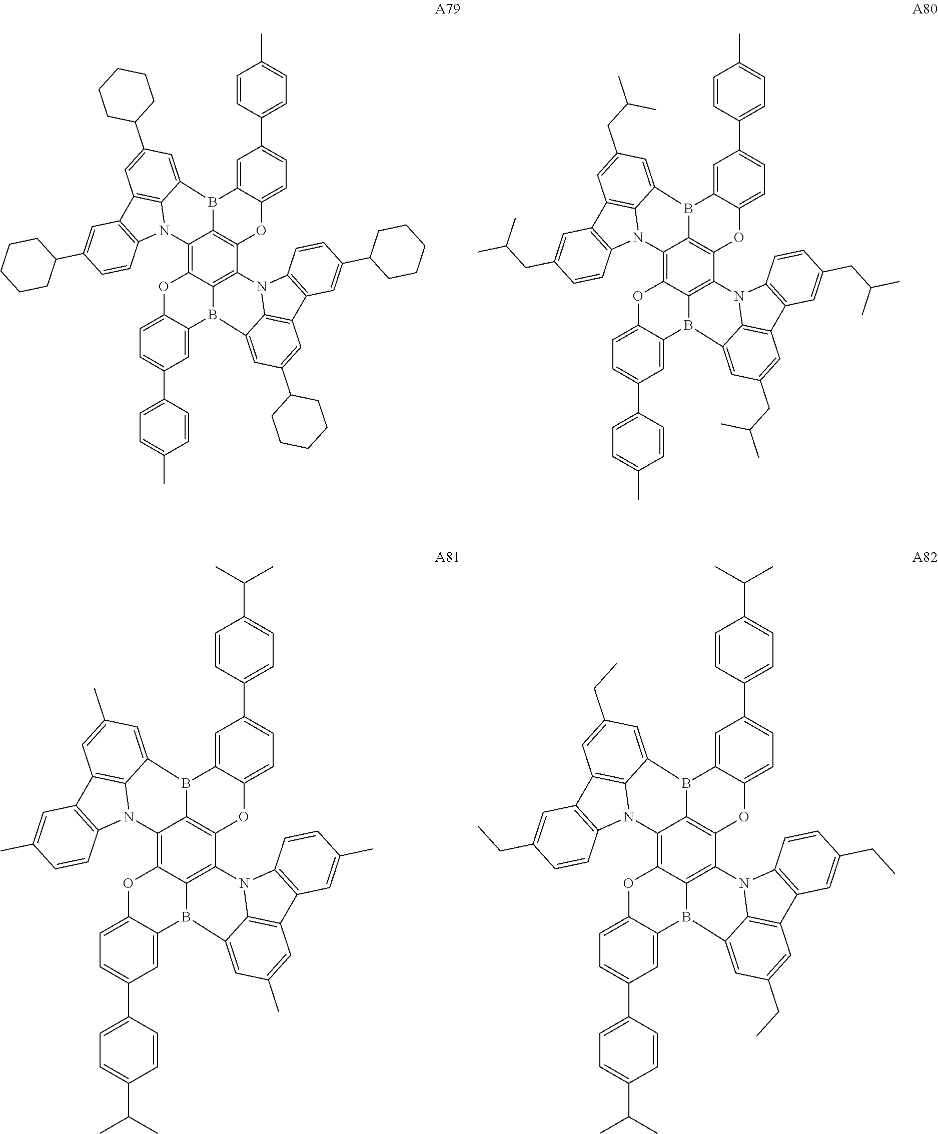

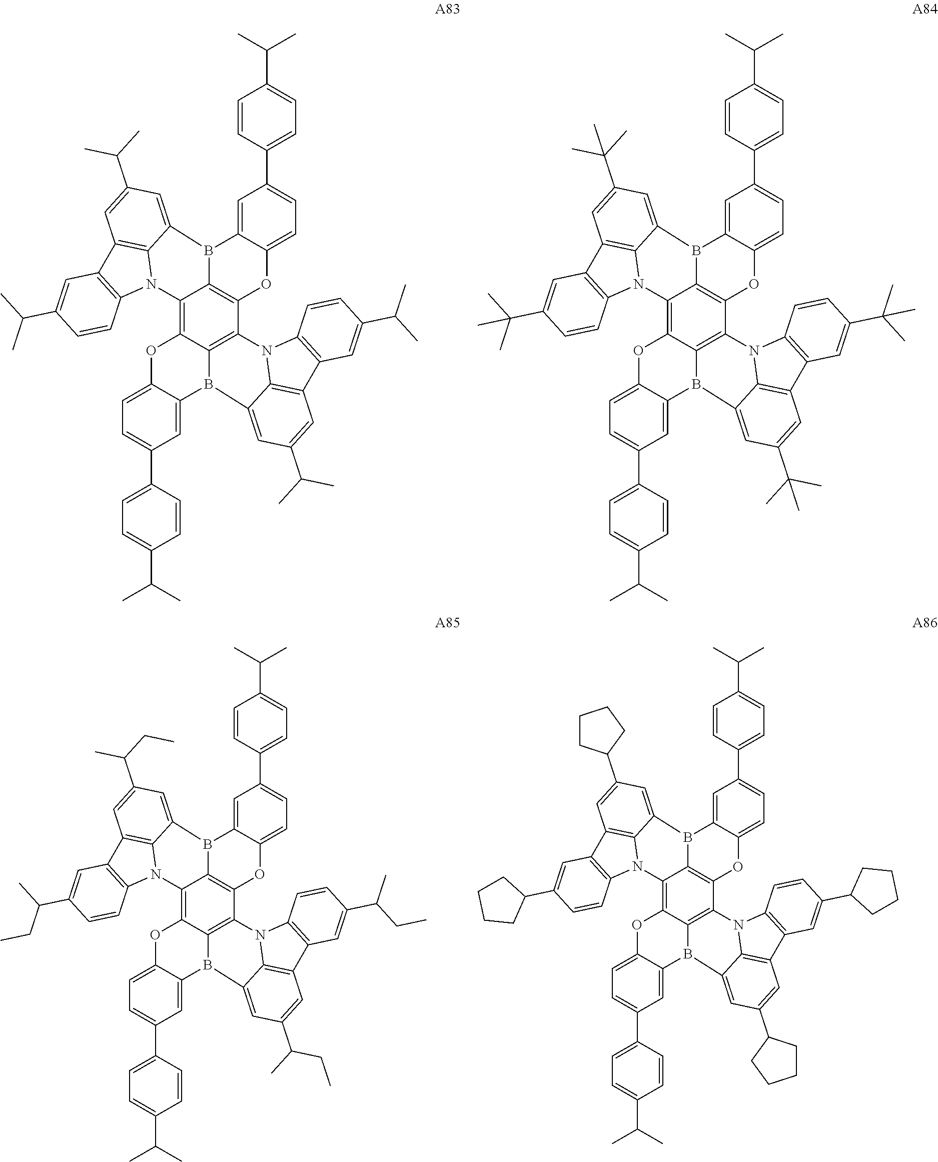

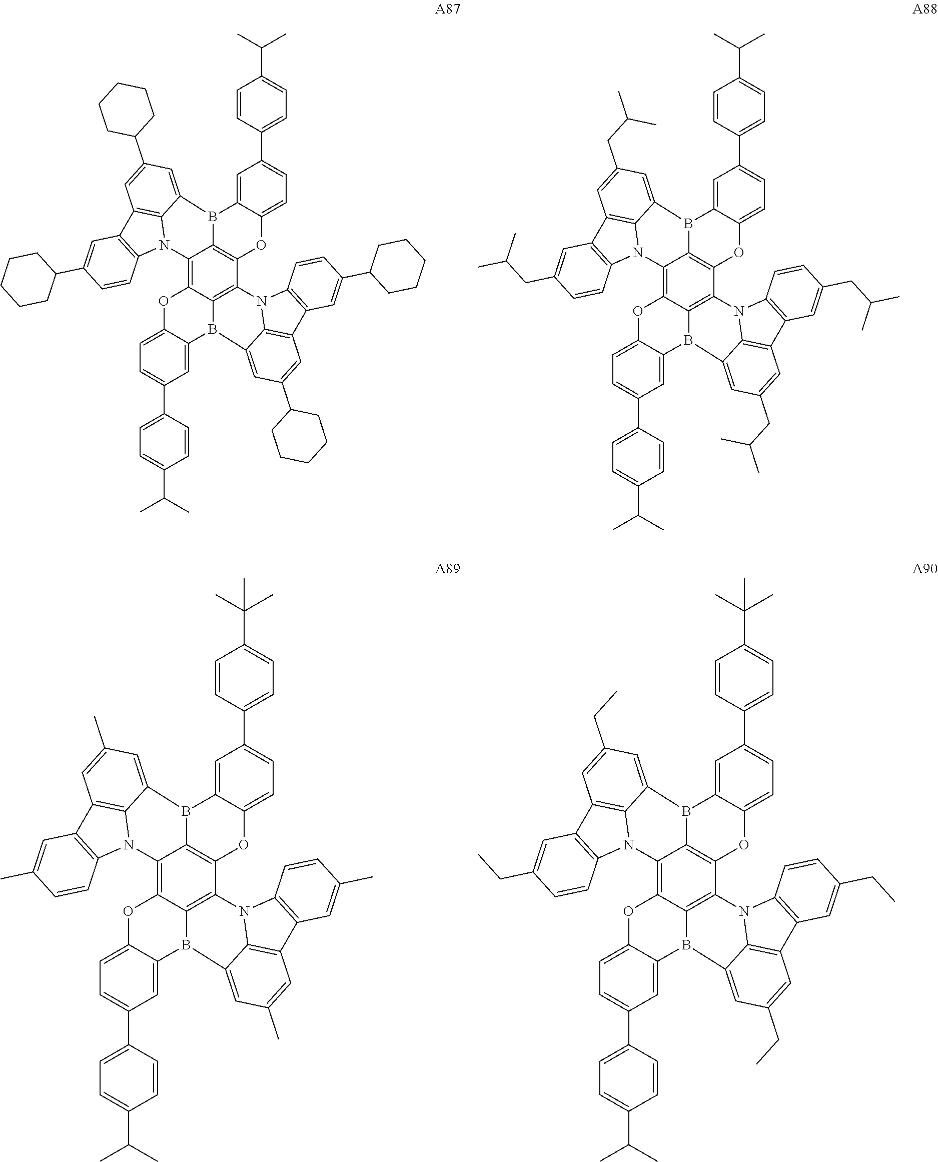

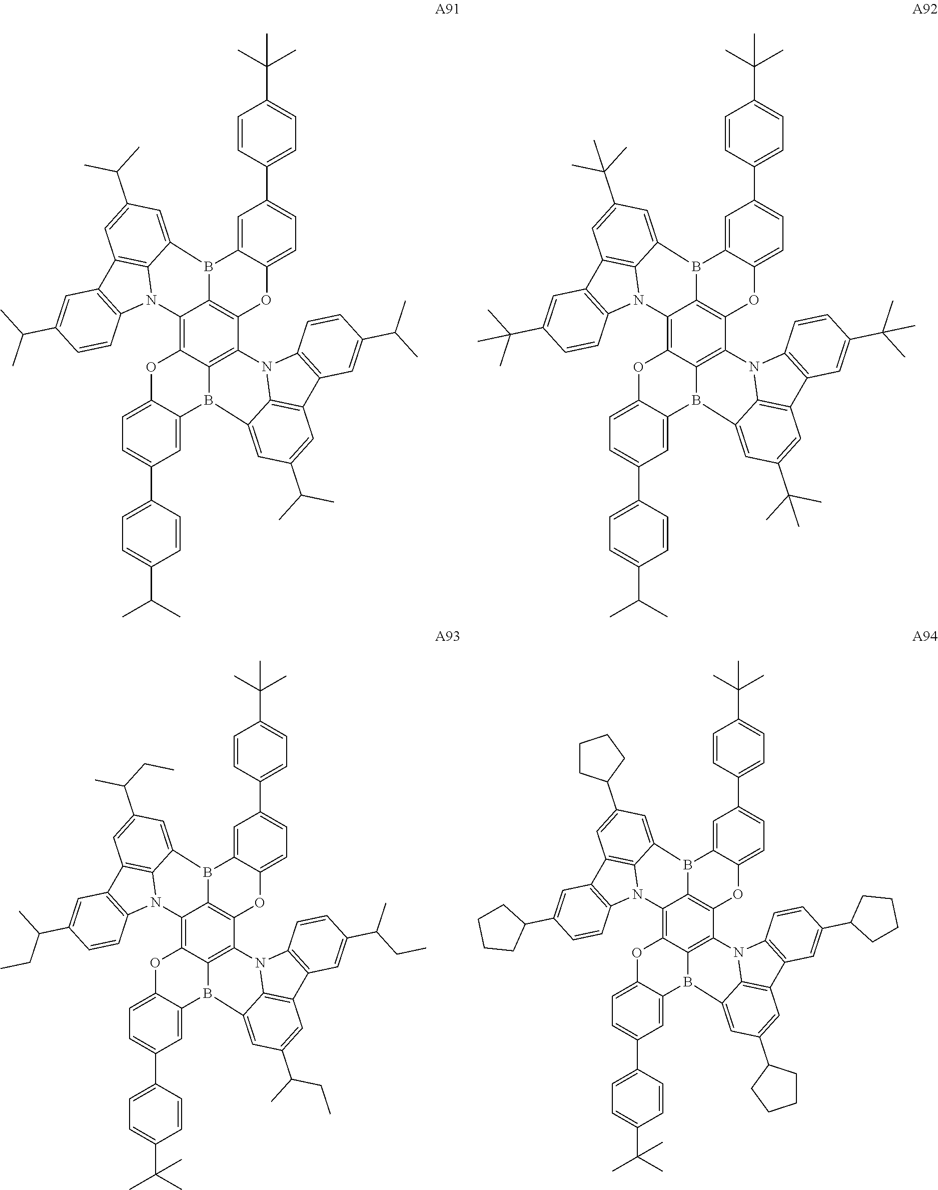

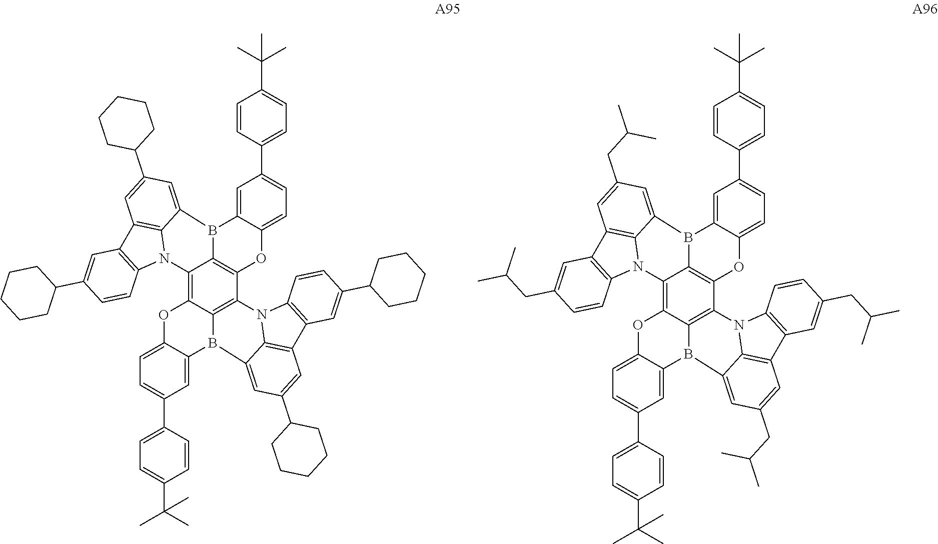 [SMILES: CC(C)(C)c1ccc(-c2ccc3c(c2)B2c4c(c5c6c(c4-n4c7ccc(C8CCCCC8)cc7c7cc(C8CCCCC8)cc2c74)Oc2ccc(-c4ccc(C(C)(C)C)cc4)cc2B6c2cc(C4CCCCC4)cc4c6cc(C7CCCCC7)ccc6n-5c24)O3)cc1 ; CC(C)Cc1ccc2c(c1)c1cc(CC(C)C)cc3c1n2-c1c2c4c(c5c1B3c1cc(-c3ccc(C(C)(C)C)cc3)ccc1O5)-n1c3ccc(CC(C)C)cc3c3cc(CC(C)C)cc(c31)B4c1cc(-c3ccc(C(C)(C)C)cc3)ccc1O2]

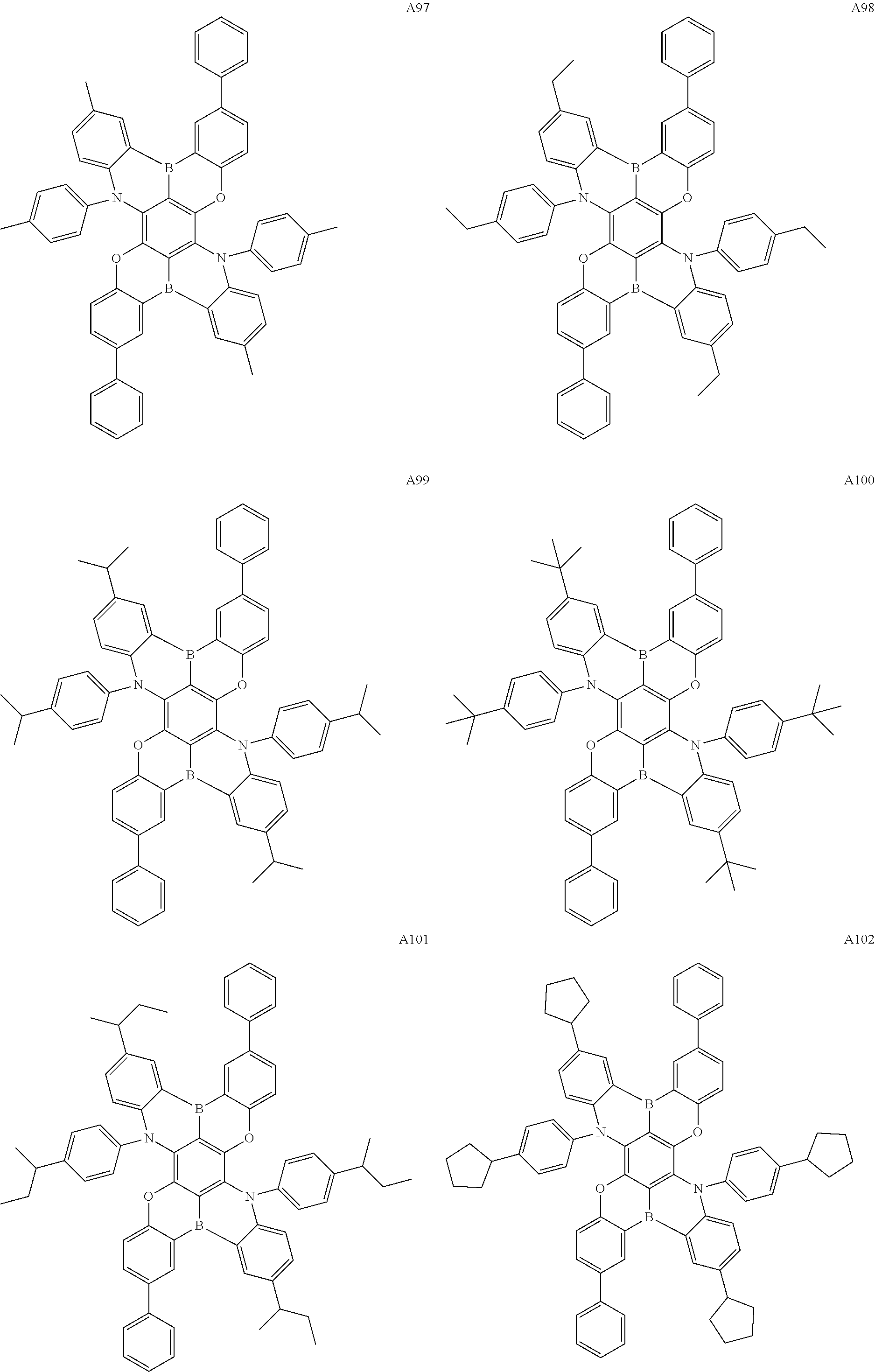

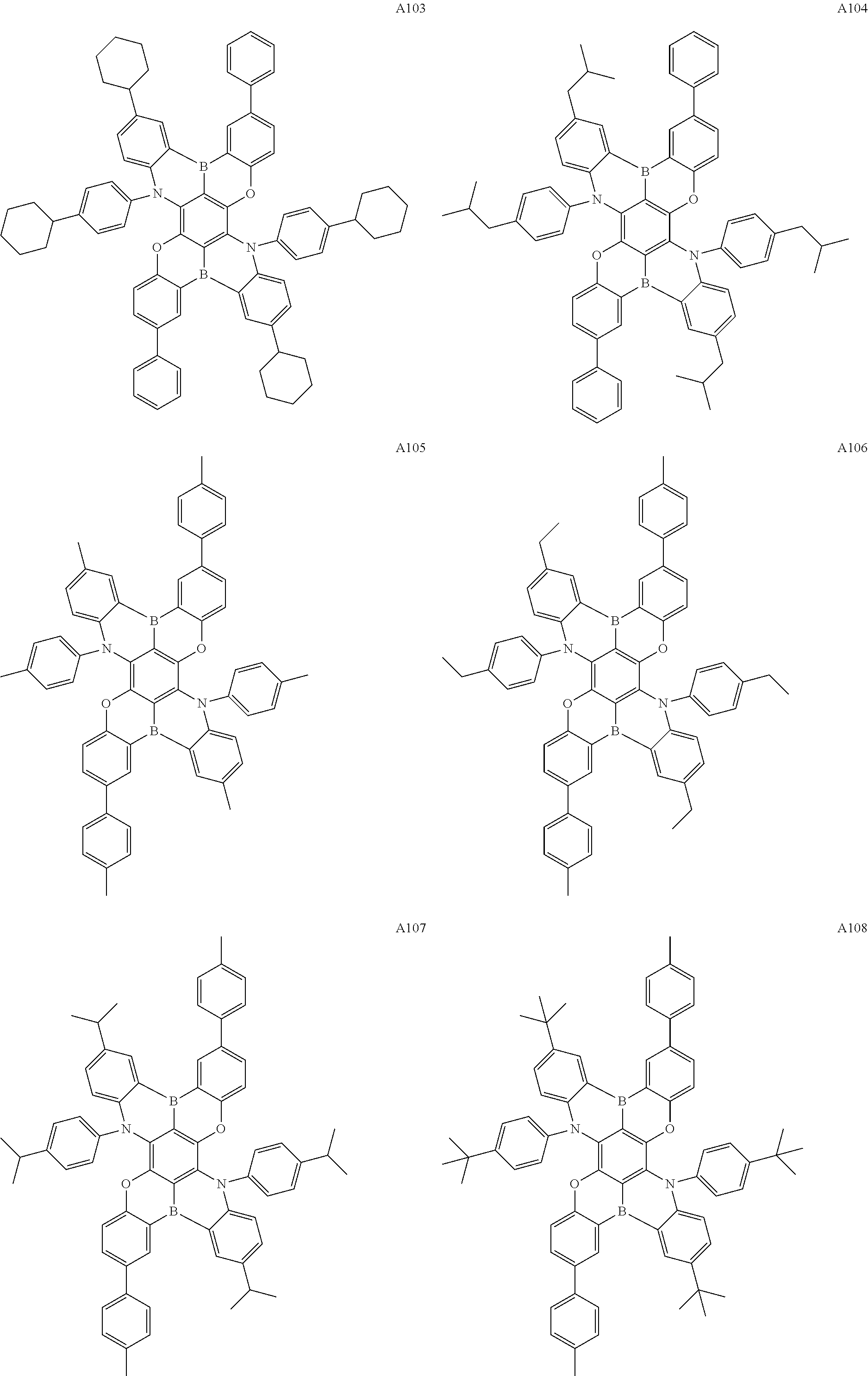

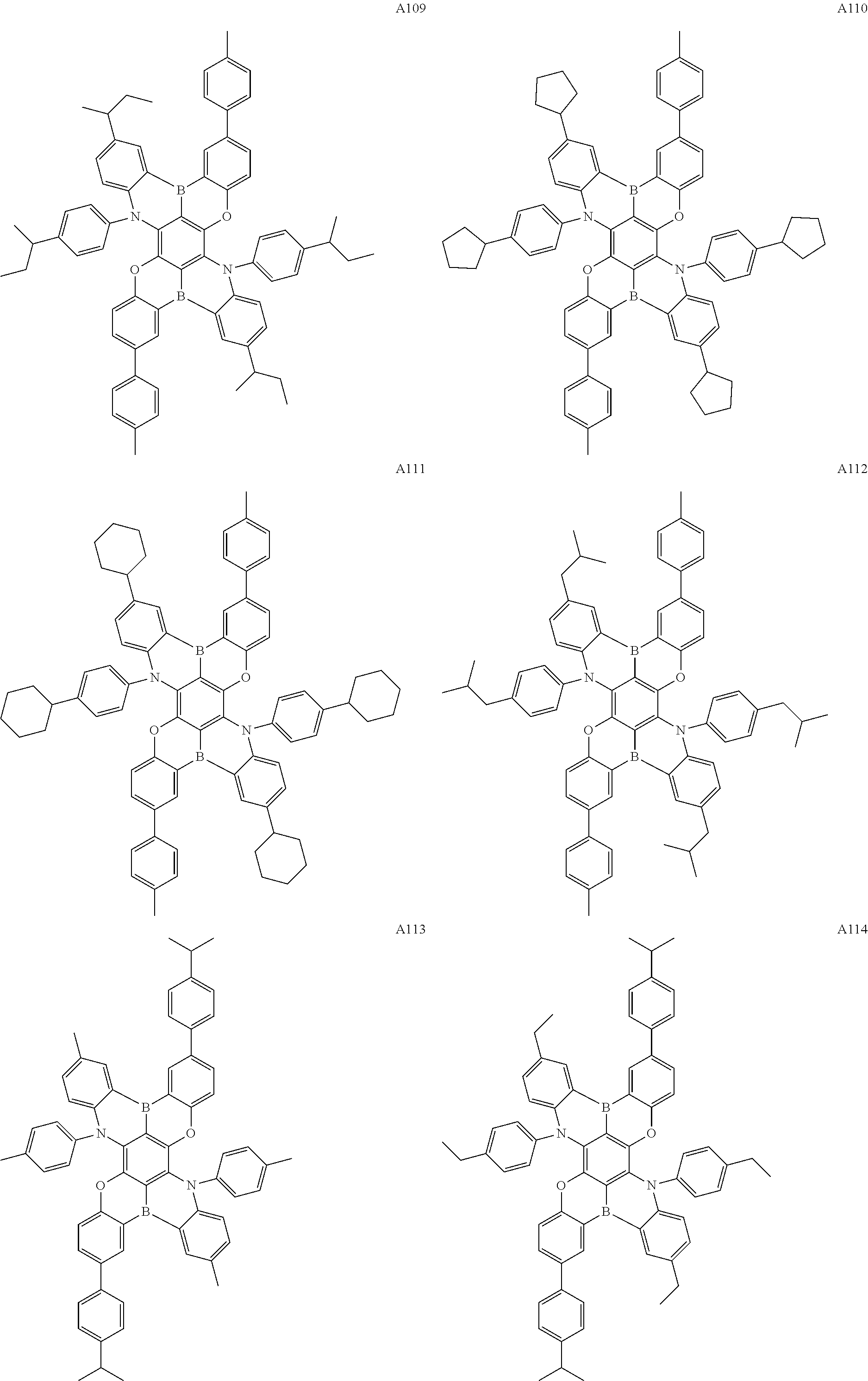

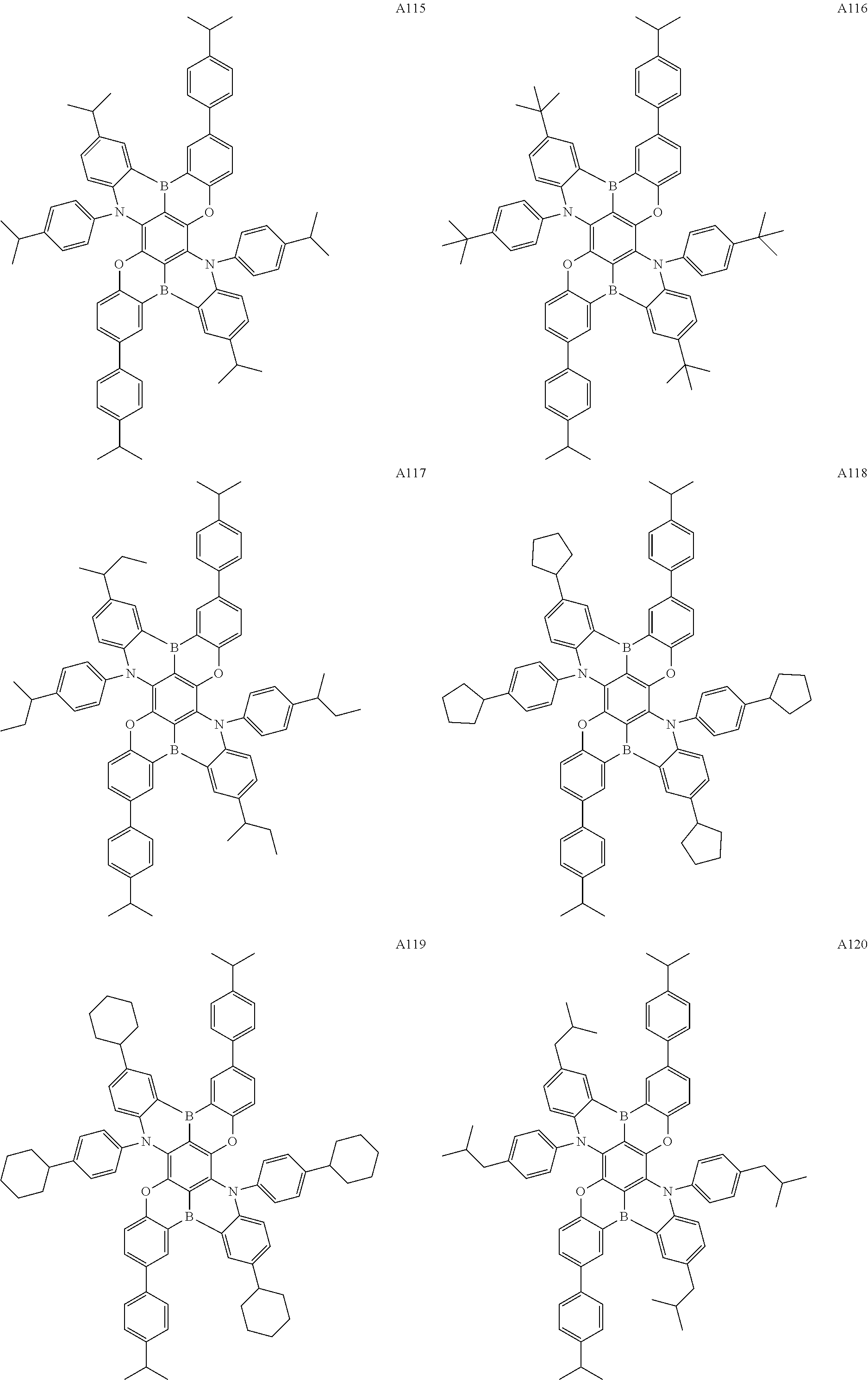

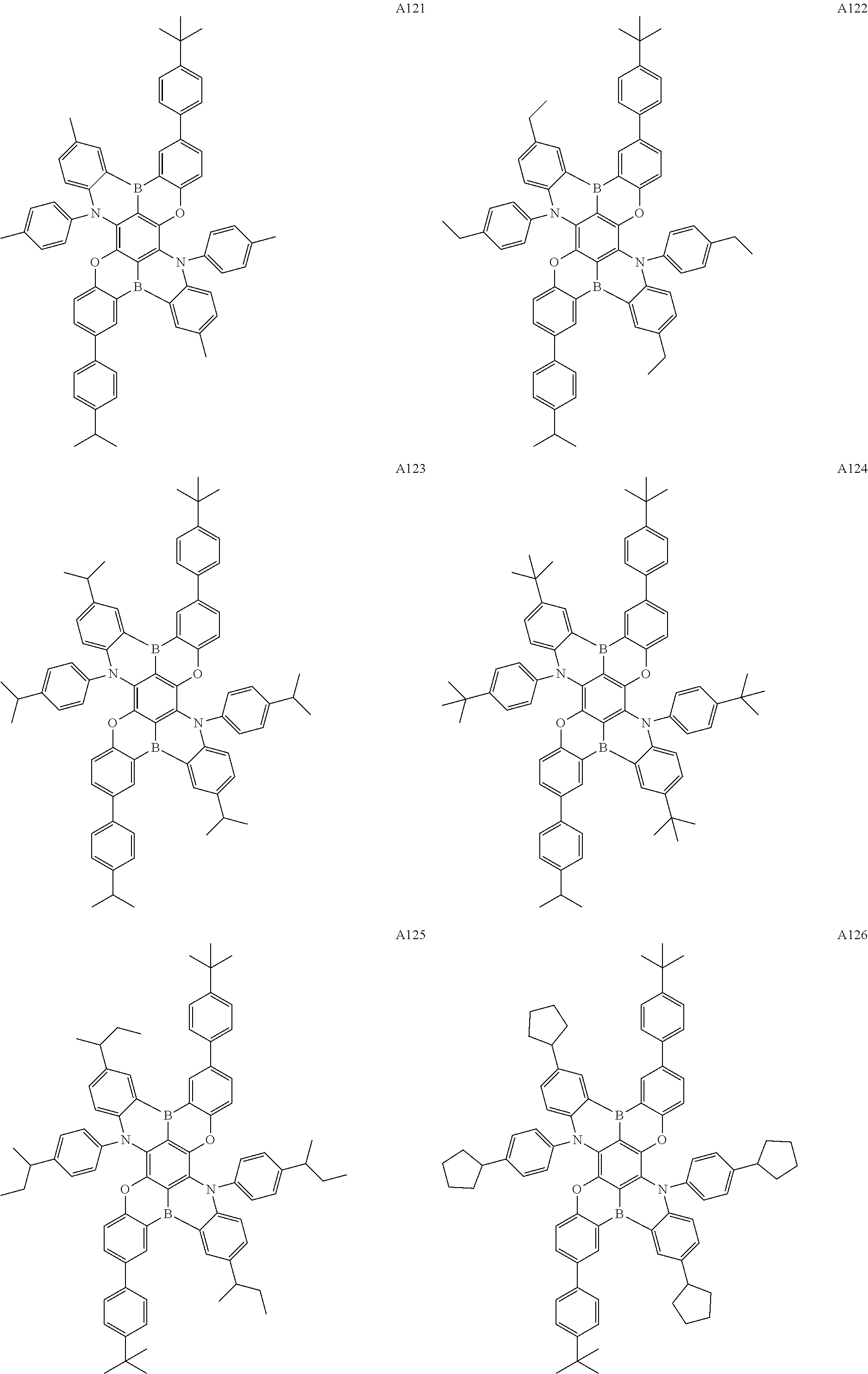

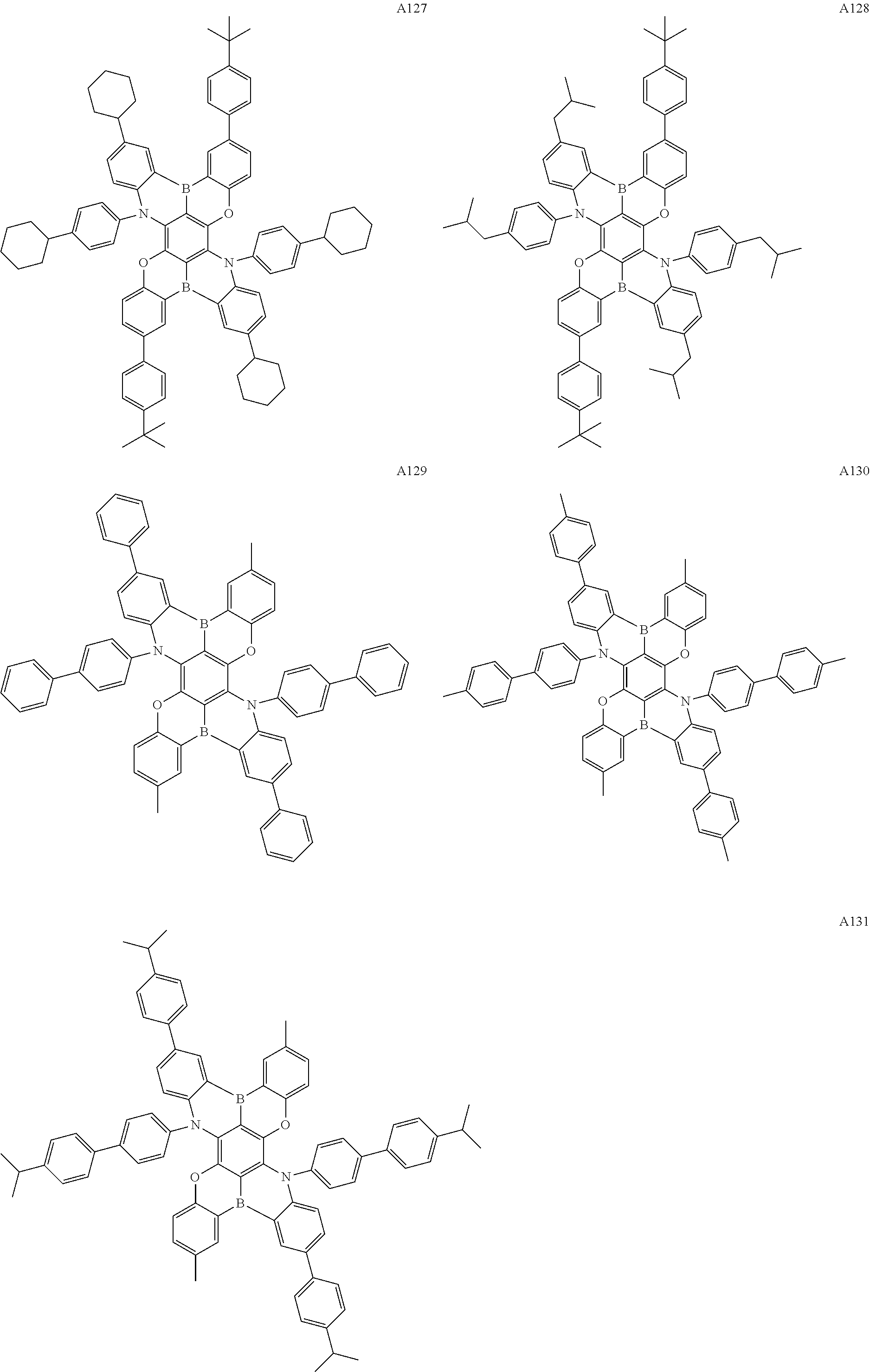

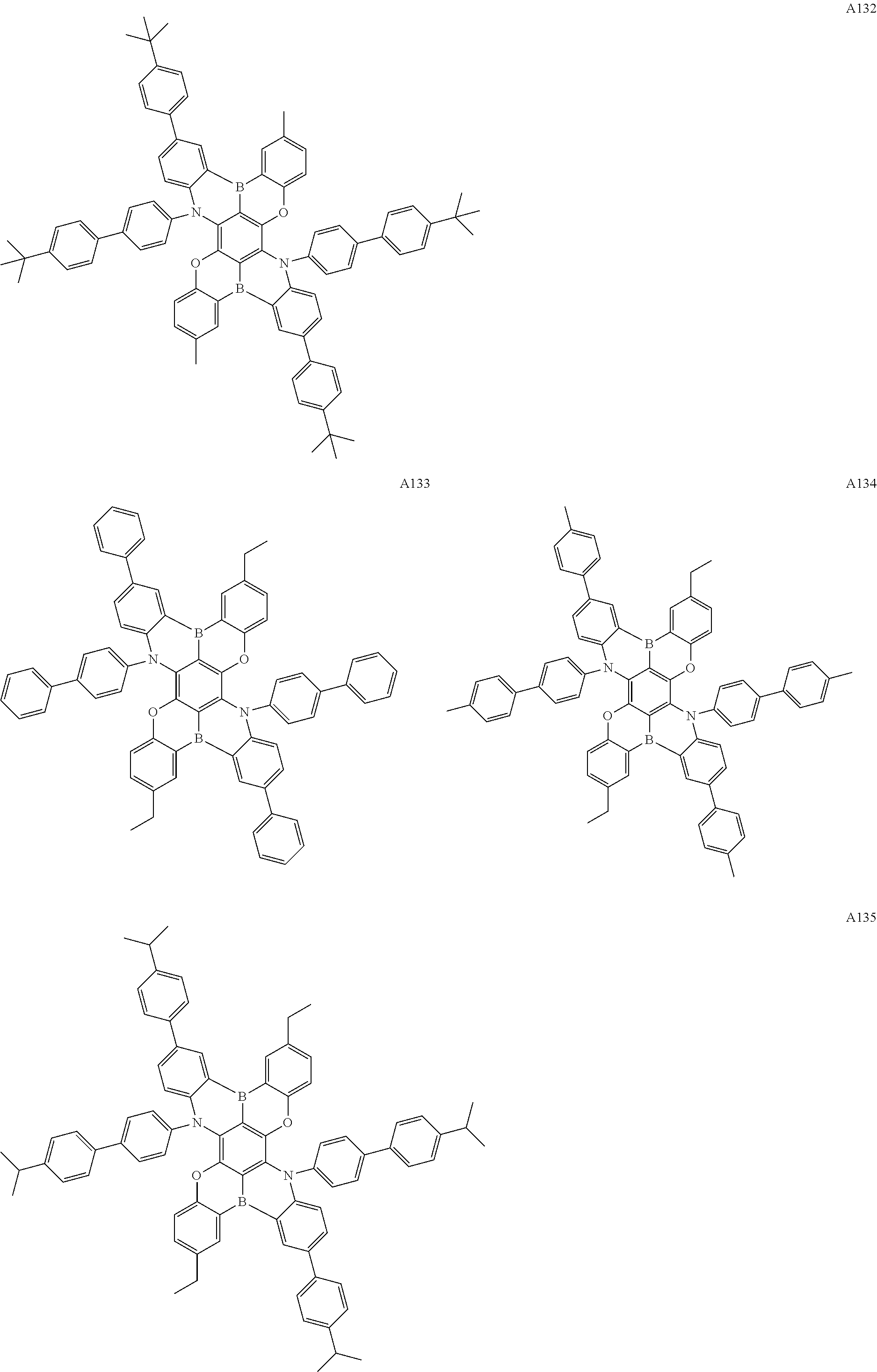

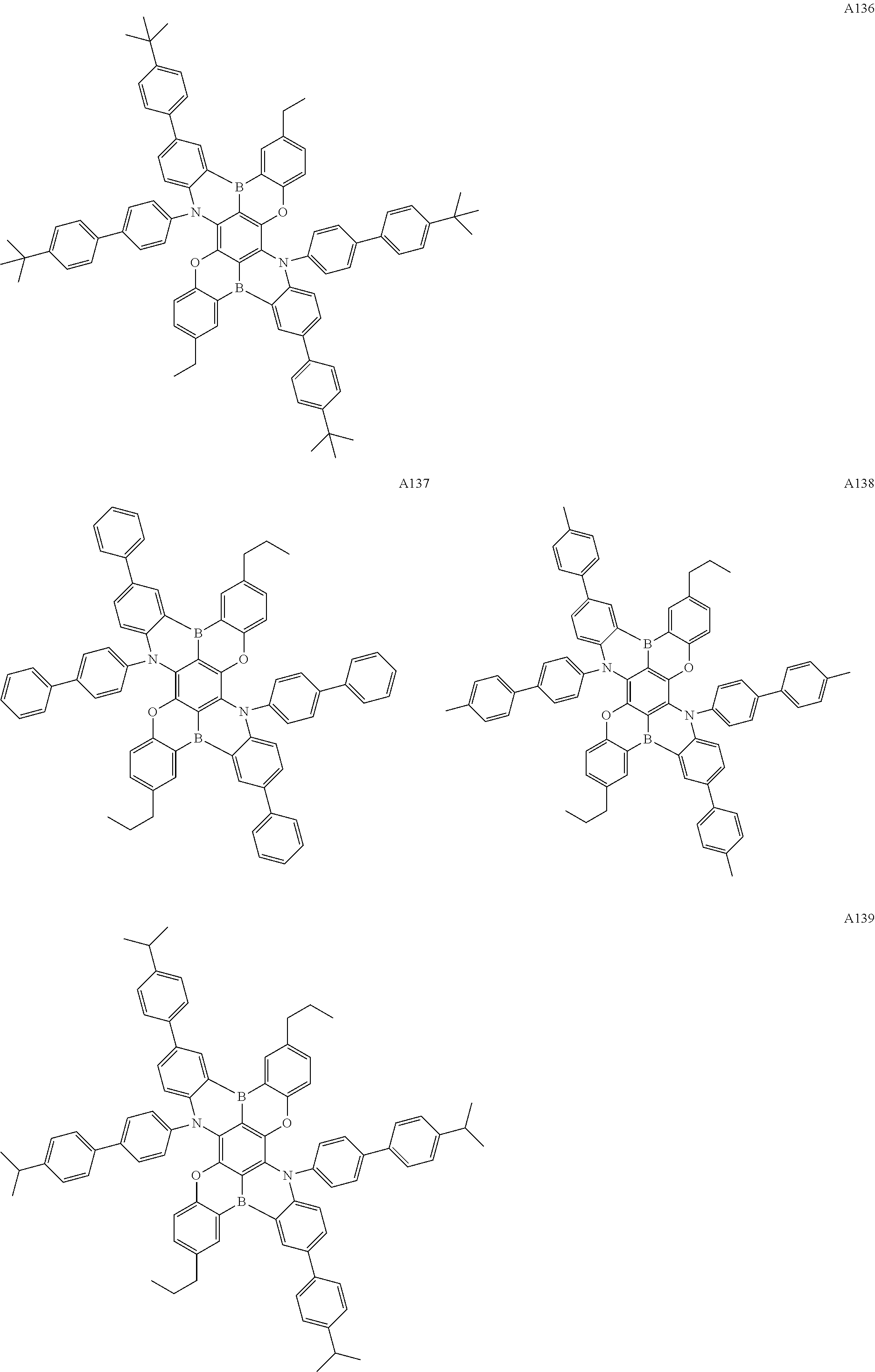

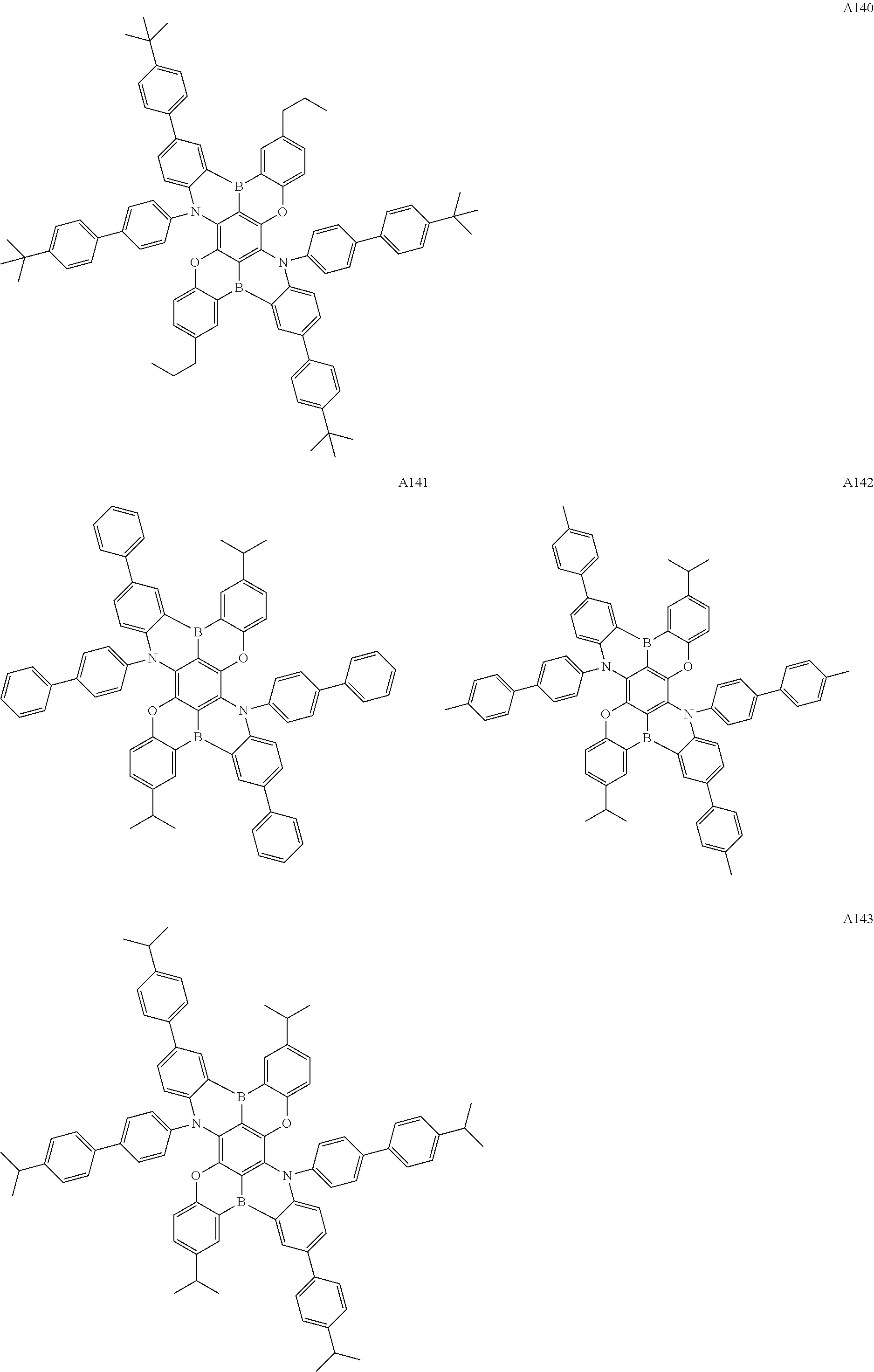

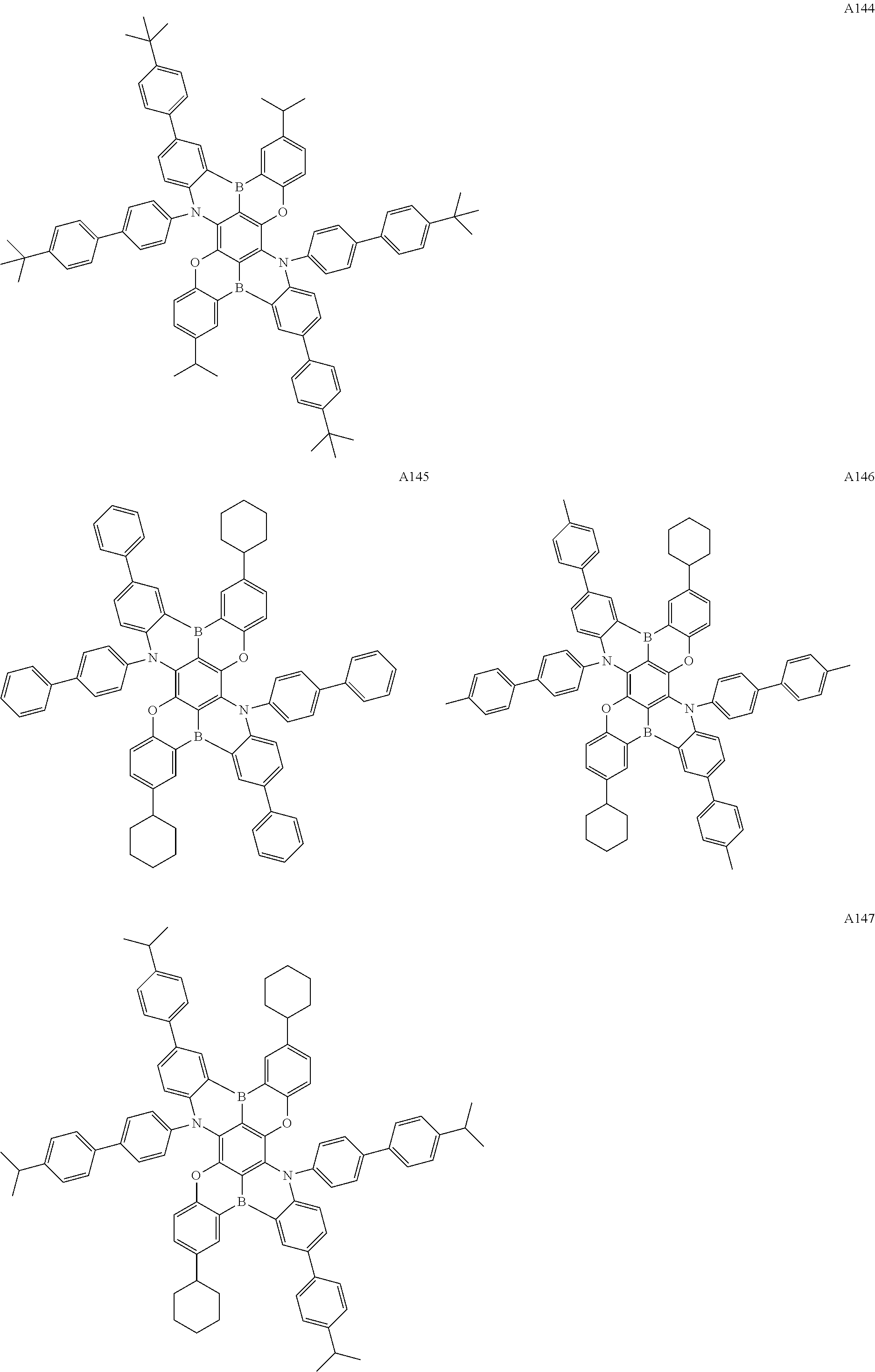

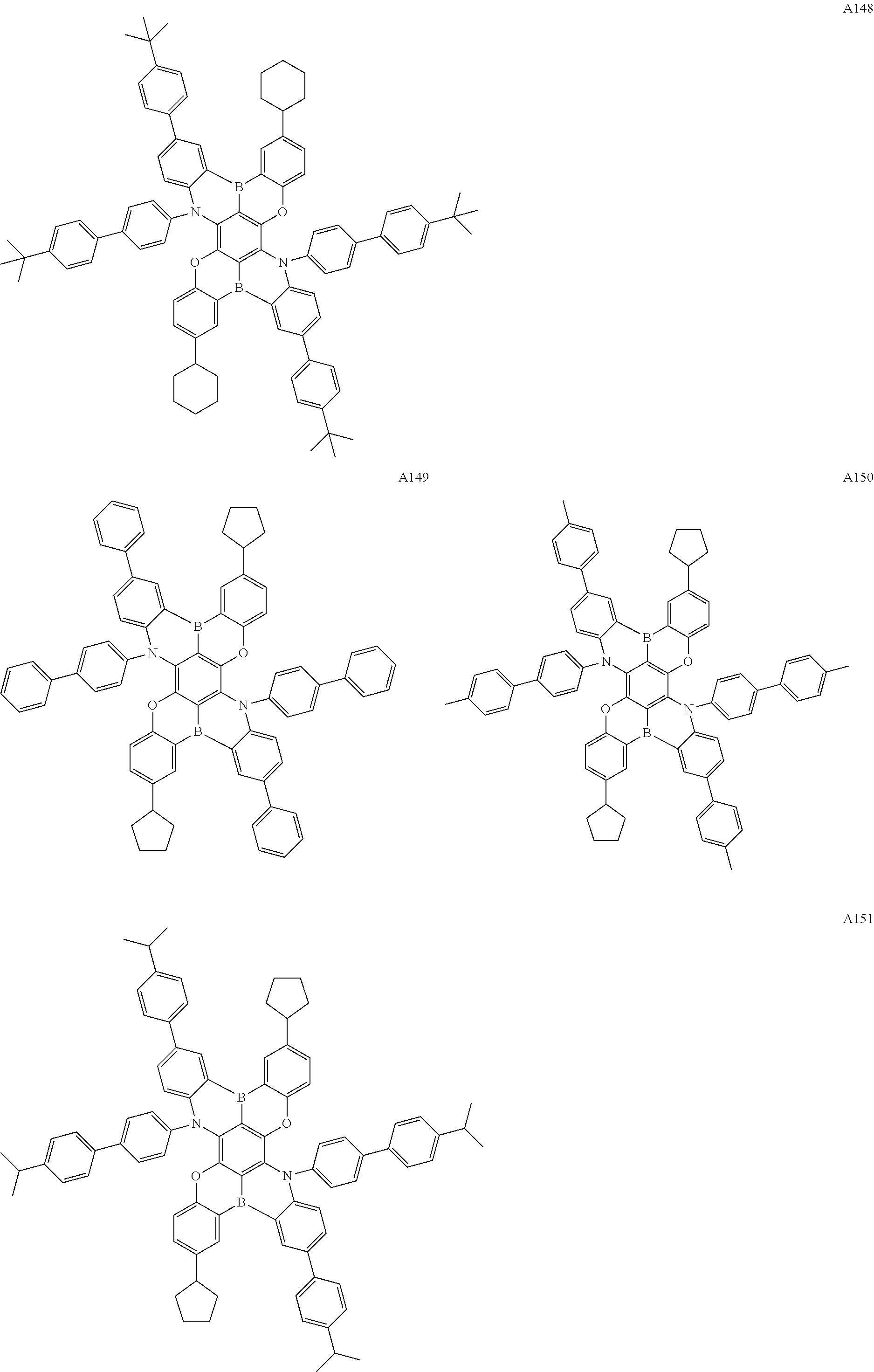

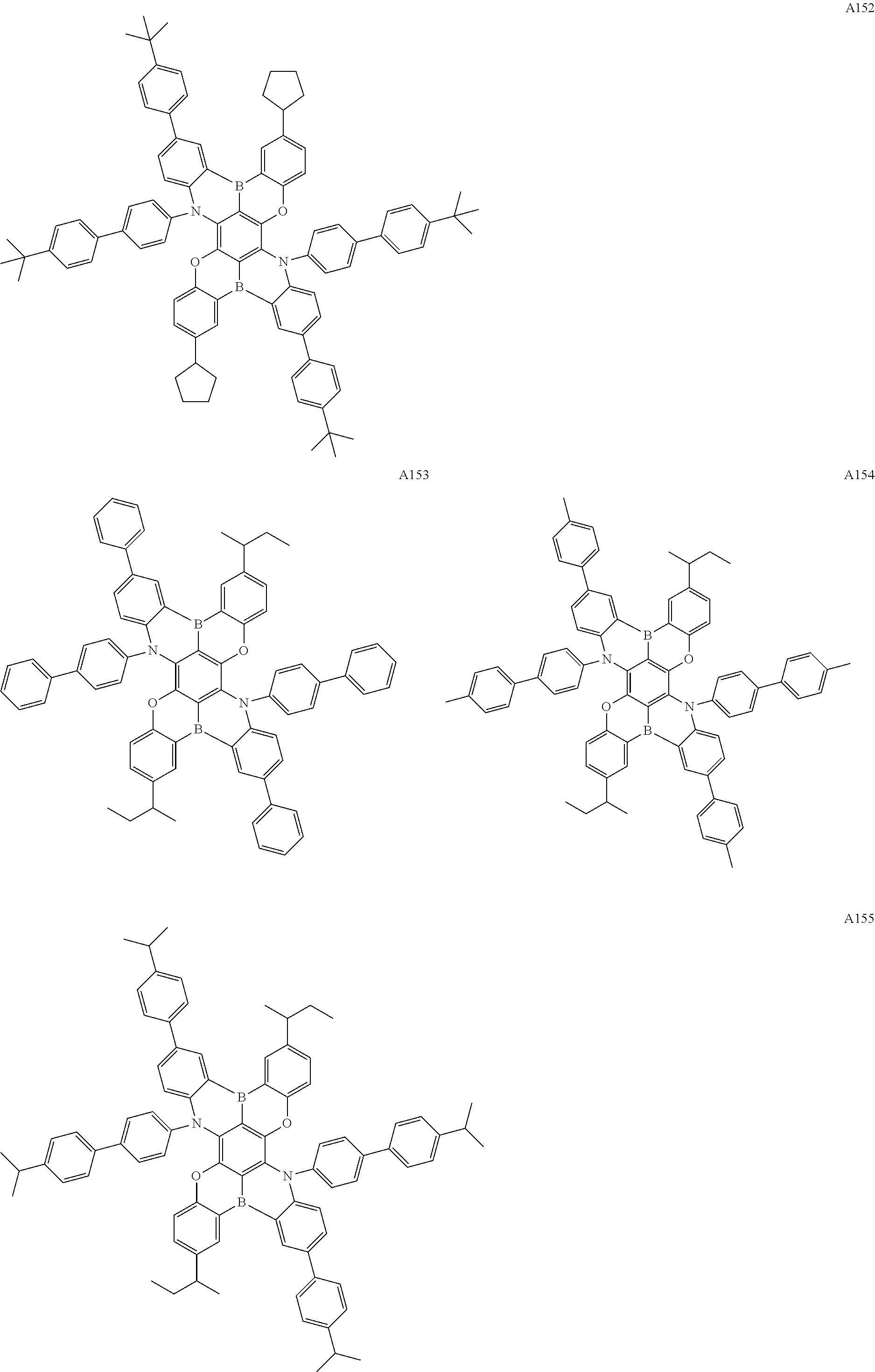

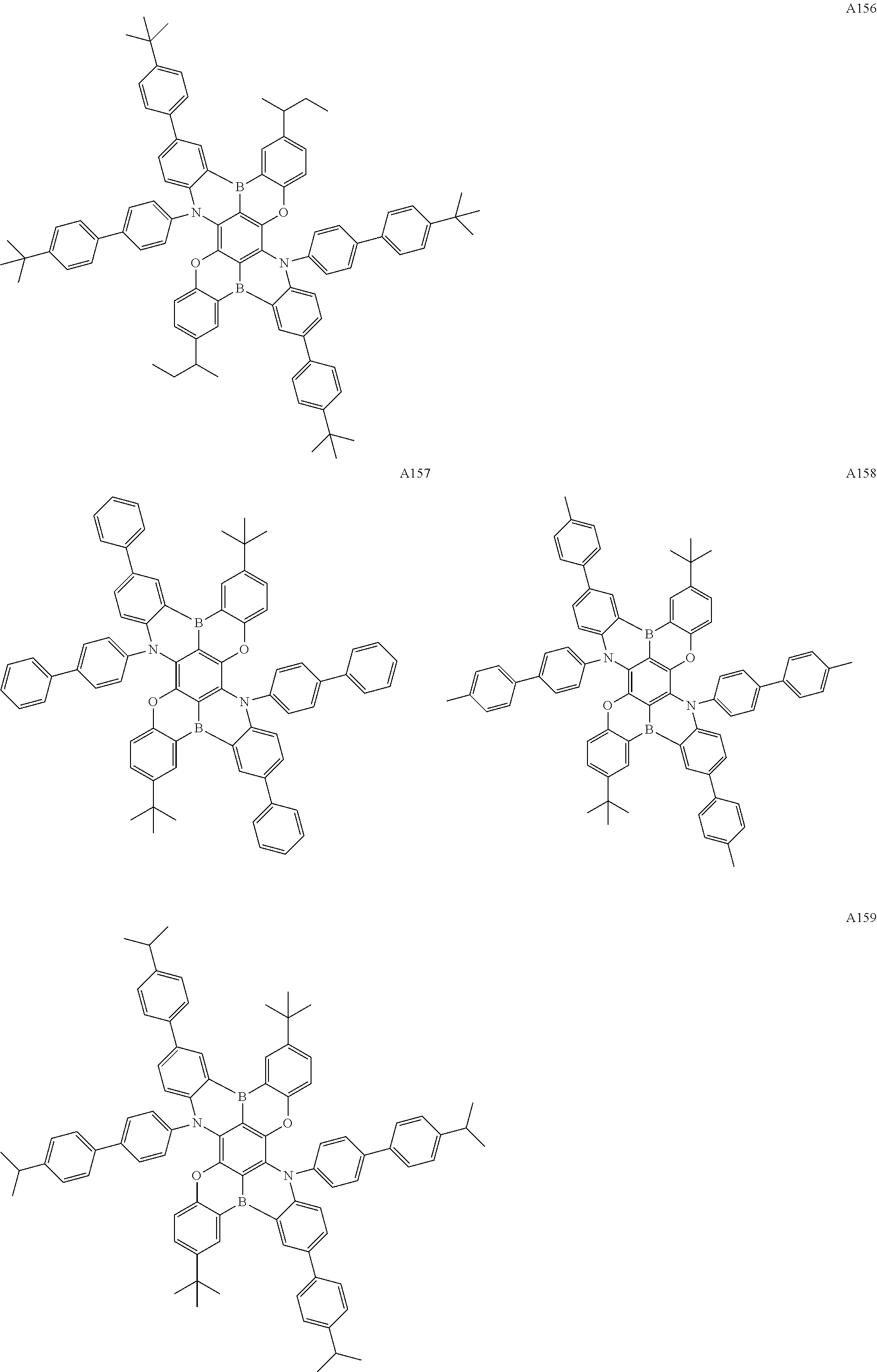

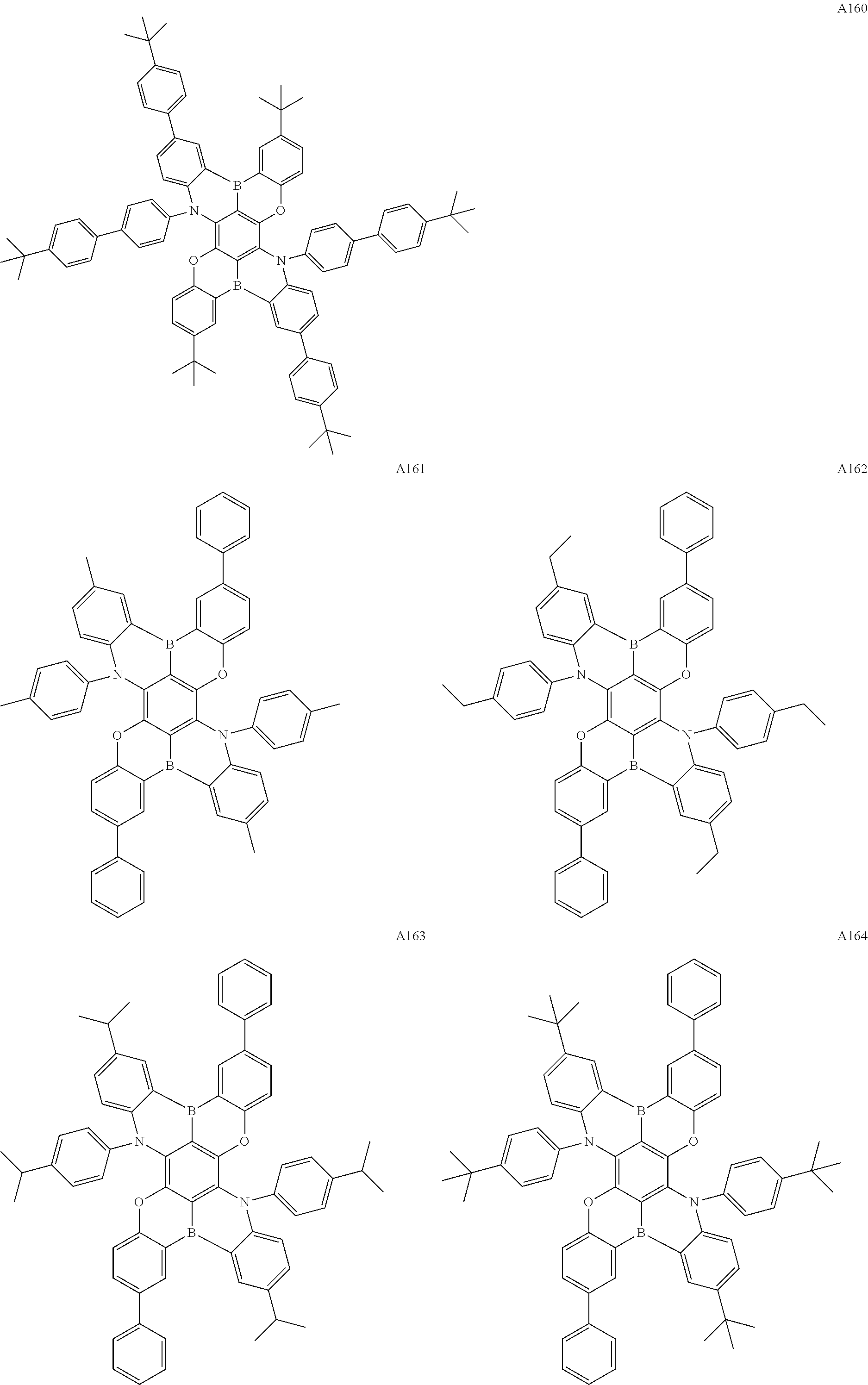

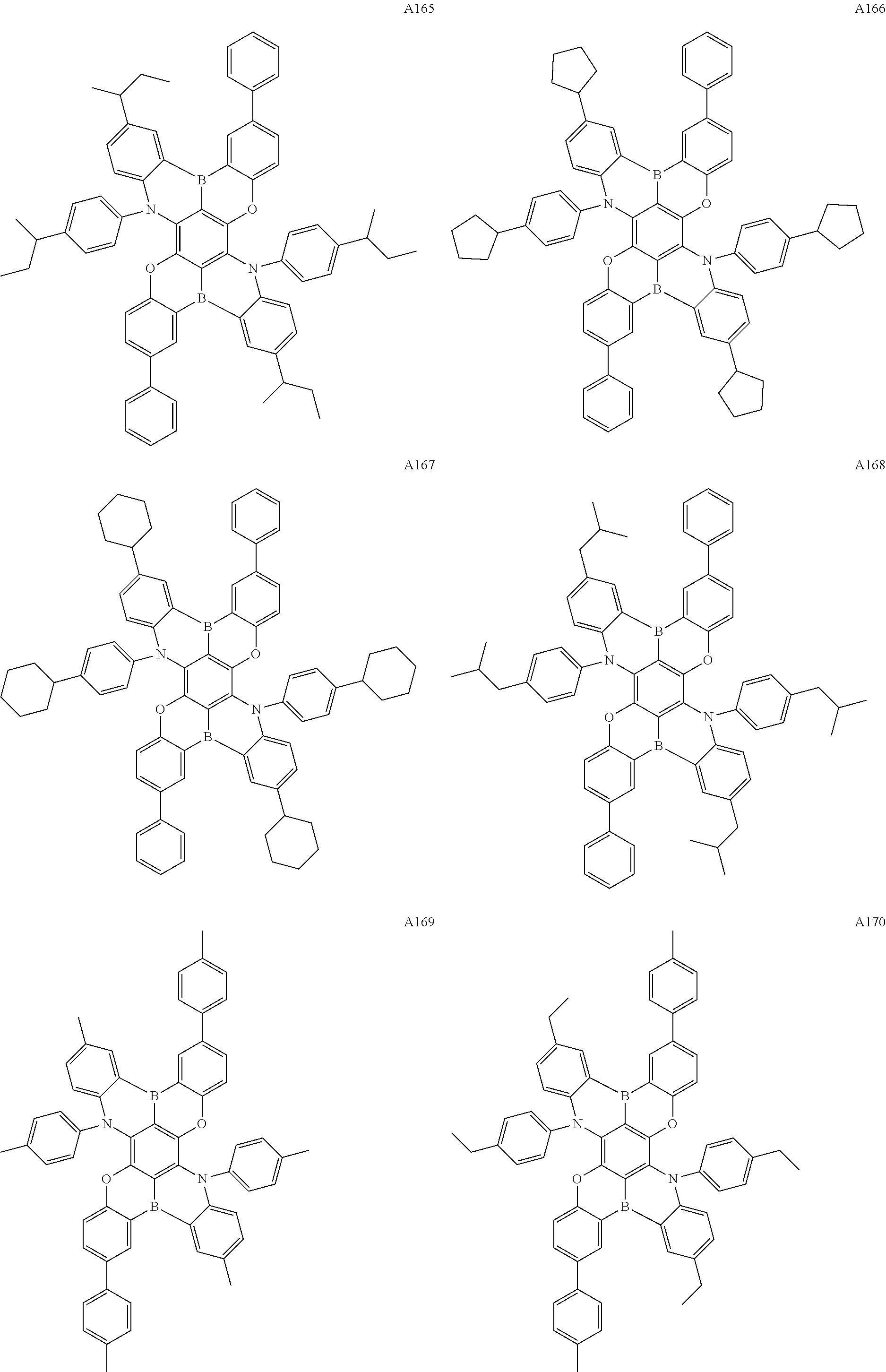

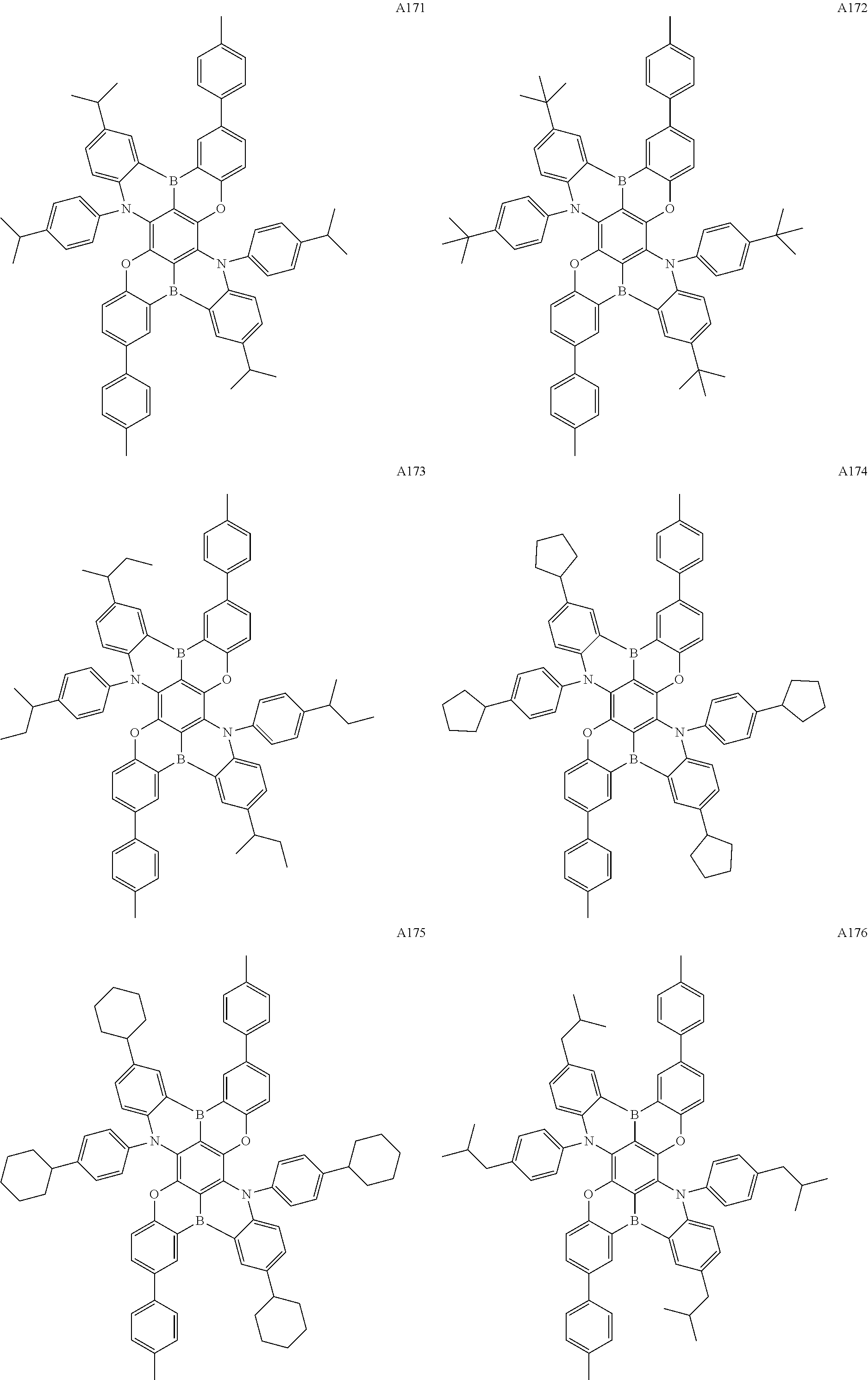

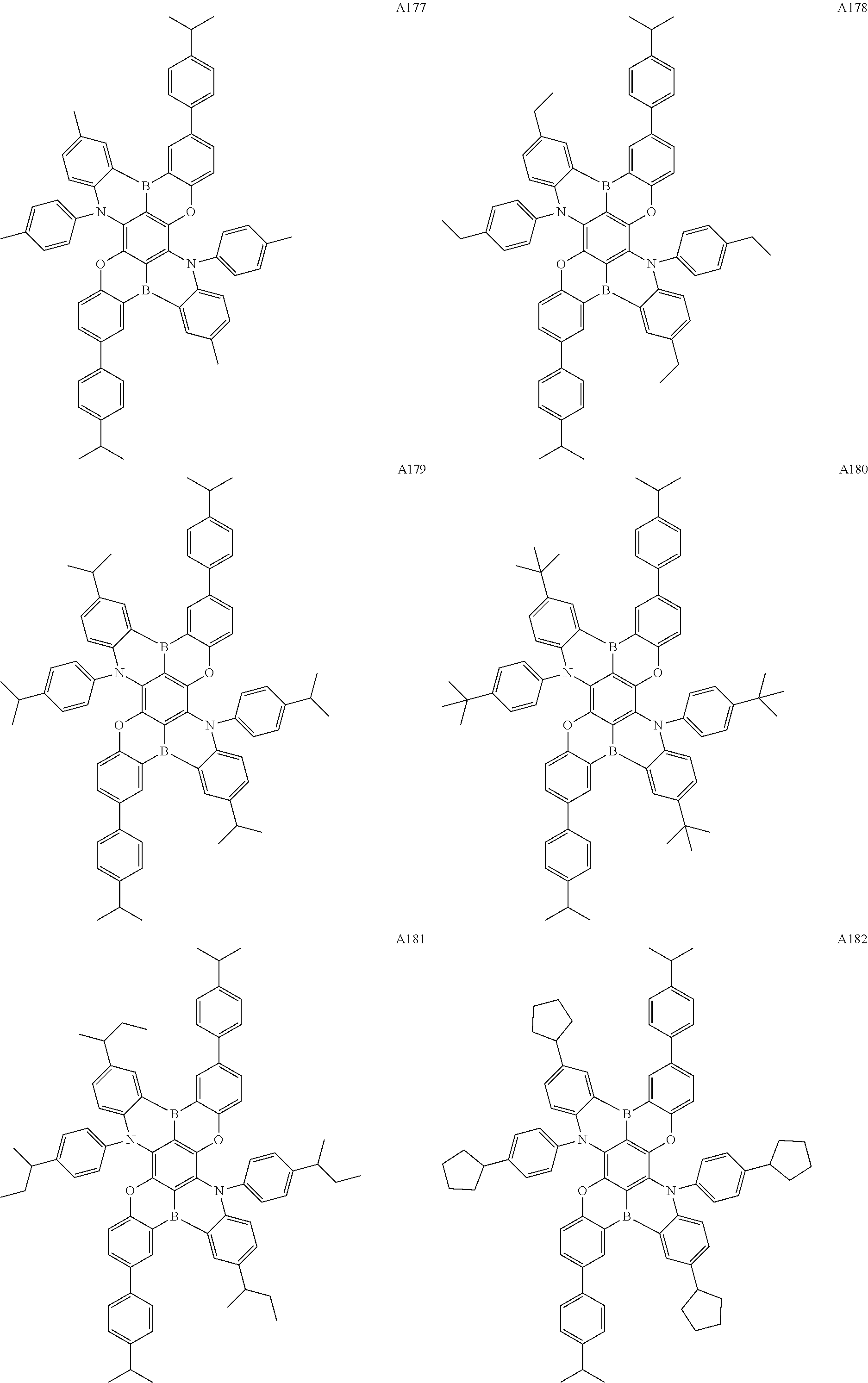

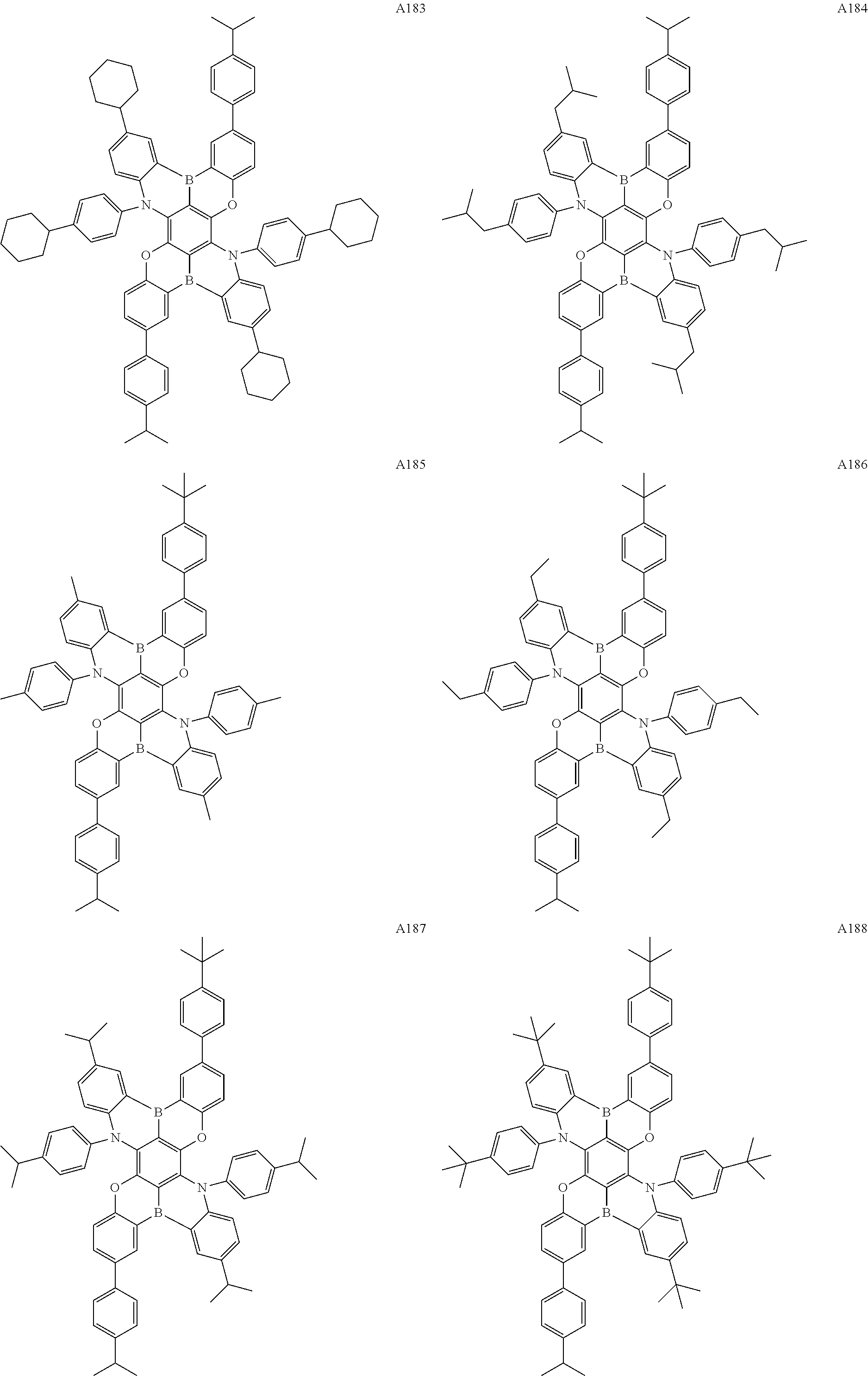

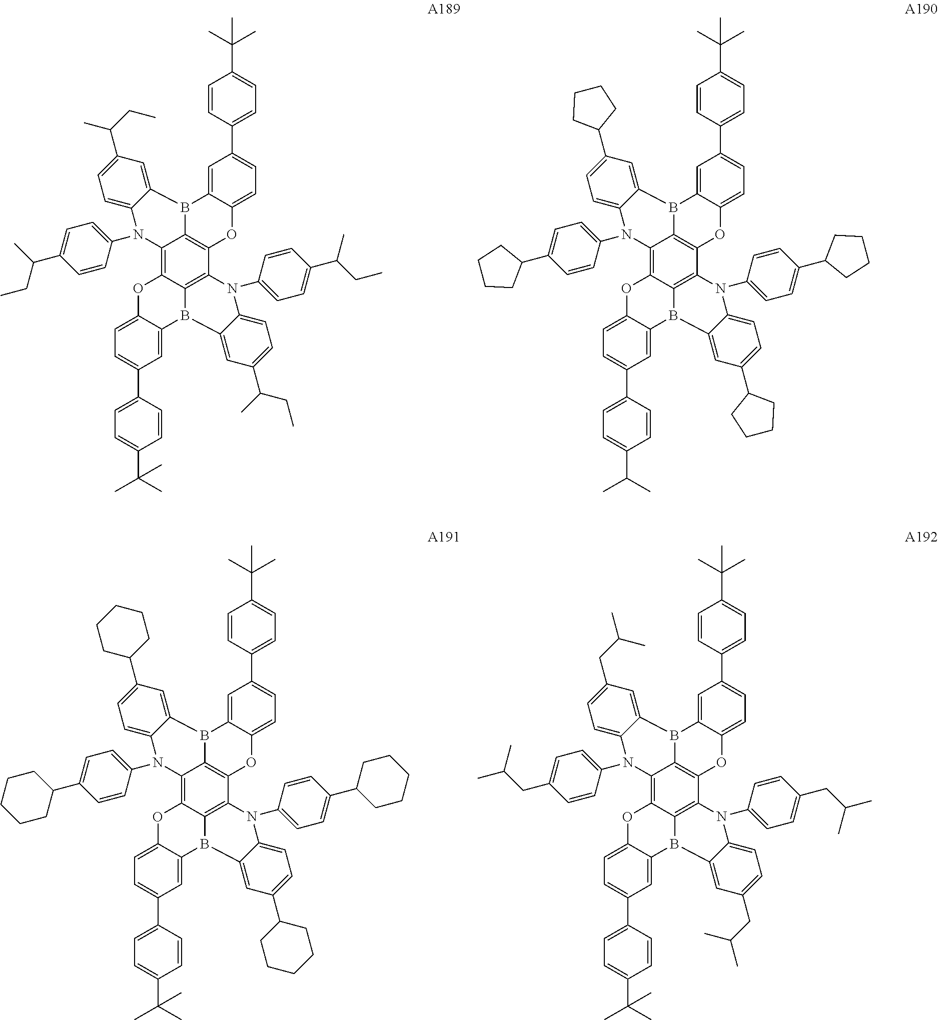

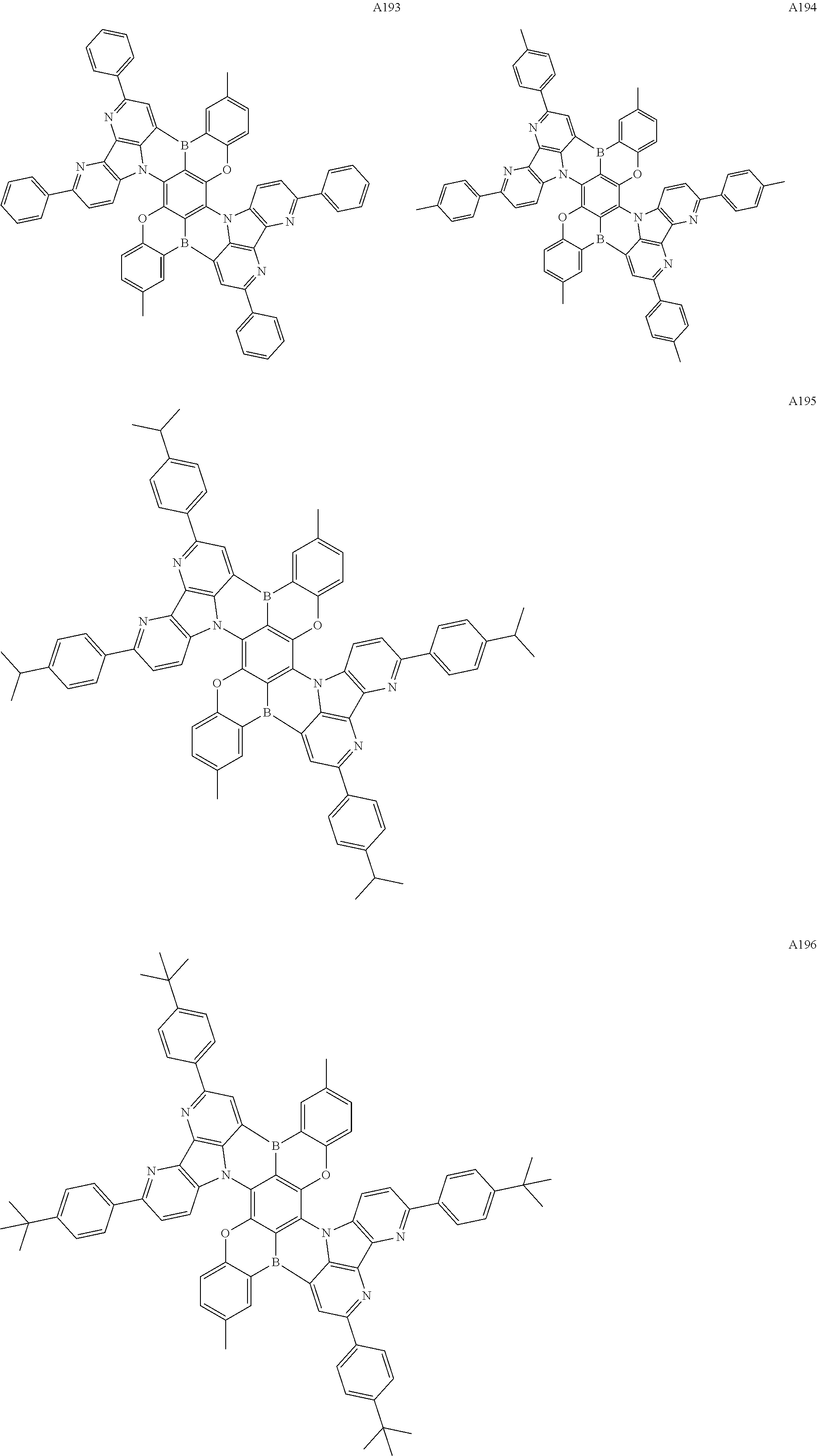

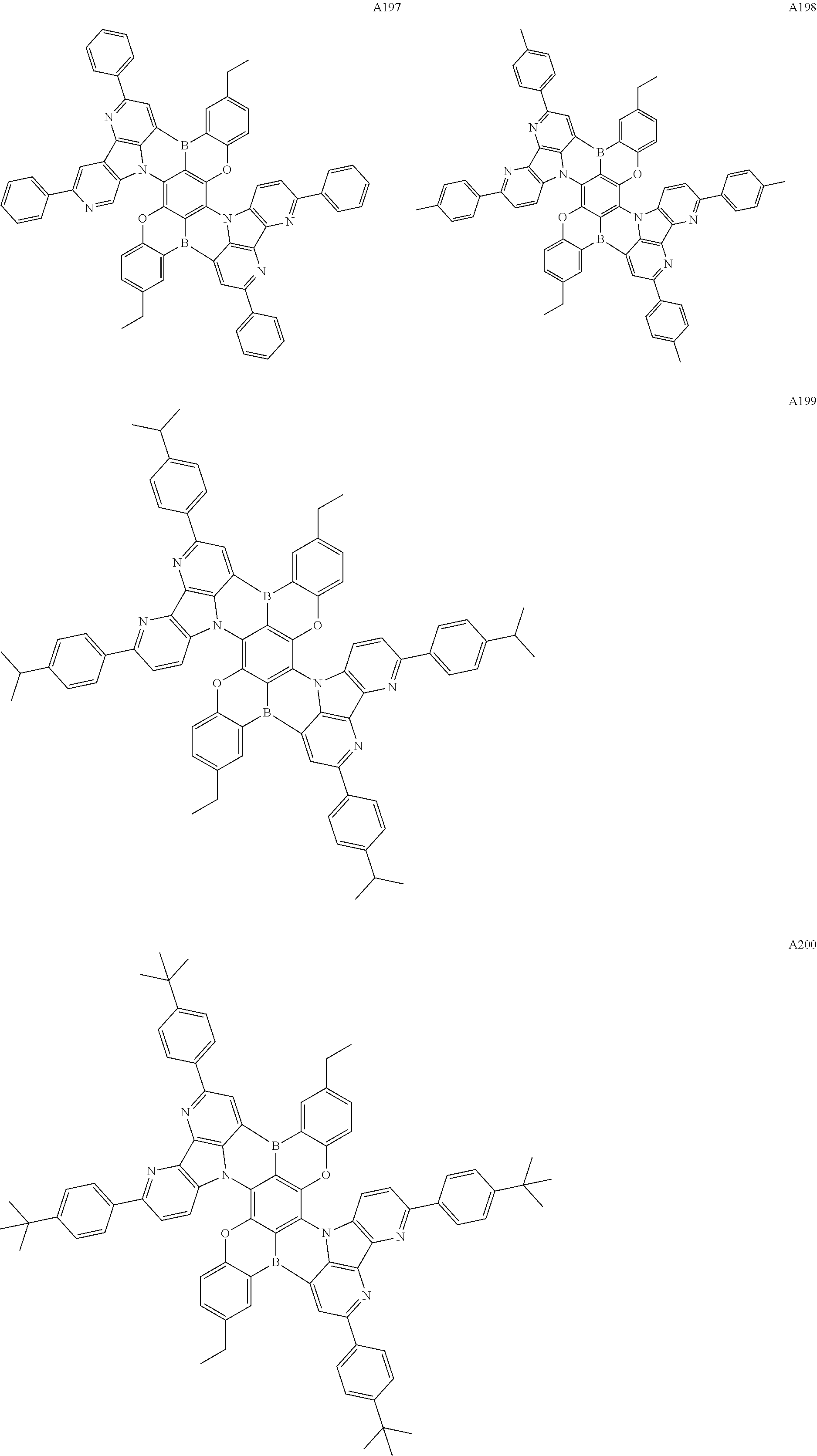

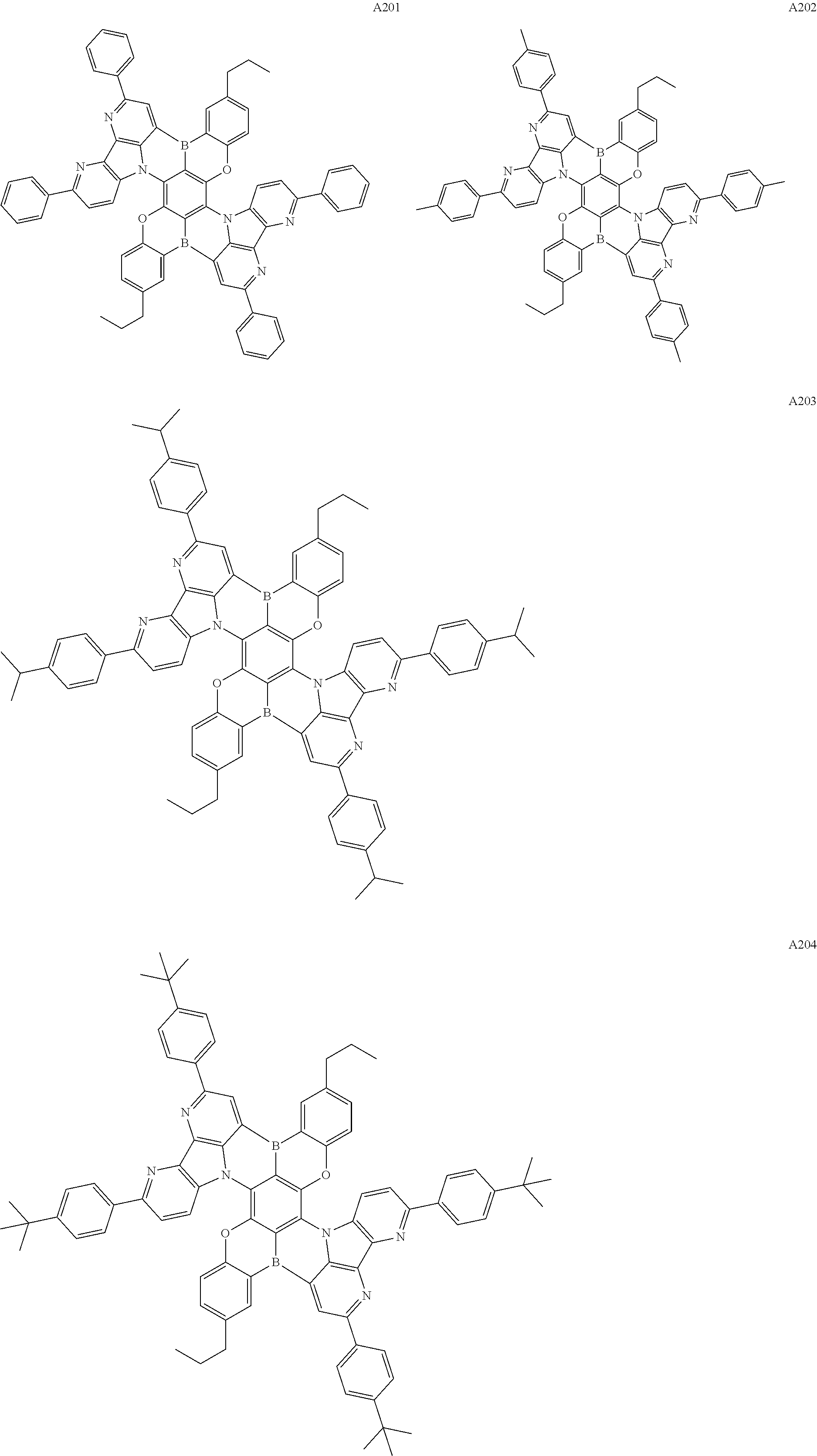

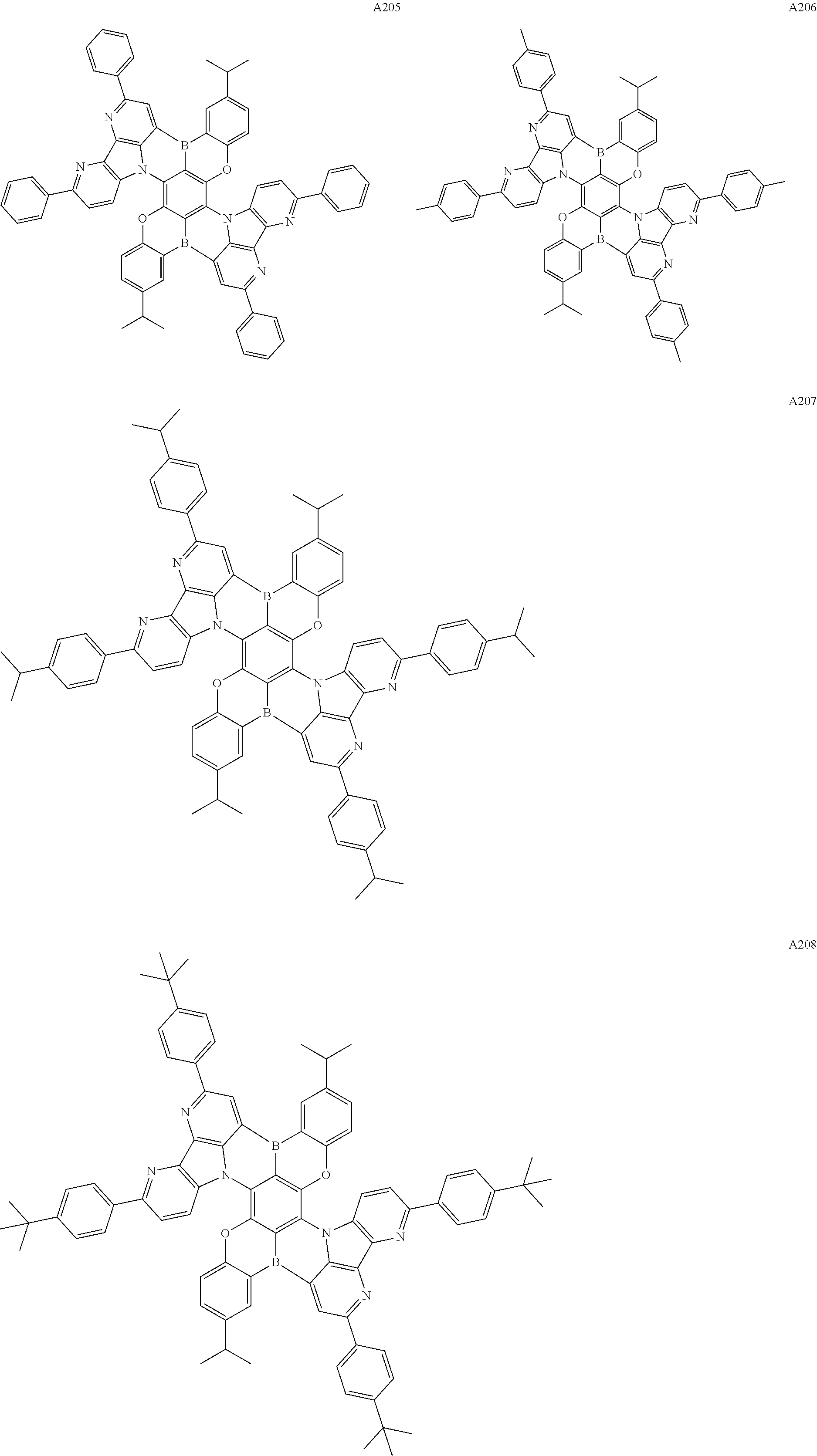

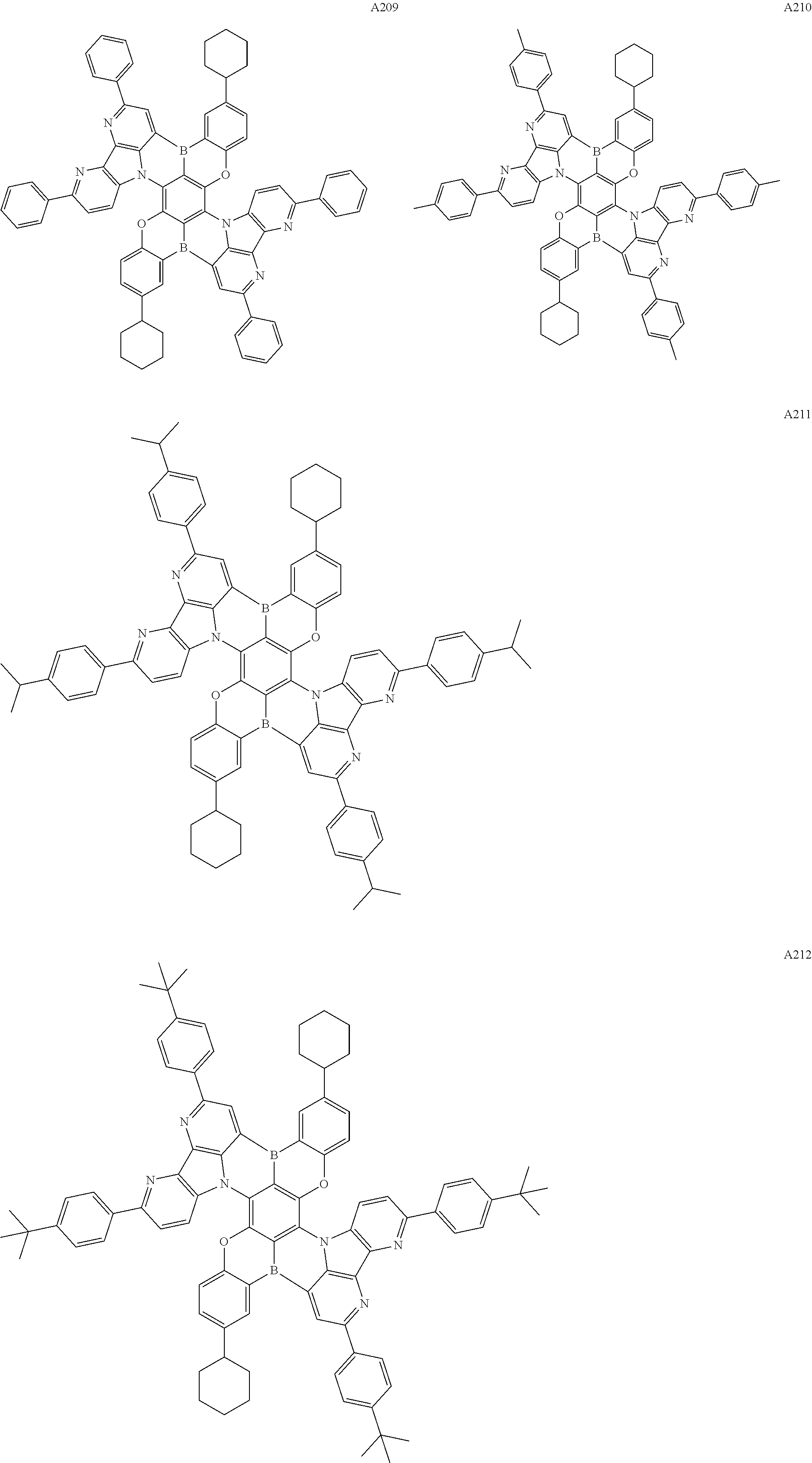

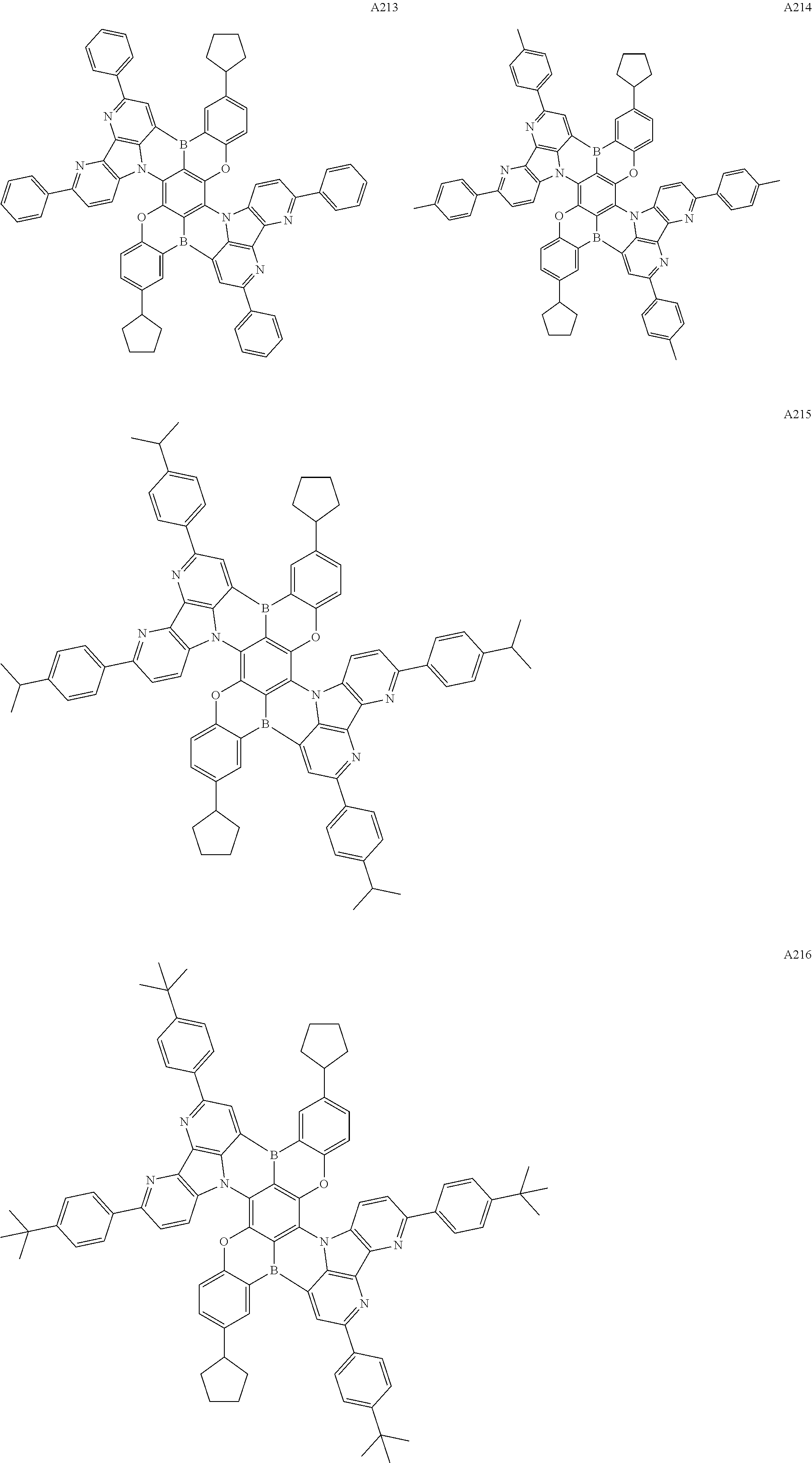

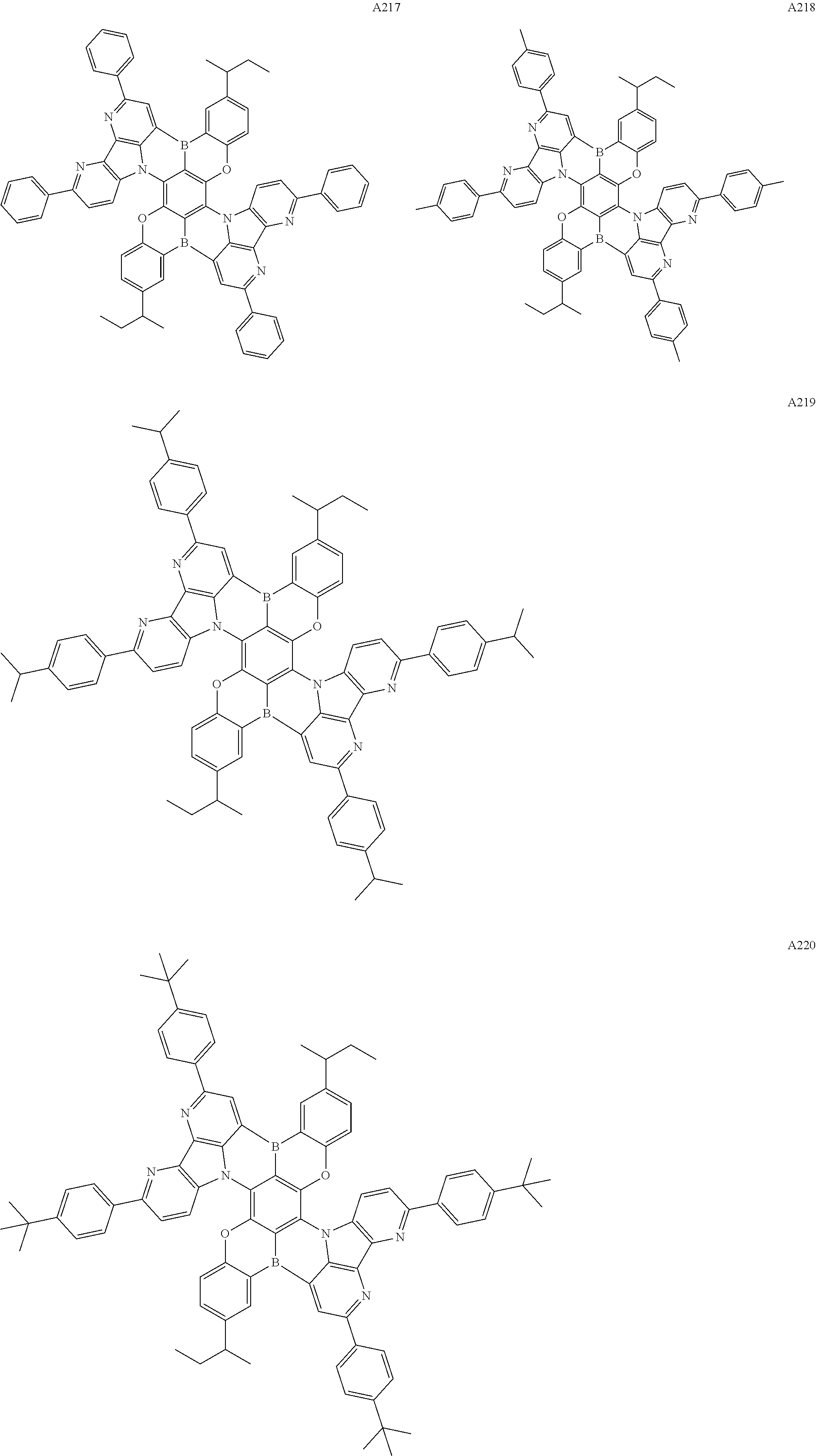

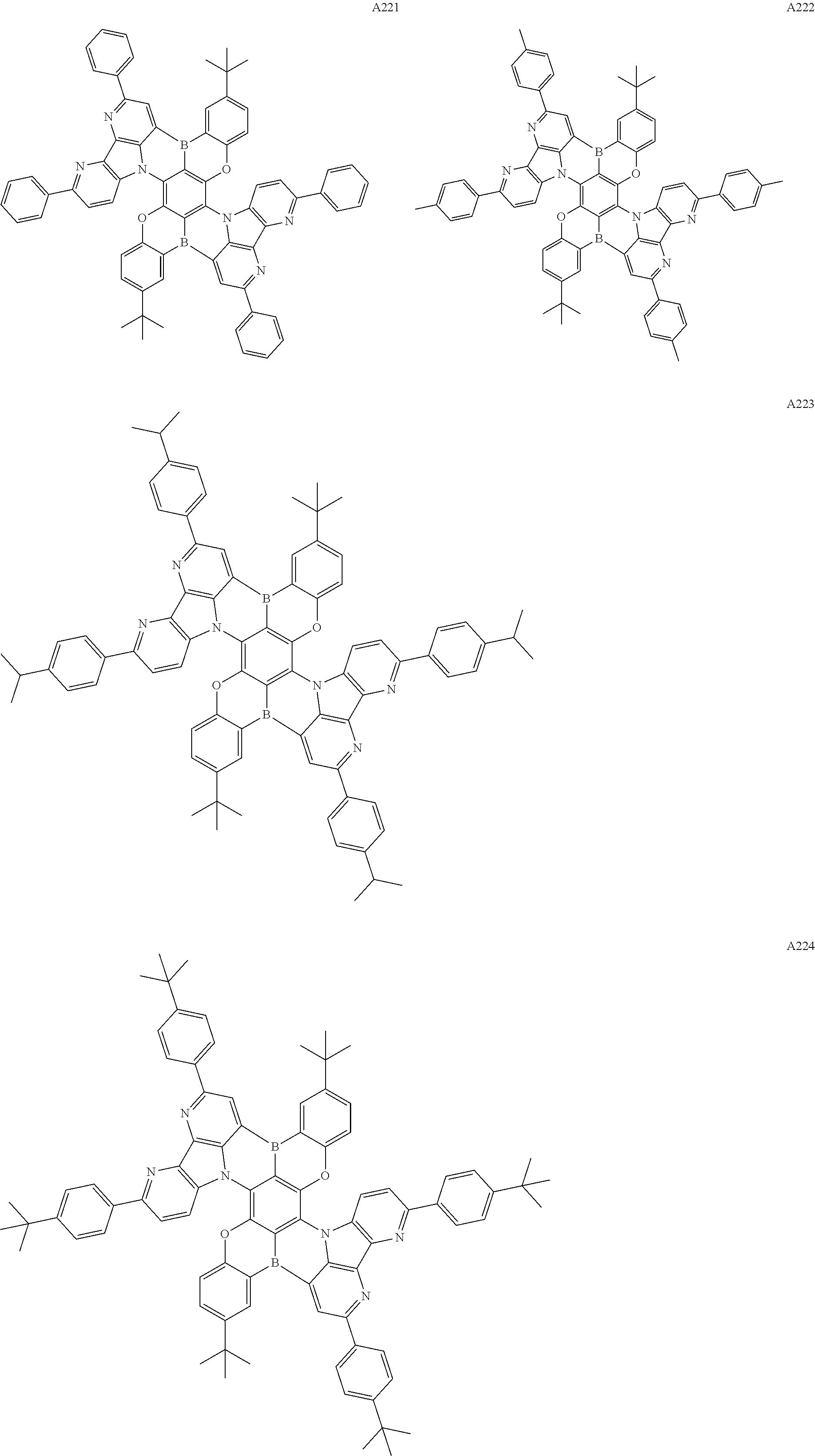

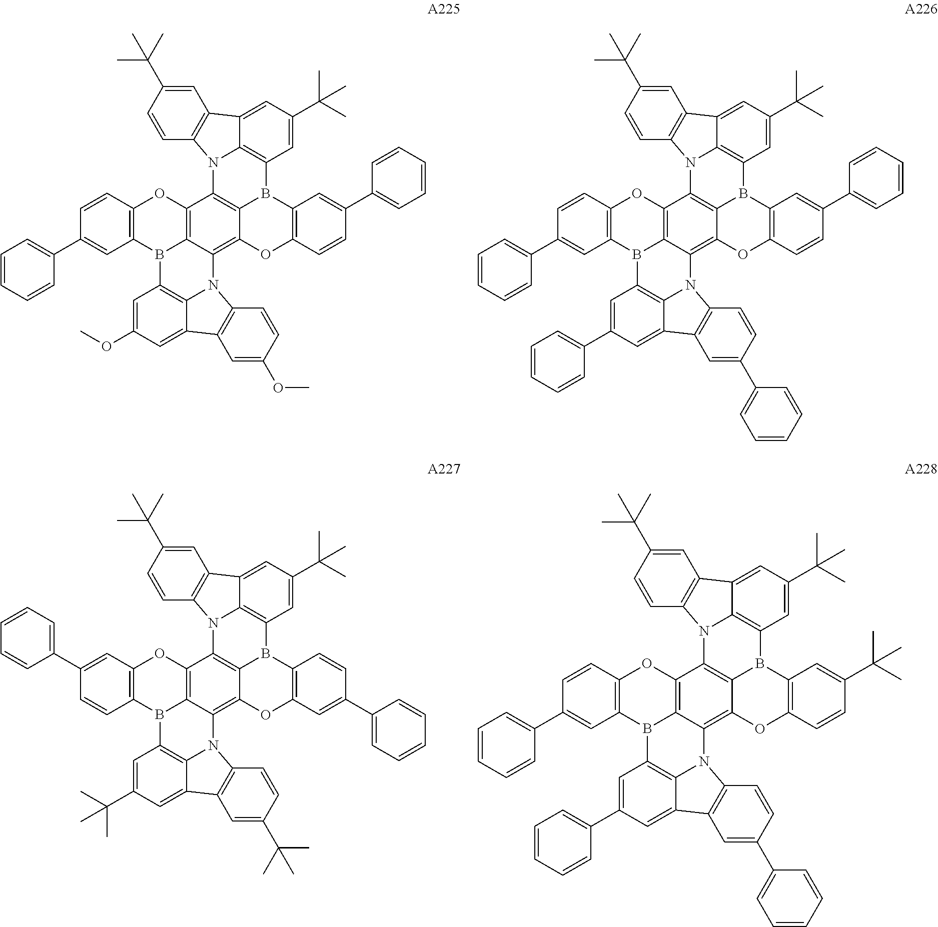

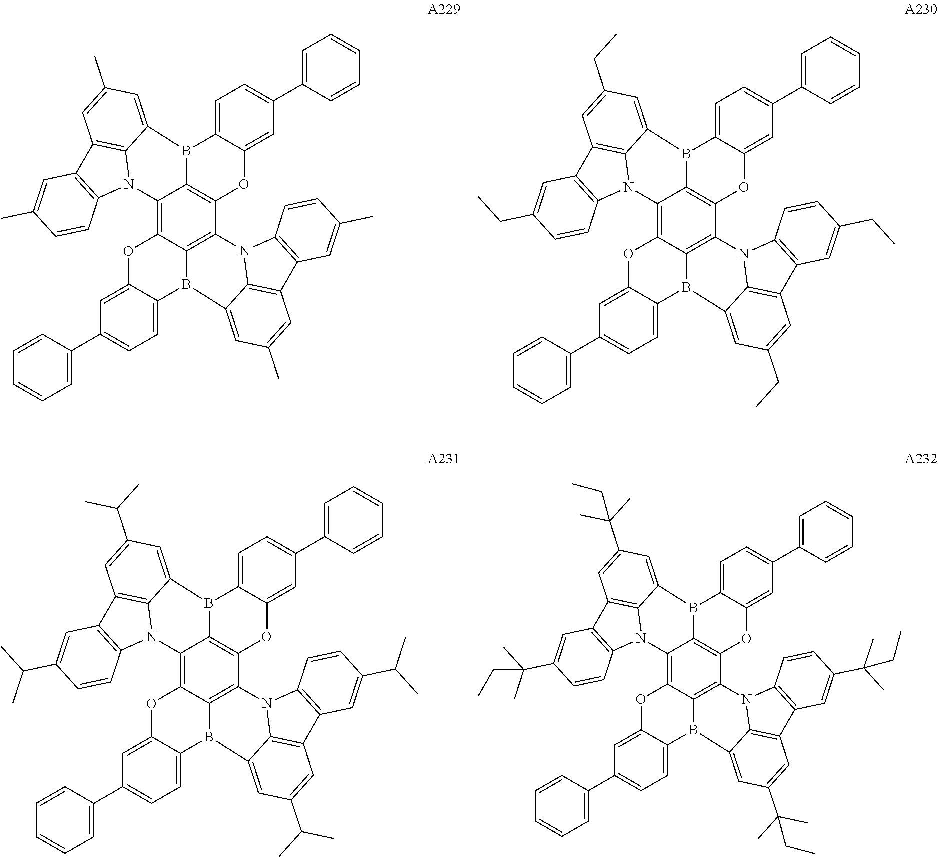

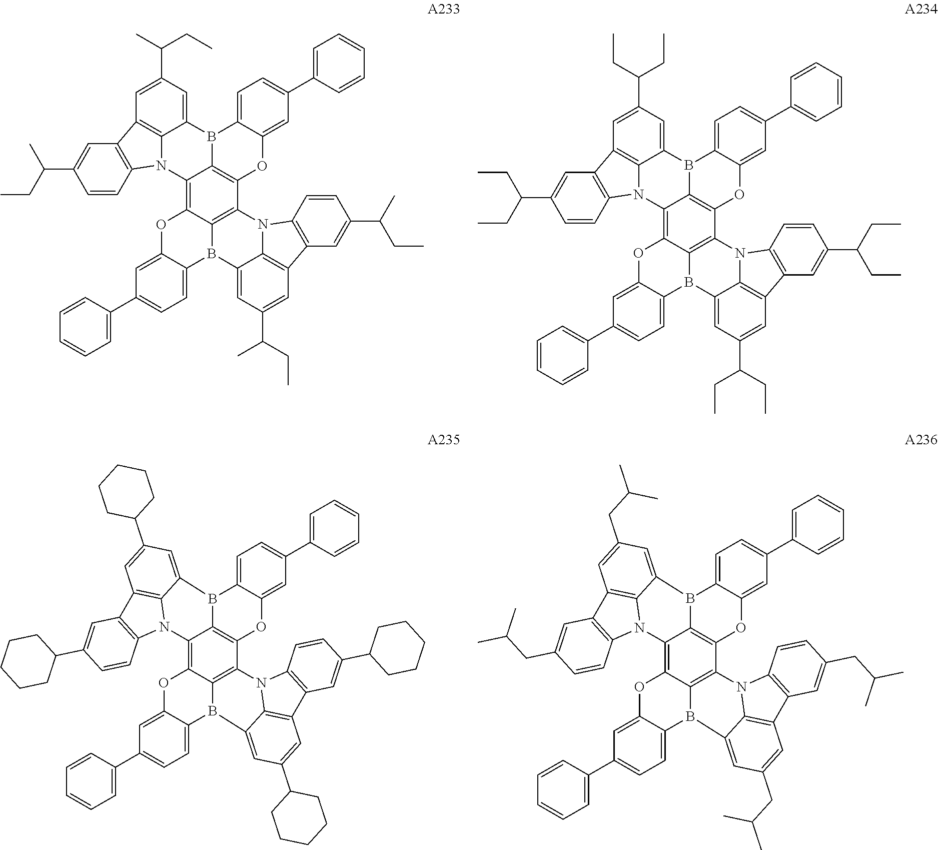

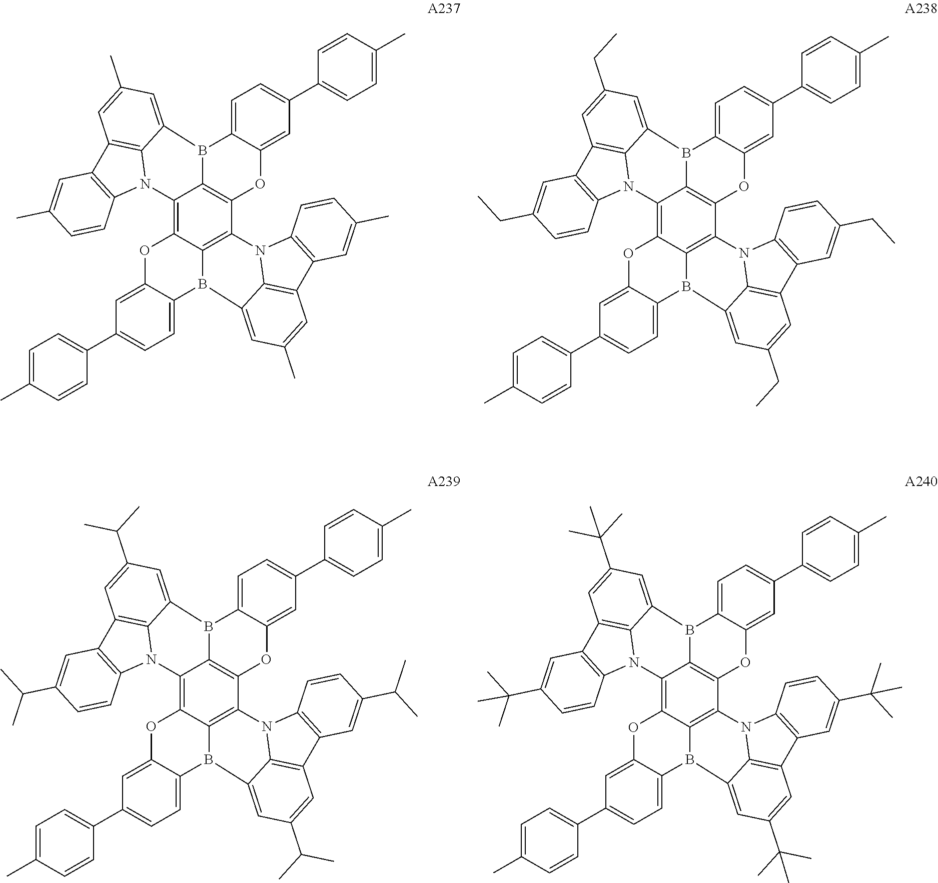

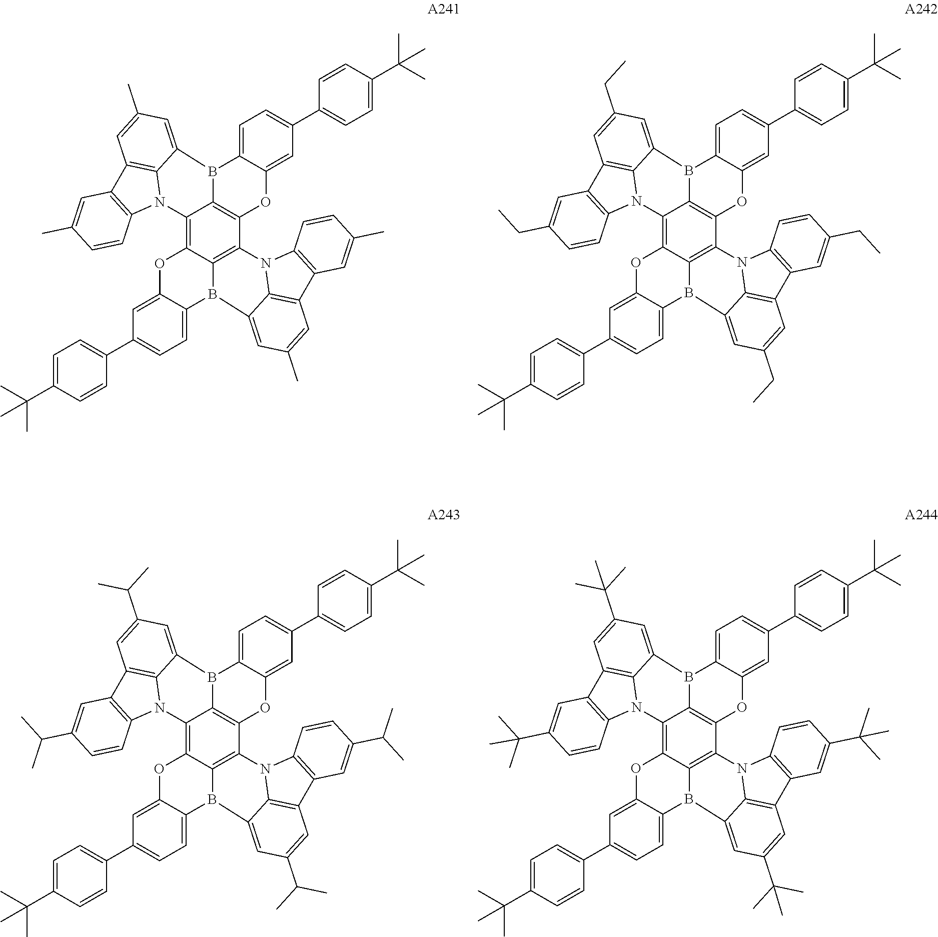

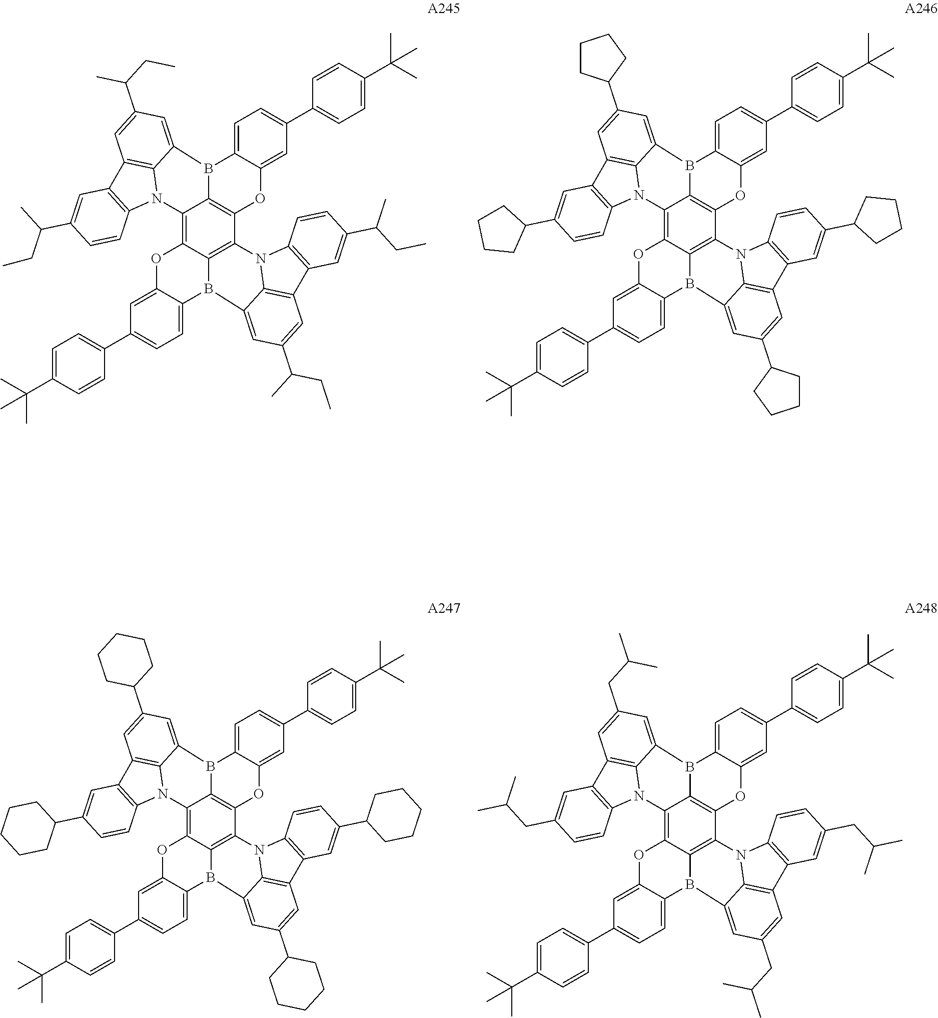

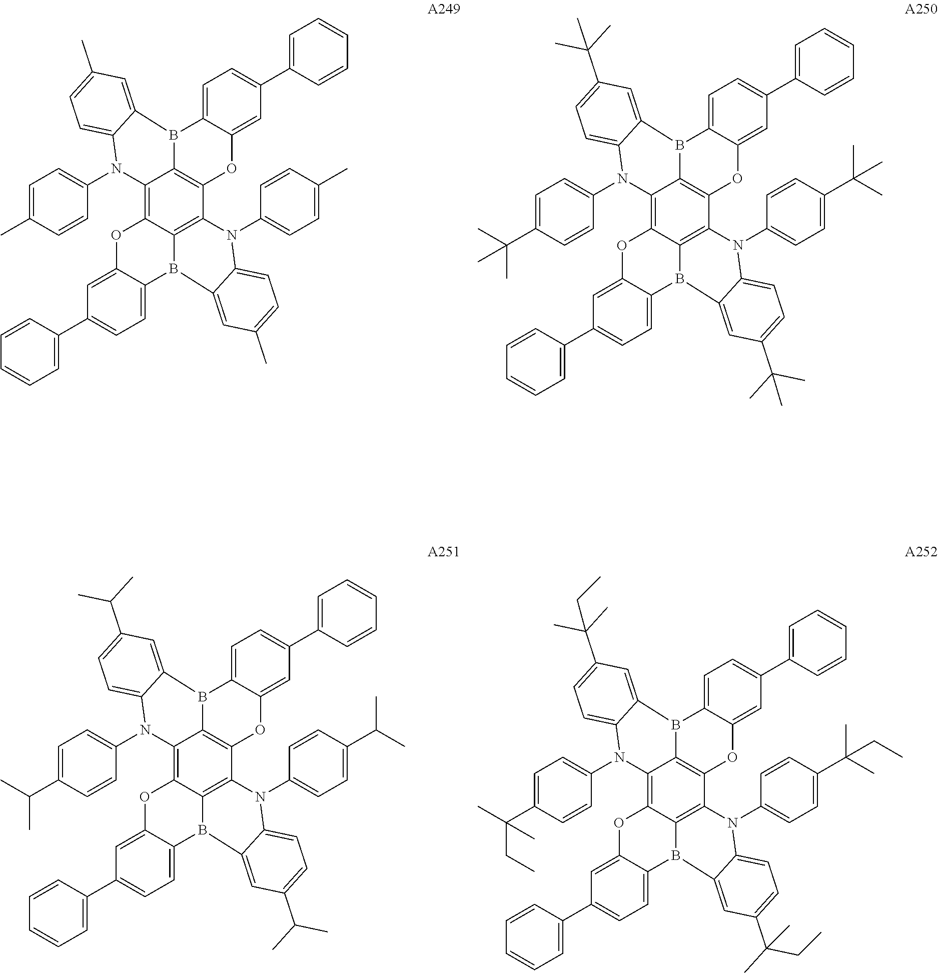

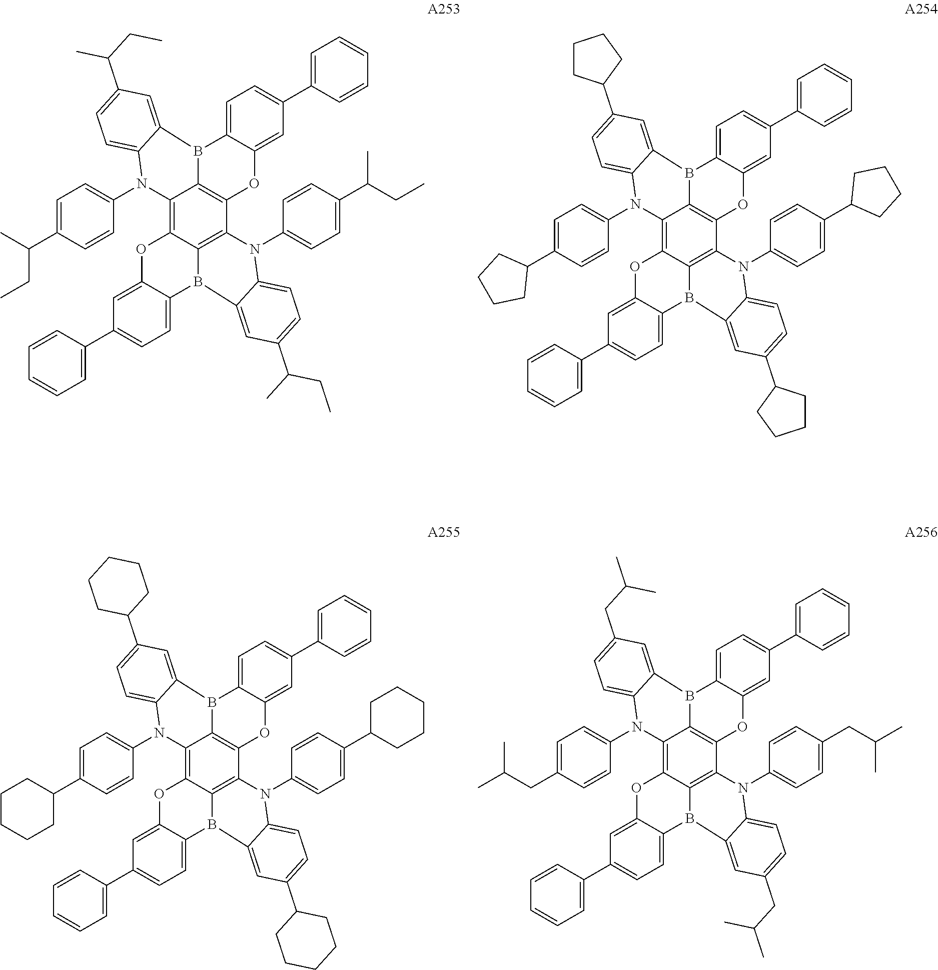

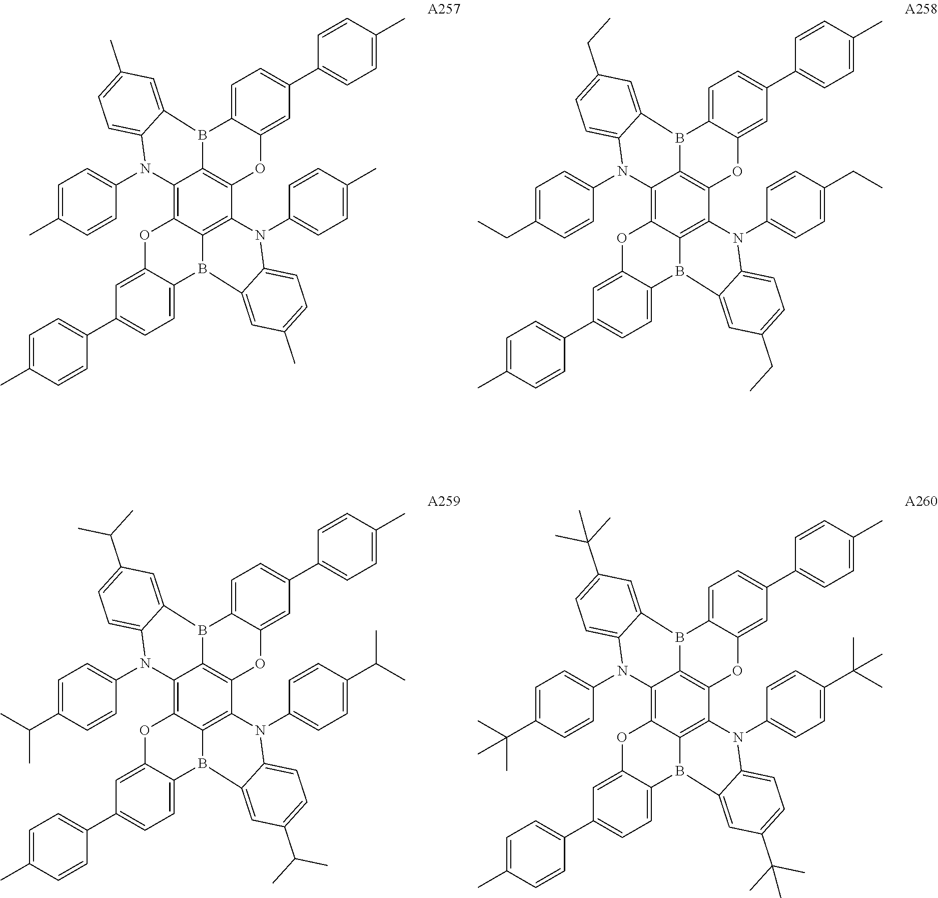

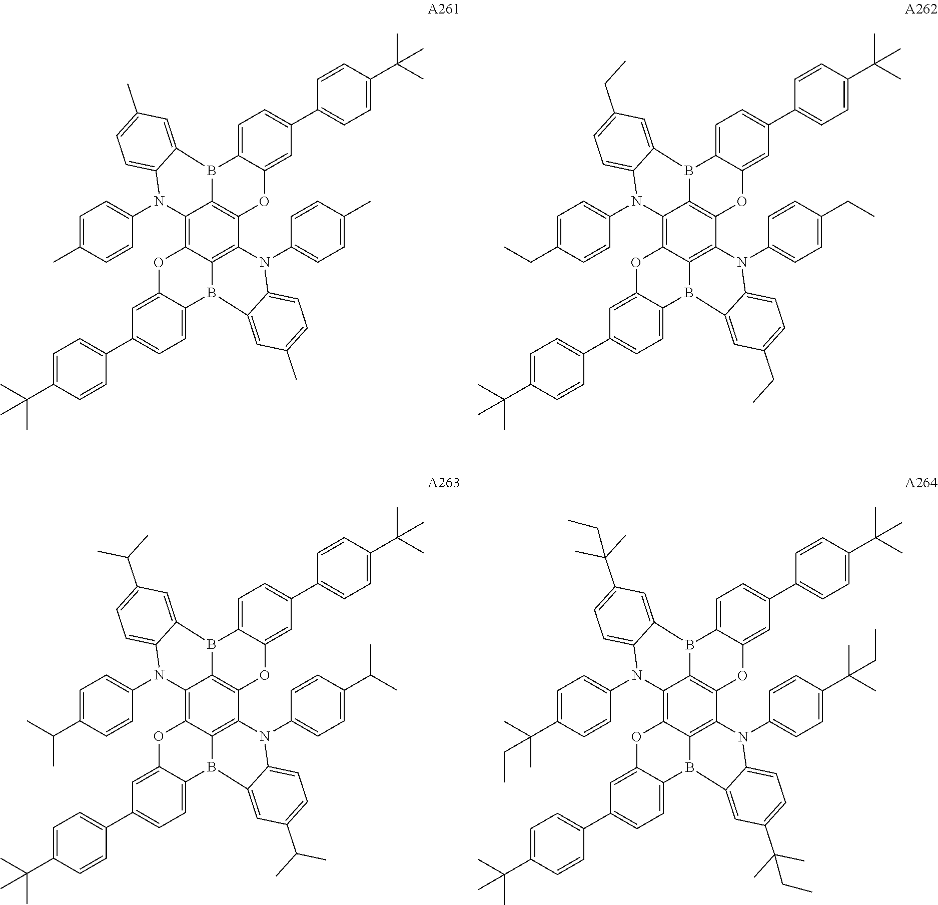

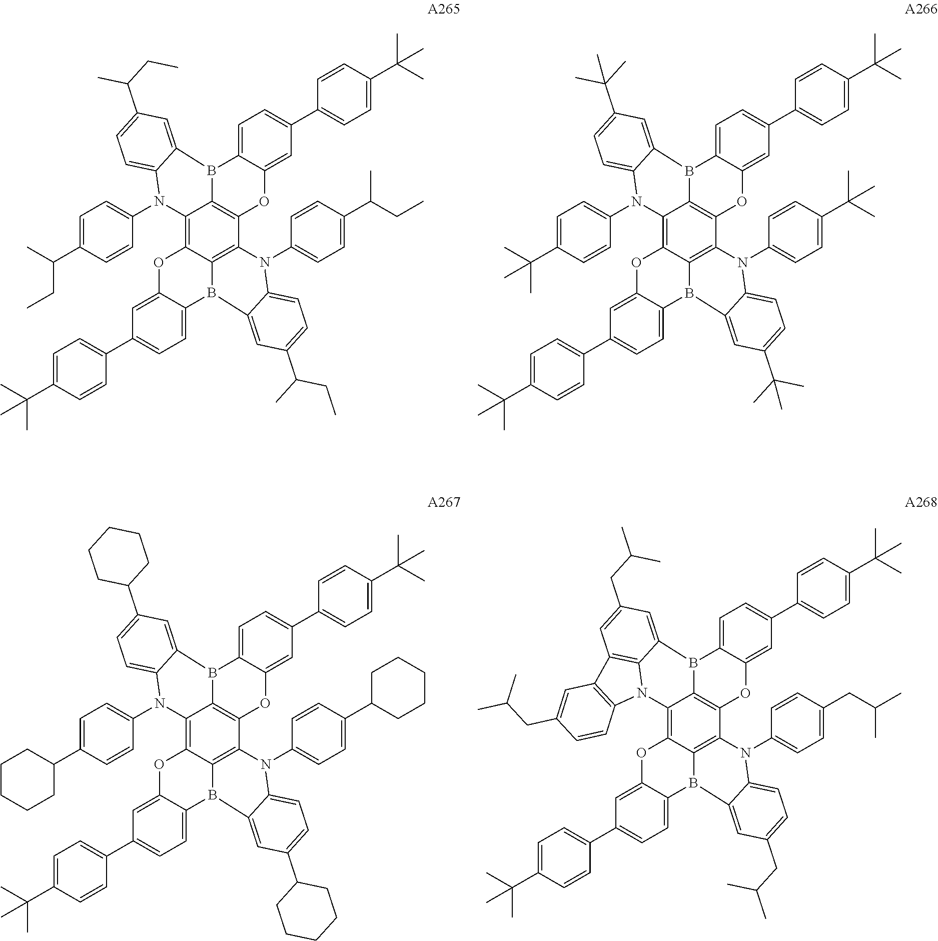

In addition, the host material may include, but is not limited to, one or more of the following compounds PH-1 to PH-85.

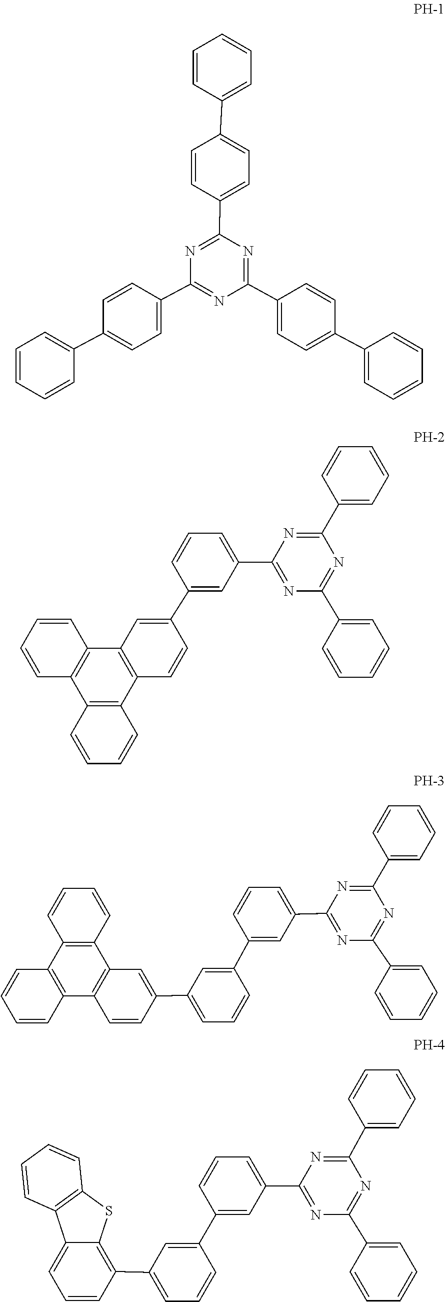 [SMILES: c1ccc(-c2ccc(-c3nc(-c4ccc(-c5ccccc5)cc4)nc(-c4ccc(-c5ccccc5)cc4)n3)cc2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4cccc(-c5cccc6c5sc5ccccc56)c4)c3)n2)cc1]

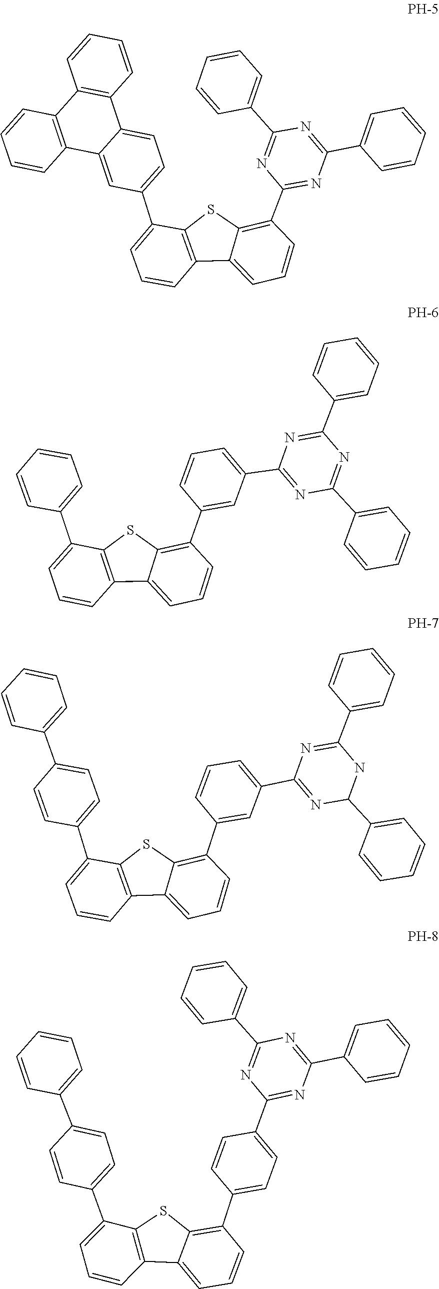

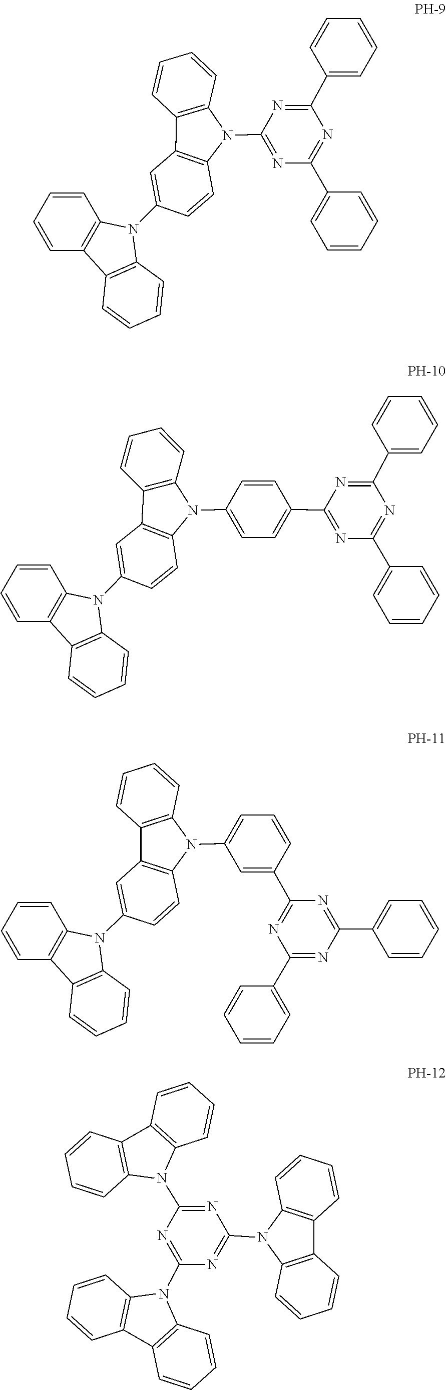 [SMILES: c1ccc(-c2nc(-c3ccccc3)nc(-n3c4ccccc4c4cc(-n5c6ccccc6c6ccccc65)ccc43)n2)cc1 ; c1ccc(-c2nc(-c3ccccc3)nc(-c3ccc(-n4c5ccccc5c5cc(-n6c7ccccc7c7ccccc76)ccc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc2c(c1)c1ccccc1n2-c1nc(-n2c3ccccc3c3ccccc32)nc(-n2c3ccccc3c3ccccc32)n1]

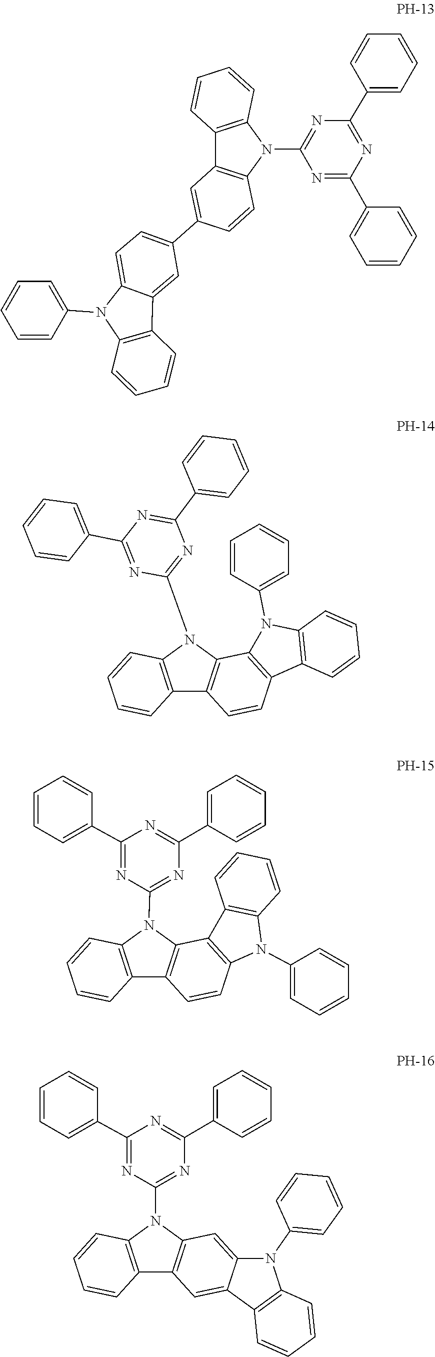 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4cc5c6ccccc6n(-c6ccccc6)c5cc43)n2)cc1]

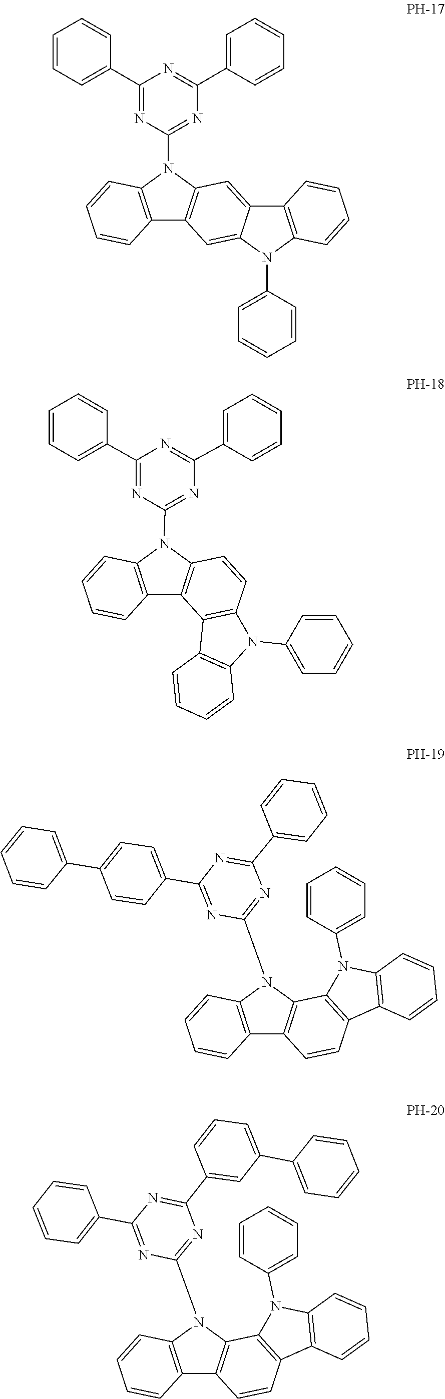

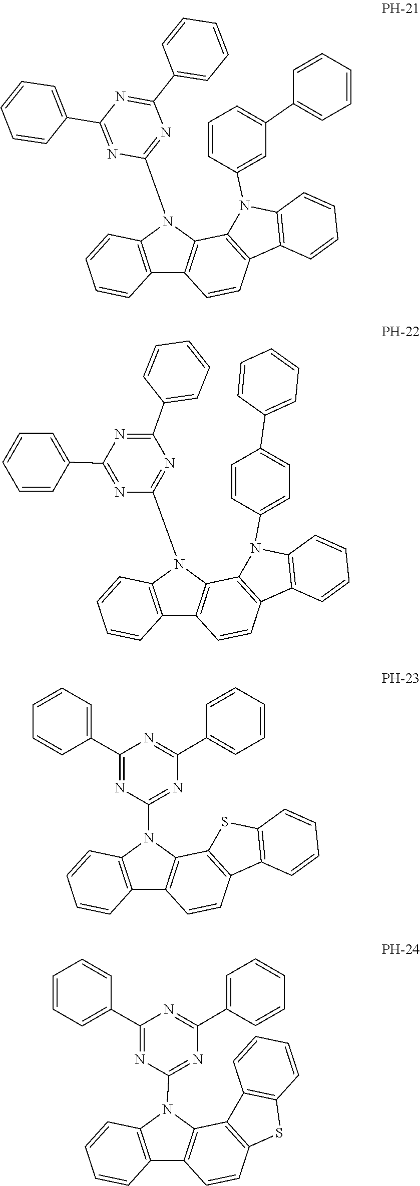 [SMILES: c1ccc(-c2cccc(-n3c4ccccc4c4ccc5c6ccccc6n(-c6nc(-c7ccccc7)nc(-c7ccccc7)n6)c5c43)c2)cc1 ; c1ccc(-c2ccc(-n3c4ccccc4c4ccc5c6ccccc6n(-c6nc(-c7ccccc7)nc(-c7ccccc7)n6)c5c43)cc2)cc1 ; c1ccc(-c2nc(-c3ccccc3)nc(-n3c4ccccc4c4ccc5c6ccccc6sc5c43)n2)cc1 ; c1ccc(-c2nc(-c3ccccc3)nc(-n3c4ccccc4c4ccc5sc6ccccc6c5c43)n2)cc1]

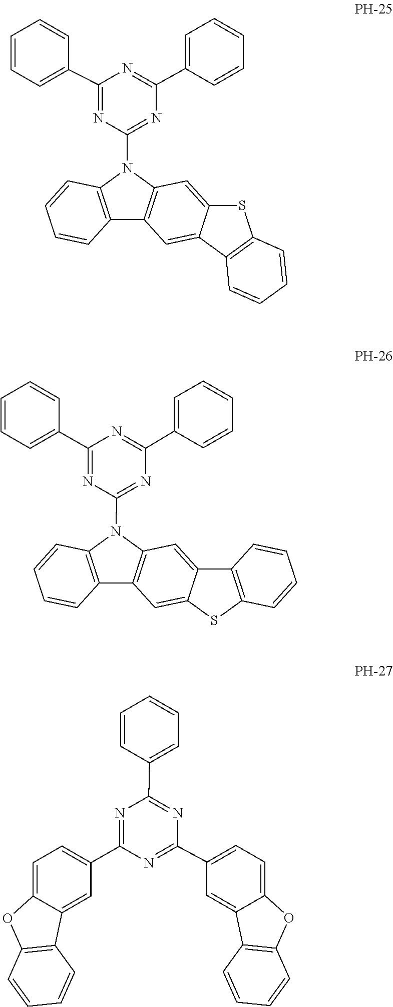 [SMILES: c1ccc(-c2nc(-c3ccccc3)nc(-n3c4ccccc4c4cc5c(cc43)sc3ccccc35)n2)cc1 ; c1ccc(-c2nc(-c3ccccc3)nc(-n3c4ccccc4c4cc5sc6ccccc6c5cc43)n2)cc1 ; c1ccc(-c2nc(-c3ccc4oc5ccccc5c4c3)nc(-c3ccc4oc5ccccc5c4c3)n2)cc1]

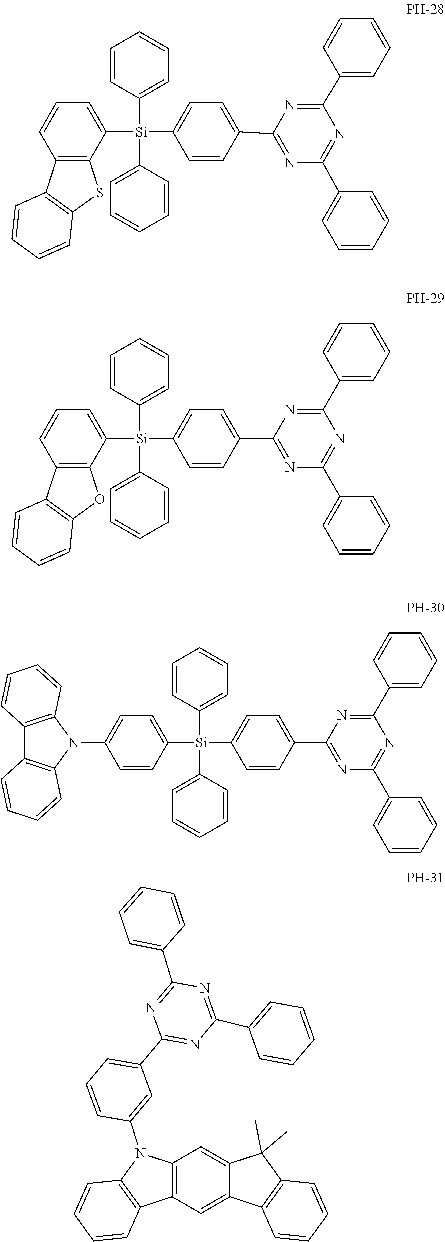 [SMILES: c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; CC1(C)c2ccccc2-c2cc3c4ccccc4n(-c4cccc(-c5nc(-c6ccccc6)nc(-c6ccccc6)n5)c4)c3cc21]

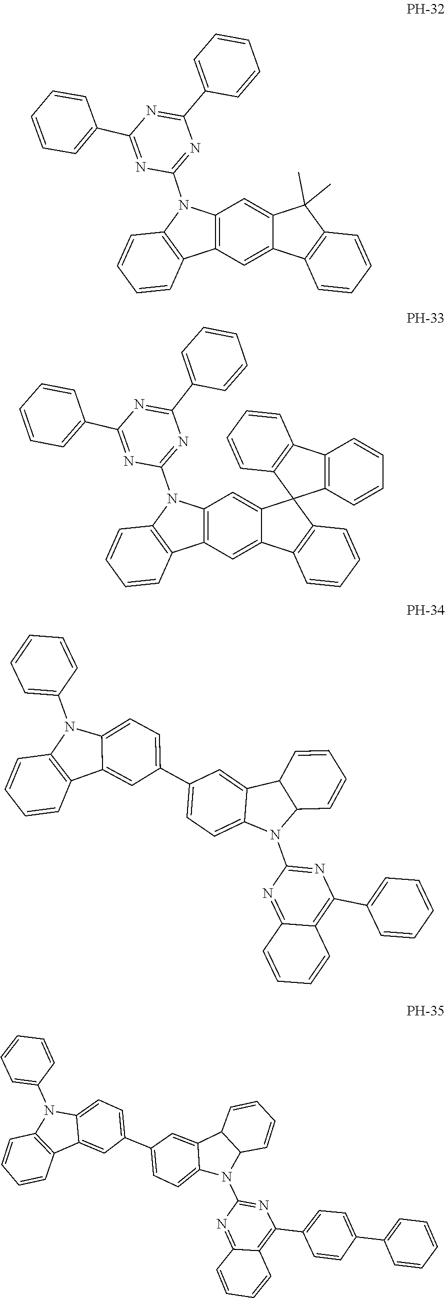 [SMILES: CC1(C)c2ccccc2-c2cc3c4ccccc4n(-c4nc(-c5ccccc5)nc(-c5ccccc5)n4)c3cc21 ; c1ccc(-c2nc(-c3ccccc3)nc(-n3c4ccccc4c4cc5c(cc43)C3(c4ccccc4-c4ccccc43)c3ccccc3-5)n2)cc1 ; C1=CC2c3cc(-c4ccc5c(c4)c4ccccc4n5-c4ccccc4)ccc3N(c3nc(-c4ccccc4)c4ccccc4n3)C2C=C1 ; C1=CC2c3cc(-c4ccc5c(c4)c4ccccc4n5-c4ccccc4)ccc3N(c3nc(-c4ccc(-c5ccccc5)cc4)c4ccccc4n3)C2C=C1]

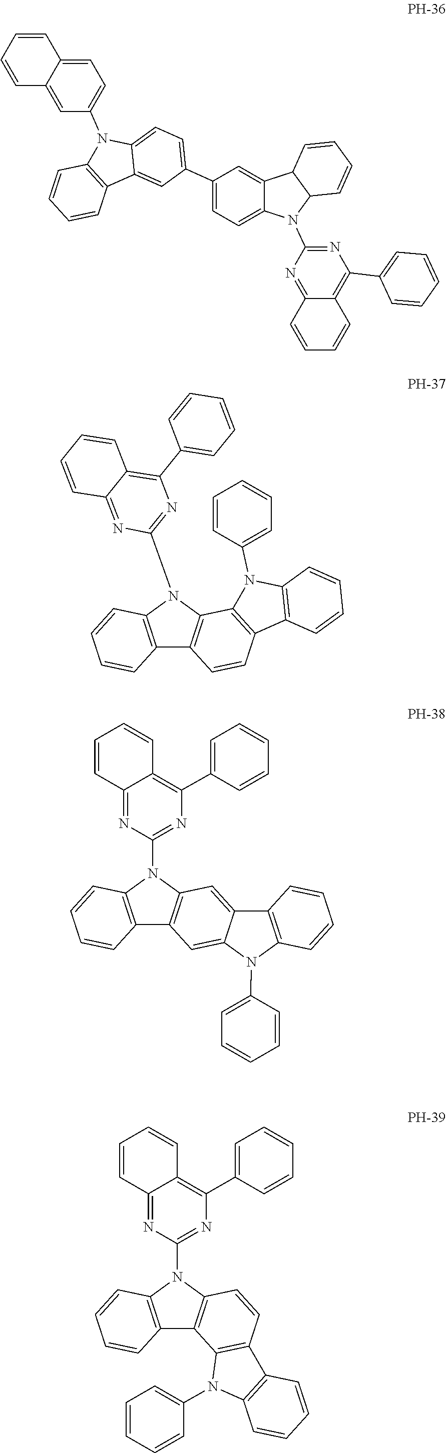 [SMILES: C1=CC2c3cc(-c4ccc5c(c4)c4ccccc4n5-c4ccc5ccccc5c4)ccc3N(c3nc(-c4ccccc4)c4ccccc4n3)C2C=C1 ; c1ccc(-c2nc(-n3c4ccccc4c4ccc5c6ccccc6n(-c6ccccc6)c5c43)nc3ccccc23)cc1 ; c1ccc(-c2nc(-n3c4ccccc4c4cc5c(cc43)c3ccccc3n5-c3ccccc3)nc3ccccc23)cc1 ; c1ccc(-c2nc(-n3c4ccccc4c4c3ccc3c5ccccc5n(-c5ccccc5)c34)nc3ccccc23)cc1]

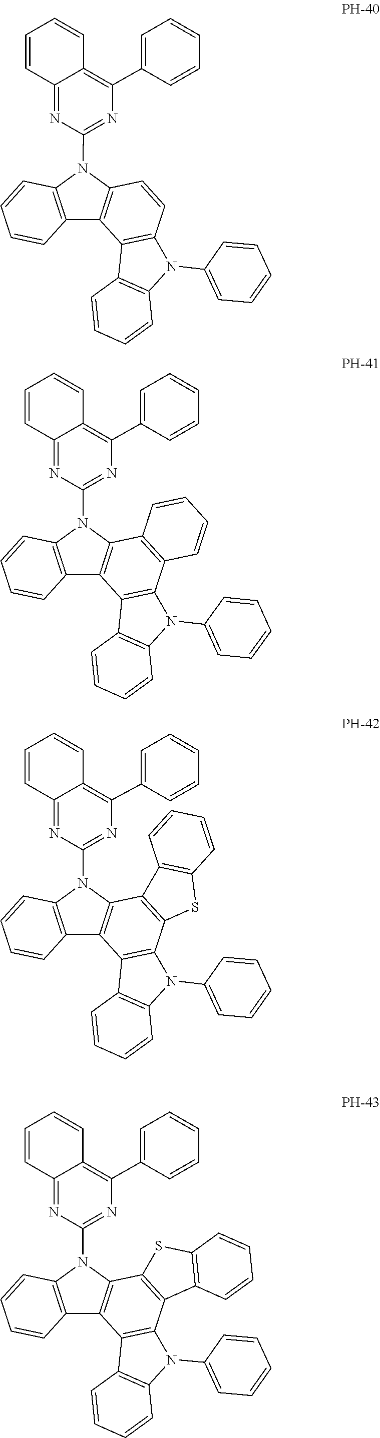 [SMILES: c1ccc(-c2nc(-n3c4ccccc4c4c5c6ccccc6n(-c6ccccc6)c5ccc43)nc3ccccc23)cc1 ; c1ccc(-c2nc(-n3c4ccccc4c4c5c6ccccc6n(-c6ccccc6)c5c5ccccc5c43)nc3ccccc23)cc1 ; c1ccc(-c2nc(-n3c4ccccc4c4c5c6ccccc6n(-c6ccccc6)c5c5sc6ccccc6c5c43)nc3ccccc23)cc1 ; c1ccc(-c2nc(-n3c4ccccc4c4c5c6ccccc6n(-c6ccccc6)c5c5c6ccccc6sc5c43)nc3ccccc23)cc1]

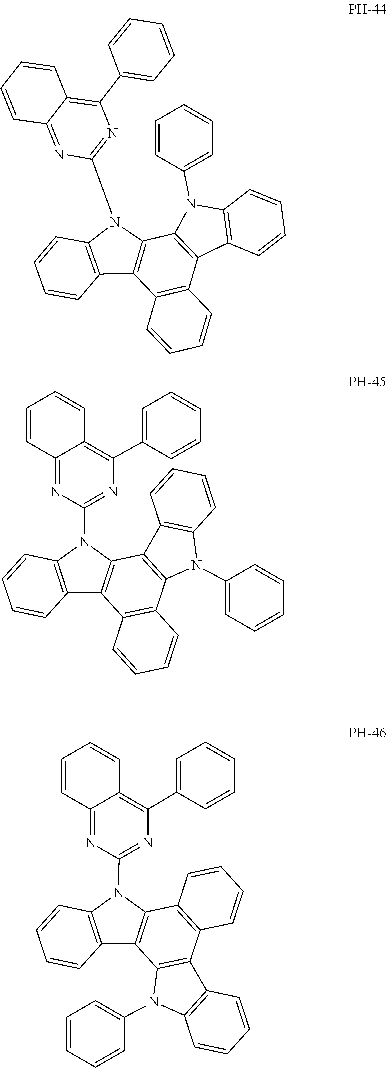

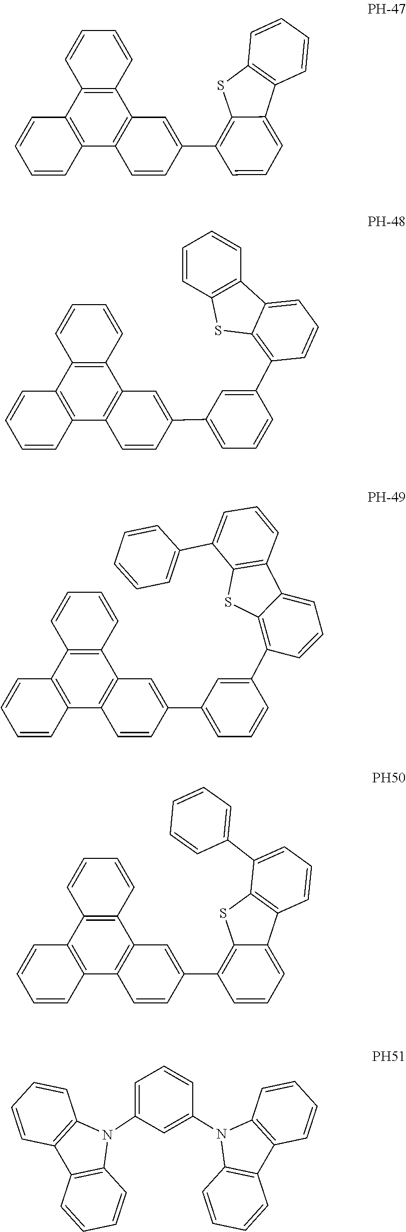 [SMILES: c1ccc2c(c1)sc1c(-c3ccc4c5ccccc5c5ccccc5c4c3)cccc12 ; c1cc(-c2ccc3c4ccccc4c4ccccc4c3c2)cc(-c2cccc3c2sc2ccccc23)c1 ; c1ccc(-c2cccc3c2sc2c(-c4cccc(-c5ccc6c7ccccc7c7ccccc7c6c5)c4)cccc23)cc1 ; c1ccc(-c2cccc3c2sc2c(-c4ccc5c6ccccc6c6ccccc6c5c4)cccc23)cc1 ; c1cc(-n2c3ccccc3c3ccccc32)cc(-n2c3ccccc3c3ccccc32)c1]

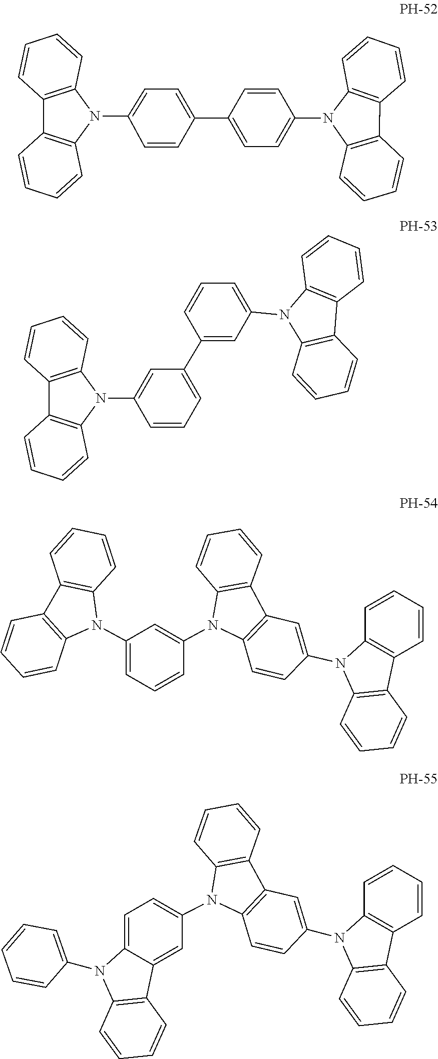 [SMILES: c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1 ; c1cc(-n2c3ccccc3c3ccccc32)cc(-n2c3ccccc3c3cc(-n4c5ccccc5c5ccccc54)ccc32)c1 ; c1ccc(-n2c3ccccc3c3cc(-n4c5ccccc5c5cc(-n6c7ccccc7c7ccccc76)ccc54)ccc32)cc1]

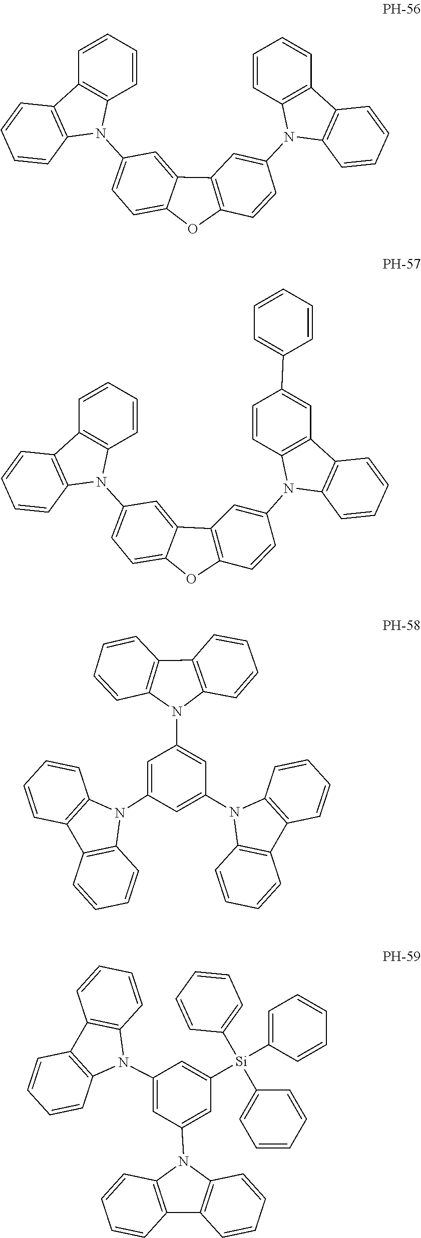 [SMILES: c1ccc2c(c1)c1ccccc1n2-c1ccc2oc3ccc(-n4c5ccccc5c5ccccc54)cc3c2c1 ; c1ccc(-c2ccc3c(c2)c2ccccc2n3-c2ccc3oc4ccc(-n5c6ccccc6c6ccccc65)cc4c3c2)cc1 ; c1ccc2c(c1)c1ccccc1n2-c1cc(-n2c3ccccc3c3ccccc32)cc(-n2c3ccccc3c3ccccc32)c1 ; c1ccc([Si](c2ccccc2)(c2ccccc2)c2cc(-n3c4ccccc4c4ccccc43)cc(-n3c4ccccc4c4ccccc43)c2)cc1]

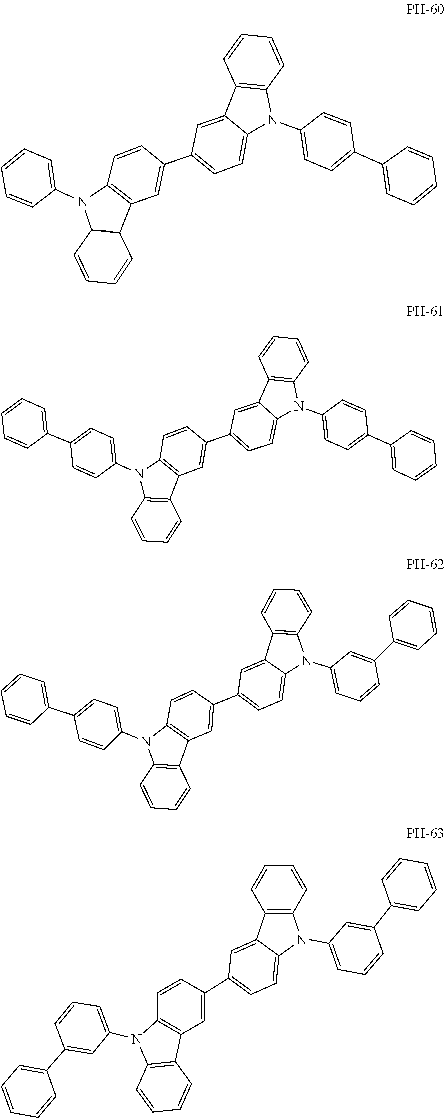 [SMILES: C1=CC23CC2(C=C1)N(c1ccccc1)c1ccc(-c2ccc4c(c2)c2ccccc2n4-c2ccc(-c4ccccc4)cc2)cc13 ; c1ccc(-c2ccc(-n3c4ccccc4c4cc(-c5ccc6c(c5)c5ccccc5n6-c5ccc(-c6ccccc6)cc5)ccc43)cc2)cc1 ; C1=Cc2c(n(-c3cccc(-c4ccccc4)c3)c3ccc(-c4ccc5c(c4)c4ccccc4n5-c4ccc(-c5ccccc5)cc4)cc23)C=CC1 ; c1ccc(-c2cccc(-n3c4ccccc4c4cc(-c5ccc6c(c5)c5ccccc5n6-c5cccc(-c6ccccc6)c5)ccc43)c2)cc1]

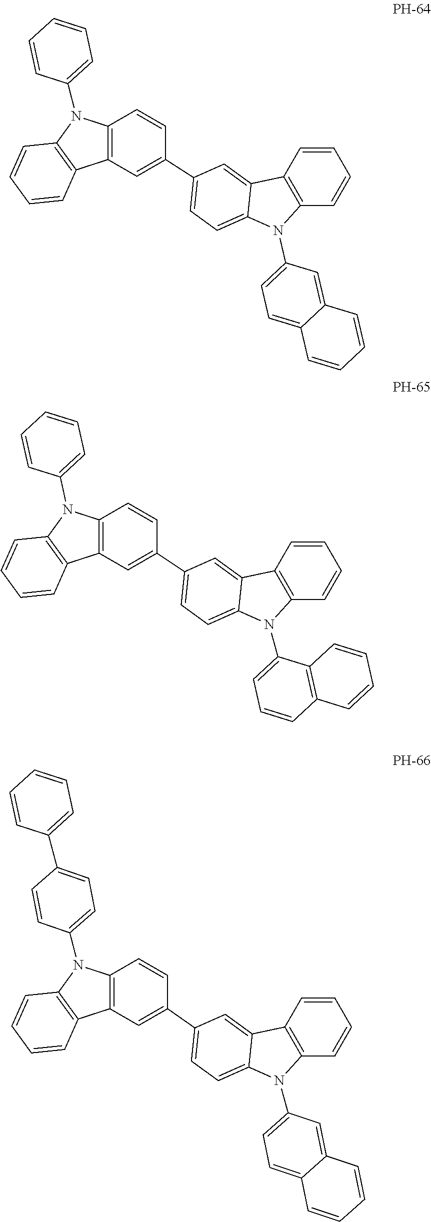 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccc6ccccc6c5)ccc43)cc2)cc1]

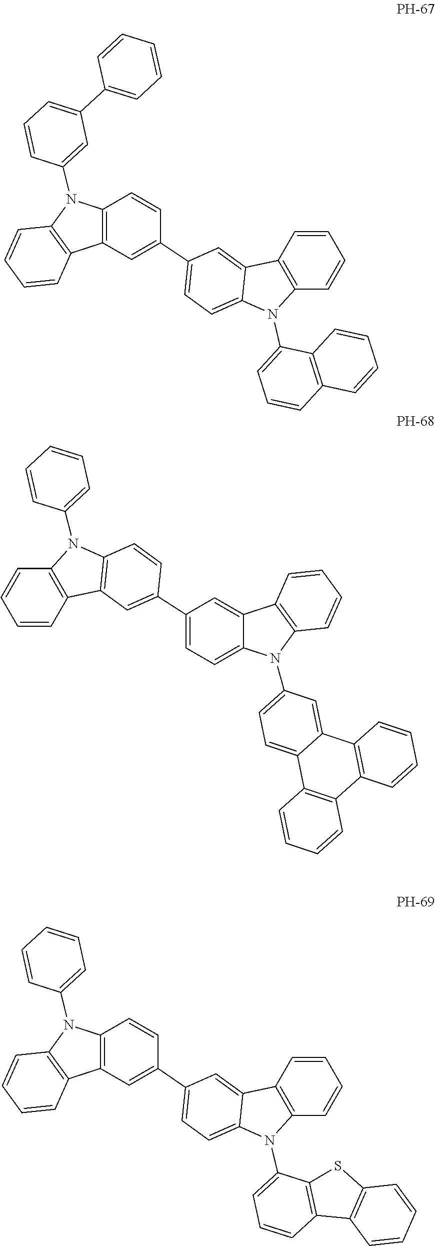 [SMILES: c1ccc(-c2cccc(-n3c4ccccc4c4cc(-c5ccc6c(c5)c5ccccc5n6-c5cccc6ccccc56)ccc43)c2)cc1 ; c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4cccc5c4sc4ccccc45)ccc32)cc1]

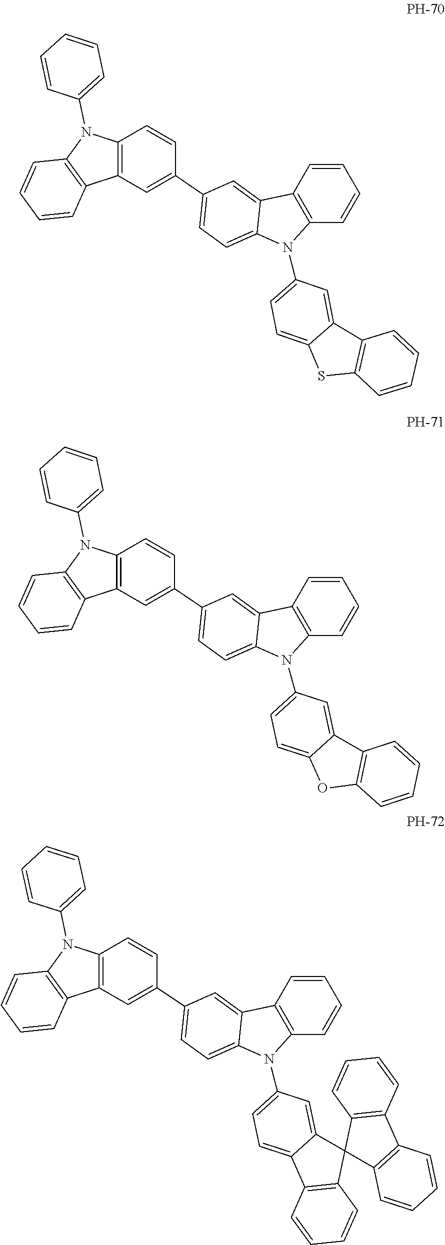 [SMILES: c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]

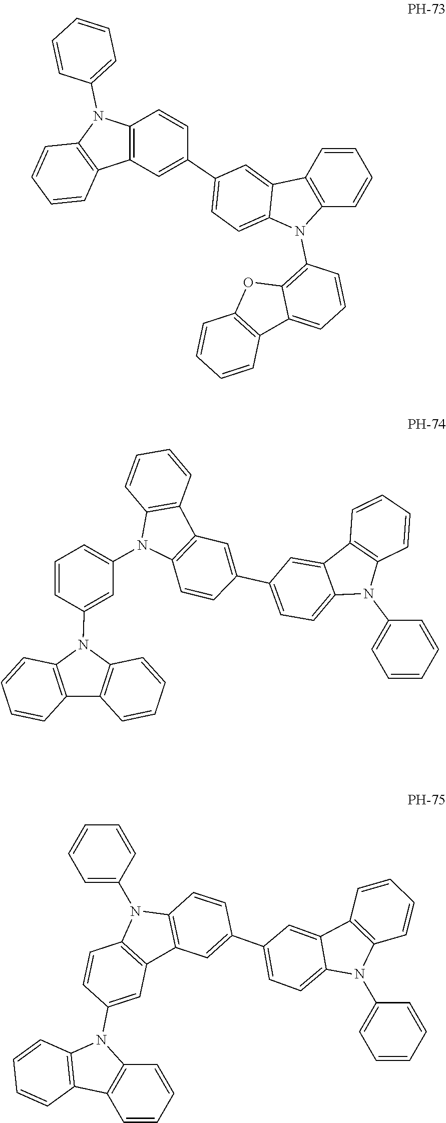 [SMILES: c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1]

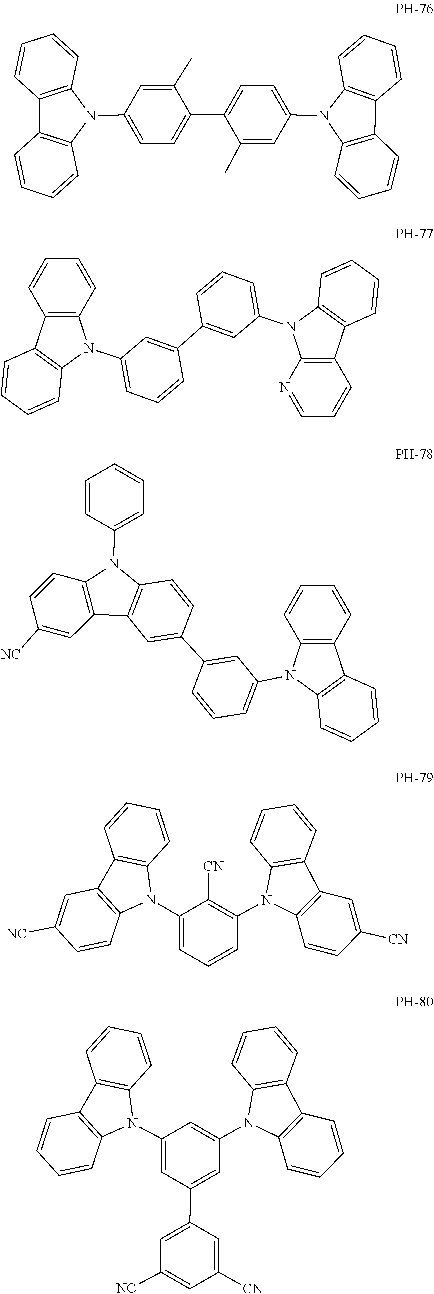 [SMILES: Cc1cc(-n2c3ccccc3c3ccccc32)ccc1-c1ccc(-n2c3ccccc3c3ccccc32)cc1C ; c1cc(-c2cccc(-n3c4ccccc4c4cccnc43)c2)cc(-n2c3ccccc3c3ccccc32)c1 ; N#Cc1ccc2c(c1)c1cc(-c3cccc(-n4c5ccccc5c5ccccc54)c3)ccc1n2-c1ccccc1 ; N#Cc1ccc2c(c1)c1ccccc1n2-c1cccc(-n2c3ccccc3c3cc(C#N)ccc32)c1C#N ; N#Cc1cc(C#N)cc(-c2cc(-n3c4ccccc4c4ccccc43)cc(-n3c4ccccc4c4ccccc43)c2)c1]

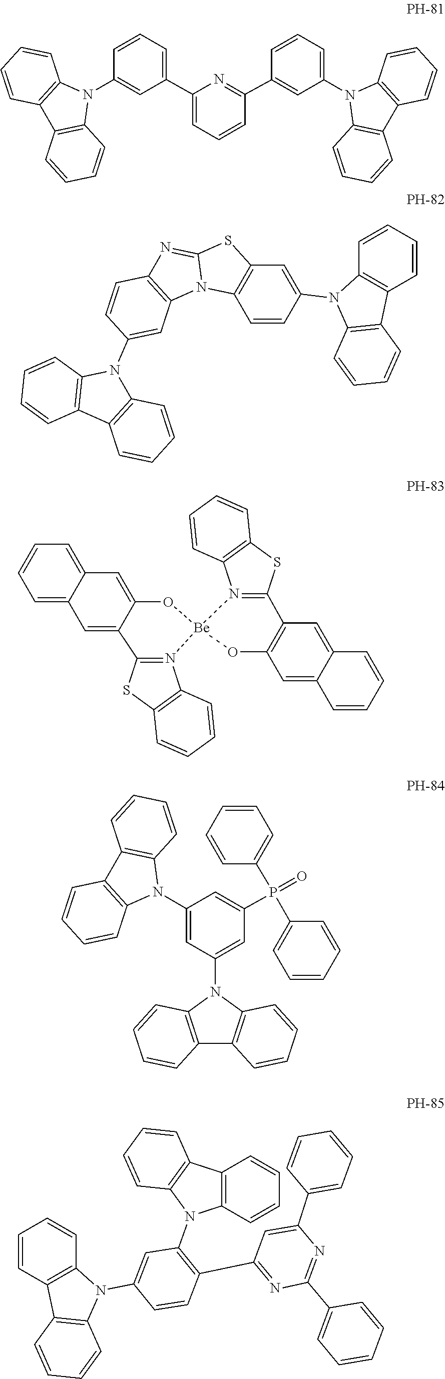

In addition, the phosphorescent sensitizer includes, but is not limited to, one or more of the following compounds RPD-1 to RPD-29:

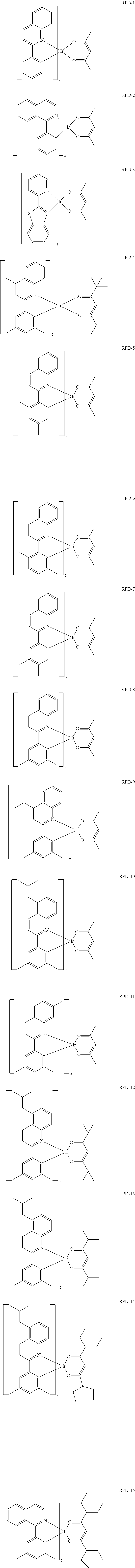

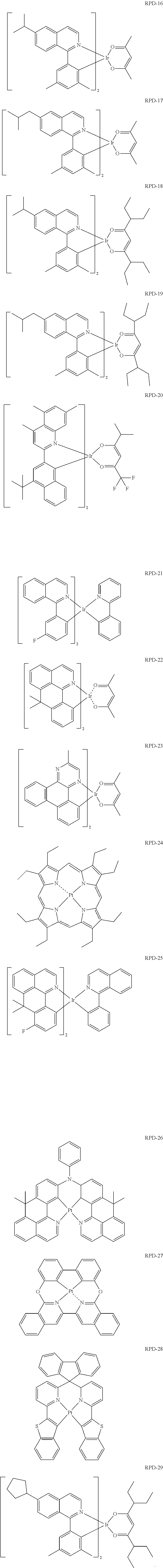

Studies have shown that comparatively, using one or more of the compounds PH-1 to PH-85 as a host material and one or more of RPD-1 to RPD-29 as a phosphorescent sensitizer is more conducive to the cooperation with the narrow-spectrum fluorescent material described above, thereby further improving the performance such as efficiency and service life of the device.

Generally, in the phosphorescence sensitized layer, the mass content of the phosphorescent sensitizer is 0.1-50%, for example, 0.1%, 3%, 5%, 8%, 10%, 12%, 15%, 18%, 20%, 25%, 30%, 35%, 40%, 45%, and 50%; the mass content of the narrow-spectrum fluorescent material is 0.1-30%, for example 0.1%, 0.3%, 0.5%, 0.8%, 1%, 1.5%, 2%, 2.5%, 3%, 4%, 5%, 6%, 7%, 8%, 9%, 10%, 12%, 15%, 18%, 20%, 25%, and 30%; and the rest is the host material.

Preferably, in the phosphorescence sensitized layer, the mass content of the phosphorescent sensitizer is 0.1-15%, more preferably not more than 10%, for example 1-10%, which is conducive to further improving the performance such as efficiency and service life of the organic light-emitting diode.

Preferably, in the phosphorescence sensitized layer, the mass content of the narrow-spectrum fluorescent material is 0.1-5%, more preferably 0.5-2%, which is conducive to further improving the performance, such as efficiency and service life of the organic light-emitting diode.

The organic light-emitting diode further includes an anode, a hole transport zone, an electron transport zone, and a cathode, and the light-emitting layer, the hole transport zone and the electron transport zone are placed between the anode and the cathode.

Specifically, as shown in FIG. 1, the organic light-emitting diode may be a single-layer device (or referred to as a single-light-emitting-layer device), that is, the device has one light-emitting layer, and the anode, hole transport zone, light-emitting layer, electron transport zone, and cathode are stacked sequentially.

In one embodiment, as shown in FIG. 2, the organic light-emitting diode is a stacked-layer device, which further includes a charge generation layer (CGL) provided between the anode and the cathode and has at least two light-emitting layers. The at least two light-emitting layers are stacked (or referred to as “piled”), specifically sequentially stacked in the direction from the anode to the cathode, and the charge generation layer is provided between two adjacent light-emitting layers (that is, a charge generation layer is provided between every two adjacent light-emitting layers).

Herein, at least one light-emitting layer is a phosphorescence sensitized layer containing a host material, a phosphorescent sensitizer and a narrow-spectrum fluorescent material described above, and the remaining light-emitting layers may also be the phosphorescence sensitized layers above, or phosphorescence layers including a host material and a phosphorescent material except for a narrow-spectrum fluorescent material described above.

When the organic light-emitting diode contains both a phosphorescence sensitized layer and a phosphorescence layer, the host material in the phosphorescence layer may be the same or different from that in the phosphorescence sensitized layer, and the phosphorescent material in the phosphorescence layer may be the same or different from the phosphorescent sensitizer in the phosphorescence sensitized layer. When the light-emitting layers of the organic light-emitting diode are all phosphorescence sensitized layers, the host materials, the phosphorescent sensitizers, and the narrow-spectrum fluorescent materials in different light-emitting layers may be the same or different

For example, the organic light-emitting diode may be a red stacked-layer device, i.e., the light-emitting layers are red light-emitting layers, and the plurality of (at least two) red light-emitting layers are sequentially stacked in the direction of the anode and the cathode, and at least one of the red light-emitting layers is the phosphorescence sensitized layer described above, which is specifically a red phosphorescence sensitized light-emitting layer for emitting red light.

In the stacked-layer device, the hole transport zone includes a first hole transport zone provided between the anode and the light-emitting layer closest to the anode (e.g., the first light-emitting layer described below), and a first electron transport zone provided between the cathode and the light-emitting layer closest to the cathode (e.g., the second light-emitting layer described below).

In addition, the charge generation layer includes an n-type charge generation layer (n-CGL) and a p-type charge generation layer (p-CGL). When an n-type charge generation layer and a p-type charge generation layer are adjacent to each other, the n-type charge generation layer is provided on one side of the p-type charge generation layer that is away from the cathode, and the p-type charge generation layer is provided on one side of the n-type charge generation layer that is away from the anode. The hole transport zone further includes a second hole transport zone, and the electron transport zone further includes a second electron transport zone. When charge generation layers are provided between two adjacent light-emitting layers, the second electron transport zone is provided between an n-type charge generation layer and a light-emitting layer, and the second hole transport zone is provided between a p-type charge generation layer and another light-emitting layer.

Specifically, the hole transport zones (the first hole transport zone and the second hole transport zone) may include at least one of a hole injection layer (HIL), a hole transport layer (HTL), and an electron blocking layer (EBL). For example, the hole transport zone may be a hole transport layer of a single-layer structure (including a single-layer hole transport layer containing only one compound, or a single-layer hole transport layer containing a plurality of compounds), or a multi-layer structure including at least one of a hole injection layer (HIL), a hole transport layer (HTL), and an electron blocking layer (EBL).

For example, the first hole transport zone includes a hole injection layer, a hole transport layer, and an electron blocking layer, and an anode, the hole injection layer, the hole transport layer, the electron blocking layer, and a light-emitting layer closest to the anode are stacked sequentially.

For example, the second hole transport zone includes a hole transport layer and an electron blocking layer, and a p-type charge generation layer, the hole transport layer, the electron blocking layer, and a light-emitting layer are stacked sequentially.

Specifically, the electron transport zones (the first electron transport zone and the second electron transport zone) may include at least one of an electron injection layer (EIL), an electron transport layer (ETL), and a hole blocking layer (HBL). For example, the electron transport zone may be an electron transport layer of a single-layer structure (including a single-layer electron transport layer containing only one compound, or a single-layer electron transport layer containing a plurality of compounds), or a multi-layer structure including at least one of an electron injection layer (EIL), an electron transport layer (ETL), and a hole blocking layer (HBL).

For example, the first electron transport zone includes an electron injection layer, an electron transport layer, and a hole blocking layer, and a light-emitting layer closest to the cathode, the hole blocking layer, the electron transport layer, the electron injection layer, and a cathode are stacked sequentially.

For example, the second electron transport zone includes an electron transport layer and a hole blocking layer, and a light-emitting layer, the hole blocking layer, the electron transport layer, and an n-type charge generation layer are stacked sequentially.

In some specific examples, as shown in FIG. 1, the organic light-emitting diode is a single-layer device including an anode 10, a first hole injection layer 11, a first hole transport layer 21, a first electron blocking layer 31, a first light-emitting layer 41, a first hole blocking layer 51, a first electron transport layer 61, a first electron injection layer 81 and a cathode 20, which are stacked sequentially.

In other specific examples, as shown in FIG. 2, the organic light-emitting diode includes two light-emitting layers, which are a first light-emitting layer 41 and a second light-emitting layer 42, respectively, and an anode 10, the first light-emitting layer 41, the second light-emitting layer 42, and a cathode 20 are sequentially stacked, wherein the first light-emitting layer 41 is a phosphorescence sensitized layer, and the second light-emitting layer 42 is a phosphorescence layer; alternatively the second light-emitting layer 42 is a phosphorescence sensitized layer, and the first light-emitting layer 41 is a phosphorescence layer; alternatively, both the first light-emitting layer 41 and the second light-emitting layer 42 are phosphorescence sensitized layers.

Herein, a first hole transport zone provided between the anode 10 and the first light-emitting layer 41 includes a first hole injection layer 11, a first hole transport layer 21, and a first electron blocking layer 31; a second electron transport zone provided between the first light-emitting layer 41 and an n-type charge generation layer 72 includes a second hole blocking layer 52 and a second electron transport layer 62; a second hole transport zone provided between a p-type charge generation layer 71 and the second light-emitting layer 42 includes a second hole transport layer 22 and a second electron blocking layer 32; a first electron transport zone provided between the second light-emitting layer 42 and the cathode 20 includes a first hole blocking layer 51, a first electron transport layer 61, and a first electron injection layer 81; the anode 10, the first hole injection layer 11, the first hole transport layer 21, the first electron blocking layer 31, the first light-emitting layer 41, the second hole blocking layer 52, the second electron transport layer 62, the n-type charge generation layer 72, the p-type charge generation layer 71, the second hole transport layer 22, the second electron blocking layer 32, the second light-emitting layer 42, the first hole blocking layer 51, the first electron transport layer 61, the first electron injection layer 81, and the cathode 20 are sequentially stacked.

Specifically, the host material in the phosphorescence layer may include, but is not limited to, one or more of the compounds PH-1 to PH-85, and the phosphorescent material in the phosphorescence layer may include, but is not limited to, one or more of the compounds RPD-1 to RPD-29. In addition, in the phosphorescence layer, the mass content of the phosphorescent material is 0.1-20%, for example, 0.1%, 0.5%, 1%, 3%, 5%, 8%, 10%, 12%, 15%, 18%, and 20%, and the rest is the host material.

In addition, the light-emitting layer (a phosphorescence sensitized layer or a phosphorescence layer) may have a thickness of 200 Å-500 Å, for example, 200 Å, 220 Å, 250 Å, 280 Å, 300 Å, 350 Å, 380 Å, 400 Å, 450 Å, 480 Å, and 500 Å, and 300-400 Å is generally preferred.

Generally, the material of the n-type charge generation layer may include an organic matrix material or a mixture of an organic matrix material and a doping material. The organic matrix material includes, for example, an o-phenanthroline compound, which includes, but is not limited to, one or more of the following compounds CGL-1 to CGL-12. The doping material may include a metal and/or a metal compound such as a metal salt, which includes, but is not limited to, one or more of Liq, LiF, NaCl, CsF, Li₂O, Cs₂CO₃, BaO, Na, Li, Ca, Mg, Ag, and Y b.

In some specific examples, in the n-type charge generation layer, the mass content of the doping material may be 0.1-20%, for example, 0.1%, 0.5%, 1%, 3%, 5%, 8%, 10%, 12%, 15%, 18%, and 20%, and the rest is the organic matrix material.

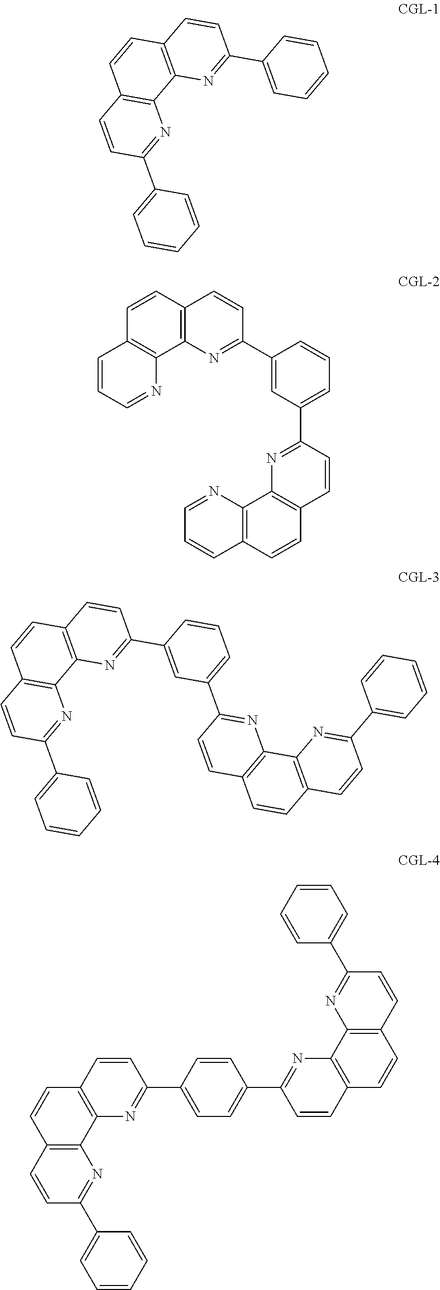

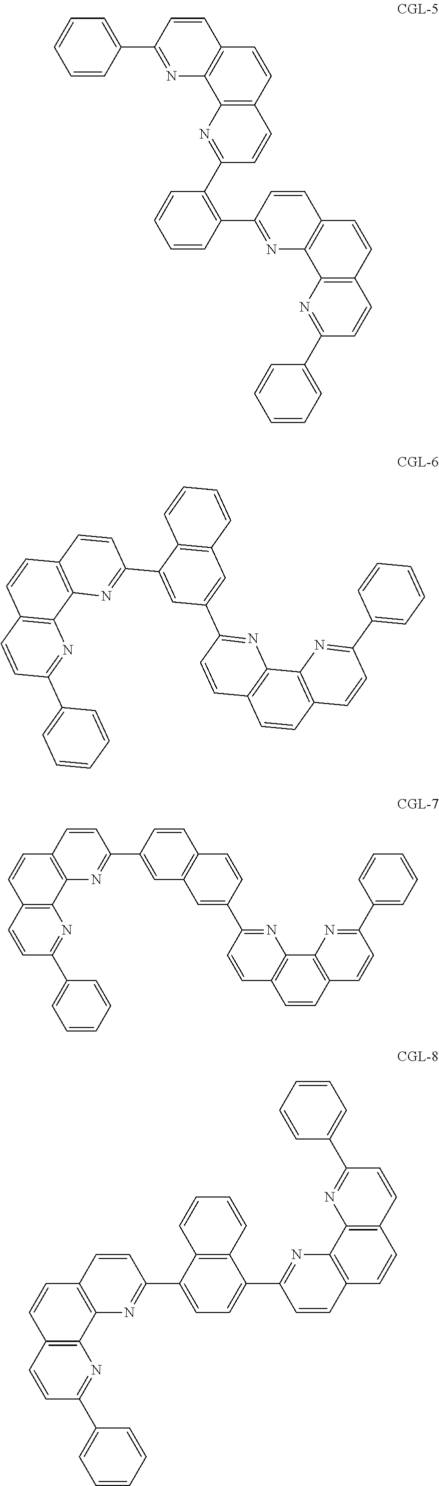 [SMILES: c1ccc(-c2ccc3ccc4ccc(-c5ccccc5-c5ccc6ccc7ccc(-c8ccccc8)nc7c6n5)nc4c3n2)cc1 ; c1ccc(-c2ccc3ccc4ccc(-c5cc(-c6ccc7ccc8ccc(-c9ccccc9)nc8c7n6)c6ccccc6c5)nc4c3n2)cc1 ; c1ccc(-c2ccc3ccc4ccc(-c5ccc6ccc(-c7ccc8ccc9ccc(-c%10ccccc%10)nc9c8n7)cc6c5)nc4c3n2)cc1 ; c1ccc(-c2ccc3ccc4ccc(-c5ccc(-c6ccc7ccc8ccc(-c9ccccc9)nc8c7n6)c6ccccc56)nc4c3n2)cc1]

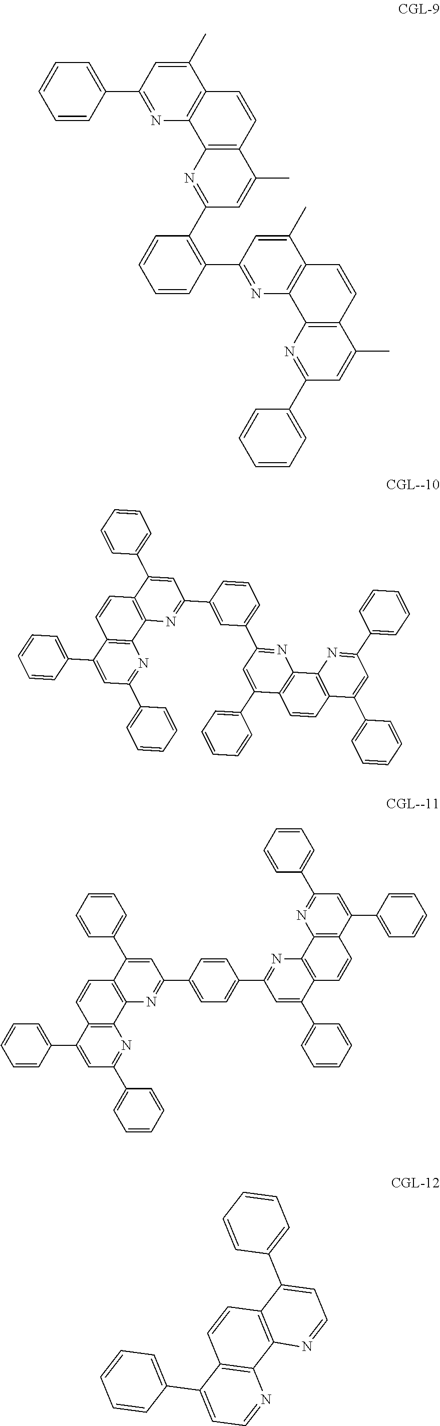 [SMILES: Cc1cc(-c2ccccc2)nc2c1ccc1c(C)cc(-c3ccccc3-c3cc(C)c4ccc5c(C)cc(-c6ccccc6)nc5c4n3)nc12 ; c1ccc(-c2cc(-c3ccccc3)c3ccc4c(-c5ccccc5)cc(-c5cccc(-c6cc(-c7ccccc7)c7ccc8c(-c9ccccc9)cc(-c9ccccc9)nc8c7n6)c5)nc4c3n2)cc1 ; c1ccc(-c2cc(-c3ccccc3)c3ccc4c(-c5ccccc5)cc(-c5ccc(-c6cc(-c7ccccc7)c7ccc8c(-c9ccccc9)cc(-c9ccccc9)nc8c7n6)cc5)nc4c3n2)cc1 ; c1ccc(-c2ccnc3c2ccc2c(-c4ccccc4)ccnc23)cc1]

In addition, the material of the p-type charge generation layer may include, but is not limited to, one or more of the following compounds HT-1 to HT-51 and HI-1 to HI-3. For example, it may be a mixture of a first type of compound (one or more of HT-1 to HT-51) and a second type of compound (one or more of HI-1 to HI-3).

In some specific examples, in the p-type charge generation layer, the mass content of the second type of compound is 0.1-30%, for example, 0.1%, 0.5%, 1%, 3%, 5%, 8%, 10%, 12%, 15%, 18%, 20%, 22%, 25%, 28%, and 30%, and the rest is the first type of compound.

In addition, the organic light-emitting diode further includes a substrate, on which an anode can be formed by sputtering or depositing an anode material, and the remaining layers can be formed through vacuum thermal evaporation, spin coating, printing and other conventional methods in the art. This will not be explained in detail. Herein, the substrate may be a glass or polymer material with excellent mechanical strength, thermal stability, water resistance and transparency. Additionally, a substrate used as a display may also be provided with a thin film transistor (TFT).

For example, the anode includes indium tin oxide (ITO), indium zinc oxide (IZO), tin dioxide (SnO₂), zinc oxide (ZnO) and other transparent conductive oxide materials and combinations thereof. The cathode material may be magnesium (Mg), silver (A g), aluminum (AI), aluminum-lithium (Al—Li), calcium (Ca), magnesium-indium (Mg—In), magnesium-silver (Mg—Ag) and other metals or alloys and any combination thereof.

In some examples, the organic light-emitting diode may be a top light-emitting device (or referred to as a top-emitting device), and a substrate structure with an anode may be a top-emitting substrate structure conventionally used in the art for a top-emitting device. For example, a substrate structure with an anode includes an ITO layer, a silver layer and an ITO layer, which are stacked sequentially and have a thickness of 100 Å, 1,000 Å and 100 Å, respectively.

In addition, the side of the cathode that is away from the anode may further be provided with a capping layer (CPL) 9, which is used to adjust the top-emission microcavity to adjust the light color and efficiency of the top-emitting device.

Herein, the thickness of the capping layer 9 may be a conventional thickness of such layers in the art, for example 500-800 Å, such as 500 Å, 550 Å, 600 Å, 650 Å, 700 Å, 750 Å and 800 Å.

In addition, the material of the capping layer 9 may be a conventional material for such layers in the art, including, for example, one or more of the following compounds

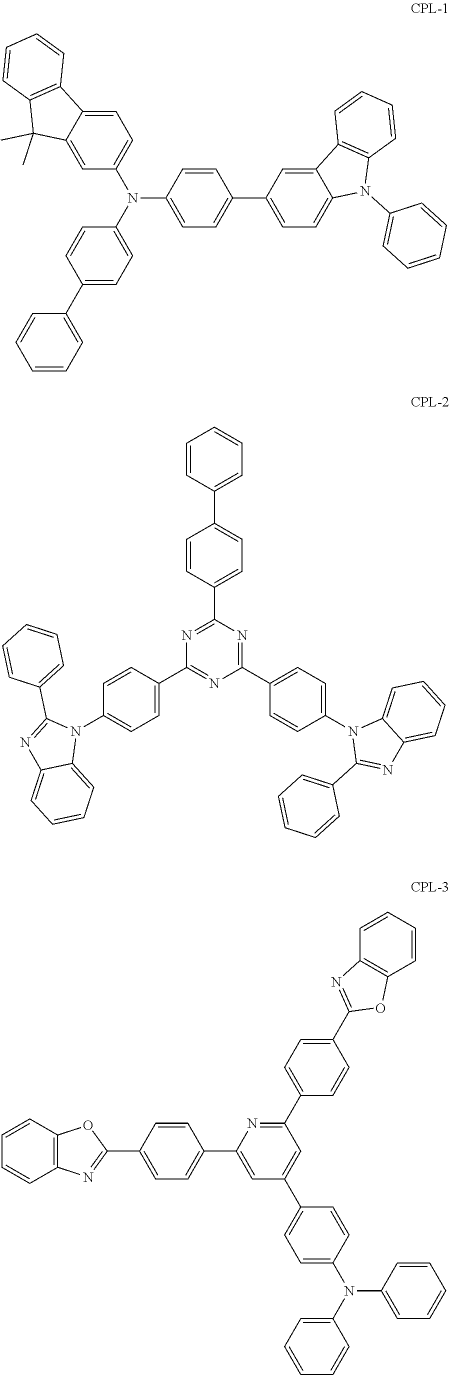 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3nc(-c4ccc(-n5c(-c6ccccc6)nc6ccccc65)cc4)nc(-c4ccc(-n5c(-c6ccccc6)nc6ccccc65)cc4)n3)cc2)cc1 ; c1ccc(N(c2ccccc2)c2ccc(-c3cc(-c4ccc(-c5nc6ccccc6o5)cc4)nc(-c4ccc(-c5nc6ccccc6o5)cc4)c3)cc2)cc1]

In addition, the material of the hole transport zone includes, but is not limited to, one or more of the following compounds: a phthalocyanine derivative (such as CuPc), a conductive polymer or a conductive-dopant-containing polymer (such as poly(phenylene vinylene), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), and polyaniline/poly(4-styrenesulfonate) (Pani/PSS)), and an aromatic amine derivative, wherein the aromatic amine derivative includes one or more of the following compounds HT-1 to HT-51:

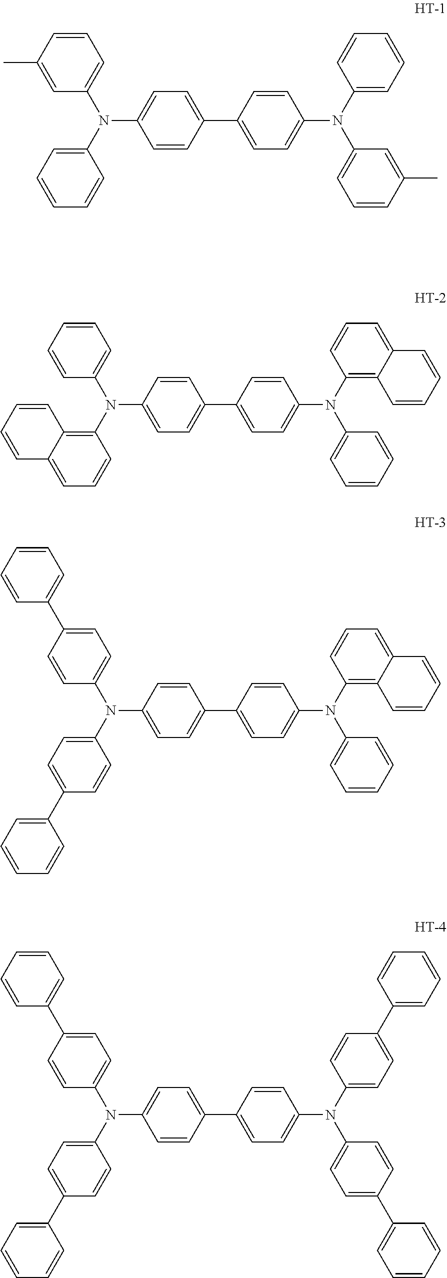

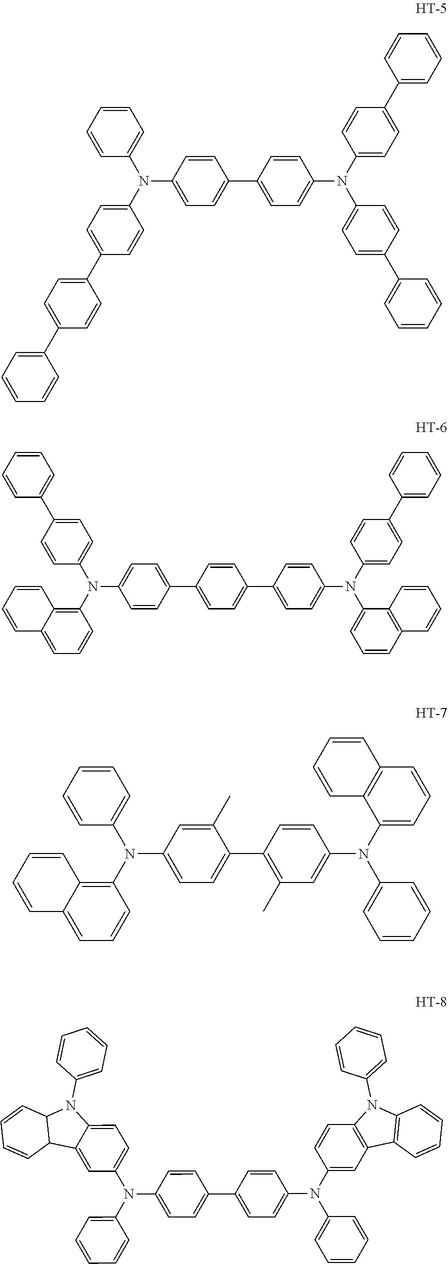 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(-c5ccc(N(c6ccc(-c7ccccc7)cc6)c6cccc7ccccc67)cc5)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C ; C1=CC2c3cc(N(c4ccccc4)c4ccc(-c5ccc(N(c6ccccc6)c6ccc7c(c6)c6ccccc6n7-c6ccccc6)cc5)cc4)ccc3N(c3ccccc3)C2C=C1]

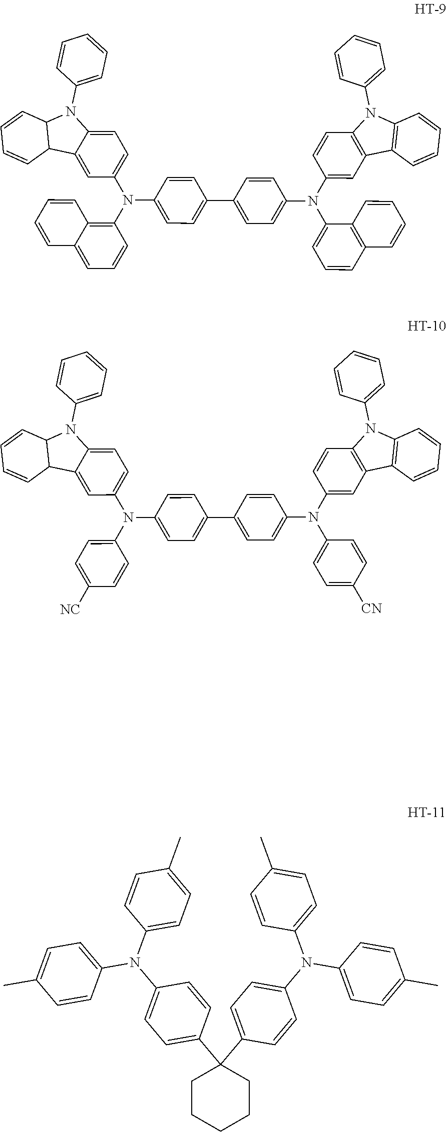

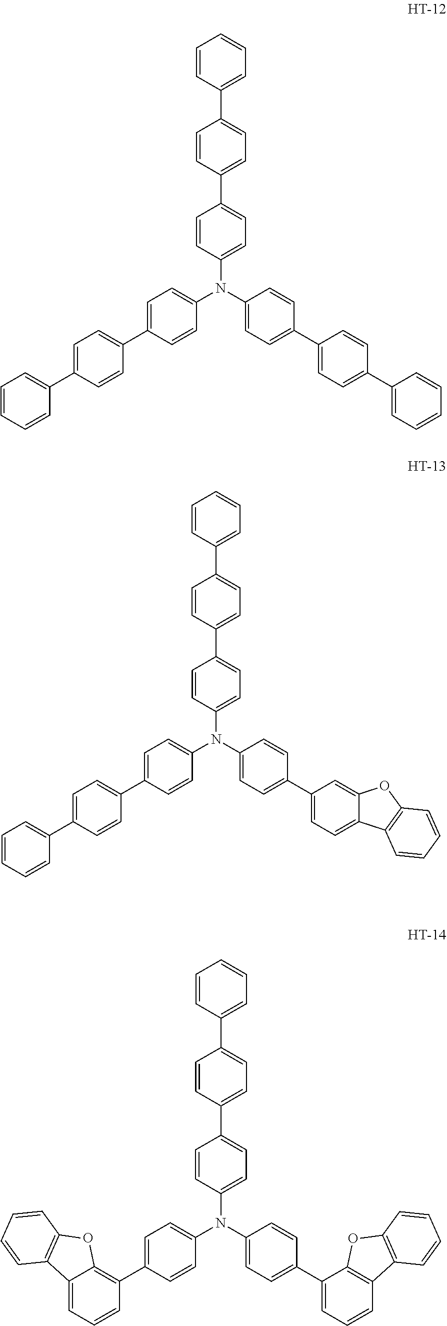 [SMILES: c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

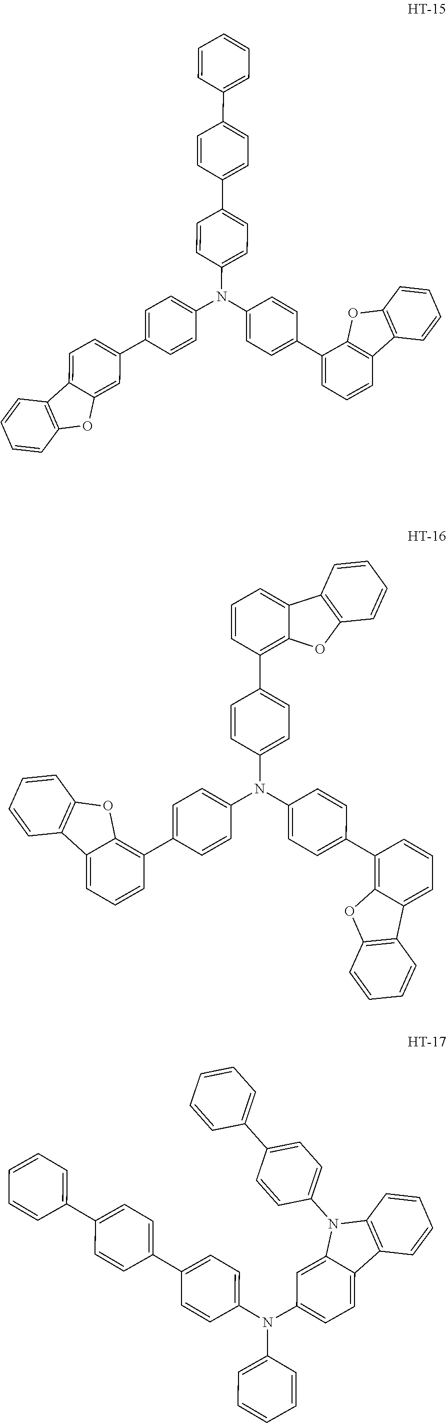 [SMILES: c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(-c2ccc(-c3ccc(N(c4ccccc4)c4ccc5c6ccccc6n(-c6ccc(-c7ccccc7)cc6)c5c4)cc3)cc2)cc1]

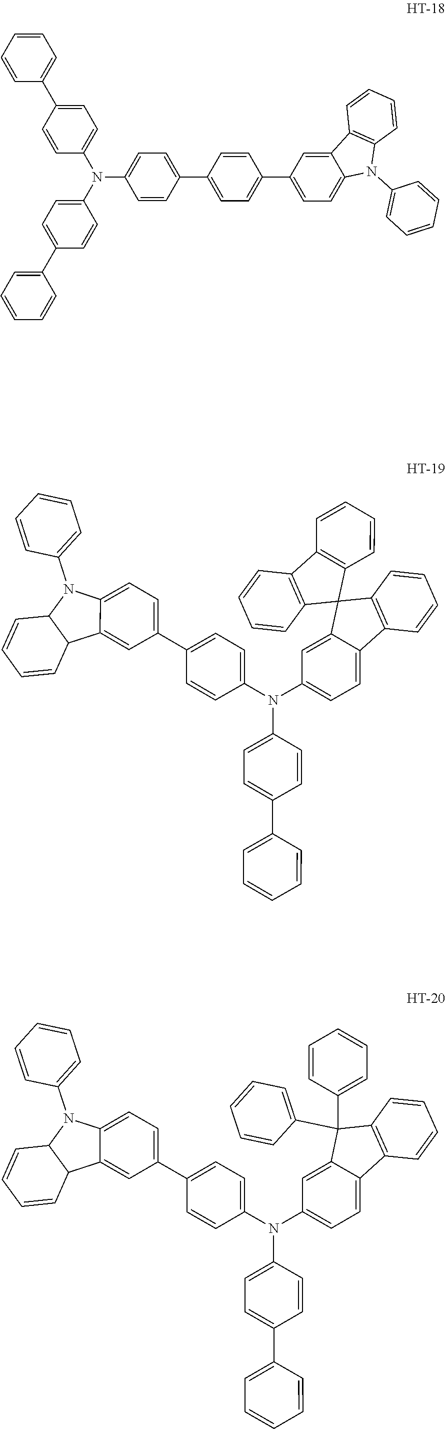 [SMILES: c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1 ; C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1]

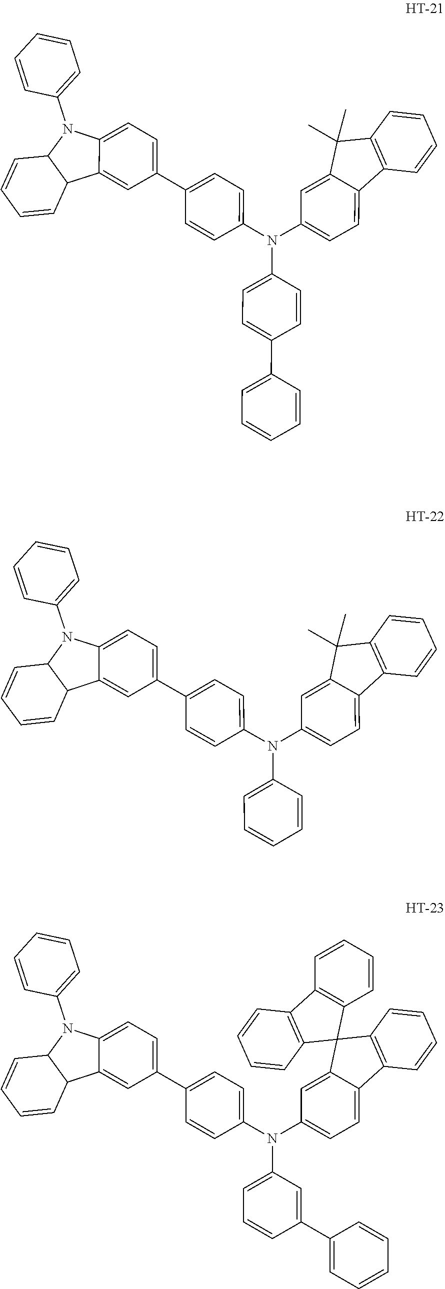 [SMILES: CC1(C)c2ccccc2-c2ccc(N(c3ccc(-c4ccccc4)cc3)c3ccc(-c4ccc5c(c4)C4C=CC=CC4N5c4ccccc4)cc3)cc21 ; CC1(C)c2ccccc2-c2ccc(N(c3ccccc3)c3ccc(-c4ccc5c(c4)C4C=CC=CC4N5c4ccccc4)cc3)cc21 ; C1=CC2c3cc(-c4ccc(N(c5cccc(-c6ccccc6)c5)c5ccc6c(c5)C5(c7ccccc7-c7ccccc75)c5ccccc5-6)cc4)ccc3N(c3ccccc3)C2C=C1]

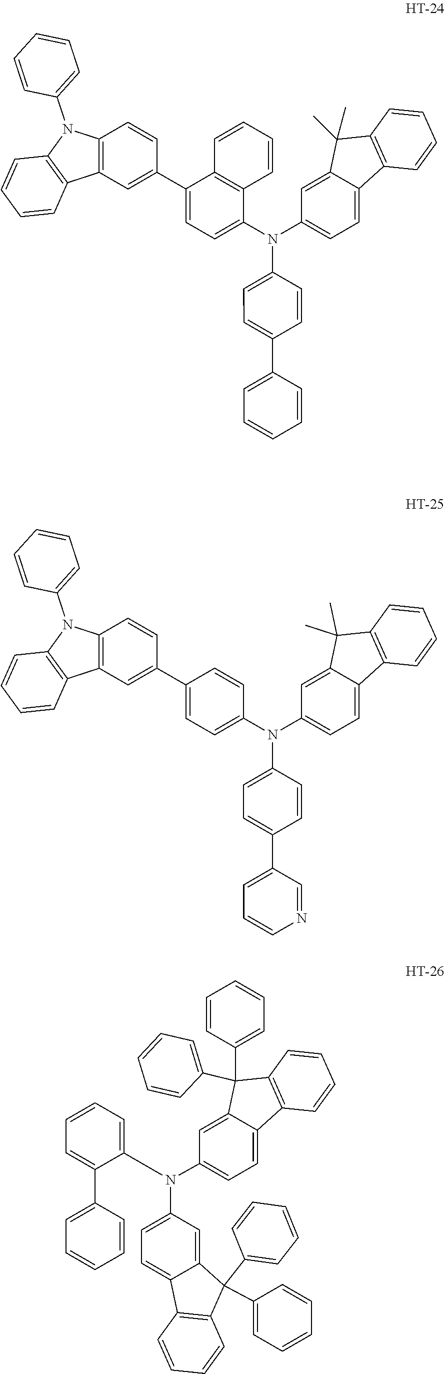 [SMILES: CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

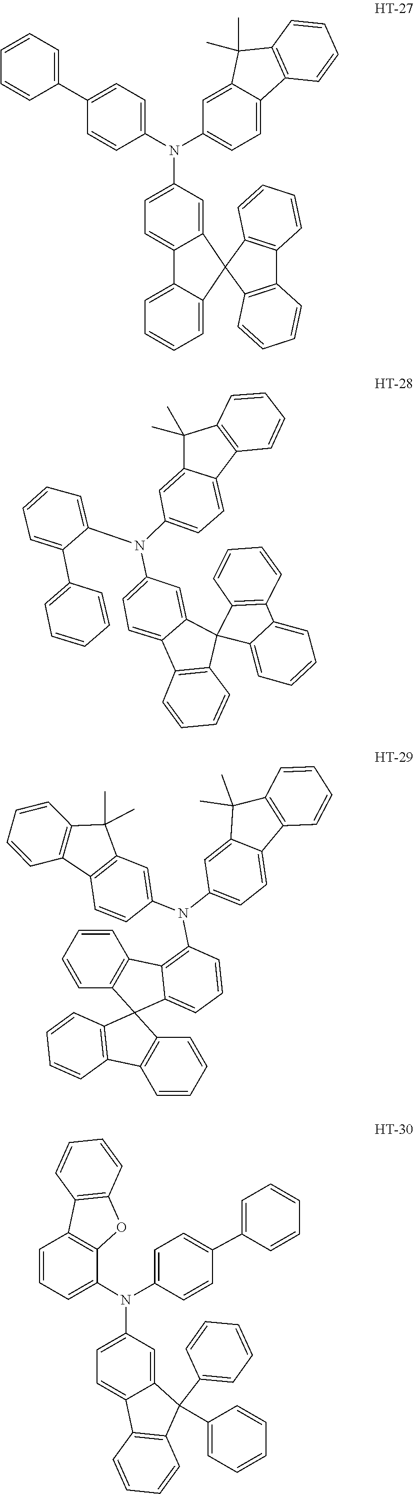

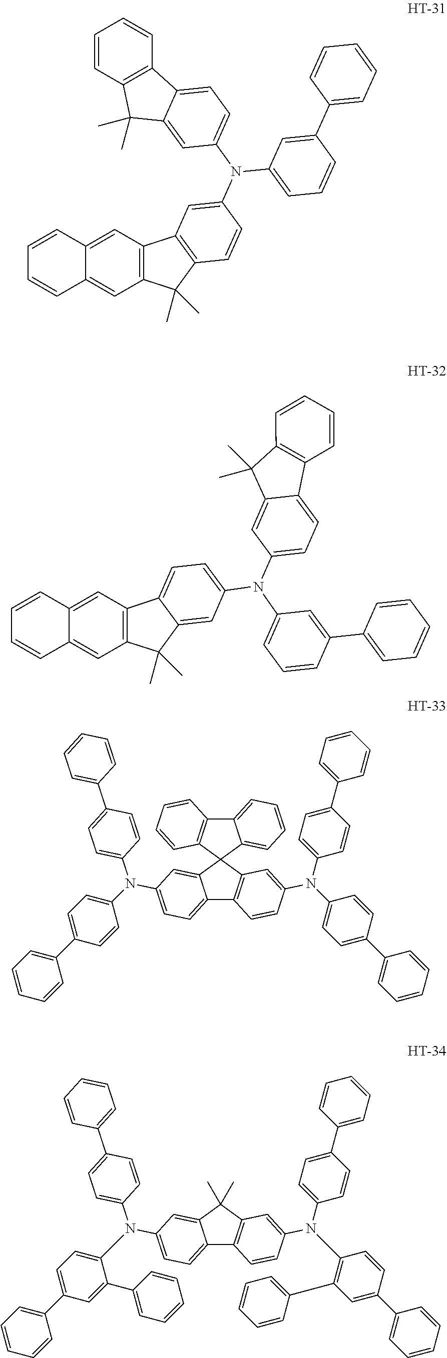 [SMILES: CC1(C)c2ccccc2-c2ccc(N(c3cccc(-c4ccccc4)c3)c3ccc4c(c3)-c3cc5ccccc5cc3C4(C)C)cc21 ; CC1(C)c2ccccc2-c2ccc(N(c3cccc(-c4ccccc4)c3)c3ccc4c(c3)C(C)(C)c3cc5ccccc5cc3-4)cc21 ; c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; CC1(C)c2cc(N(c3ccc(-c4ccccc4)cc3)c3ccc(-c4ccccc4)cc3-c3ccccc3)ccc2-c2ccc(N(c3ccc(-c4ccccc4)cc3)c3ccc(-c4ccccc4)cc3-c3ccccc3)cc21]

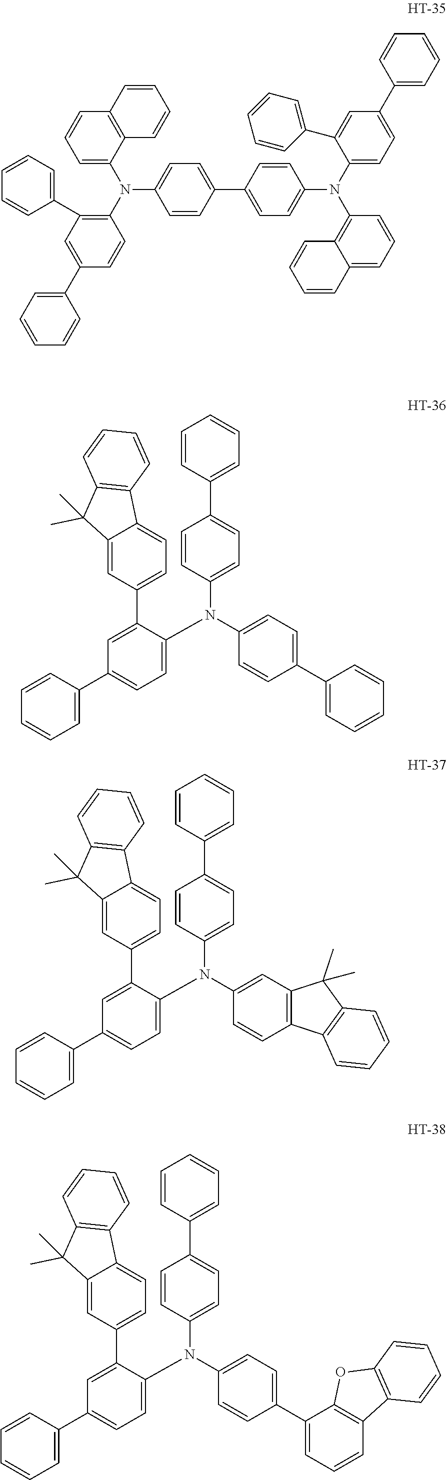 [SMILES: c1ccc(-c2ccc(N(c3ccc(-c4ccc(N(c5ccc(-c6ccccc6)cc5-c5ccccc5)c5cccc6ccccc56)cc4)cc3)c3cccc4ccccc34)c(-c3ccccc3)c2)cc1 ; CC1(C)c2ccccc2-c2ccc(-c3cc(-c4ccccc4)ccc3N(c3ccc(-c4ccccc4)cc3)c3ccc(-c4ccccc4)cc3)cc21 ; CC1(C)c2ccccc2-c2ccc(-c3cc(-c4ccccc4)ccc3N(c3ccc(-c4ccccc4)cc3)c3ccc4c(c3)C(C)(C)c3ccccc3-4)cc21 ; CC1(C)c2ccccc2-c2ccc(-c3cc(-c4ccccc4)ccc3N(c3ccc(-c4ccccc4)cc3)c3ccc(-c4cccc5c4oc4ccccc45)cc3)cc21]

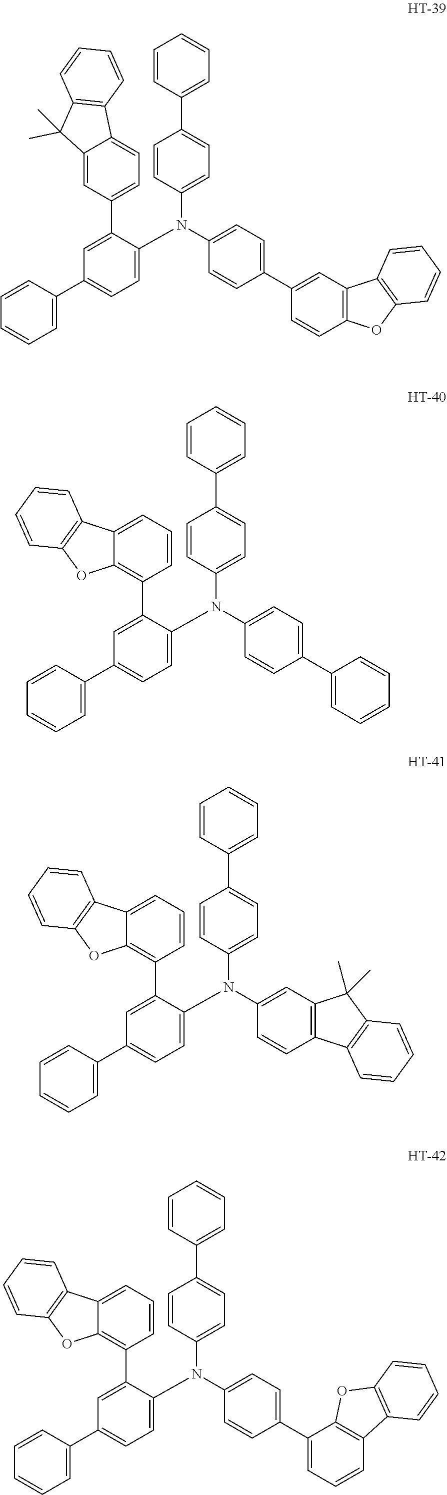 [SMILES: CC1(C)c2ccccc2-c2ccc(-c3cc(-c4ccccc4)ccc3N(c3ccc(-c4ccccc4)cc3)c3ccc(-c4ccc5oc6ccccc6c5c4)cc3)cc21 ; c1ccc(-c2ccc(N(c3ccc(-c4ccccc4)cc3)c3ccc(-c4ccccc4)cc3-c3cccc4c3oc3ccccc34)cc2)cc1 ; CC1(C)c2ccccc2-c2ccc(N(c3ccc(-c4ccccc4)cc3)c3ccc(-c4ccccc4)cc3-c3cccc4c3oc3ccccc34)cc21 ; c1ccc(-c2ccc(N(c3ccc(-c4cccc5c4oc4ccccc45)cc3)c3ccc(-c4ccccc4)cc3-c3cccc4c3oc3ccccc34)cc2)cc1]

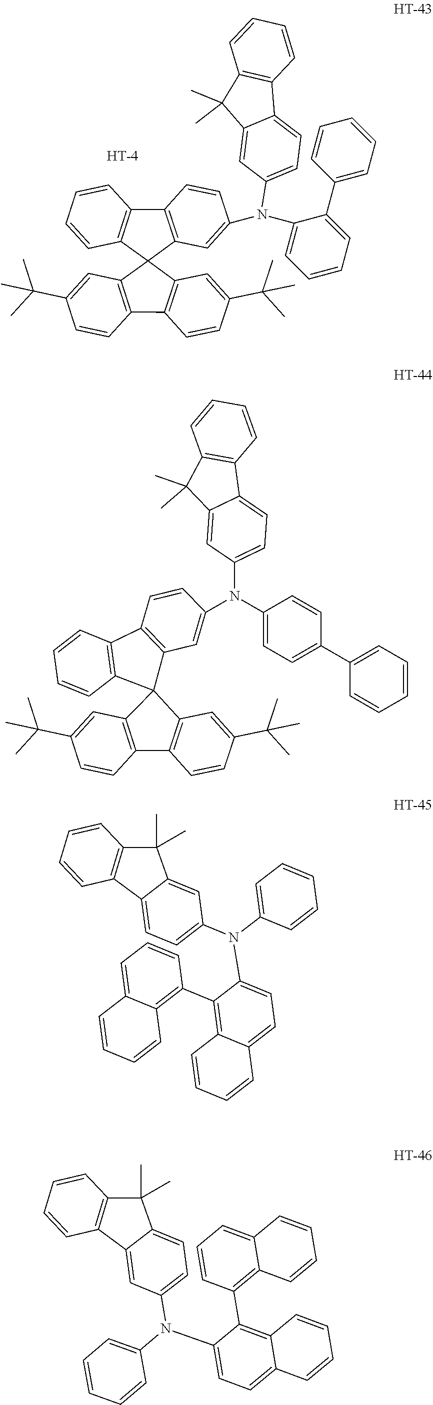

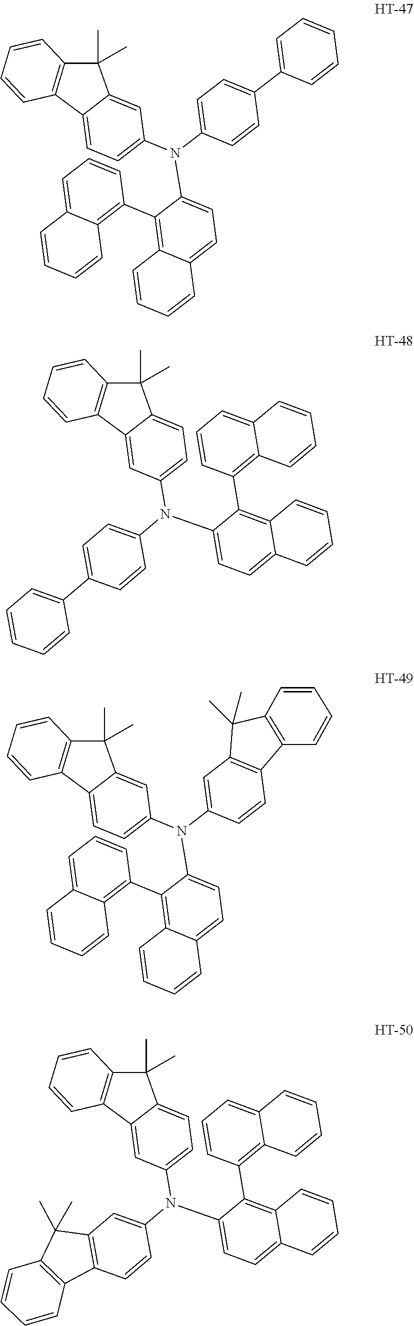

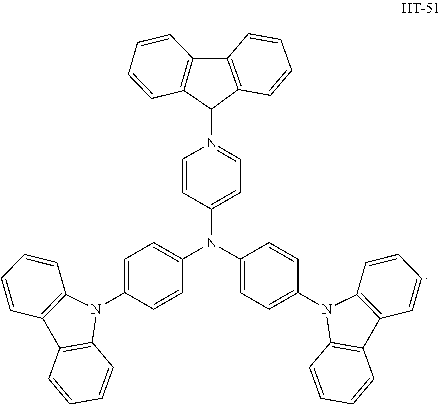

In addition, the material of the hole injection layer may include, but is not limited to, one or more of the HT-1 to HT-51 above and the HI-1 to HI-3 below:

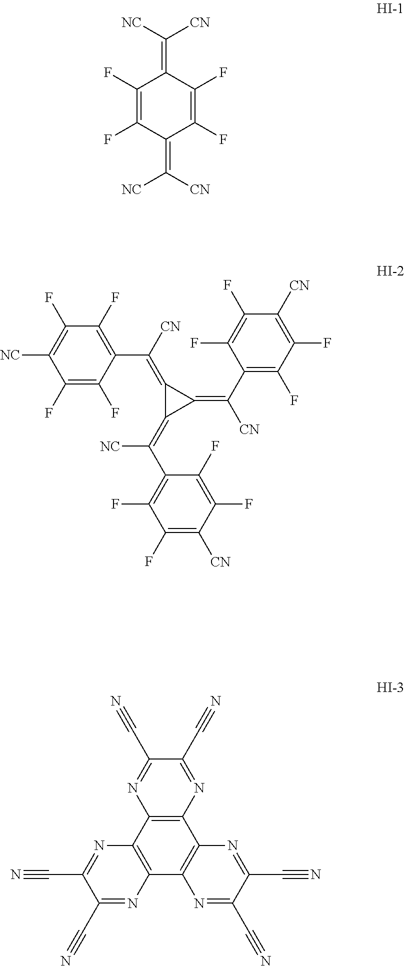 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#Cc1nc2c3nc(C#N)c(C#N)nc3c3nc(C#N)c(C#N)nc3c2nc1C#N]

In addition, the material of the electron blocking layer may include, but is not limited to, one or more of the HT-1 to HT-51 above and the PH-47 to PH-77 above.

In addition, the material of the electron transport layer may include, but is not limited to, one or more of the ET-1 to ET-73 below:

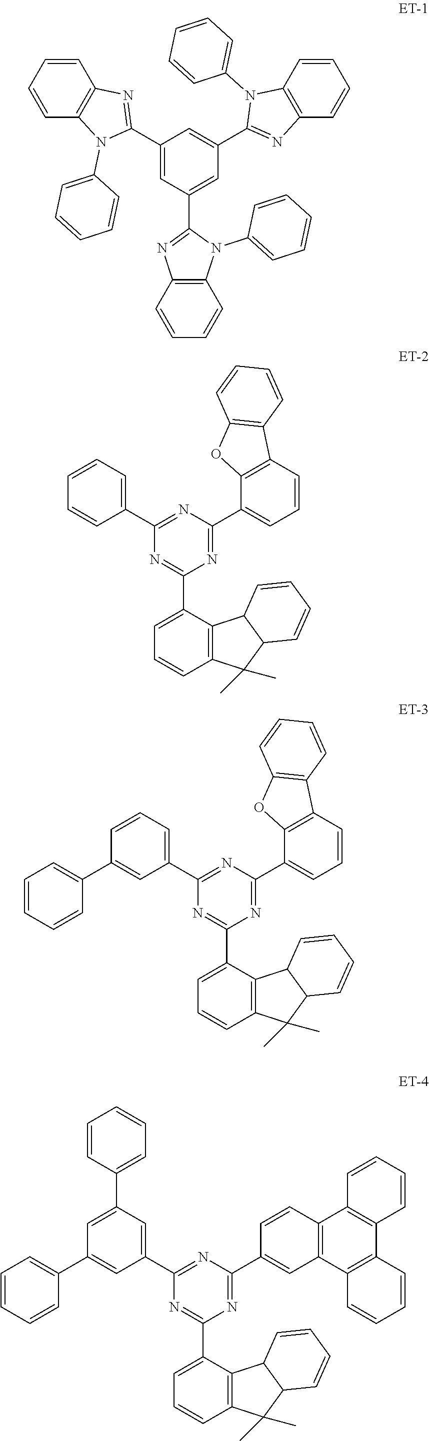

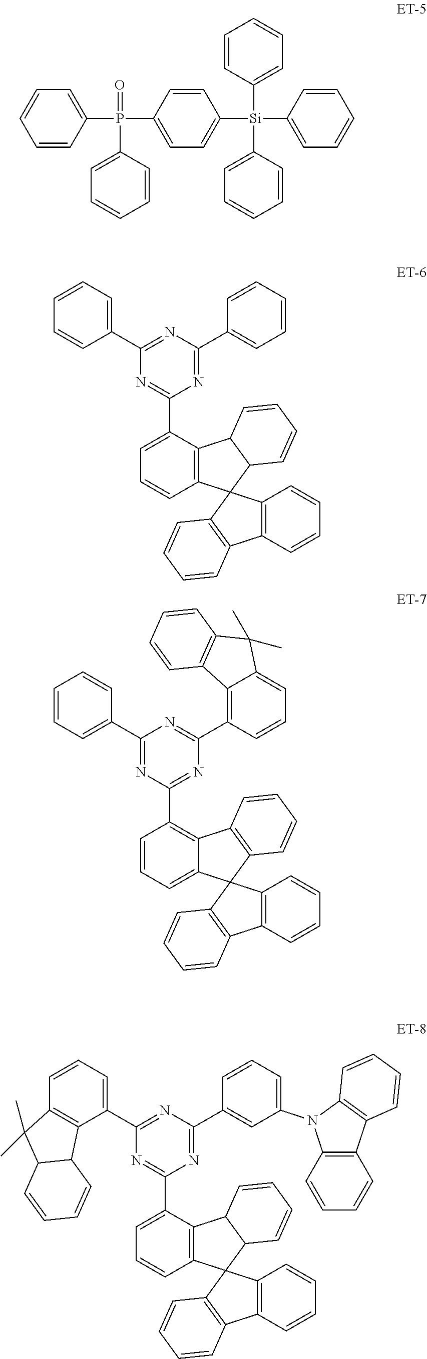

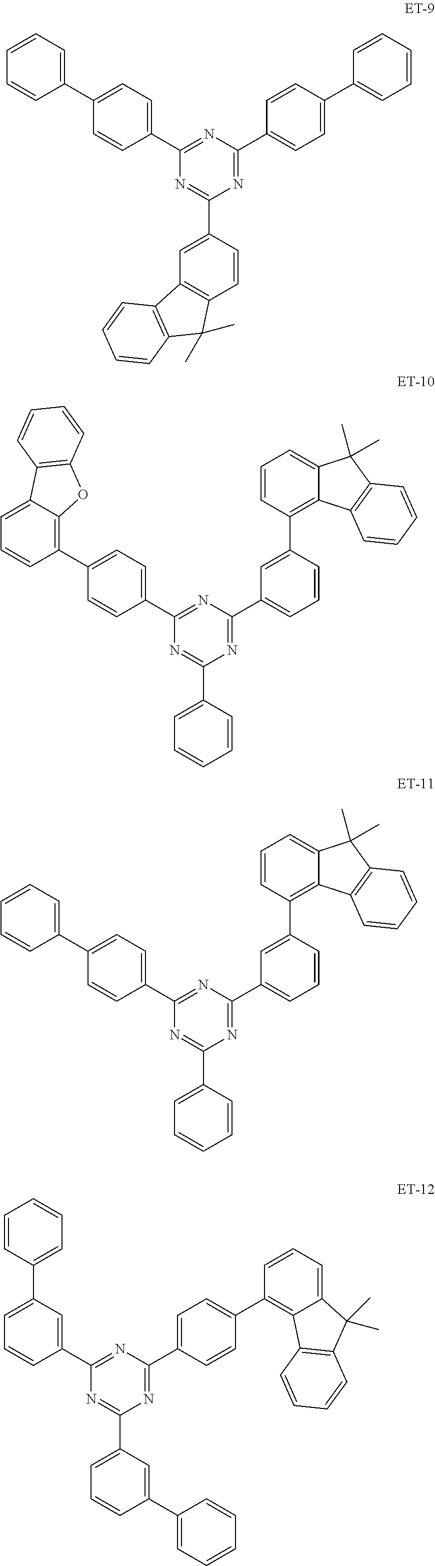 [SMILES: CC1(C)c2ccccc2-c2cc(-c3nc(-c4ccc(-c5ccccc5)cc4)nc(-c4ccc(-c5ccccc5)cc4)n3)ccc21 ; CC1(C)c2ccccc2-c2c(-c3cccc(-c4nc(-c5ccccc5)nc(-c5ccc(-c6cccc7c6oc6ccccc67)cc5)n4)c3)cccc21 ; CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21]

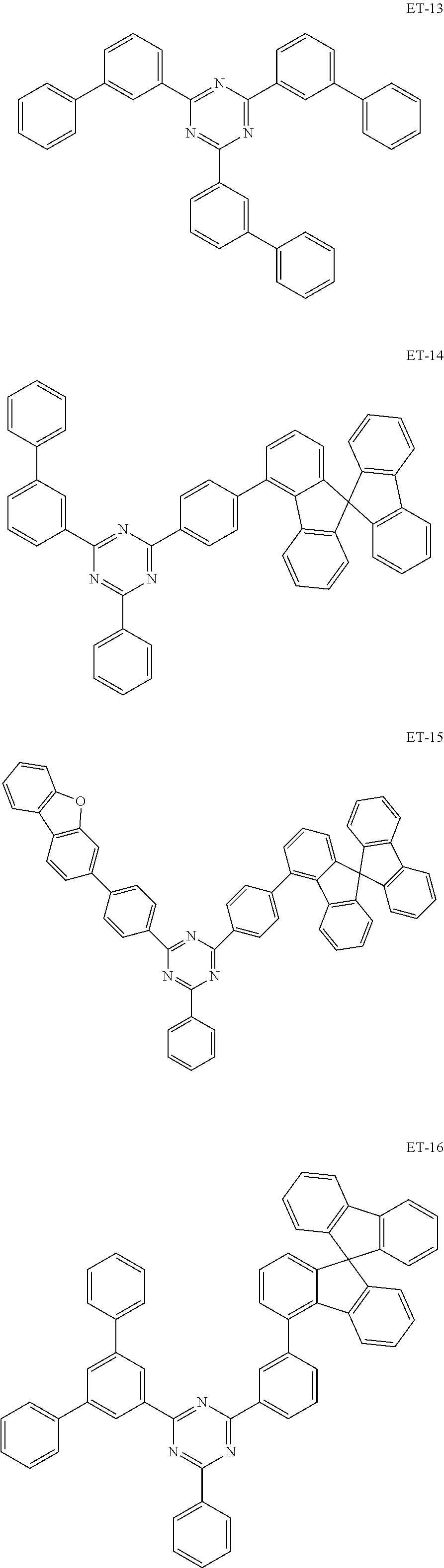 [SMILES: c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4ccc(-c5cccc6c5-c5ccccc5C65c6ccccc6-c6ccccc65)cc4)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1 ; c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1]

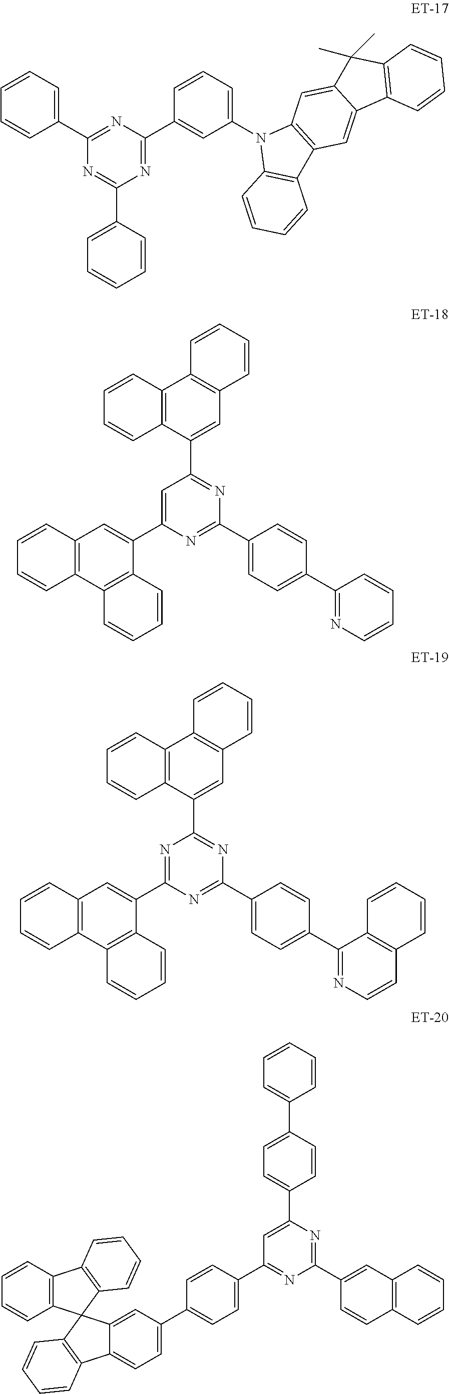 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1 ; c1ccc2c(-c3ccc(-c4nc(-c5cc6ccccc6c6ccccc56)nc(-c5cc6ccccc6c6ccccc56)n4)cc3)nccc2c1 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1]

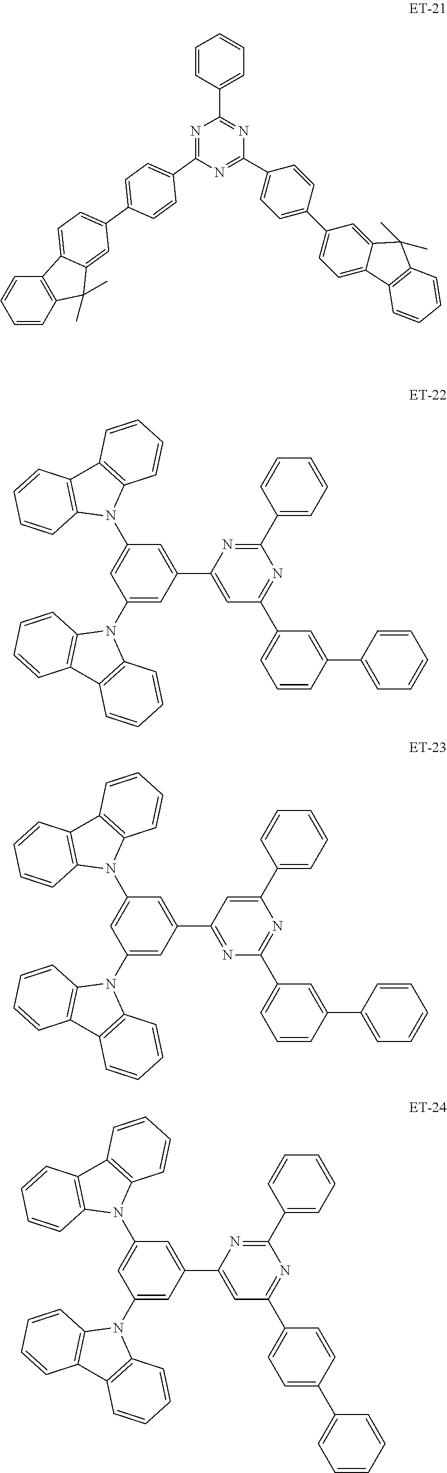

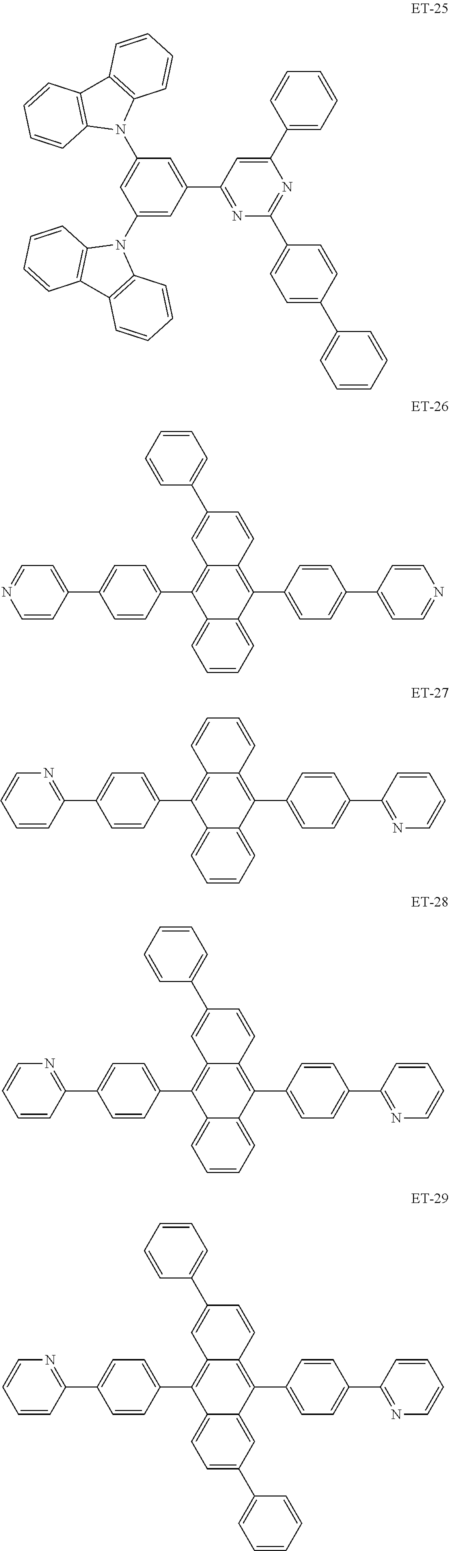 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1 ; c1ccc(-c2ccc3c(-c4ccc(-c5ccccn5)cc4)c4cc(-c5ccccc5)ccc4c(-c4ccc(-c5ccccn5)cc4)c3c2)cc1]

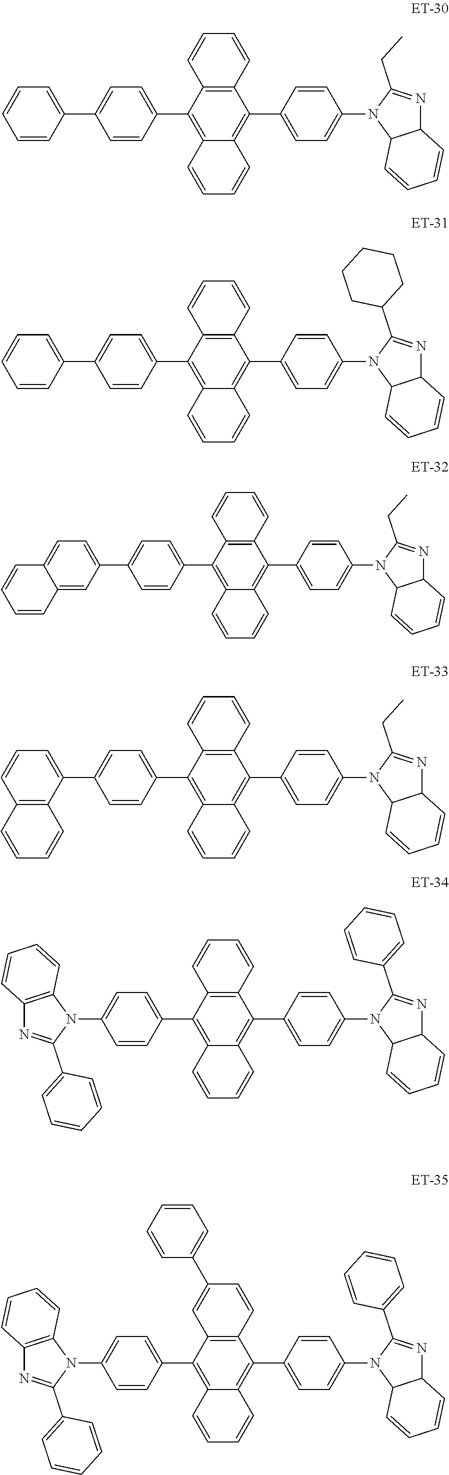

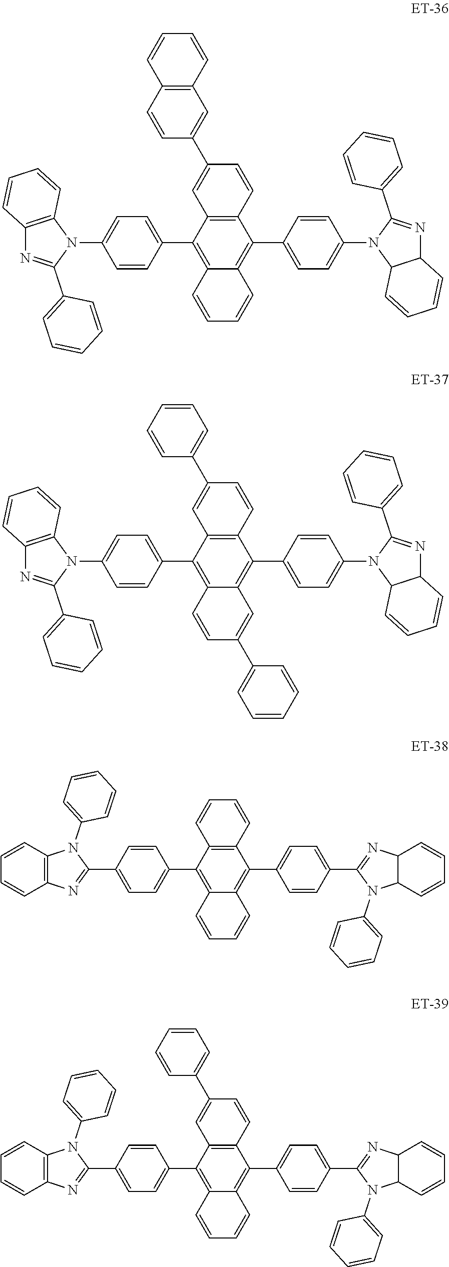 [SMILES: C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1 ; C1=CC2N=C(c3ccc(-c4c5ccccc5c(-c5ccc(-c6nc7ccccc7n6-c6ccccc6)cc5)c5ccccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1]

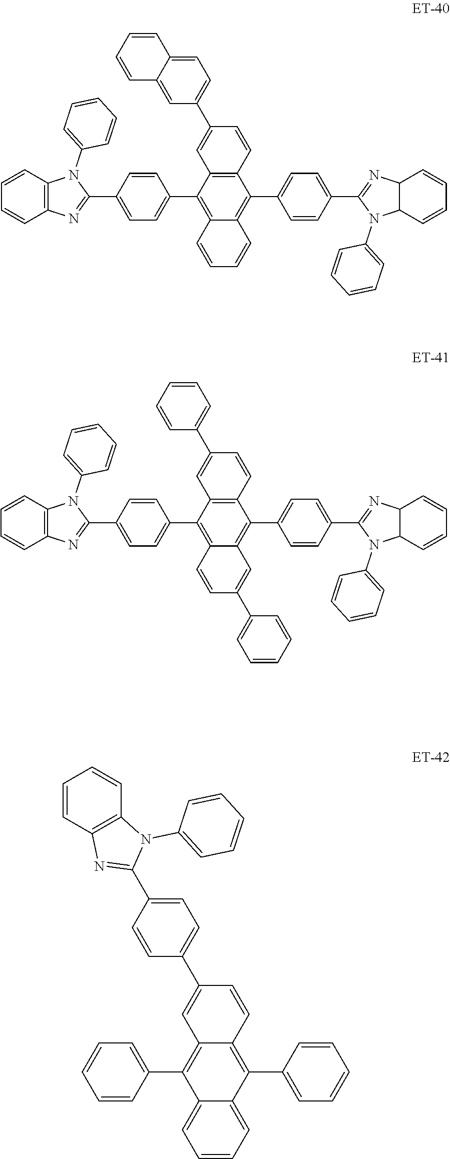 [SMILES: C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1 ; c1ccc(-c2c3ccccc3c(-c3ccccc3)c3cc(-c4ccc(-c5nc6ccccc6n5-c5ccccc5)cc4)ccc23)cc1]

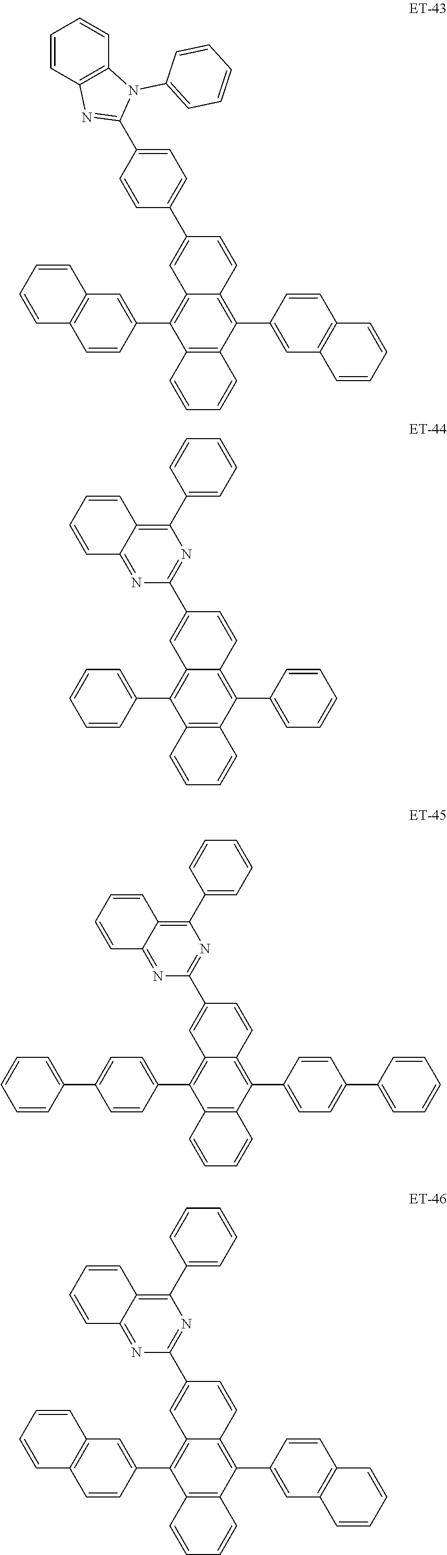

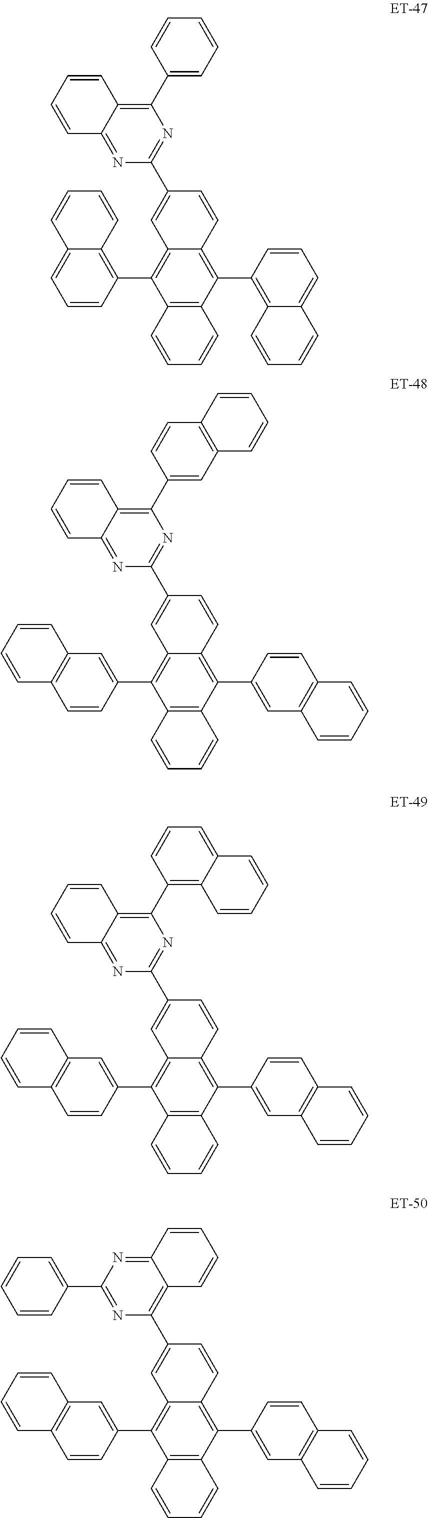

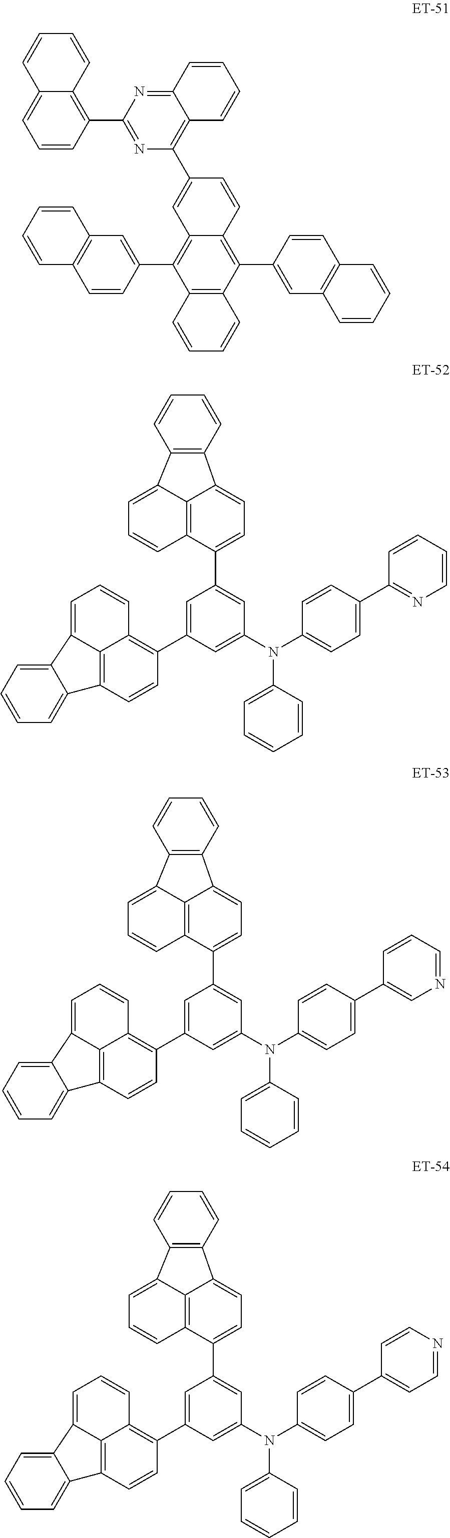

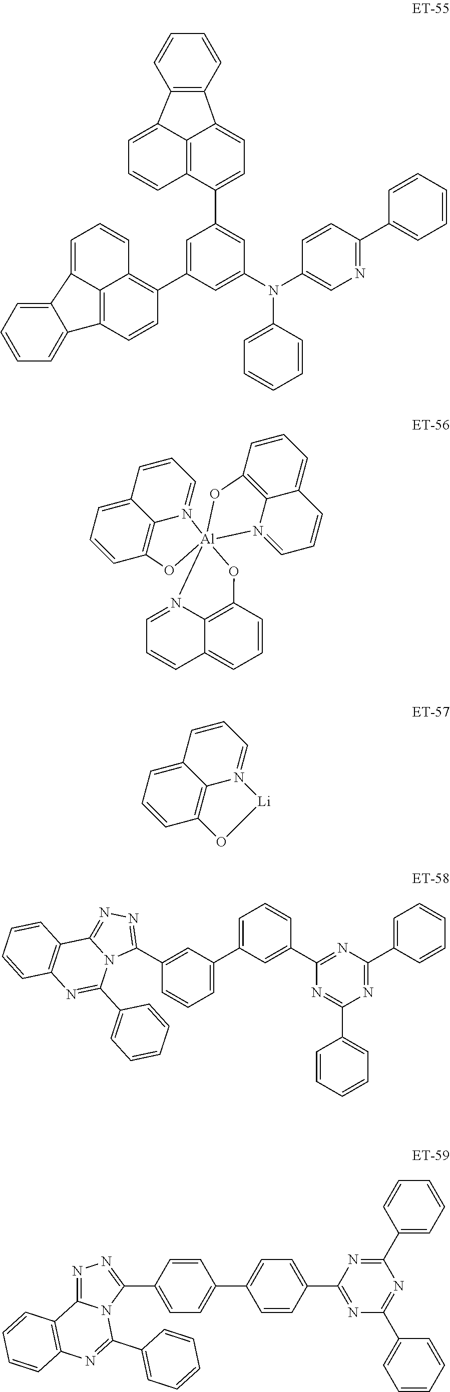

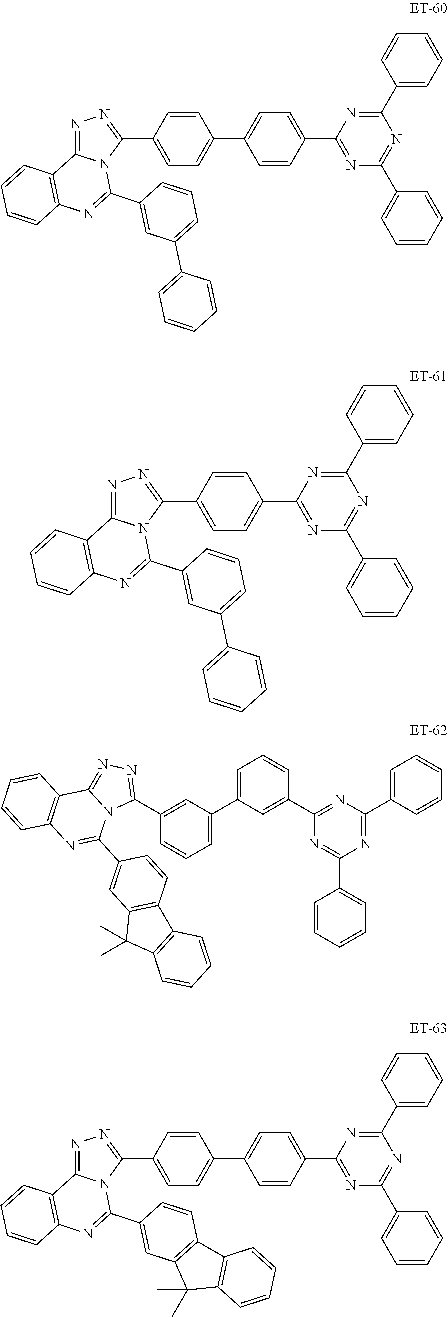 [SMILES: c1ccc(-c2cccc(-c3nc4ccccc4c4nnc(-c5ccc(-c6ccc(-c7nc(-c8ccccc8)nc(-c8ccccc8)n7)cc6)cc5)n34)c2)cc1 ; c1ccc(-c2cccc(-c3nc4ccccc4c4nnc(-c5ccc(-c6nc(-c7ccccc7)nc(-c7ccccc7)n6)cc5)n34)c2)cc1 ; CC1(C)c2ccccc2-c2ccc(-c3nc4ccccc4c4nnc(-c5cccc(-c6cccc(-c7nc(-c8ccccc8)nc(-c8ccccc8)n7)c6)c5)n34)cc21 ; CC1(C)c2ccccc2-c2ccc(-c3nc4ccccc4c4nnc(-c5ccc(-c6ccc(-c7nc(-c8ccccc8)nc(-c8ccccc8)n7)cc6)cc5)n34)cc21]

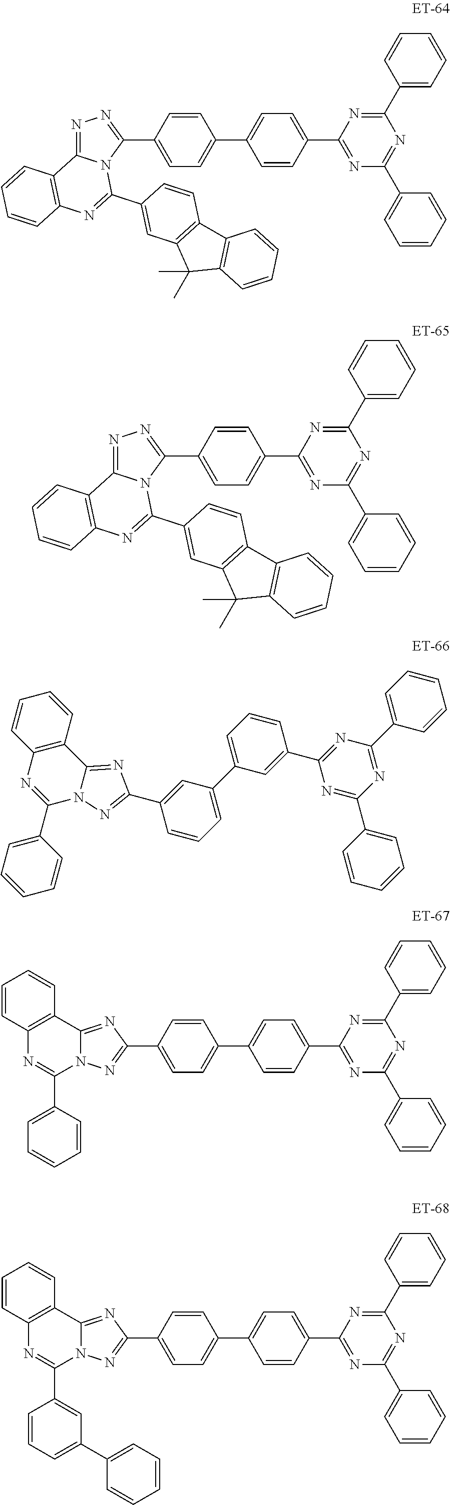 [SMILES: CC1(C)c2ccccc2-c2ccc(-c3nc4ccccc4c4nnc(-c5ccc(-c6ccc(-c7nc(-c8ccccc8)nc(-c8ccccc8)n7)cc6)cc5)n34)cc21 ; CC1(C)c2ccccc2-c2ccc(-c3nc4ccccc4c4nnc(-c5ccc(-c6nc(-c7ccccc7)nc(-c7ccccc7)n6)cc5)n34)cc21 ; c1ccc(-c2nc(-c3ccccc3)nc(-c3cccc(-c4cccc(-c5nc6c7ccccc7nc(-c7ccccc7)n6n5)c4)c3)n2)cc1 ; c1ccc(-c2nc(-c3ccccc3)nc(-c3ccc(-c4ccc(-c5nc6c7ccccc7nc(-c7ccccc7)n6n5)cc4)cc3)n2)cc1 ; c1ccc(-c2cccc(-c3nc4ccccc4c4nc(-c5ccc(-c6ccc(-c7nc(-c8ccccc8)nc(-c8ccccc8)n7)cc6)cc5)nn34)c2)cc1]

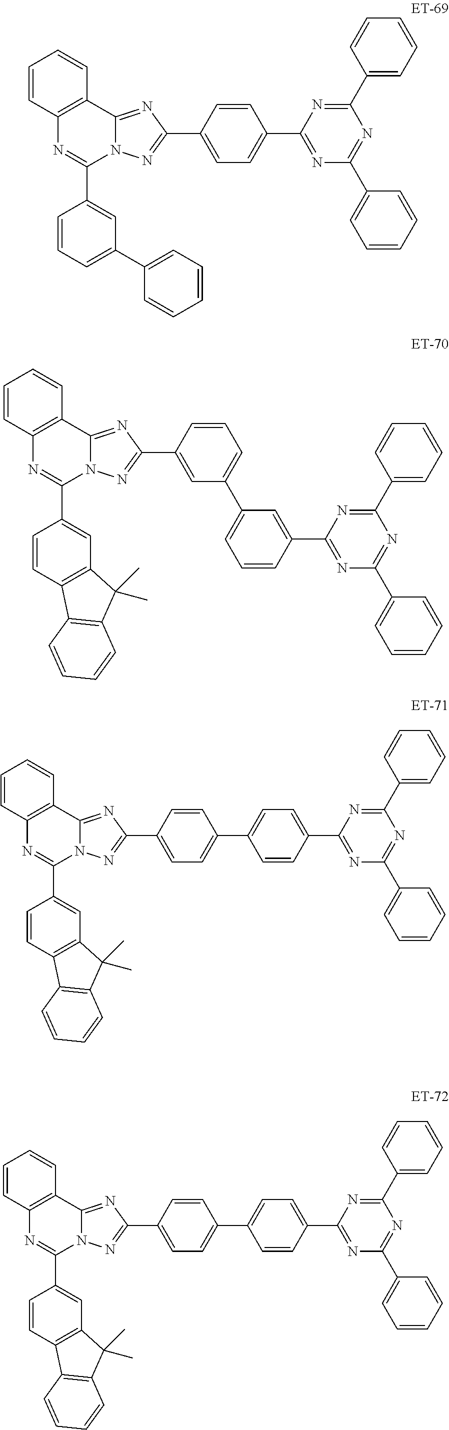 [SMILES: c1ccc(-c2cccc(-c3nc4ccccc4c4nc(-c5ccc(-c6nc(-c7ccccc7)nc(-c7ccccc7)n6)cc5)nn34)c2)cc1 ; CC1(C)c2ccccc2-c2ccc(-c3nc4ccccc4c4nc(-c5cccc(-c6cccc(-c7nc(-c8ccccc8)nc(-c8ccccc8)n7)c6)c5)nn34)cc21 ; CC1(C)c2ccccc2-c2ccc(-c3nc4ccccc4c4nc(-c5ccc(-c6ccc(-c7nc(-c8ccccc8)nc(-c8ccccc8)n7)cc6)cc5)nn34)cc21 ; CC1(C)c2ccccc2-c2ccc(-c3nc4ccccc4c4nc(-c5ccc(-c6ccc(-c7nc(-c8ccccc8)nc(-c8ccccc8)n7)cc6)cc5)nn34)cc21]

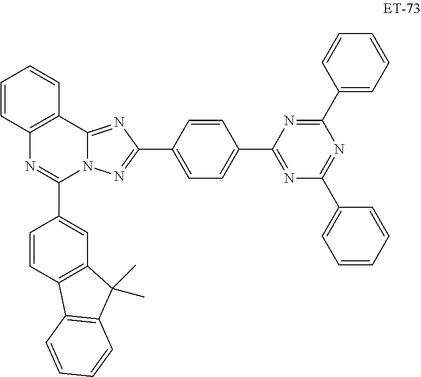 [SMILES: CC1(C)c2ccccc2-c2ccc(-c3nc4ccccc4c4nc(-c5ccc(-c6nc(-c7ccccc7)nc(-c7ccccc7)n6)cc5)nn34)cc21]

In addition, the material of the hole blocking layer may include, but is not limited to, one or more of the ET-1 to ET-73 above and the PH-1 to PH-46 above.

In addition, the material of the electron injection layer may include, but is not limited to, one or more of LiQ, LiF, NaCl, CsF, Li₂O, CS₂CO₃, BaO, Na, Li, Ca, Mg, or Y b.

An example of the present application further provides a display apparatus, comprising the organic light-emitting diode described above. The display apparatus may specifically be a display device such as an OLED display, and any product or component comprising the display device and having a display function, such as a television, a digital camera, a mobile phone and a tablet computer. The display apparatus has the same advantages as the organic light-emitting diode described above compared to the prior art, and no more detailed description is to be given here.

The organic light-emitting diode of the present application will be further introduced with specific examples below.

In the following examples, the full width at half maximum of the narrow-spectrum fluorescent material used (e.g., A 68, A 84, A 92, A 227, A 231, A 232, A 244, and A 266) is between 30-35 nm; and the full width at half maximum of the phosphorescent material RPD-8 is about 65 nm.

In the following examples and comparative examples, the current efficiency and L 95 lifespan of the devices in the examples and comparative examples are measured, and the ratios of the current efficiency of the devices in the examples and comparative examples to the current efficiency of the device in comparative example 1 are calculated, respectively, as the efficiency ratios. The results are shown in Table 1. The ratios of the L 95 lifespan of the devices in the examples and comparative examples to the L 95 lifespan of the device in comparative example 1 are calculated, respectively, as the lifespan ratios, and the results are shown in Table 1.

Herein, the current efficiency of the organic light-emitting diodes provided in examples and comparative examples of devices is measured using a digital source meter and PR 650 under the same luminance. Specifically, the voltage is increased at a rate of 0.1 V/see, and when the luminance of the device reaches 6,000 cd/m², the current efficiency (CE) of the device at this time can be directly determined on PR 650.

The LT95 lifespan test is as follows: at a constant current, the time taken for luminance to decrease from 10000 cd/m² to 9500 cd/m² of the organic light-emitting diodes is measured using a luminance meter, in hour (h).

### Example 1

The device in this example was a top red light-emitting stacked-layer device, which had a structure as shown in FIG. 2 and was prepared by a method including the following steps:

(1) a top-emitting substrate coated with an ITO conductive layer (anode) was sonicated in a commercial cleaning agent, rinsed in deionized water, sonicated in a mixed solvent of acetone: ethanol to remove oil, baked in a clean environment until moisture was completely removed, and cleaned with ultraviolet light and ozone, and then the surface was bombarded with a low-energy cation beam;

(2) the top-emitting substrate with an ITO conductive layer described above was placed in a vacuum cavity evacuated to less than 1×10⁻⁵ Pa; and an HT-28 material and an HI-2 material were co-evaporated onto the anode layer film as a first hole injection layer, where the proportion of the HI-2 material was 3%, the evaporation rate of the HT-28 material was 1 Å/s, and the total thickness of the evaporated film (i.e., the thickness of the first hole injection layer) was 100 Å; 3% was based on the sum of the mass of the HT-24 material and the HI-2 material of 100%, i.e., the total mass of the second hole injection layer of 100%; the percentages below were all based on the total mass of the corresponding functional layer of 100%; in addition, the total thickness of the evaporated film was the thickness of the corresponding functional layer formed via evaporation, which will not be explained in detail;

(3) a first hole transport layer was evaporated onto the first hole injection layer under vacuum using an HT-28 material at an evaporation rate of 1 Å/s, with the total thickness of the evaporated film being 250 Å;

(4) a first electron blocking layer was evaporated onto the first hole transport layer under vacuum using an HT-29 material at an evaporation rate of 1 Å/s, with the total thickness of the evaporated film being 250 Å;

(5) a first light-emitting layer comprising 94% of a host material PH5, 5% of a phosphorescent sensitizer PRD8, and 1% of a narrow-spectrum fluorescent dye A 227 was co-evaporated onto the first electron blocking layer, where a multi-source co-evaporation method was used, the host material was evaporated at a rate of 1 Å/s, and the total thickness of the evaporated film was 400 Å;

(6) a second hole blocking layer was evaporated onto the first light-emitting layer under vacuum using a PH-31 material at an evaporation rate of 1 Å/s, with the total thickness of the evaporated film being 50 Å;

(7) an ET-52 material and an ET-57 material, in a mass ratio of 1:1, were co-evaporated onto the second hole blocking layer under vacuum as a second electron transport layer, with the evaporation rate of the two materials being 1 Å/s, and the total thickness of the evaporated film being 200 Å;

(8) a CGL-3 material and metal Y b were co-evaporated onto the second electron transport layer as an n-type charge generation layer, with CGL-3 evaporated at a rate of 1 Å/s, the proportion of metal Y b being 3%, and a total thickness being 100 Å;

(9) an HI-2 material and an HT-28 material were evaporated onto the n-type charge generation layer as a p-type charge generation layer, with HT-28 evaporated at a rate of 1 Å/s, the proportion of HI-2 being 5%, and a total thickness being 100 Å;

(10) a second hole transport layer was evaporated onto the p-type charge generation layer under vacuum using an HT-28 material, with an evaporation rate being 1 Å/s, and the total thickness of the evaporated film being 250 Å;

(11) a second electron blocking layer was evaporated onto the second hole transport layer under vacuum using an HT-29 material, with an evaporation rate being 1 Å/s, and the total thickness of the evaporated film being 450 Å;

(12) a second light-emitting layer comprising 94% of a host material PH5 and 6% of a phosphorescent material PRD8 was co-evaporated onto the second electron blocking layer, where a multi-source co-evaporation method was used, the host material was evaporated at a rate of 1 Å/s, and the total thickness of the evaporated film was 400 Å;

(13) a first hole blocking layer was evaporated onto the second light-emitting layer under vacuum using a PH-31 material, with an evaporation rate being 1 Å/s, and the total thickness of the evaporated film being 50 Å;

(14) an ET-52 material and an ET-57 material, in a mass ratio of 1:1, were co-evaporated onto the first hole blocking layer under vacuum as a first electron transport layer, with the evaporation rate of the two materials being 1 Å/s, and the total thickness of the evaporated film being 280 Å;

(15) a Y b material was evaporated onto the first electron transport layer under vacuum as a first electron injection layer with a thickness of 10 Å;

(16) M g and A g materials, in a mass ratio of 1:9 (i.e., M g:Ag=1:9), were evaporated onto the first electron injection layer as a cathode, with the total thickness of the evaporated film being 130 Å; and

(17) a CPL-3 material was evaporated onto the cathode as a capping layer, with CPL-3 evaporated at a rate of 1 Å/s, and the total thickness of the evaporated film being 650 Å.

Example 2: The conditions of Example 2 were the same as those of Example 1, with the only exception that the second light-emitting layer was a phosphorescence sensitized layer (with the same composition as that of the first light-emitting layer (the phosphorescence sensitized layer) in Example 1), and the first light-emitting layer is a phosphorescence layer (with the same composition as that of the second light-emitting layer (the phosphorescence layer) in Example 1).

Example 3: The conditions of Example 3 were the same as those of Example 1, with the only exception that both the first light-emitting layer and the second light-emitting layer were phosphorescence sensitized layers (with the same composition as that of the first light-emitting layer (the phosphorescence sensitized layer) in Example 1); in addition, the preparation process for the device of Example 3 differed from that of Example 1 only in that, in step (12), a second light-emitting layer including 94% of a host material PH5, 5% of a phosphorescent sensitizer PRD8, and 1% of a narrow-spectrum fluorescent dye A 227 was co-evaporated onto the second electron blocking layer under vacuum, using a multi-source co-evaporation method, with the host material evaporated at a rate of 1 Å/s, and the total thickness of evaporated film being 400 Å.

Examples 4-12: Examples 4-12 differed from Example 3 only in that, different narrow-spectrum fluorescent materials were used in the phosphorescence sensitized layer, and the narrow-spectrum fluorescent materials used in Examples 3-12 were shown in Table 1.

Examples 13-20: The conditions of Examples 13-20 were the same as those of Example 3, with the only exception that the types of the host materials in the phosphorescence sensitized layer were different. See Table 1 for details.

Examples 21-25: The conditions of Examples 21-25 were the same as those of Example 3, with the only exception that the types of the phosphorescent sensitizers in the phosphorescence sensitized layer were different. See Table 1 for details.

Examples 26-36: The conditions of Examples 26-36 were the same as those of Example 3, with the only exception that, in the phosphorescence sensitized layer, the mass contents of the host material, the phosphorescent sensitizer and the fluorescent material were different. See Table 1 for details;

Examples 37-38: Examples 37-38 differed from Example 3 only in that the composition of the first light-emitting layer and the second light-emitting layer was different. See Table 1 for details.

Example 39: Example 39 differed from Example 3 only in that the composition of the second light-emitting layer was different. See Table 1 for details.

Comparative example 1: The conditions of Comparative example 1 were the same as those of Example 1, except that both the first light-emitting layer and the second light-emitting layer were phosphorescence layers (with the same composition as that of the second light-emitting layer (the phosphorescence layer) in Example 1);

Comparative example 2: The conditions of Comparative example 2 were the same as those of Example 1, except that the device was one with a single light-emitting layer, having a structure as shown in FIG. 1, i.e. including an anode, a first hole injection layer, a first hole transport layer, a first electron blocking layer, a first light-emitting layer (a phosphorescence sensitized layer), a first hole blocking layer, a first electron transport layer, a first electron injection layer, and a cathode, which were stacked sequentially. The device with a single light-emitting layer was prepared according to steps (1)-(5) and (13)-(17) in Example 1, which will not be repeated.

Comparative example 3: Comparative example 3 differed from Example 3 only in that the composition of the first light-emitting layer and the second light-emitting layers was different. See Table 1 for details.

Herein, PH′-1, RPD′-1, and A′-1 had the following structural formula:

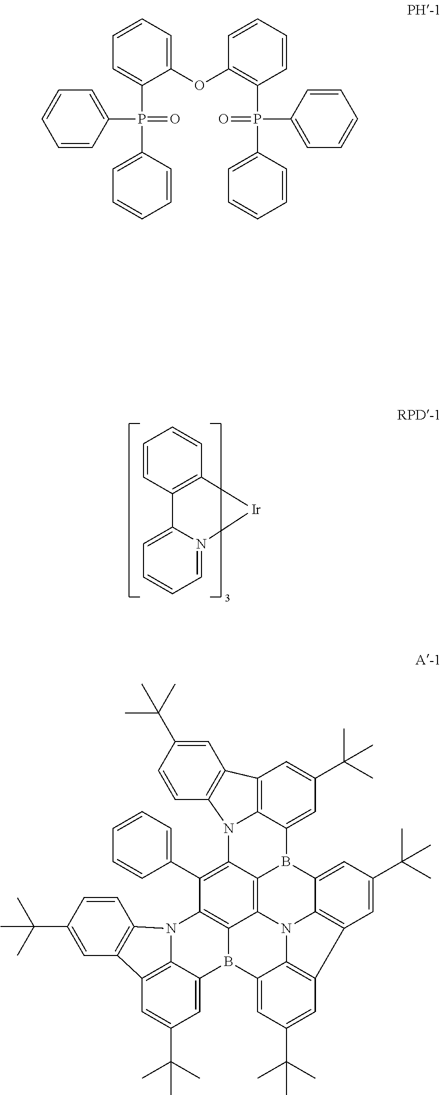

The composition of the first and second light-emitting layers in Examples 1-39 and Comparative examples 1-3, and the performance test results of the devices were summarized in Table 1.

TABLE 1

| | Composition of first light- | | | Composition of second light- | | | | |
|---|---|---|---|---|---|---|---|---|
| | emitting layer | | | emitting layer | | | | |
| | (Percentage refers to the mass | | | (Percentage refers to the mass | | | | |
| | content of a material in the | | | content of a material in the | | | Performance of | |
| | first light-emitting layer) | | | second light-emitting layer) | | | device | |
| | Host | Phosphorescent | Fluorescent | Host | Phosphorescent | Fluorescent | Efficiency | Lifespan |
| Example | material | sensitizer | material | material | sensitizer | material | ratio | ratio |
| Comparative | PH-5, | RPD-8, | / | PH-5, | RPD-8, | / | 100% | 100% |
| example 1 | 94% | 6% | | 94% | 6% | | | |
| Comparative | PH-5, | RPD-8, | A 227, | / | / | / | 61% | 81% |
| example 2 | 94% | 5% | 1% | | | | | |
| Comparative | PH′-1, | RPD′-1, | A′-1, | PH′-1, | RPD′-1, | A′-1, | 88% | 25% |
| example 3 | 89% | 10% | 1% | 89% | 10% | 1% | | |
| Example | PH-5, | RPD-8, | A 227, | PH-5, | RPD-8, | / | 112% | 159% |
| 1 | 94% | 5% | 1% | 94% | 6% | | | |
| Example | PH-5, | RPD-8, | / | PH-5, | RPD-8, | A 227, | 119% | 172% |
| 2 | 94% | 6% | | 94% | 5% | 1% | | |
| Example | PH-5, | RPD-8, | A 227, | PH-5, | RPD-8, | A 227, | 127% | 229% |
| 3 | 94% | 5% | 1% | 94% | 5% | 1% | | |
| Example | PH-5, | RPD-8, | A 231, | PH-5, | RPD-8, | A 231, | 143% | 243% |
| 4 | 94% | 5% | 1% | 94% | 5% | 1% | | |
| Example | PH-5, | RPD-8, | A 232, | PH-5, | RPD-8, | A 232, | 145% | 251% |
| 5 | 94% | 5% | 1% | 94% | 5% | 1% | | |
| Example | PH-5, | RPD-8, | A 244, | PH-5, | RPD-8, | A 244, | 141% | 221% |
| 6 | 94% | 5% | 1% | 94% | 5% | 1% | | |
| Example | PH-5, | RPD-8, | A 252, | PH-5, | RPD-8, | A 252, | 133% | 213% |
| 7 | 94% | 5% | 1% | 94% | 5% | 1% | | |
| Example | PH-5, | RPD-8, | A 255, | PH-5, | RPD-8, | A 255, | 131% | 211% |
| 8 | 94% | 5% | 1% | 94% | 5% | 1% | | |
| Example | PH-5, | RPD-8, | A 266, | PH-5, | RPD-8, | A 266, | 138% | 218% |
| 9 | 94% | 5% | 1% | 94% | 5% | 1% | | |
| Example | PH-5, | RPD-8, | A 68, | PH-5, | RPD-8, | A 68, | 124% | 207% |
| 10 | 94% | 5% | 1% | 94% | 5% | 1% | | |
| Example | PH-5, | RPD-8, | A 84, | PH-5, | RPD-8, | A 84, | 121% | 204% |
| 11 | 94% | 5% | 1% | 94% | 5% | 1% | | |
| Example | PH-5, | RPD-8, | A 92, | PH-5, | RPD-8, | A 92, | 122% | 201% |
| 12 | 94% | 5% | 1% | 94% | 5% | 1% | | |
| Example | PH-41, | RPD-8, | A 227, | PH-41, | RPD-8, | A 227, | 117% | 217% |
| 13 | 94% | 5% | 1% | 94% | 5% | 1% | | |
| Example | PH-47, | RPD-8, | A 227, | PH-47, | RPD-8, | A 227, | 123% | 224% |
| 14 | 94% | 5% | 1% | 94% | 5% | 1% | | |
| Example | PH-59, | RPD-8, | A 227, | PH-59, | RPD-8, | A 227, | 121% | 221% |
| 15 | 94% | 5% | 1% | 94% | 5% | 1% | | |
| Example | PH-60, | RPD-8, | A 227, | PH-60, | RPD-8, | A 227, | 119% | 218% |
| 16 | 94% | 5% | 1% | 94% | 5% | 1% | | |
| Example | PH-70 | RPD-8, | A 227, | PH-70, | RPD-8, | A 227, | 117% | 214% |
| 17 | 94% | 5% | 1% | 94% | 5% | 1% | | |
| Example | PH-77, | RPD-8, | A 227, | PH-77 | RPD-8, | A 227, | 118% | 217% |
| 18 | 94% | 5% | 1% | 94% | 5% | 1% | | |
| Example | PH-41:PH-60 = | RPD-8, | A 227, | PH-41:PH-60 = | RPD-8, | A 227, | 126% | 227% |
| 19 | 1:1, 94%* | 5% | 1% | 1:1, 94%* | 5% | 1% | | |
| Example | PH-5:PH-47 = | RPD-8, | A 227, | PH-5:PH-47 = | RPD-8, | A 227, | 128% | 231% |
| 20 | 1:1, 94%* | 5% | 1% | 1:1, 94%* | 5% | 1% | | |
| Example | PH-5, | RPD-15, | A 227, | PH-5, | RPD-15, | A 227, | 124% | 268% |
| 21 | 94% | 5% | 1% | 94% | 5% | 1% | | |
| Example | PH-5, | RPD-29, | A 227, | PH-5, | RPD-29, | A 227, | 131% | 282% |
| 22 | 94% | 5% | 1% | 94% | 5% | 1% | | |
| Example | PH-5, | RPD-20, | A 227, | PH-5, | RPD-20, | A 227, | 135% | 287% |
| 23 | 94% | 5% | 1% | 94% | 5% | 1% | | |
| Example | PH-5, | RPD-22, | A 227, | PH-5, | RPD-22, | A 227, | 122% | 265% |
| 24 | 94% | 5% | 1% | 94% | 5% | 1% | | |
| Example | PH-5, | RPD-27, | A 227, | PH-5, | RPD-27, | A 227, | 121% | 264% |
| 25 | 94% | 5% | 1% | 94% | 5% | 1% | | |
| Example | PH-5, | RPD-8, | A 227, | PH-5, | RPD-8, | A 227, | 117% | 191% |
| 26 | 94.7% | 5% | 0.3% | 94.7% | 5% | 0.3% | | |
| Example | PH-5, | RPD-8, | A 227, | PH-5, | RPD-8, | A 227, | 121% | 198% |
| 27 | 94.5% | 5% | 0.5% | 94.5% | 5% | 0.5% | | |
| Example | PH-5, | RPD-8, | A 227, | PH-5, | RPD-8, | A 227, | 131% | 233% |
| 28 | 93% | 5% | 2% | 93% | 5% | 2% | | |
| Example | PH-5, | RPD-8, | A 227, | PH-5, | RPD-8, | A 227, | 125% | 226% |
| 29 | 90% | 5% | 5% | 90% | 5% | 5% | | |
| Example | PH-5, | RPD-8, | A 227, | PH-5, | RPD-8, | A 227, | 114% | 181% |
| 30 | 75% | 5% | 20% | 75% | 5% | 20% | | |
| Example | PH-5, | RPD-8, | A 227, | PH-5, | RPD-8, | A 227, | 119% | 187% |
| 31 | 98.5% | 0.5% | 1% | 98.5% | 0.5% | 1% | | |
| Example | PH-5, | RPD-8, | A 227, | PH-5, | RPD-8, | A 227, | 123% | 219% |
| 32 | 98% | 1% | 1% | 98% | 1% | 1% | | |
| Example | PH-5, | RPD-8, | A 227, | PH-5, | RPD-8, | A 227, | 125% | 226% |
| 33 | 97% | 2% | 1% | 97% | 2% | 1% | | |
| Example | PH-5, | RPD-8, | A 227, | PH-5, | RPD-8, | A 227, | 119% | 211% |
| 34 | 89% | 10% | 1% | 89% | 10% | 1% | | |
| Example | PH-5, | RPD-8, | A 227, | PH-5, | RPD-8, | A 227, | 113% | 194% |
| 35 | 79% | 20% | 1% | 79% | 20% | 1% | | |
| Example | PH-5, | RPD-8, | A 227, | PH-5, | RPD-8, | A 227, | 105% | 189% |
| 36 | 59% | 40% | 1% | 59% | 40% | 1% | | |
| Example | PH-5, | RPD-8, | A 227, | PH-47, | RPD-15, | A 227, | 121% | 222% |
| 37 | 94% | 5% | 1% | 94% | 5% | 1% | | |
| Example | PH-5, | RPD-8, | A 227, | PH-5, | RPD-8, | A 227, | 124% | 226% |
| 38 | 94% | 5% | 1% | 97% | 2% | 1% | | |
| Example | PH-5, | RPD-8, | A 227, | PH′-1, | RPD′-1, | A′-1, | 78% | 101% |
| 39 | 94% | 5% | 1% | 89% | 10% | 1% | | |

*denotes that the mass ratio of the two host materials is 1:1, and the sum of the mass contents of the two host materials in the light-emitting layer is 94%. For example, “PH-41:PH-60 = 1:1, 94%” means that: in the first light-emitting layer, the mass ratio of PH-41 to PH-60 is 1:1, and the ratio of the sum of the mass of PH-41 and PH-60 to the total mass of the first light-emitting layer is 94%.

As can be seen from Table 1, compared to Comparative example 1, the devices prepared in Examples 1-38 having at least one light-emitting layer that is a phosphorescence sensitized layer have significantly improved efficiency and service life; and compared to Comparative example 2, the performance such as the efficiency and service life of the stacked-layer devices having two light-emitting layers are more significantly improved.

In addition, it can be seen from Examples 1-3 that the devices having a first light-emitting layer and a second light-emitting layer that are both phosphorescence sensitized layers exhibit better performance, such as better efficiency and service life.

In addition, as can be seen from Examples 3-12, the efficiency and service life of devices using fluorescent materials A 227, A 231, A 232, A 244, A 252, A 255 and A 266 (Examples 3-9) are better than that of the devices using fluorescent materials A 68, A 84 and A 92 (Examples 10-12), which demonstrates that when the substituents R¹ and R² in the molecular structure of the fluorescent material are at a meta position of a carbon atom linked to an O atom, the stacked-layer device using such fluorescent materials exhibit better performance. Comparatively, A 227, A 231, A 232 and A 244 having structures as represented by Formula V-3 result in better service life and other performance. It can be seen that the R¹, R², R³, R⁴, R^{3X}, R^{4X} and other substituents will affect the performance of the device to some extent, and the devices using A 231 and A 232 exhibit more significantly improved efficiency and lifetime.

In addition, as can be seen from Examples 26-36, comparatively, when the content of the narrow-spectrum fluorescent material is in the range of 0.1-5%, more preferably 0.5-2%, and the content of the phosphorescent sensitizer does not exceed 10%, the devices will exhibit better performance, such as better efficiency and service life.

As can be seen from Example 3, Example 39, and Comparative example 3, different host materials, sensitizers, and fluorescent materials will affect the service life and efficiency of the devices. In Example 3, both the light-emitting layers are phosphorescence sensitized layers introduced with a narrow-spectrum fluorescent material with a full width at half maximum of less than 45 nm, matched with a specific host material and sensitizer, such that the resulting device exhibits more excellent performance, such as more excellent efficiency and service life.

What is claimed is:

1. An organic light-emitting diode, comprising at least one light-emitting layer, which comprises at least one phosphorescence sensitized layer, wherein the phosphorescence sensitized layer comprises a host material, a phosphorescent sensitizer, and a narrow-spectrum fluorescent material, and a full width at half maximum of the narrow-spectrum fluorescent material is less than 45 nm.

2. The organic light-emitting diode according to claim 1, wherein the light-emitting layer has a thickness of 200 Å-500 Å.

3. The organic light-emitting diode according to claim 2, wherein the light-emitting layer has a thickness of 300 Å-400 Å.

4. The organic light-emitting diode according to claim 1, wherein the number of the light-emitting layers is at least two, and the at least two light-emitting layers are stacked.

5. The organic light-emitting diode according to claim 4, wherein the organic light-emitting diode further comprising an anode and a cathode; the at least two light-emitting layers comprise a first light-emitting layer and a second light-emitting layer; the cathode, the first light-emitting layer, the second light-emitting layer and the anode are provided sequentially; and the first light-emitting layer is the phosphorescence sensitized layer, or the second light-emitting layer is the phosphorescence sensitized layer, or both the first light-emitting layer and the second light-emitting layer are the phosphorescence sensitized layers.

6. The organic light-emitting diode according to claim 1, wherein a luminescence peak of the narrow-spectrum fluorescent material is 550 nm-680 nm.

7. The organic light-emitting diode according to claim 6, wherein the emission peak of the narrow-spectrum fluorescent material is 590 nm-650 nm.

8. The organic light-emitting diode according to claim 1, wherein the narrow-spectrum fluorescent material comprises one or more of compounds having structures represented by Formula V-1, Formula V-2 and Formula V-3 below: 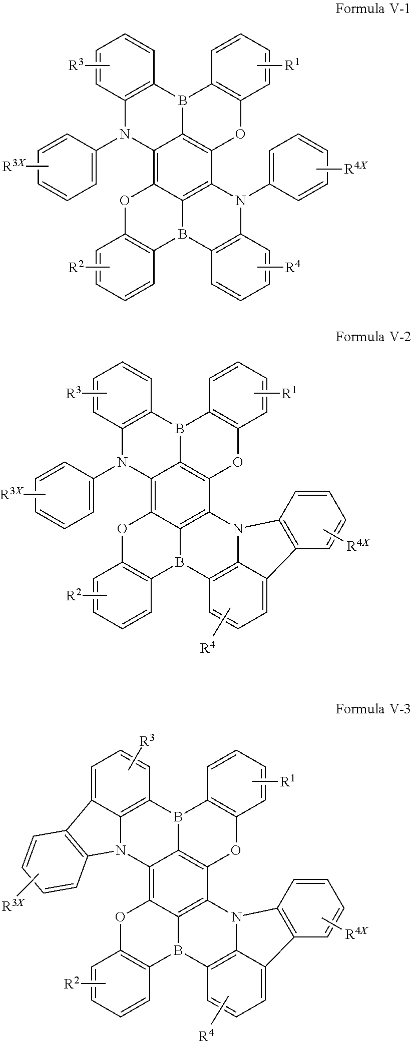
wherein R¹, R², R³, R⁴, R^{3X} and R^{4X}, each independently, represent one to the maximum permissible substituents, and R 1 and R² are each independently selected from any one of substituted or unsubstituted C1-C20 linear or branched alkyl, substituted or unsubstituted C3-C20 cycloalkyl, and substituted or unsubstituted C1-C20 alkylsilyl, and R³, R⁴, R^{3X} and R^{4X} are each independently selected from any one of substituted or unsubstituted C6-C60 aryl, and substituted or unsubstituted C3-C60 heteroarylthe substituents of R¹, R², R³, R⁴, R 3X and R^{4X}, when substituted, are each independently selected from at least one of halogen, C1-C20 linear or branched alkyl, C3-C20 cycloalkyl, nitro, cyano, amino, hydroxyl, C1-C20 alkylsilyl, C6-C60 aryl, or C3-C60 heteroaryl; and R¹, R², R³, R 4, R 3X and R^{4X} are each independently not linked to or linked to an adjacent benzene ring structure to form a ring via a chemical bond.

9. The organic light-emitting diode according to claim 1, wherein R¹, R², R³, R⁴, R^{3X} and R^{4X}, each independently, represent one to the maximum permissible substituents, and R¹ and R² are each independently selected from any one of substituted or unsubstituted C6-C60 aryl, and substituted or unsubstituted C3-C60 heteroaryl, and R³, R⁴, R^{3X} and R^{4x} are each independently selected from any one of substituted or unsubstituted C1-C20 linear or branched alkyl, substituted or unsubstituted C3-C20 cycloalkyl, and substituted or unsubstituted C1-C20 alkylsilyl; the substituents of R¹, R², R³, R⁴, R^{3X} and R^{4X}, when substituted, are each independently selected from at least one of halogen, C1-C20 linear or branched alkyl, C3-C20 cycloalkyl, nitro, cyano, amino, hydroxyl, C1-C20 alkylsilyl, C6-C60 aryl, or C3-C60 heteroaryl; and R¹, R², R³, R⁴, R^{3X} and R^{4X} are each independently not linked to or linked to an adjacent benzene ring structure to form a ring via a chemical bond.

10. The organic light-emitting diode according to claim 8, wherein
R¹ and R² are the same groups;
and R³ and R⁴ are the same groups;
and R³, R⁴, R^{3X} and R^{4X} are the same groups;
and R¹ and R² are each independently linked to a meta position of a carbon atom linked to an O atom;
and R³ and R⁴ are linked to the para position of a carbon atom linked to a N atom.

11. The organic light-emitting diode according to claim 8, wherein
R¹ and R² are the same groups;
or R³ and R⁴ are the same groups;
or R³, R⁴, R^{3X} and R^{4X} are the same groups;
or R¹ and R² are each independently linked to a meta position of a carbon atom linked to an O atom;
or R³ and R⁴ are linked to the para position of a carbon atom linked to a N atom.

12. The organic light-emitting diode according to claim 9, wherein
R¹ and R² are the same groups;
and R³ and R⁴ are the same groups;
and R³, R⁴, R^{3X} and R^{4X} are the same groups;
and R¹ and R² are each independently linked to a meta position of a carbon atom linked to an O atom;
and R³ and R⁴ are linked to the para position of a carbon atom linked to a N atom.

13. The organic light-emitting diode according to claim 1, wherein the narrow-spectrum fluorescent material comprises one or more of the following compounds A 1 to A 268:

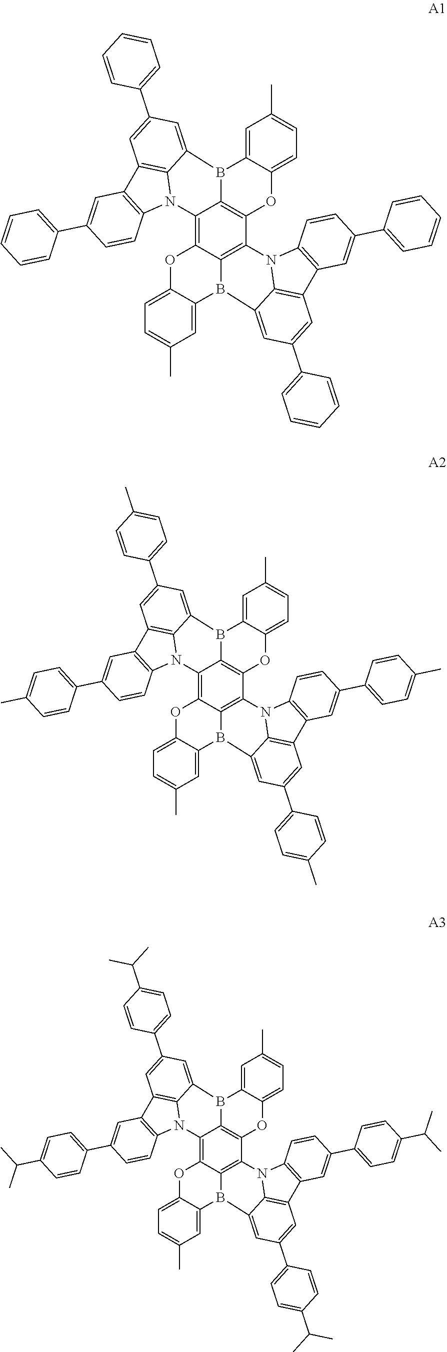

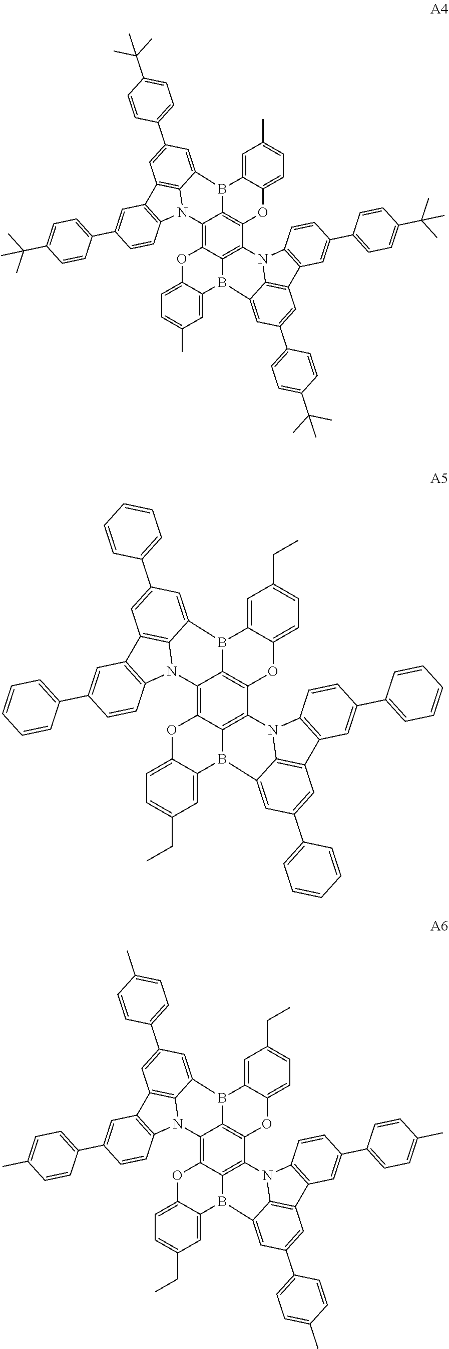

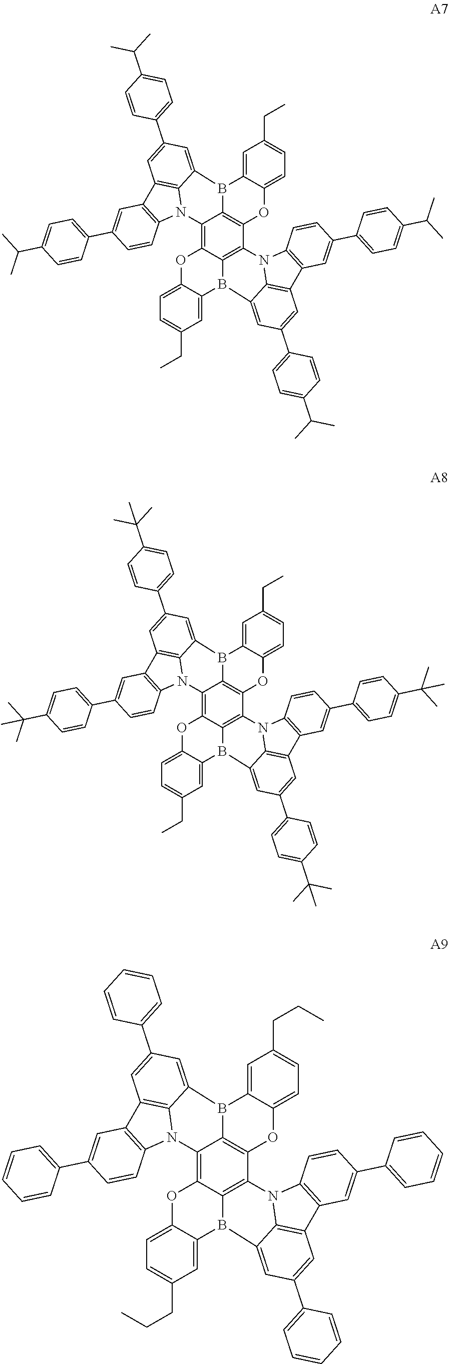

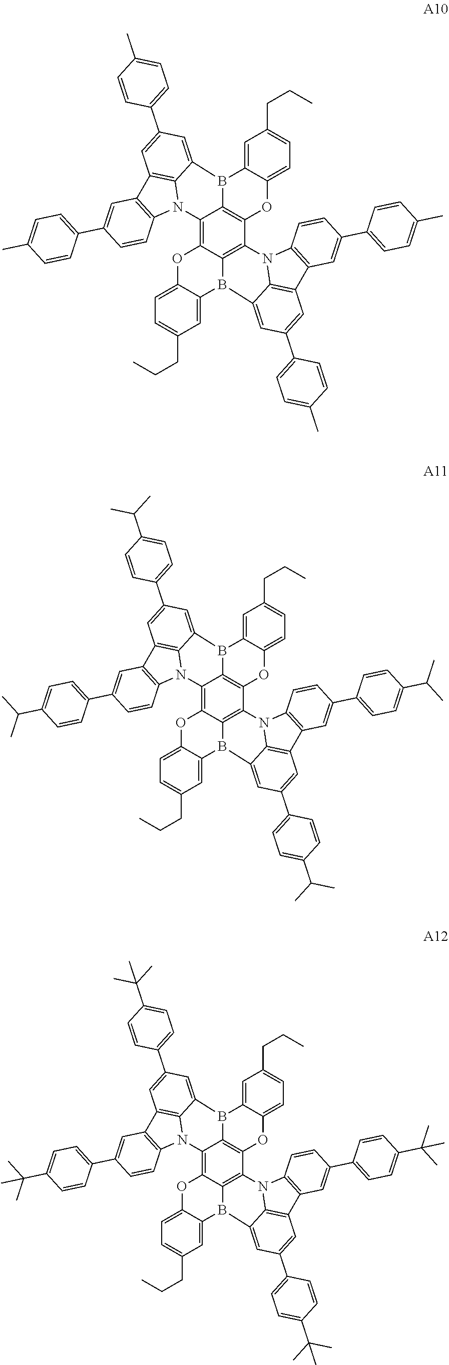

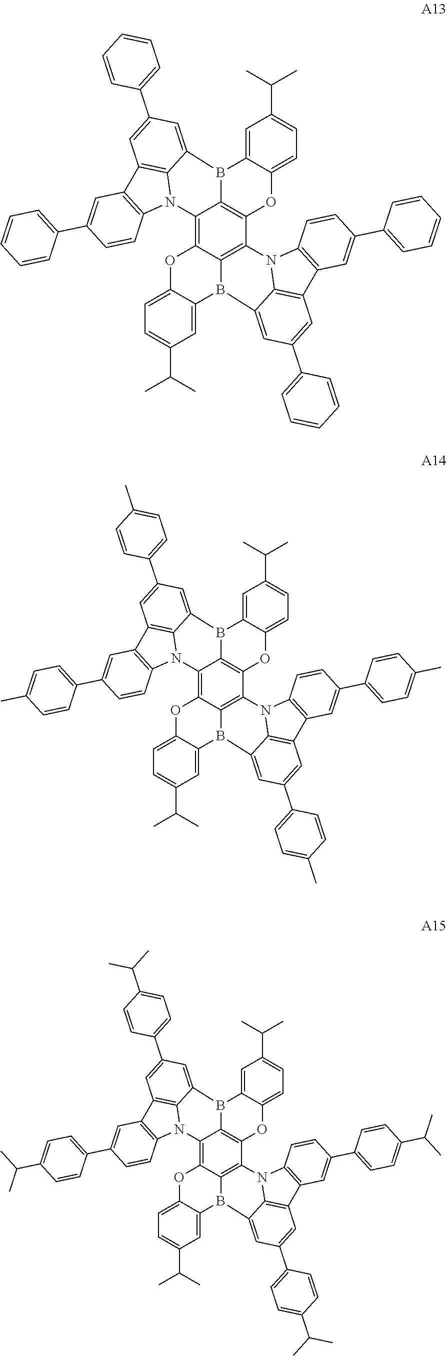

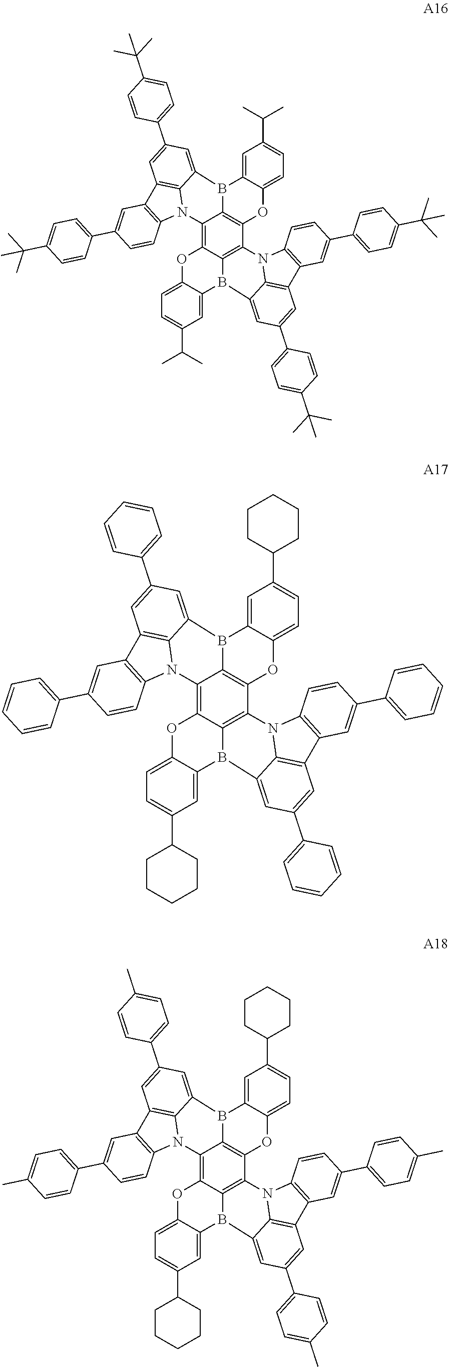

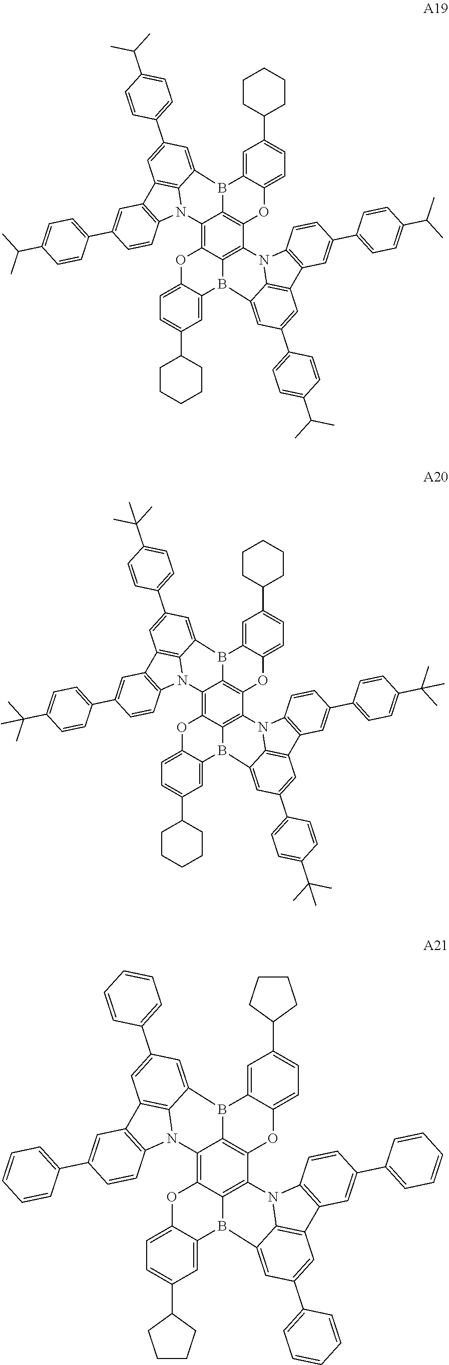

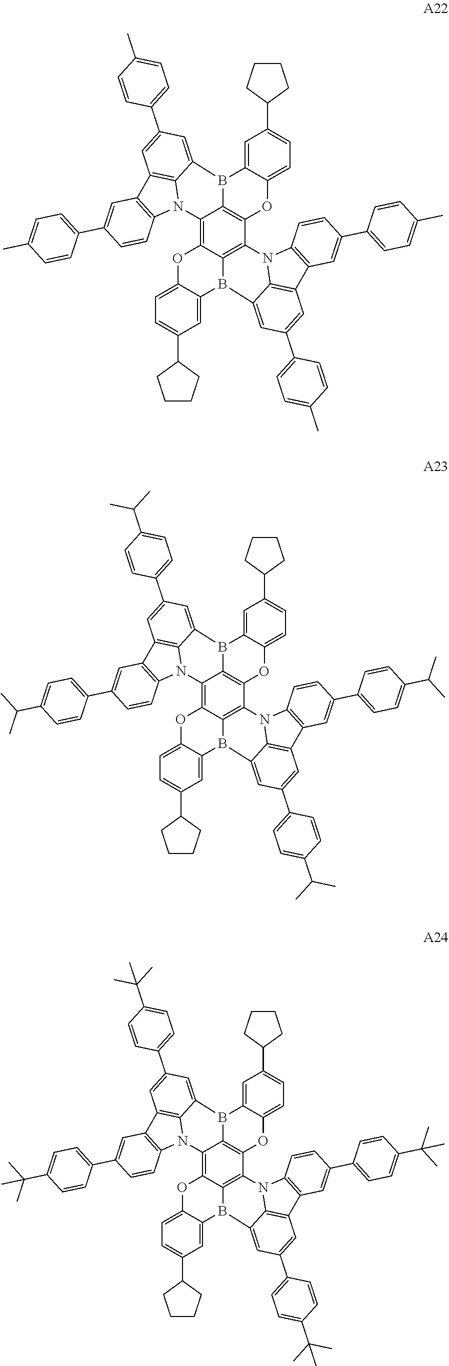

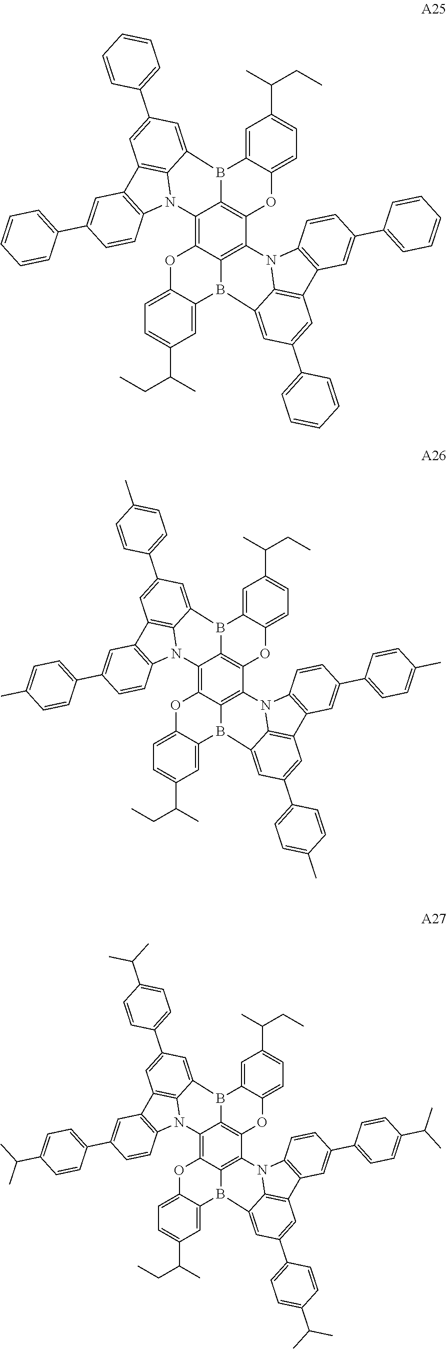

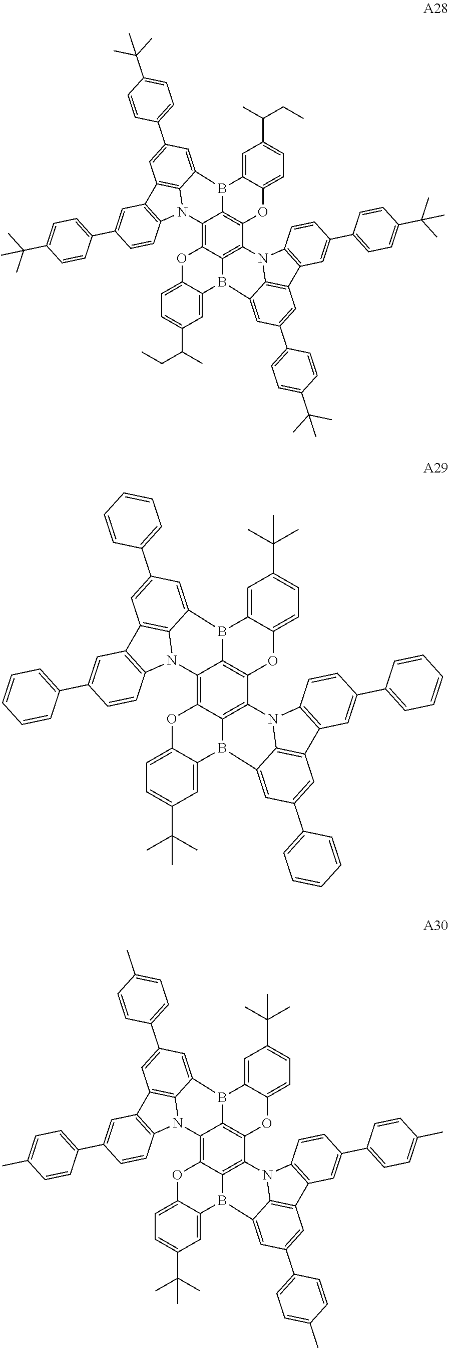

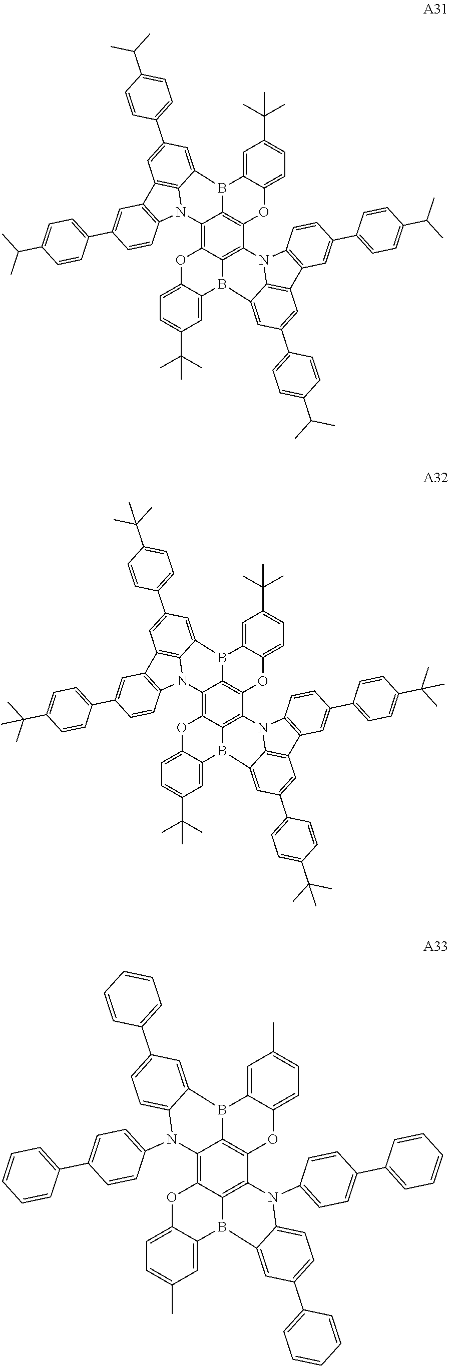

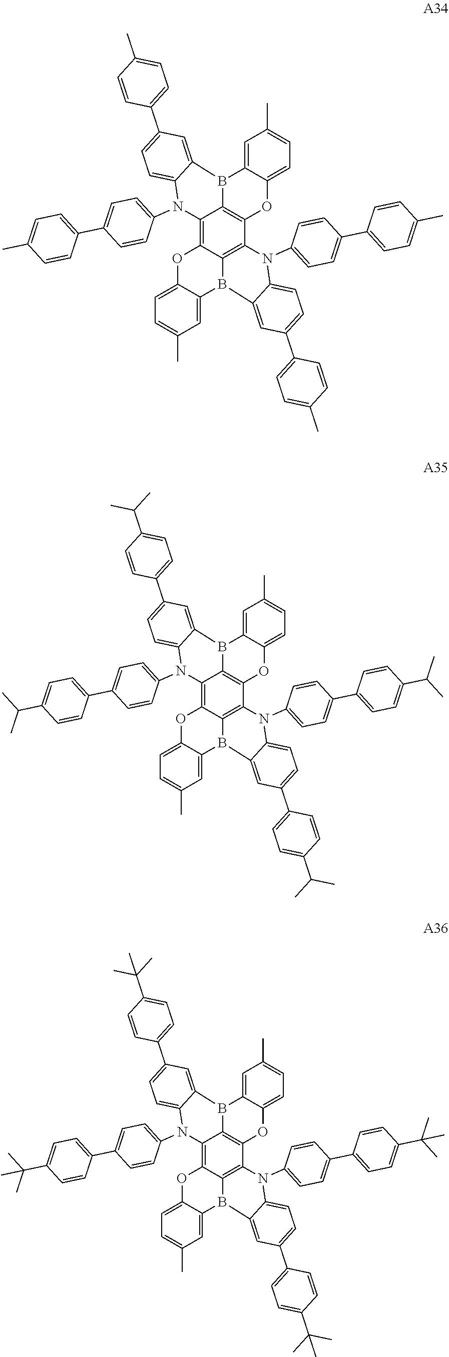

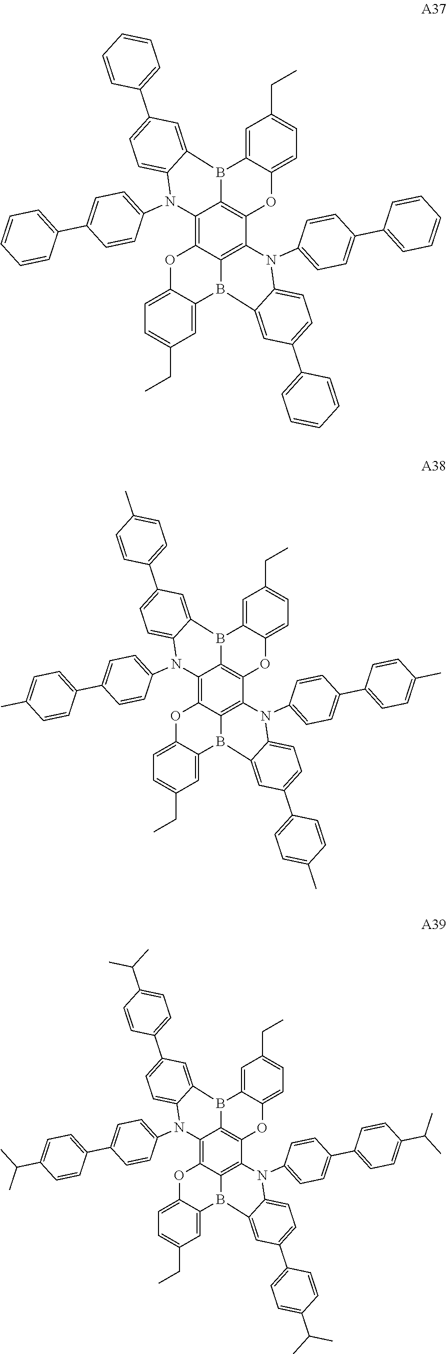

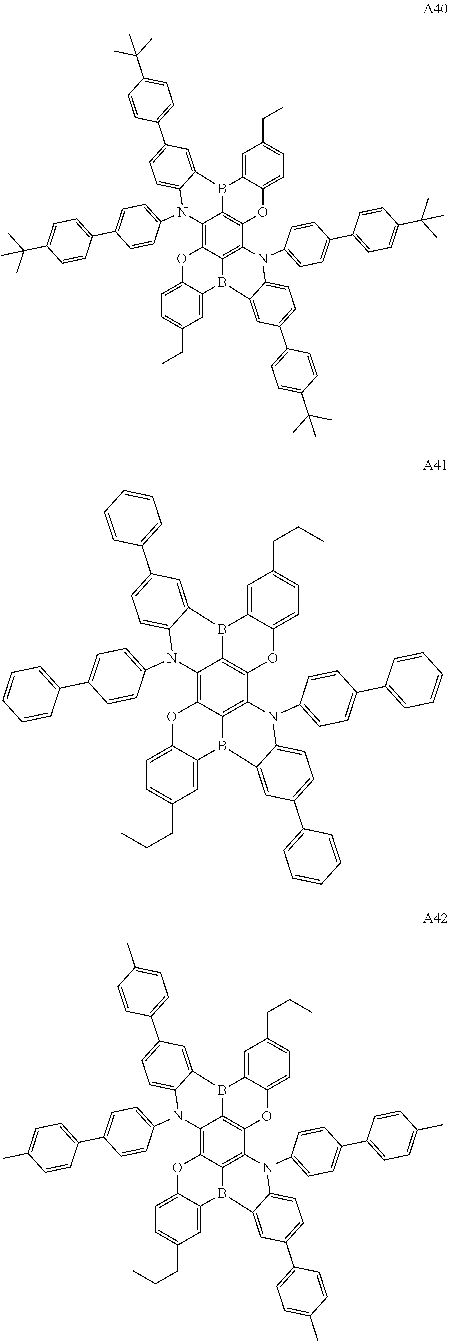

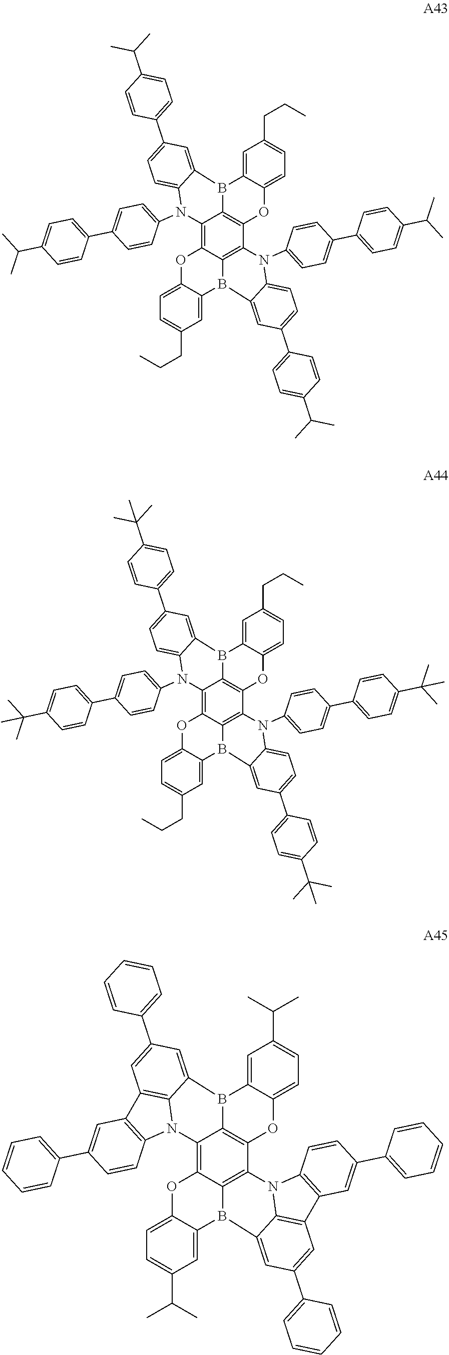

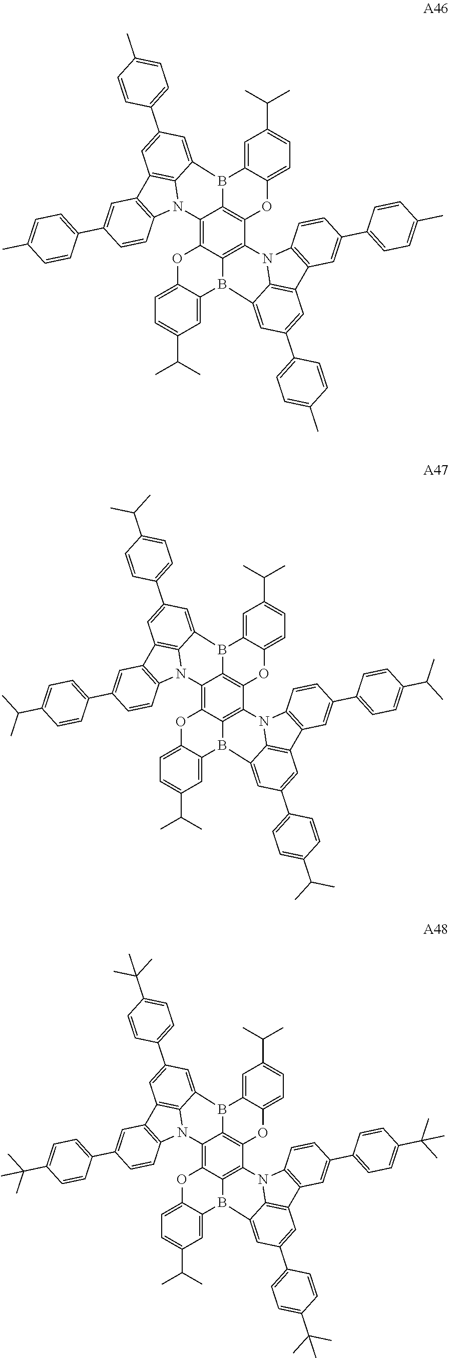

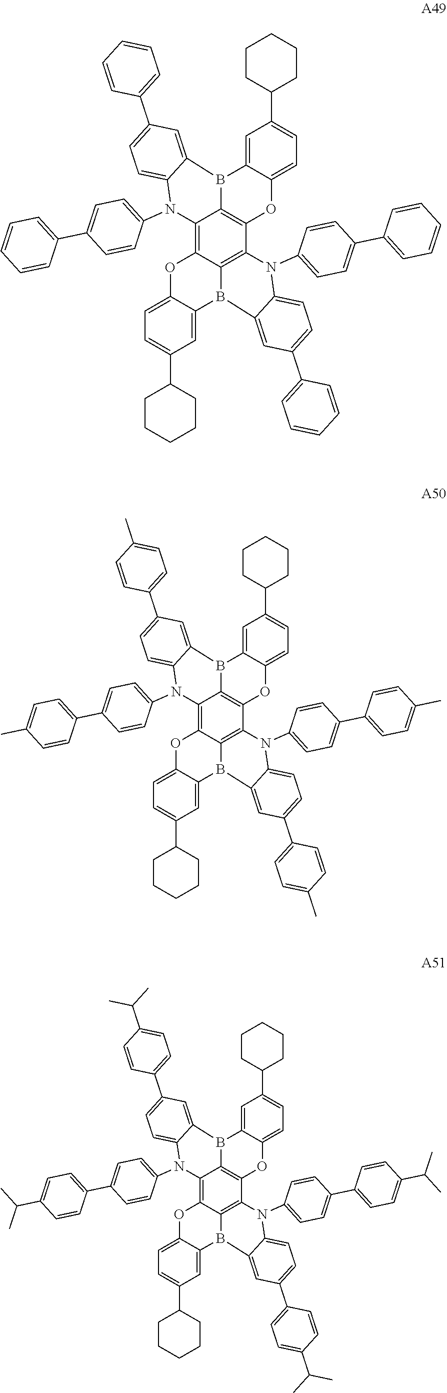

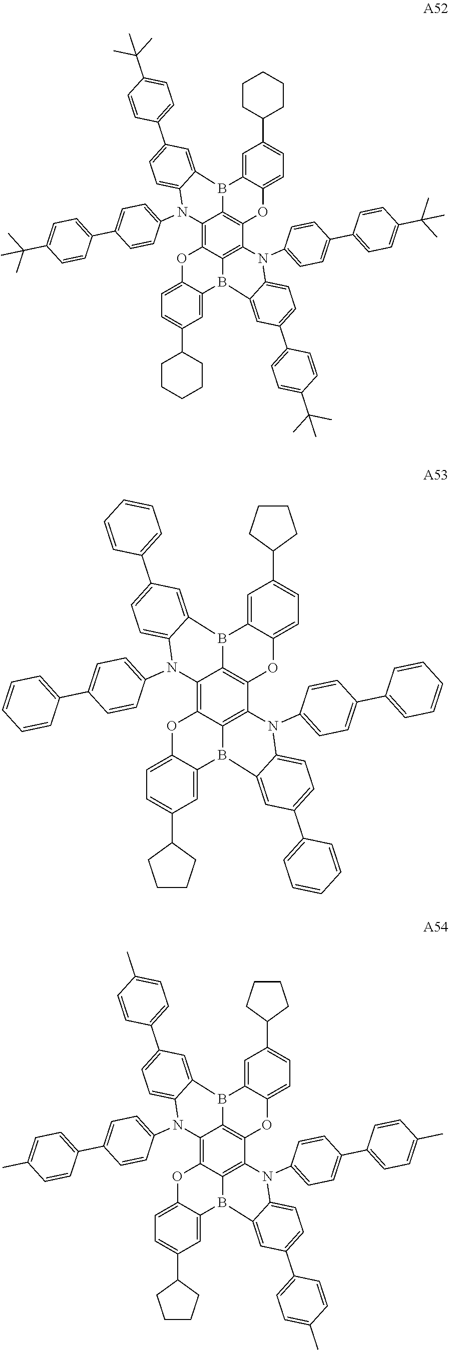

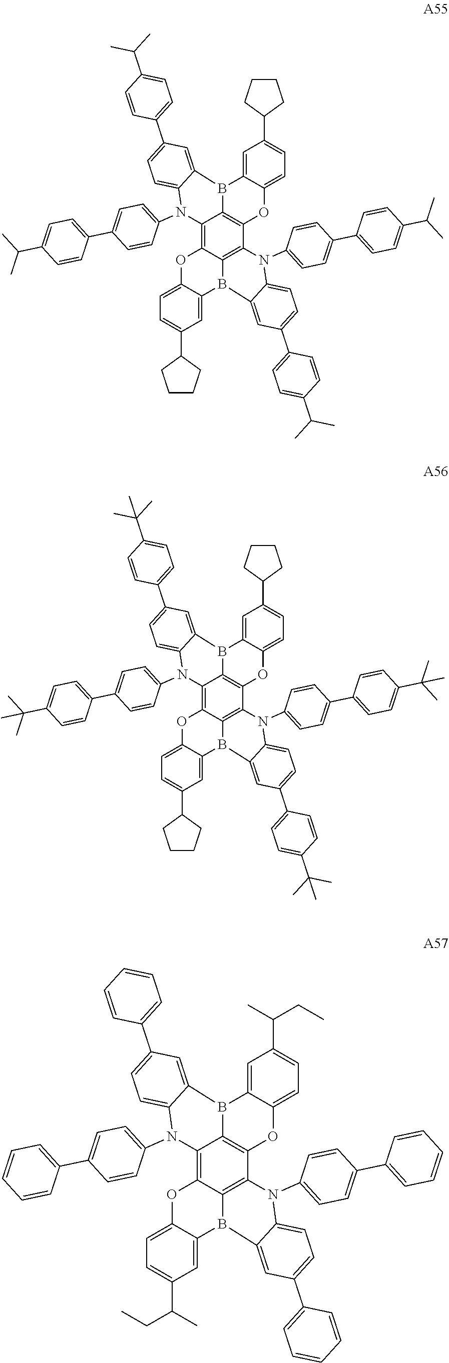

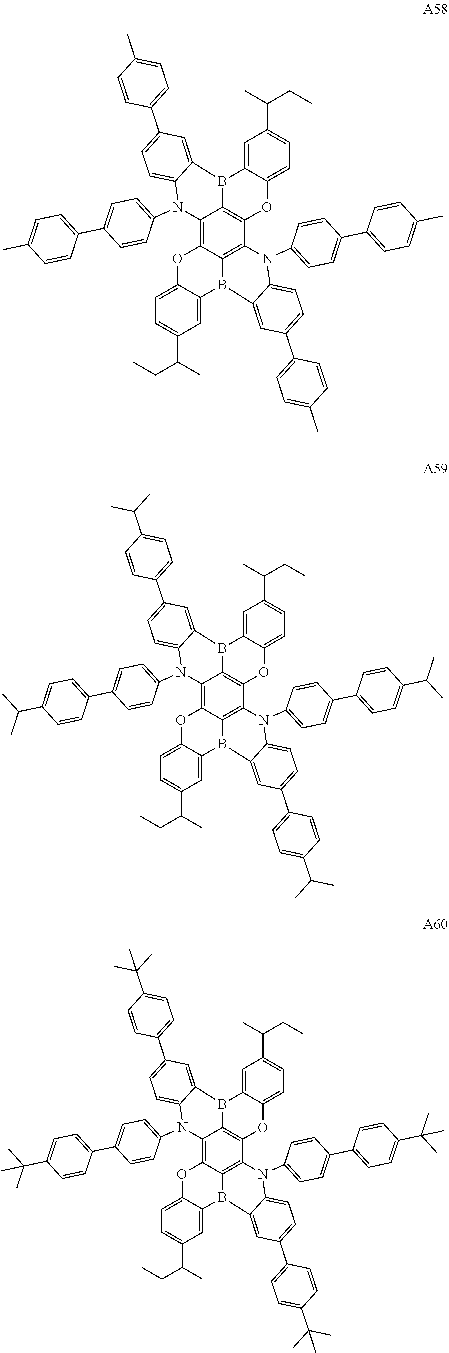

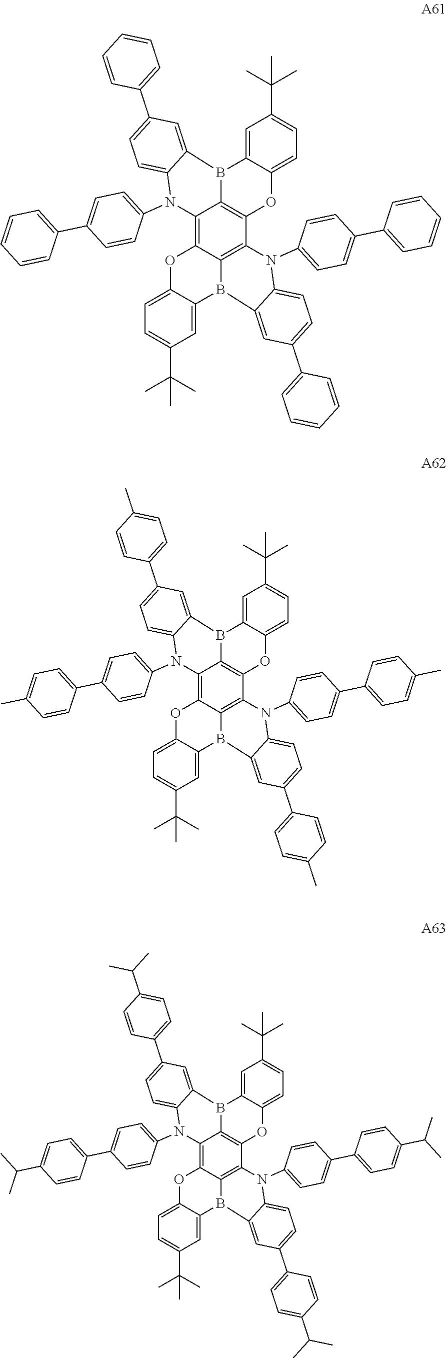

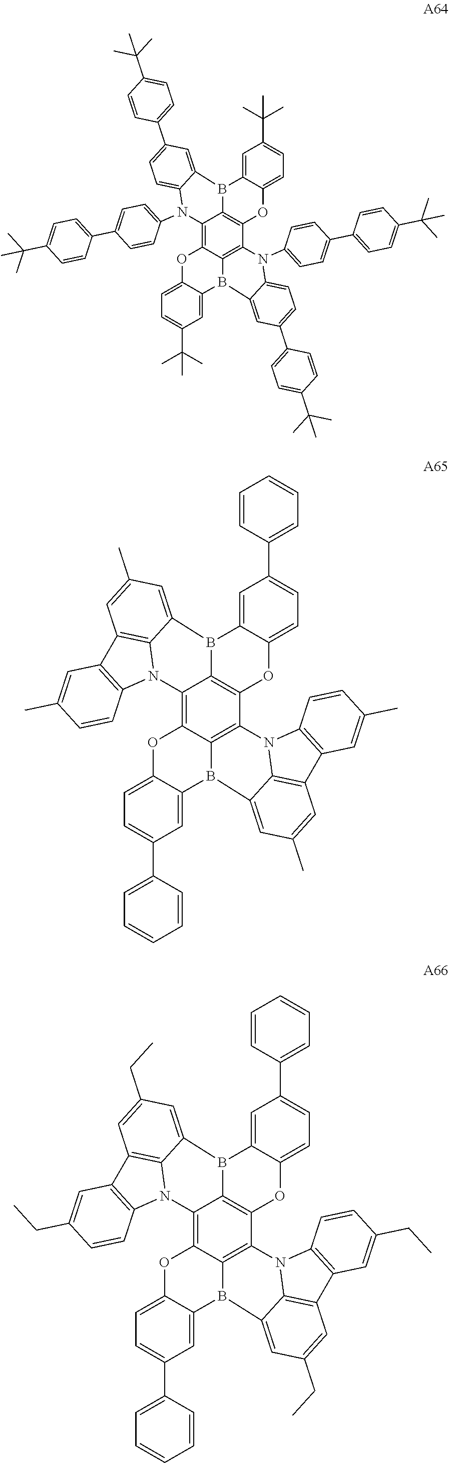

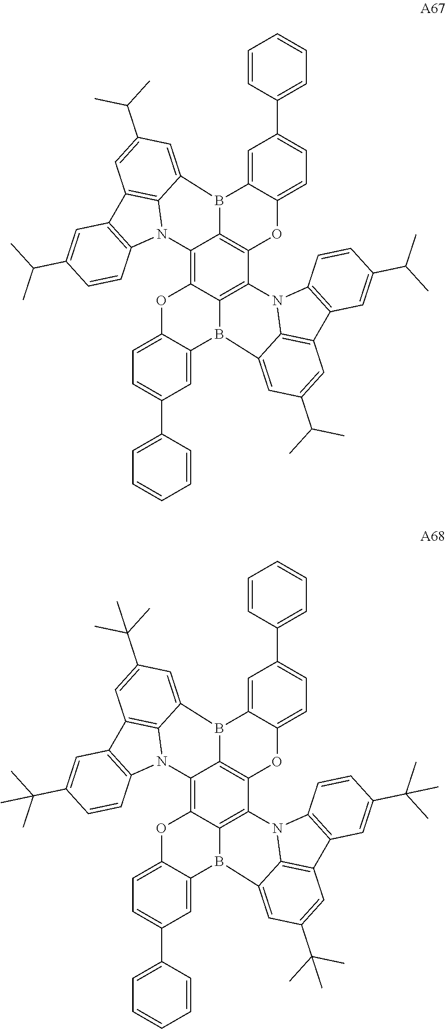

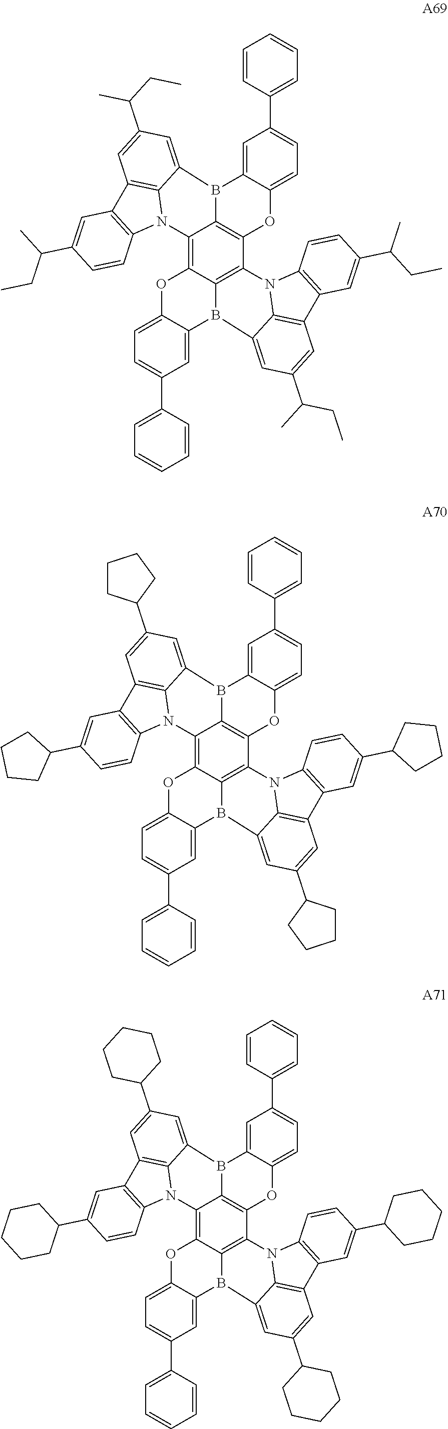 [SMILES: CCC(C)c1ccc2c(c1)c1cc(C(C)CC)cc3c1n2-c1c2c4c(c5c1B3c1cc(-c3ccccc3)ccc1O5)-n1c3ccc(C(C)CC)cc3c3cc(C(C)CC)cc(c31)B4c1cc(-c3ccccc3)ccc1O2 ; c1ccc(-c2ccc3c(c2)B2c4c(c5c6c(c4-n4c7ccc(C8CCCC8)cc7c7cc(C8CCCC8)cc2c74)Oc2ccc(-c4ccccc4)cc2B6c2cc(C4CCCC4)cc4c6cc(C7CCCC7)ccc6n-5c24)O3)cc1 ; c1ccc(-c2ccc3c(c2)B2c4c(c5c6c(c4-n4c7ccc(C8CCCCC8)cc7c7cc(C8CCCCC8)cc2c74)Oc2ccc(-c4ccccc4)cc2B6c2cc(C4CCCCC4)cc4c6cc(C7CCCCC7)ccc6n-5c24)O3)cc1]

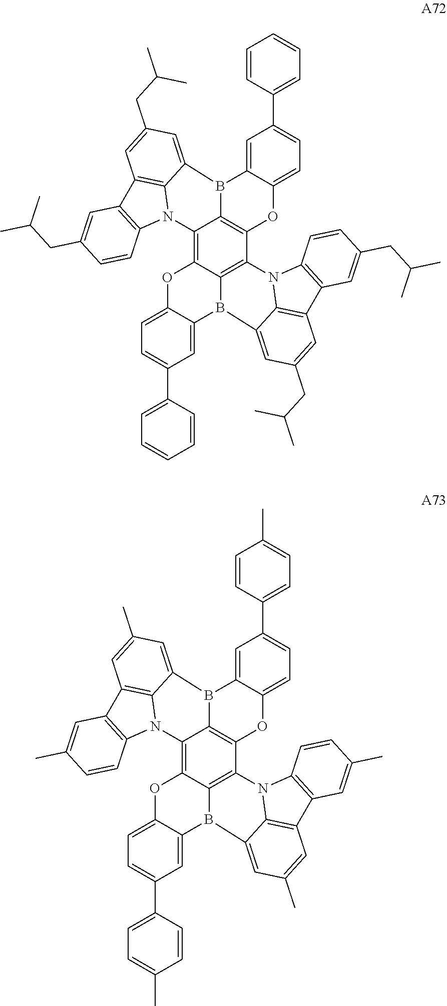

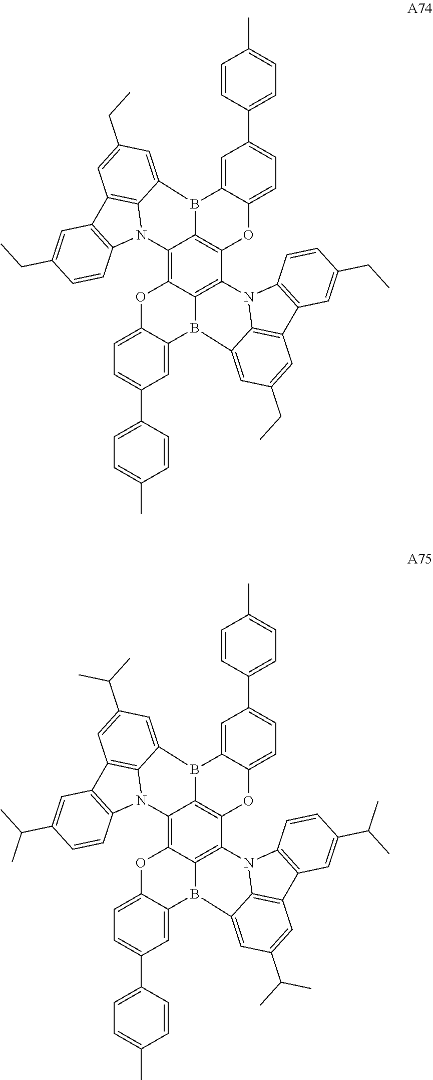

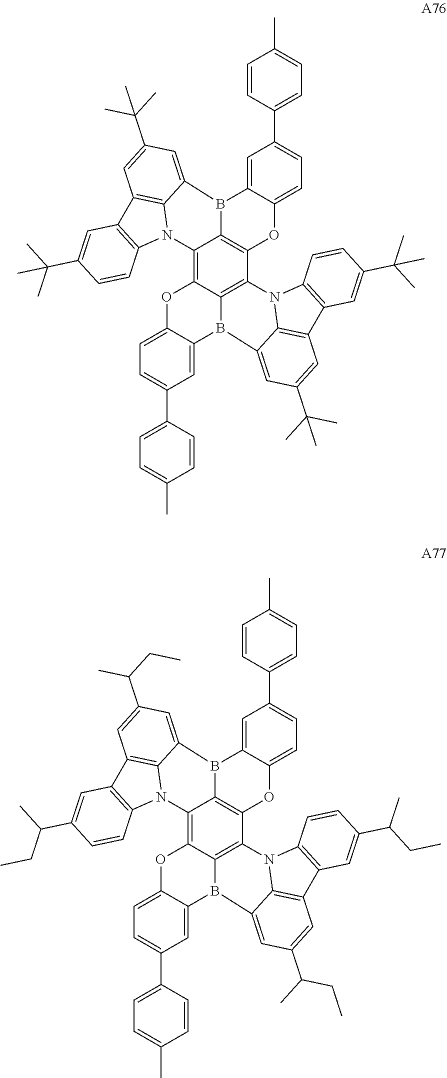

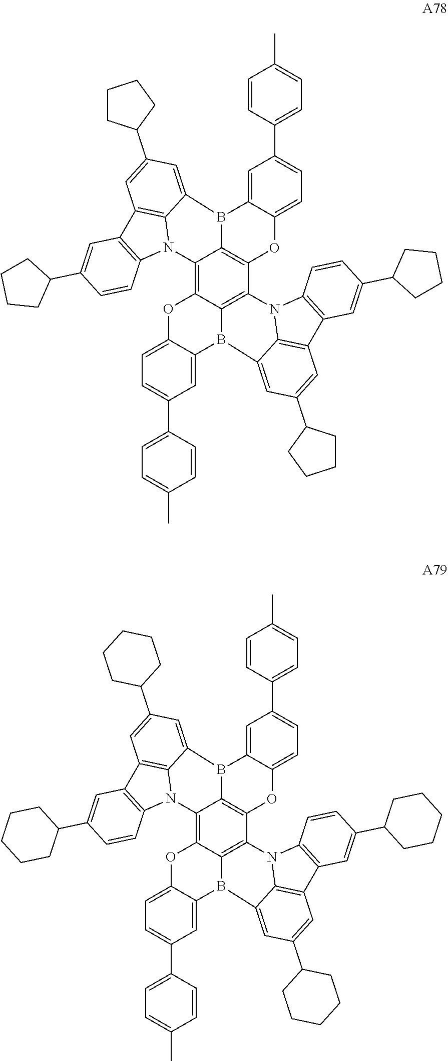 [SMILES: Cc1ccc(-c2ccc3c(c2)B2c4c(c5c6c(c4-n4c7ccc(C8CCCC8)cc7c7cc(C8CCCC8)cc2c74)Oc2ccc(-c4ccc(C)cc4)cc2B6c2cc(C4CCCC4)cc4c6cc(C7CCCC7)ccc6n-5c24)O3)cc1 ; Cc1ccc(-c2ccc3c(c2)B2c4c(c5c6c(c4-n4c7ccc(C8CCCCC8)cc7c7cc(C8CCCCC8)cc2c74)Oc2ccc(-c4ccc(C)cc4)cc2B6c2cc(C4CCCCC4)cc4c6cc(C7CCCCC7)ccc6n-5c24)O3)cc1]

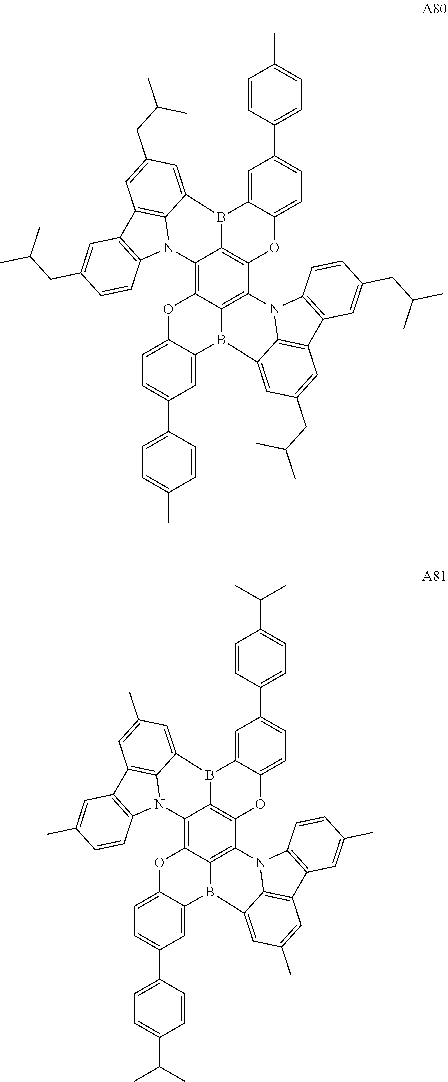

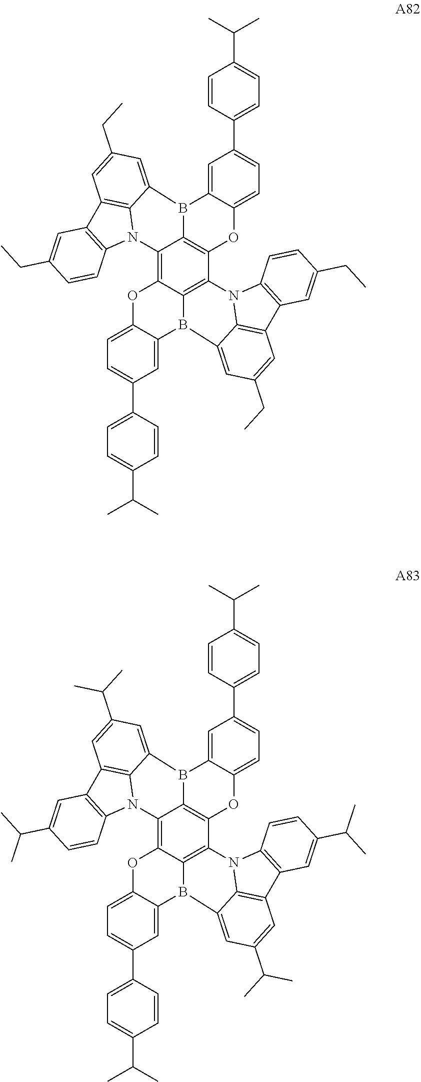

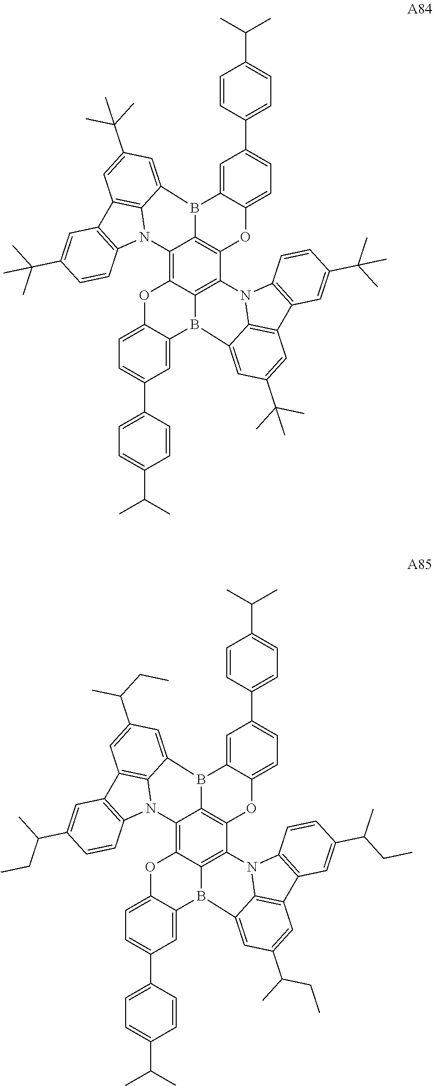

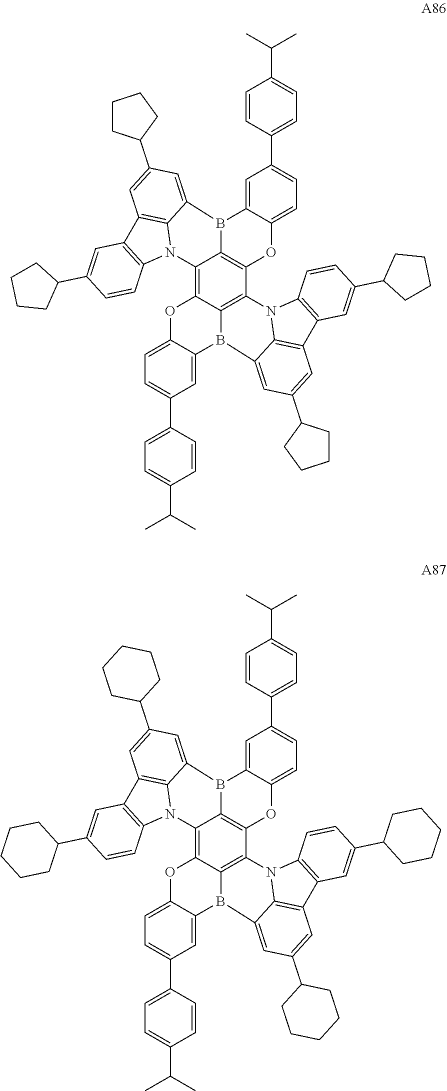 [SMILES: CC(C)c1ccc(-c2ccc3c(c2)B2c4c(c5c6c(c4-n4c7ccc(C8CCCC8)cc7c7cc(C8CCCC8)cc2c74)Oc2ccc(-c4ccc(C(C)C)cc4)cc2B6c2cc(C4CCCC4)cc4c6cc(C7CCCC7)ccc6n-5c24)O3)cc1 ; CC(C)c1ccc(-c2ccc3c(c2)B2c4c(c5c6c(c4-n4c7ccc(C8CCCCC8)cc7c7cc(C8CCCCC8)cc2c74)Oc2ccc(-c4ccc(C(C)C)cc4)cc2B6c2cc(C4CCCCC4)cc4c6cc(C7CCCCC7)ccc6n-5c24)O3)cc1]

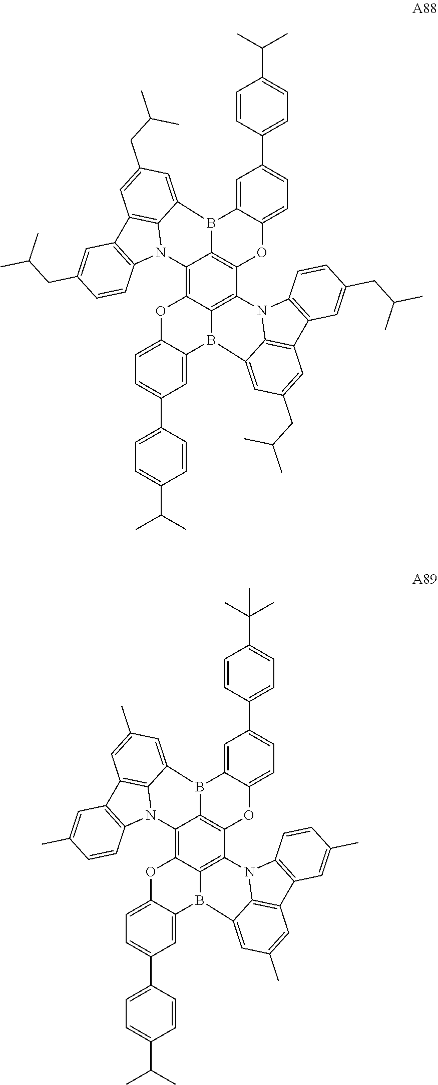

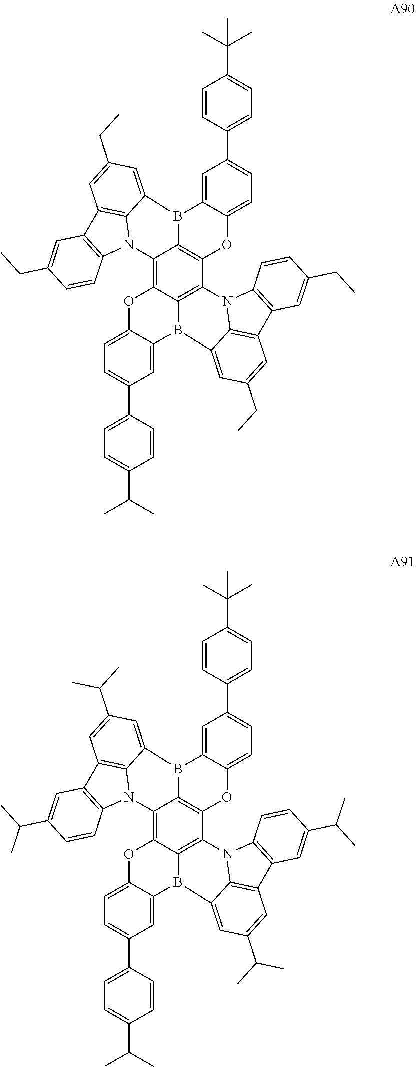

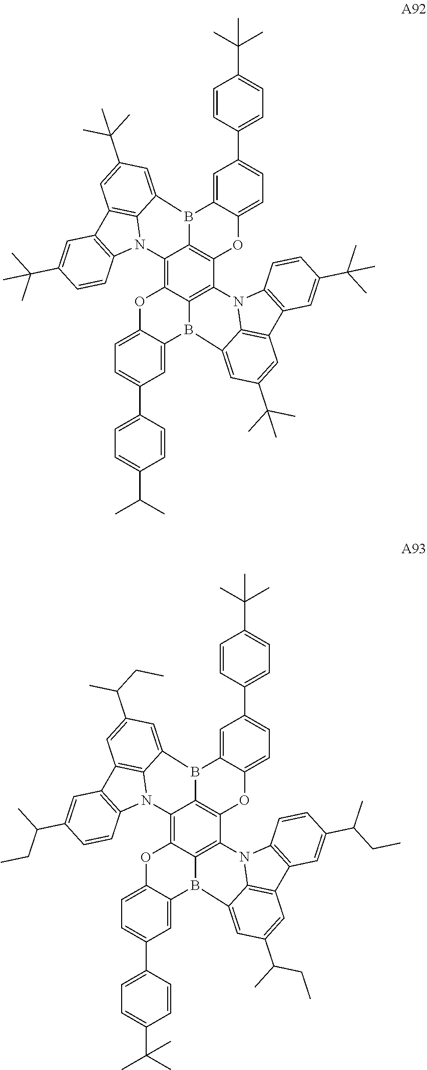

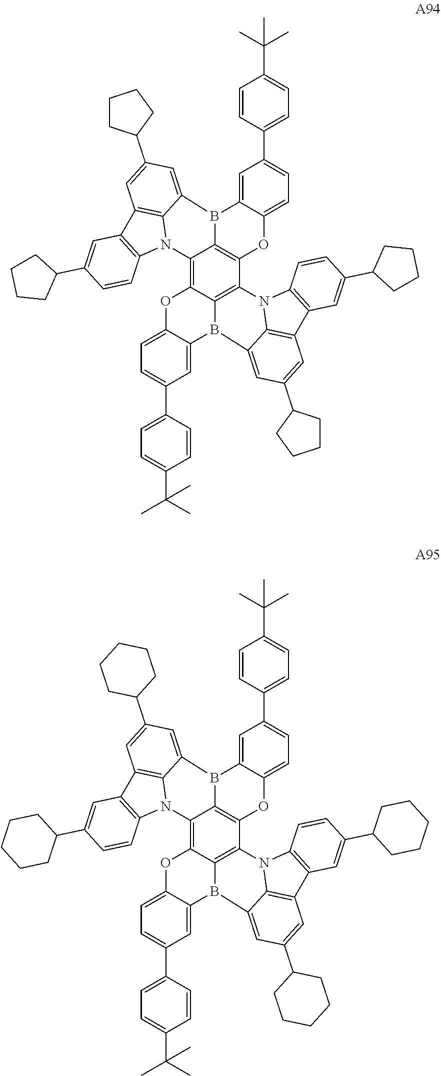 [SMILES: CC(C)(C)c1ccc(-c2ccc3c(c2)B2c4c(c5c6c(c4-n4c7ccc(C8CCCC8)cc7c7cc(C8CCCC8)cc2c74)Oc2ccc(-c4ccc(C(C)(C)C)cc4)cc2B6c2cc(C4CCCC4)cc4c6cc(C7CCCC7)ccc6n-5c24)O3)cc1 ; CC(C)(C)c1ccc(-c2ccc3c(c2)B2c4c(c5c6c(c4-n4c7ccc(C8CCCCC8)cc7c7cc(C8CCCCC8)cc2c74)Oc2ccc(-c4ccc(C(C)(C)C)cc4)cc2B6c2cc(C4CCCCC4)cc4c6cc(C7CCCCC7)ccc6n-5c24)O3)cc1]

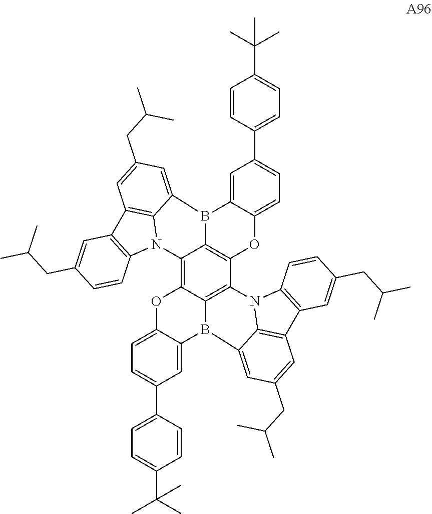 [SMILES: CC(C)Cc1ccc2c(c1)c1cc(CC(C)C)cc3c1n2-c1c2c4c(c5c1B3c1cc(-c3ccc(C(C)(C)C)cc3)ccc1O5)-n1c3ccc(CC(C)C)cc3c3cc(CC(C)C)cc(c31)B4c1cc(-c3ccc(C(C)(C)C)cc3)ccc1O2]

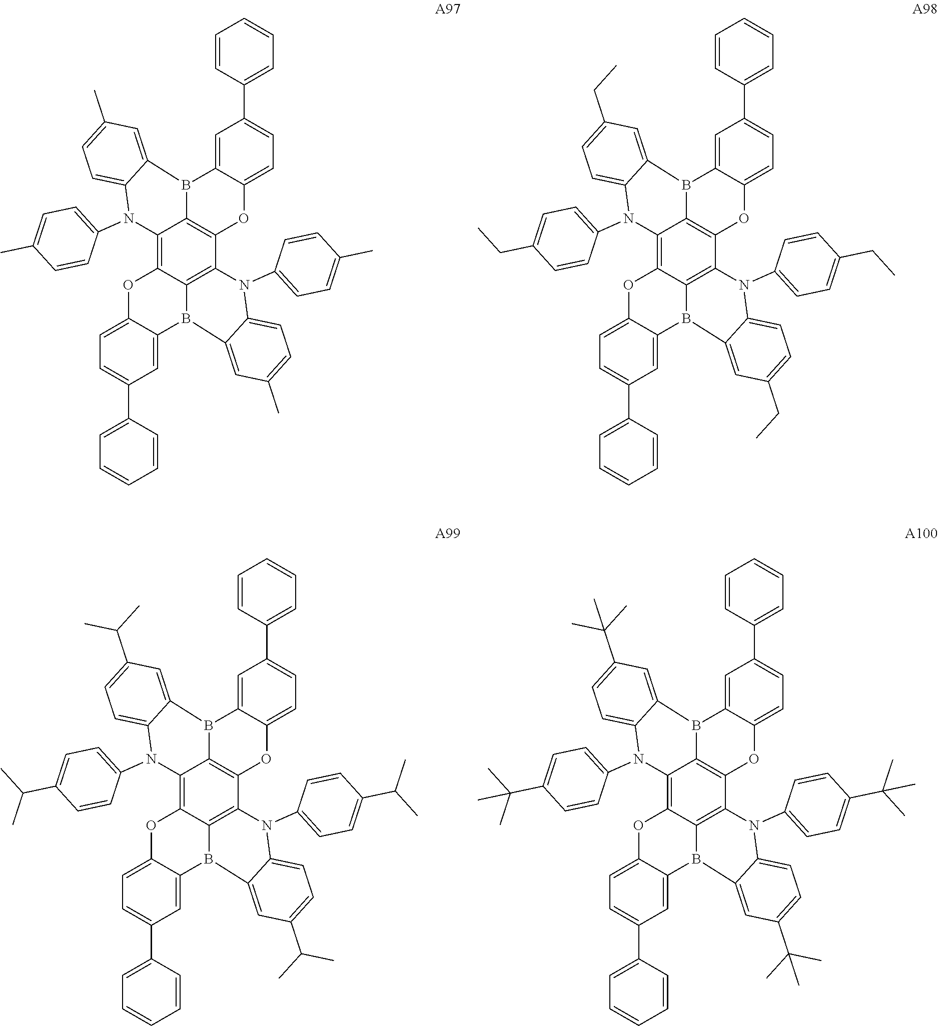

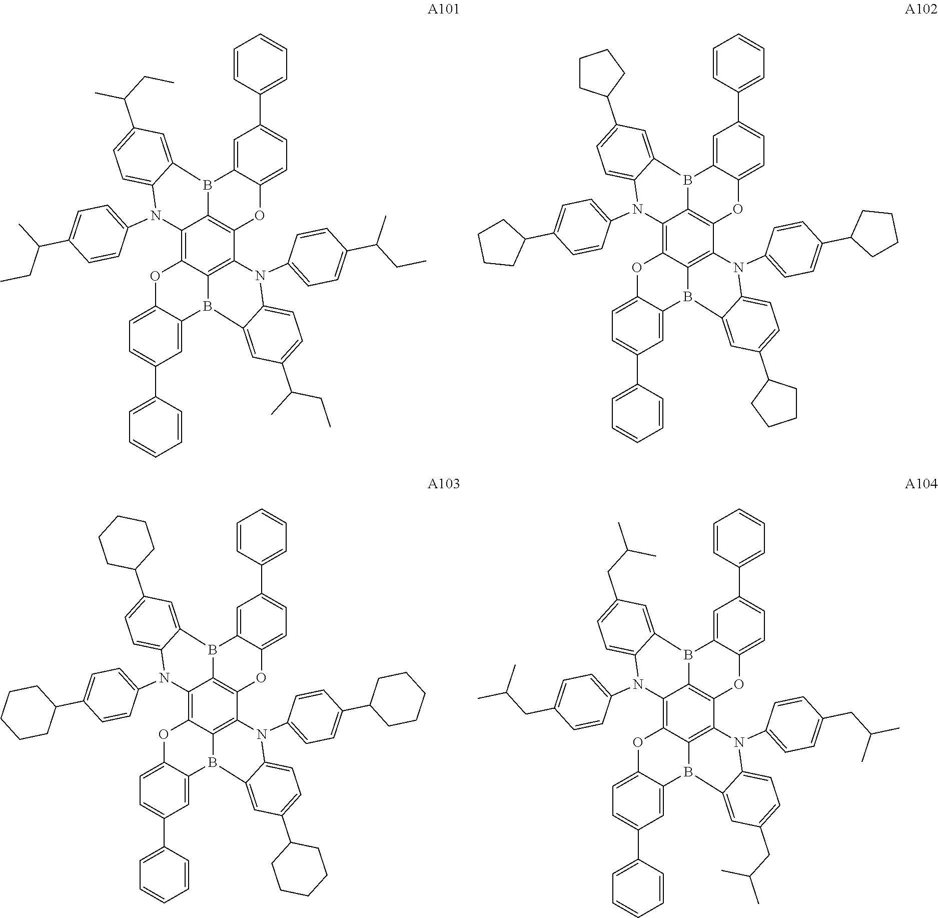

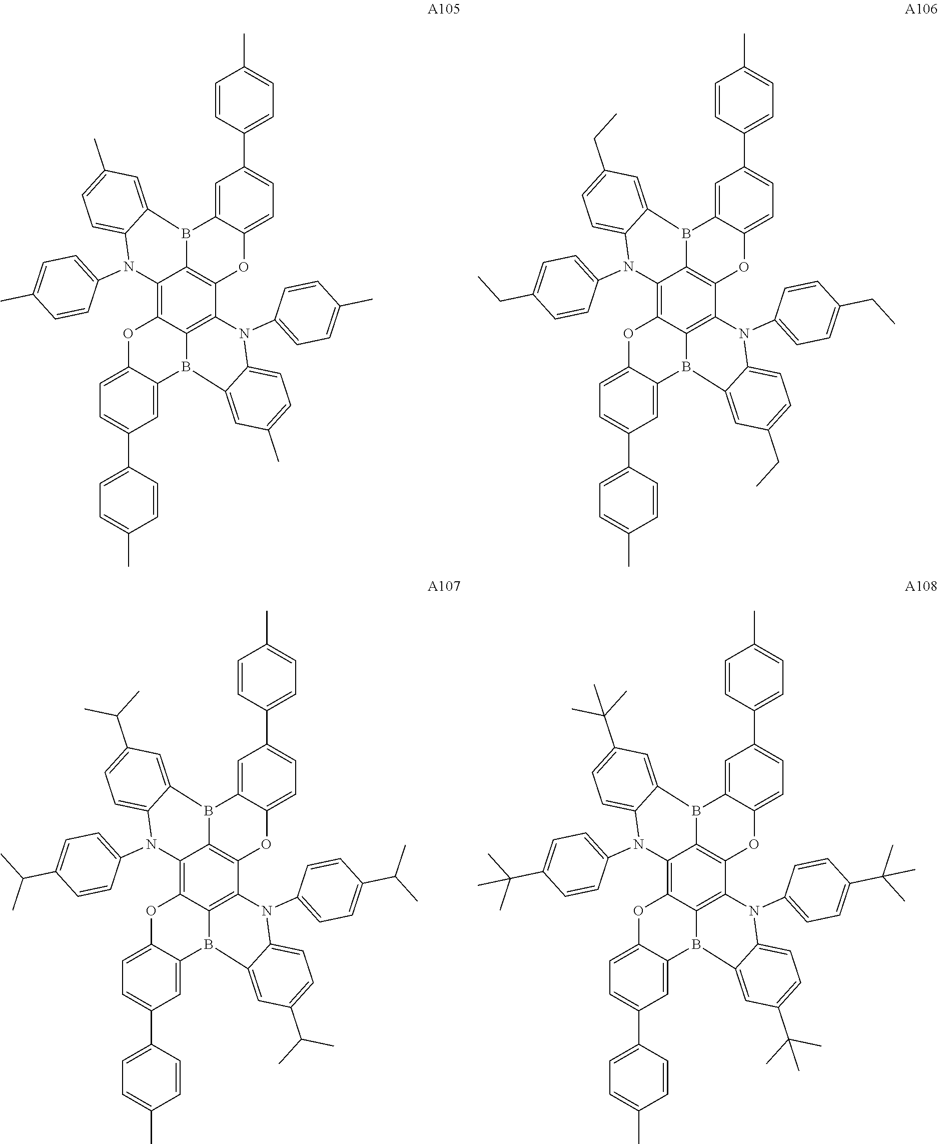

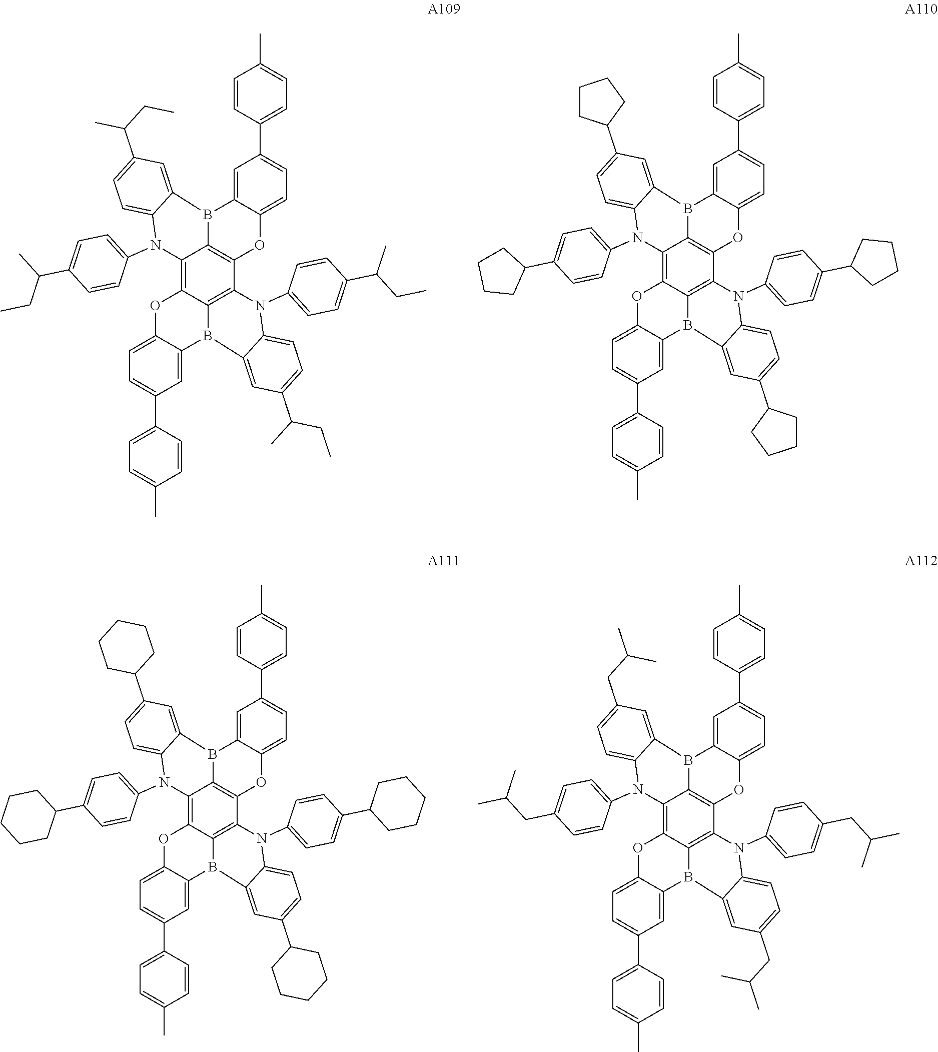

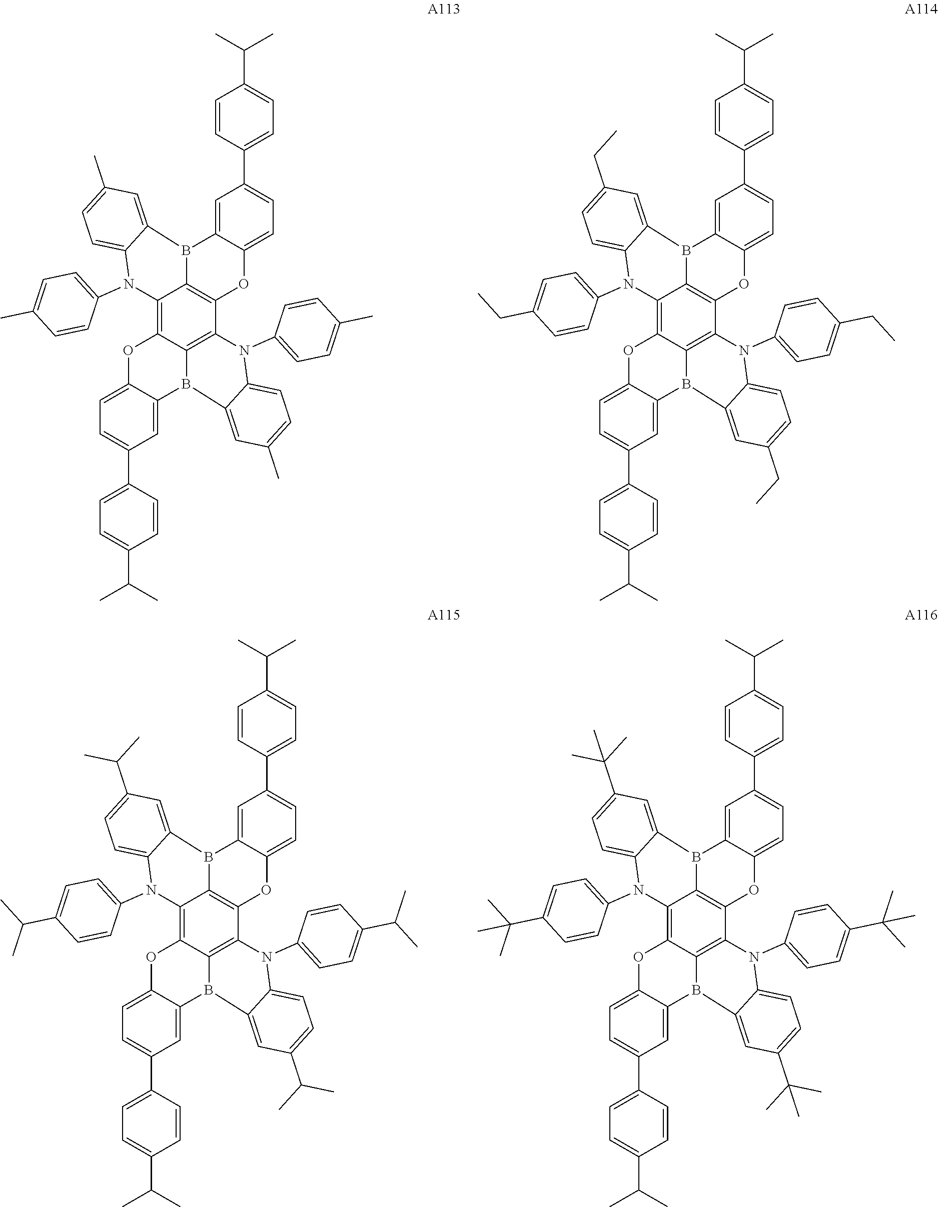

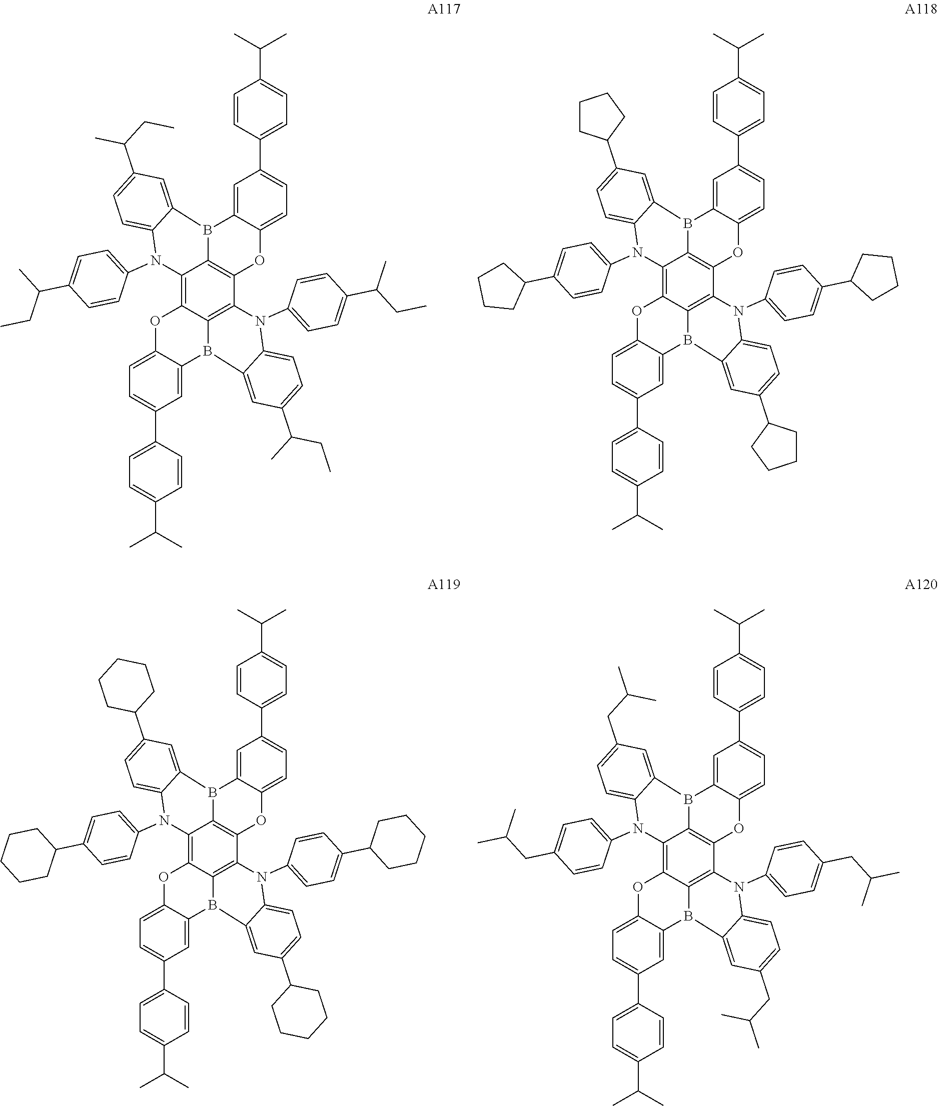

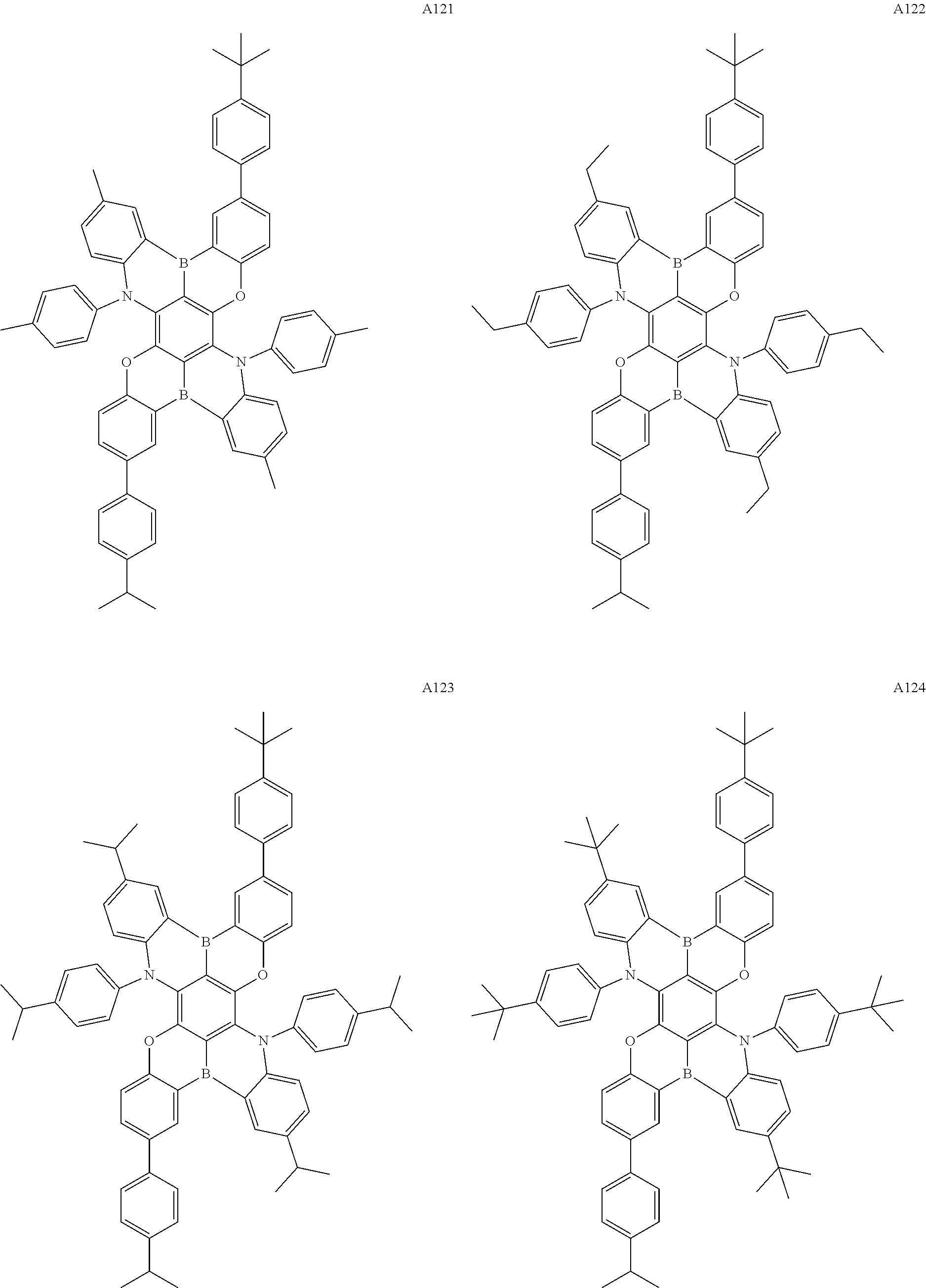

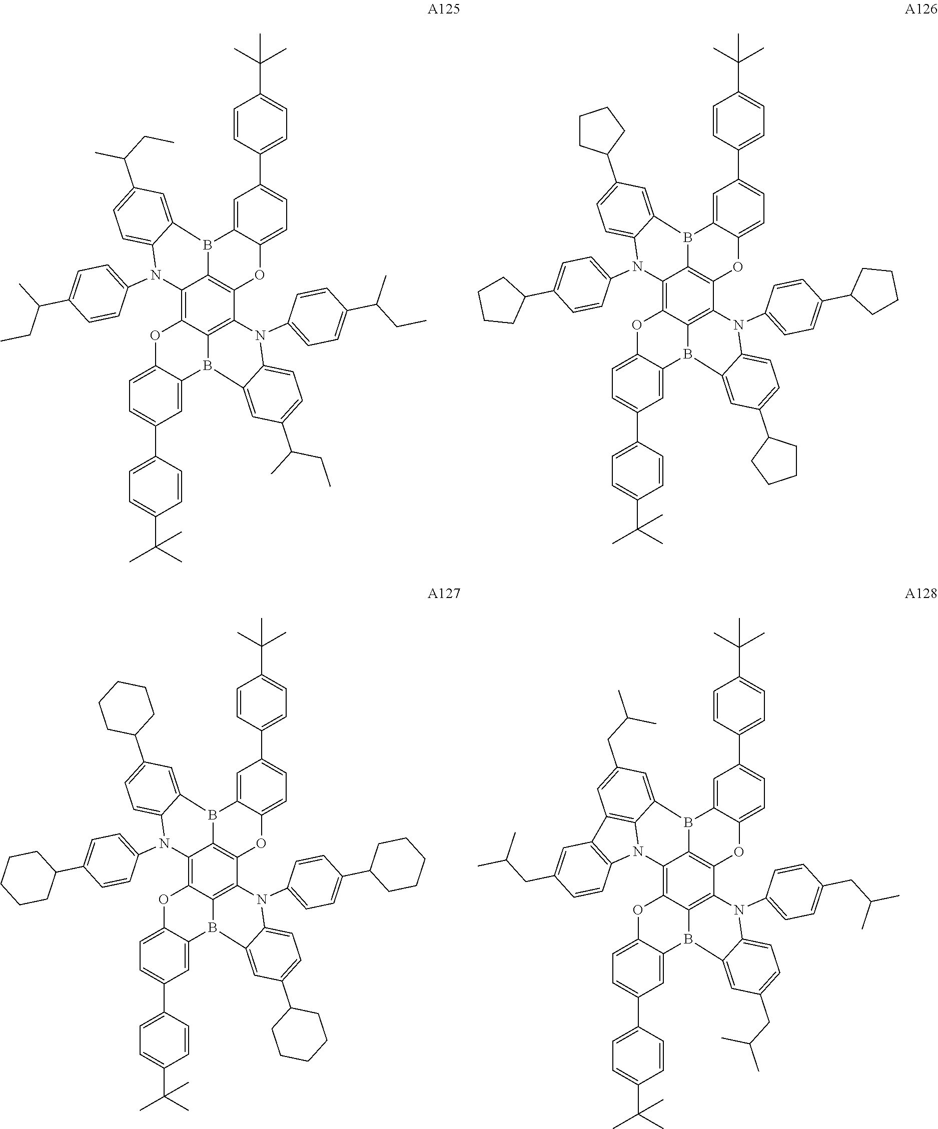

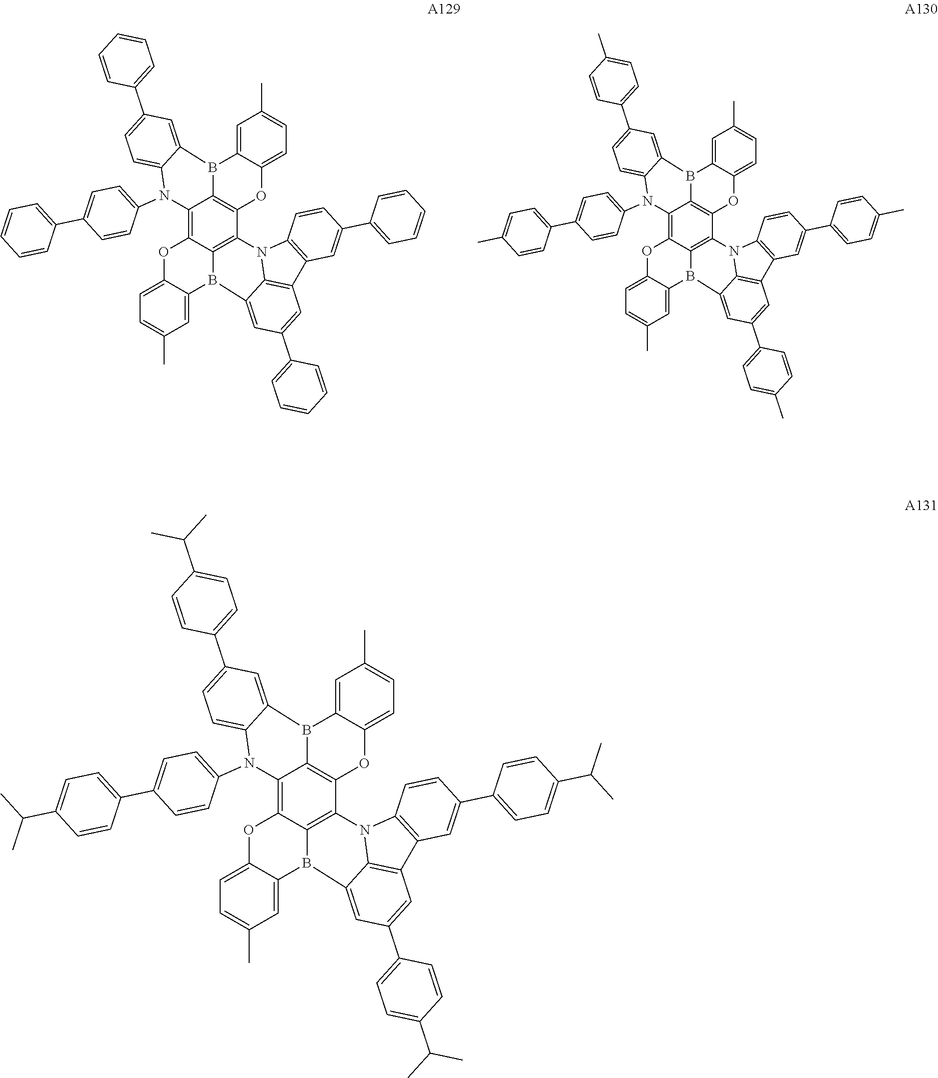

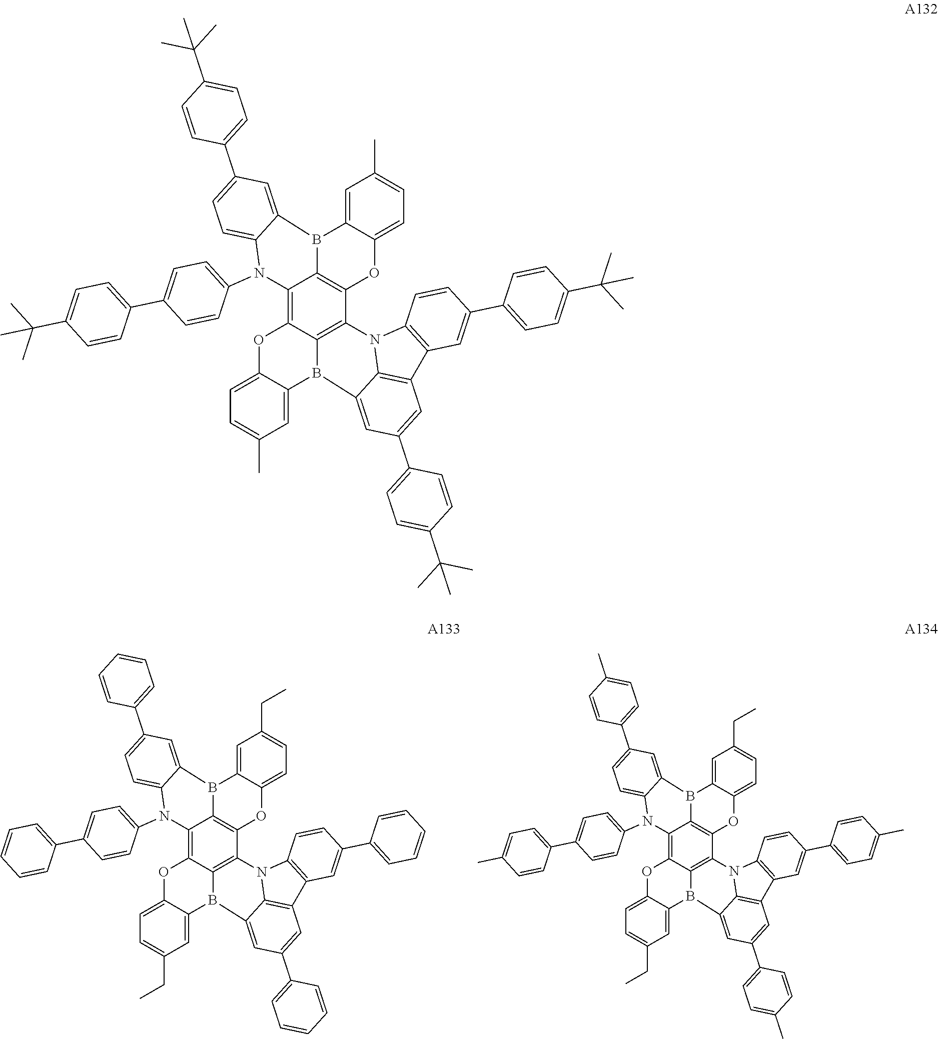

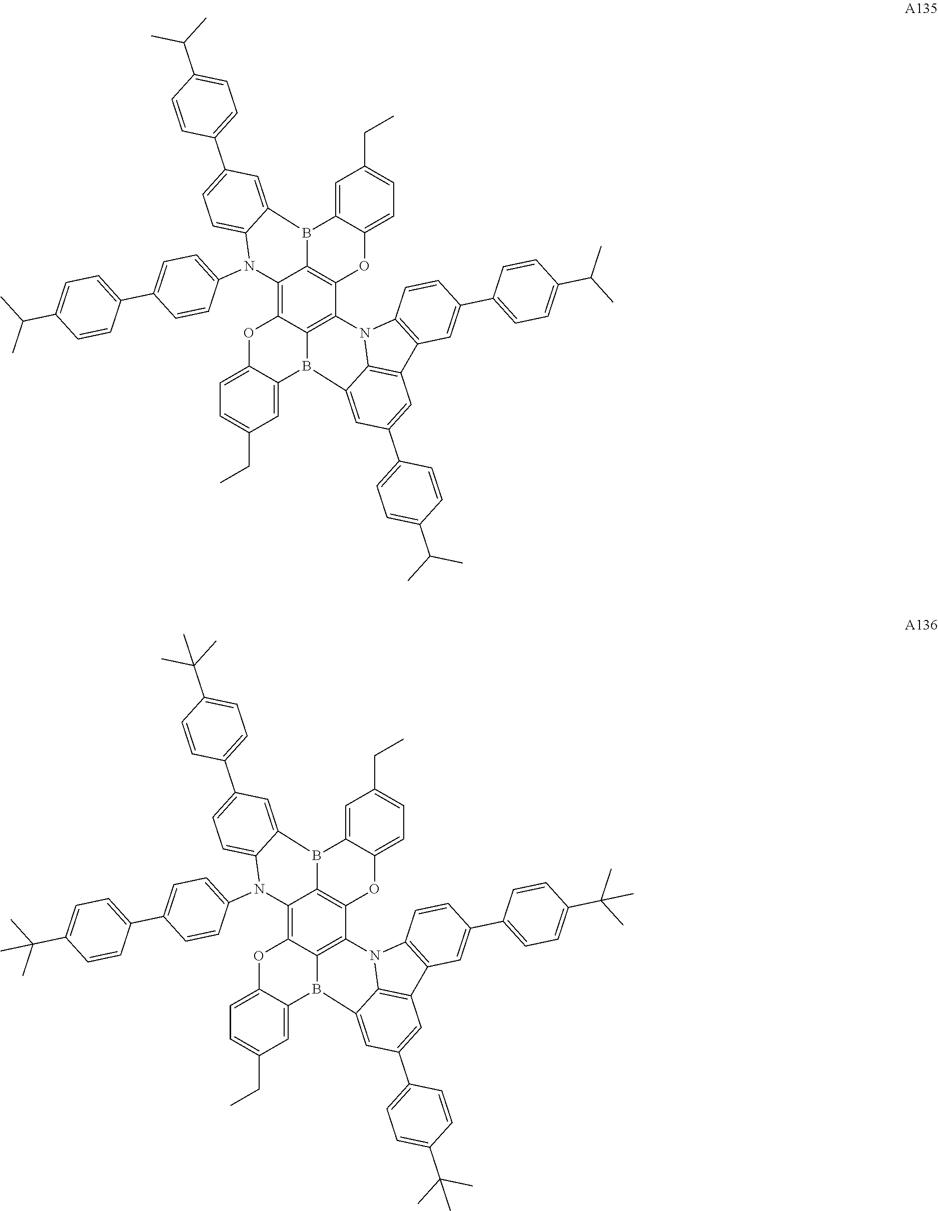

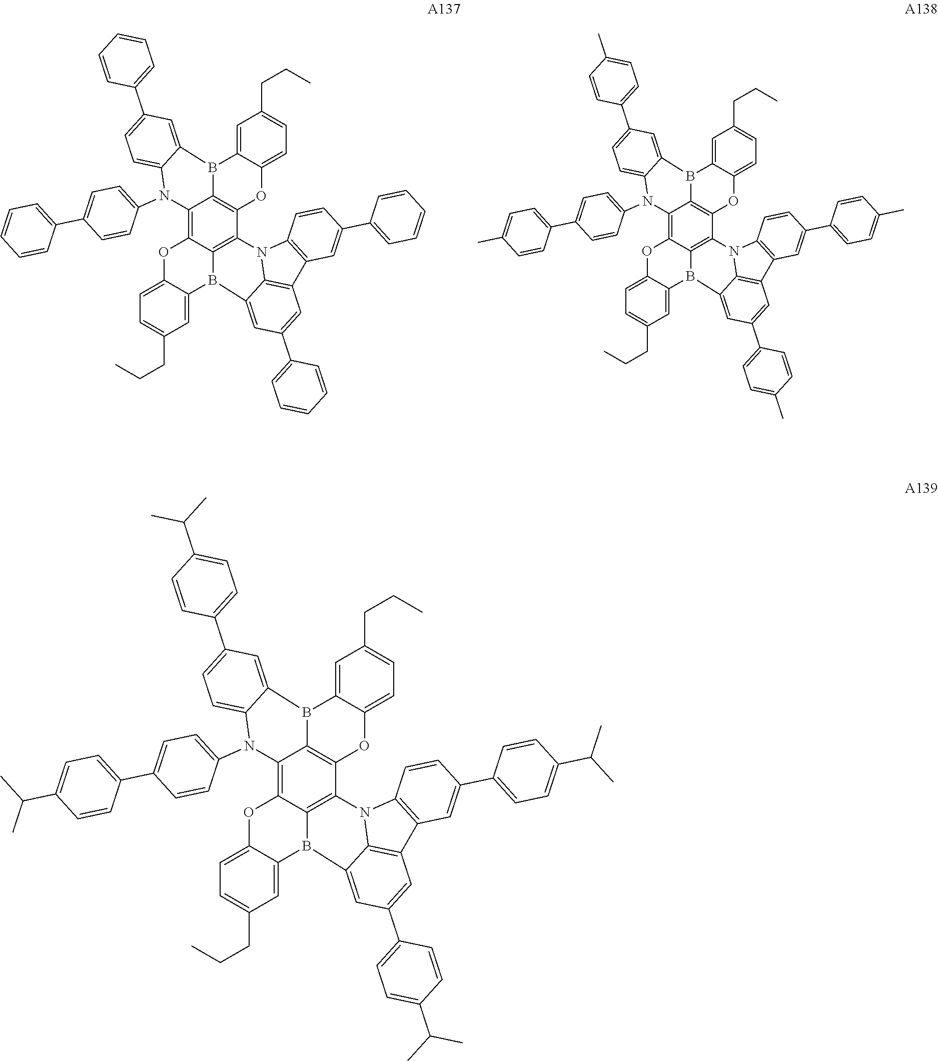

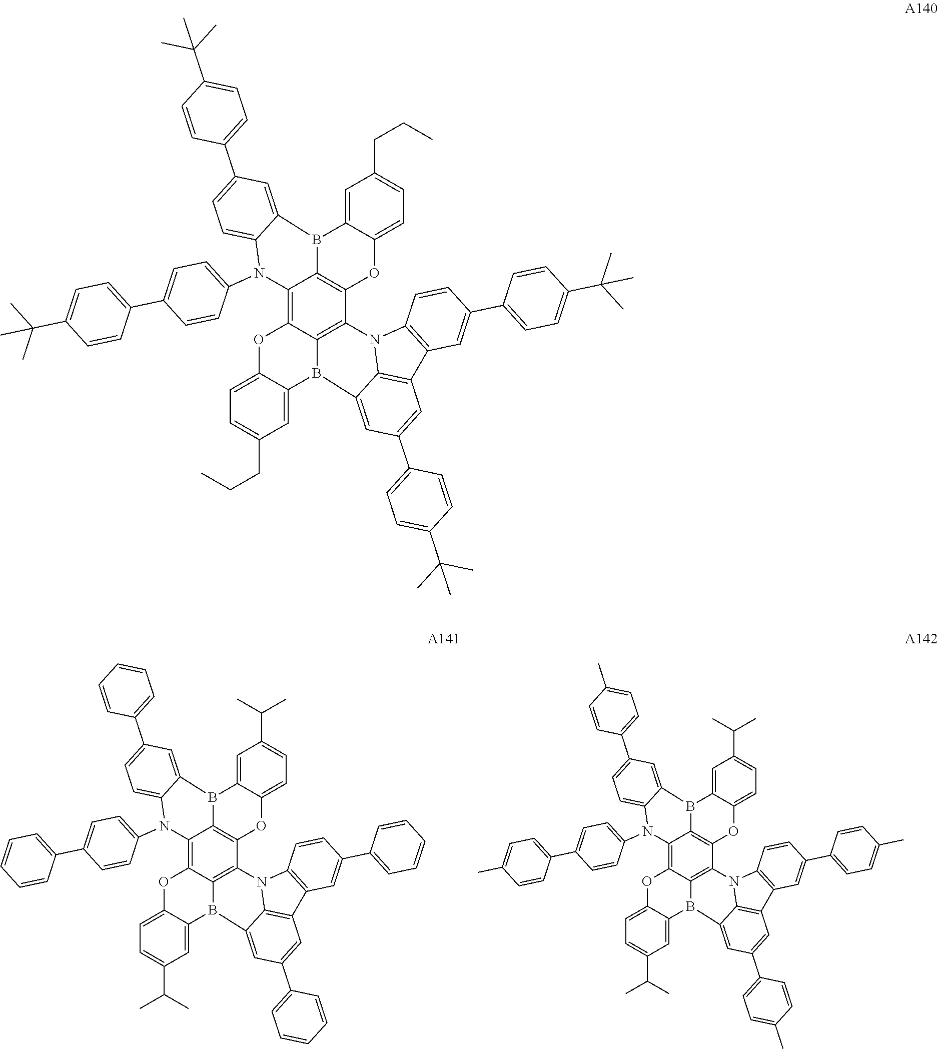

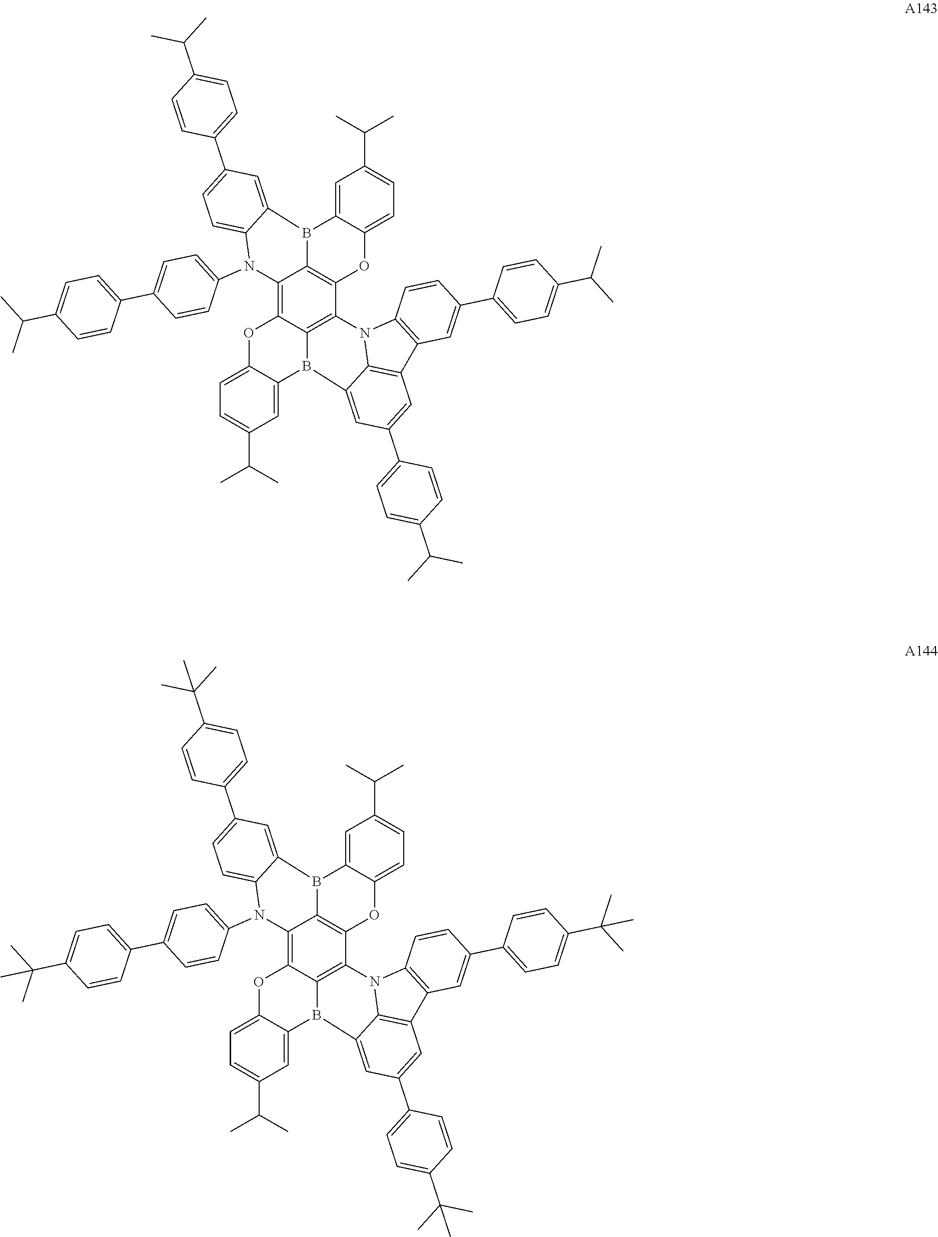

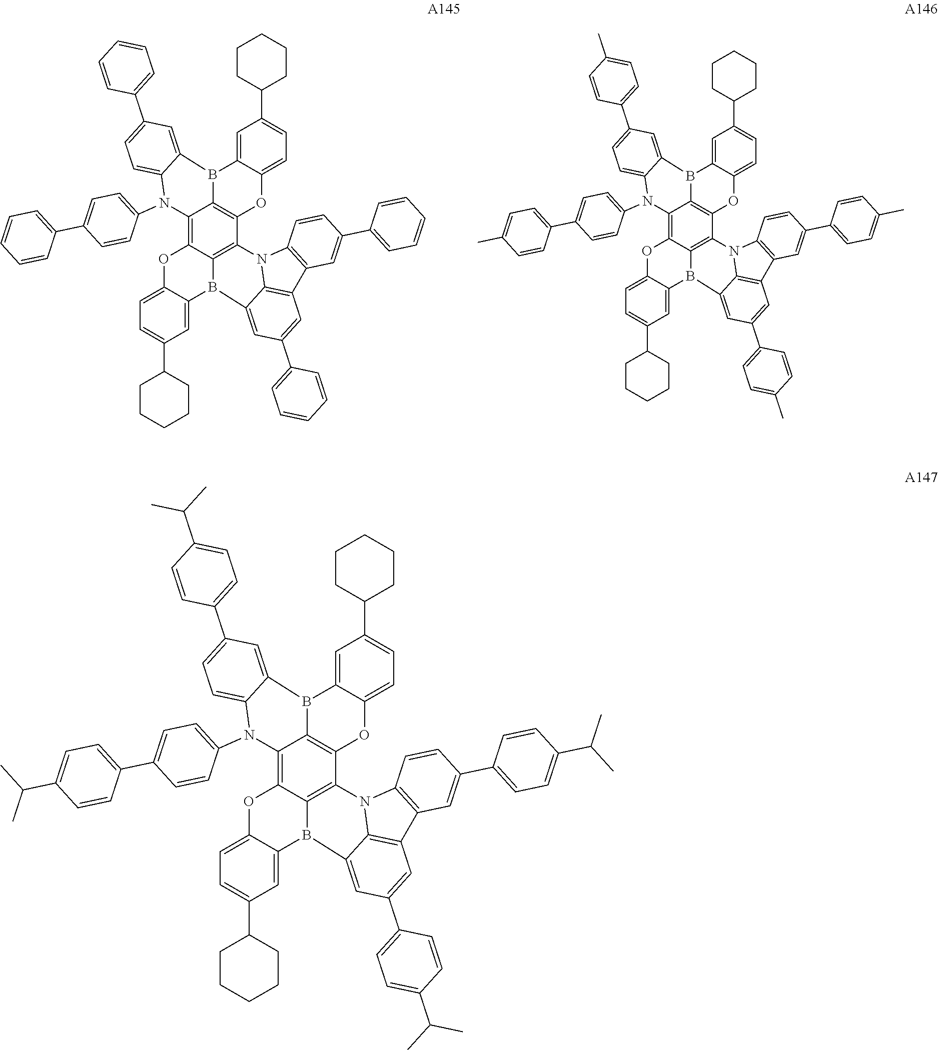

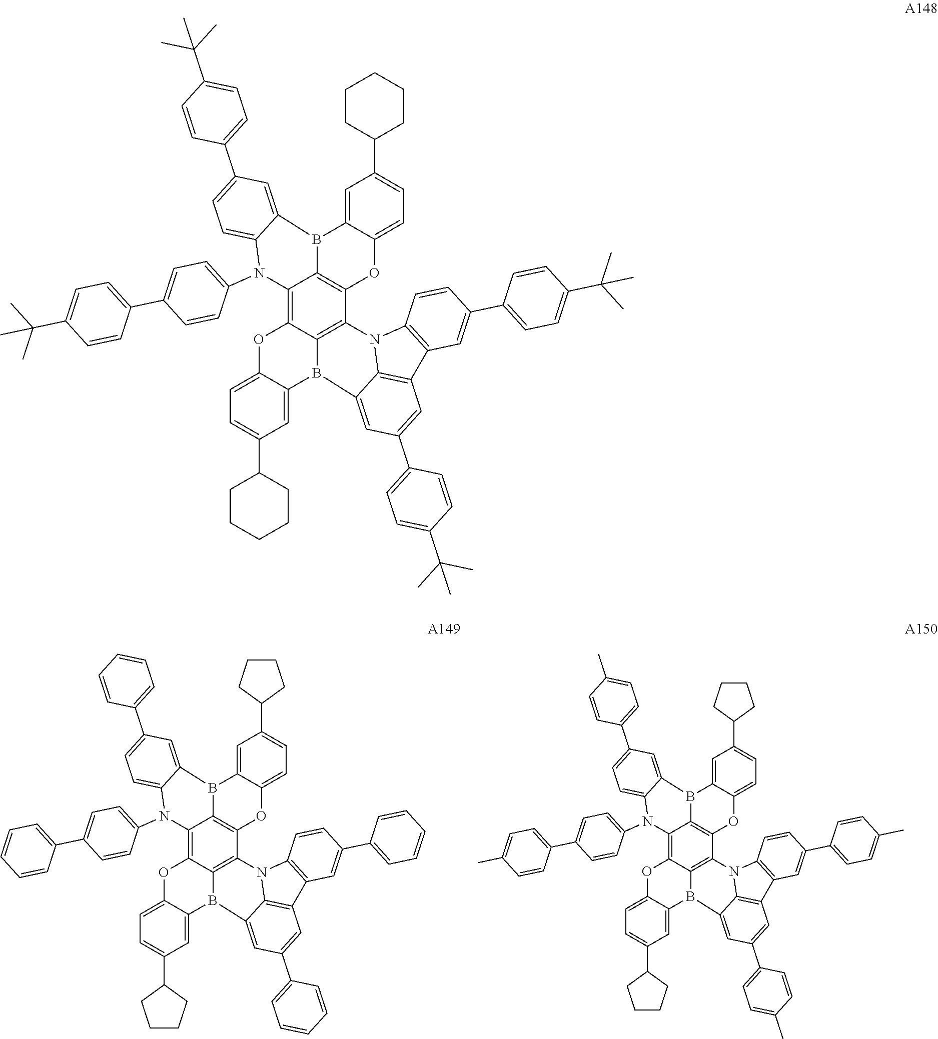

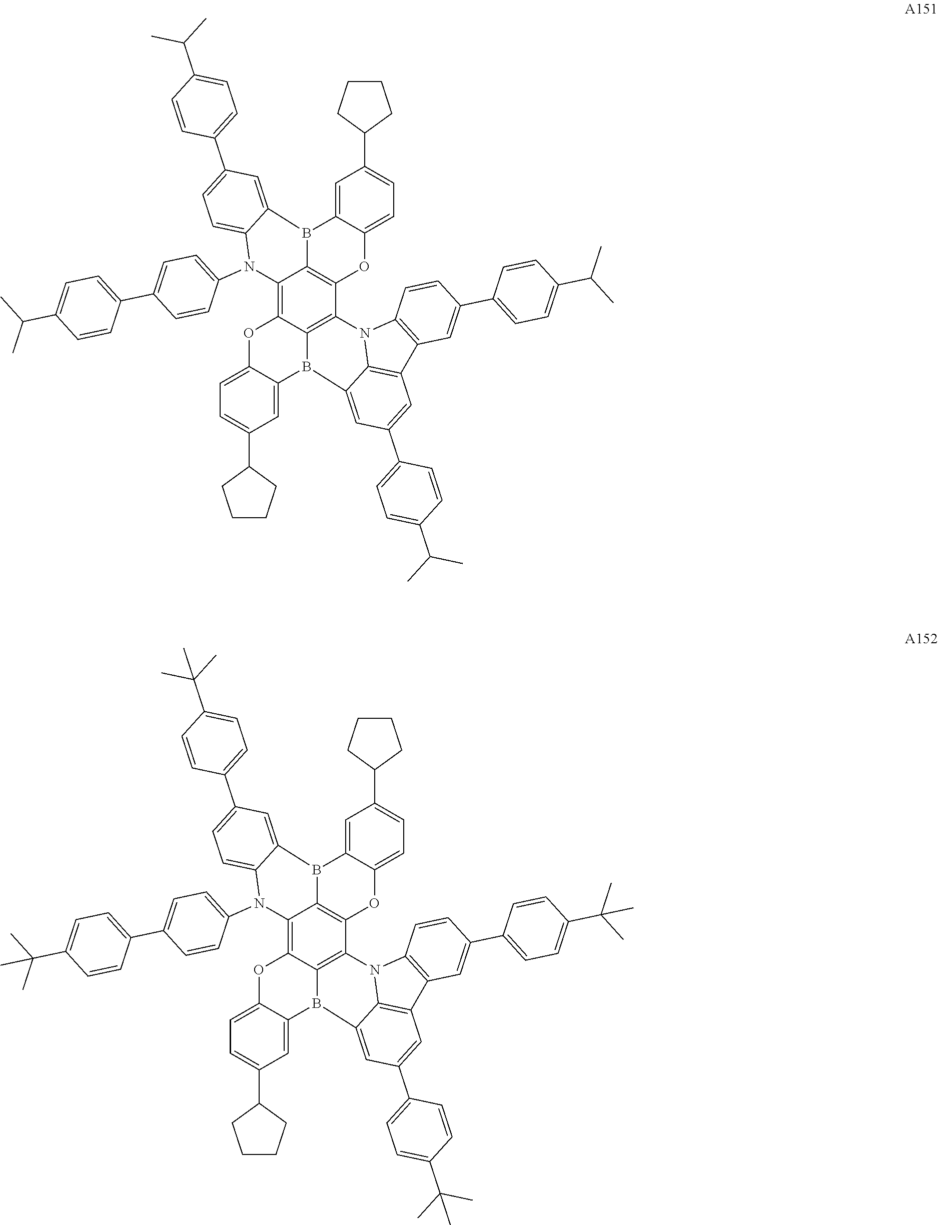

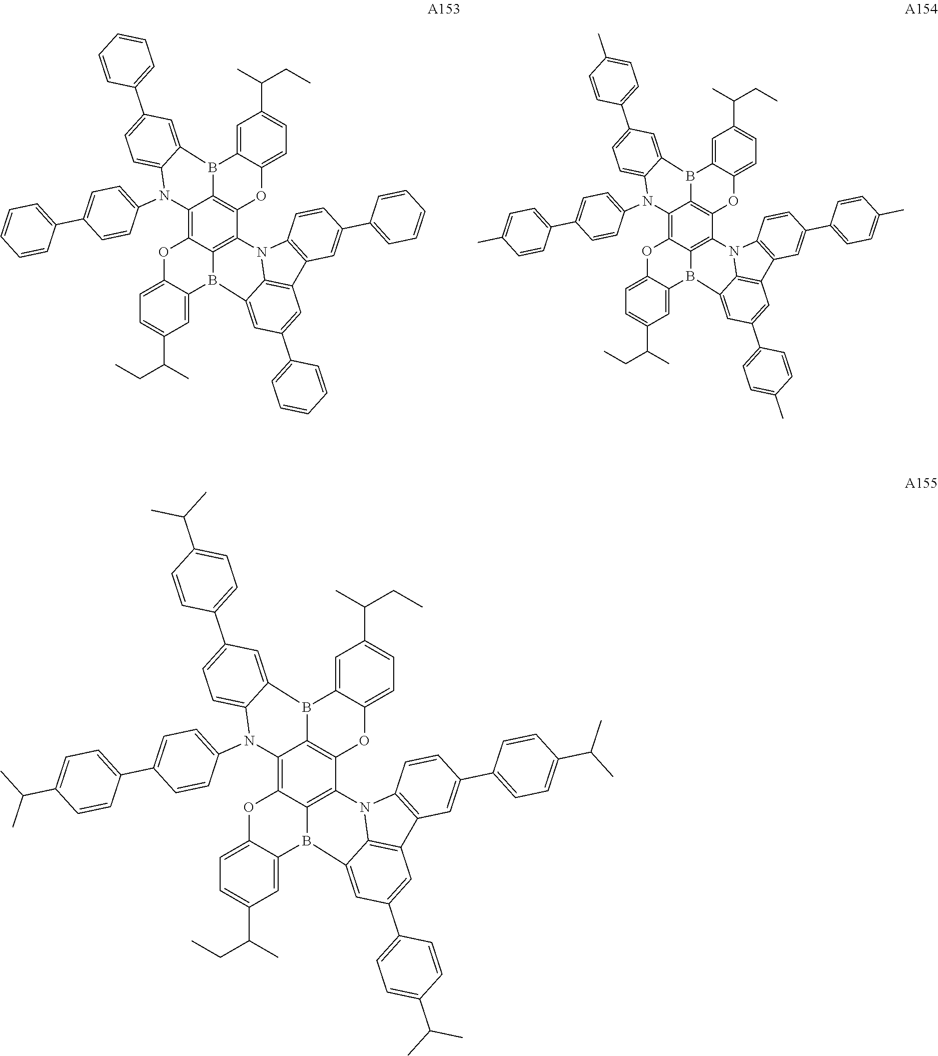

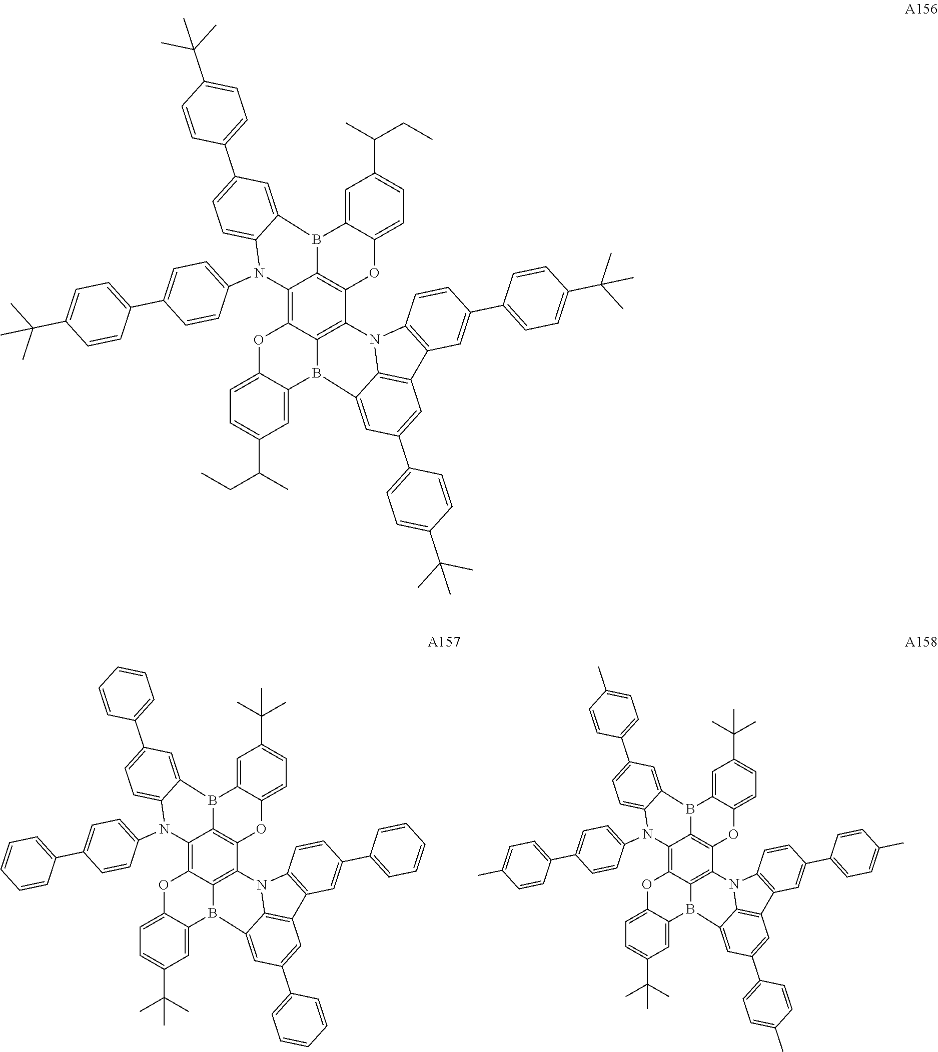

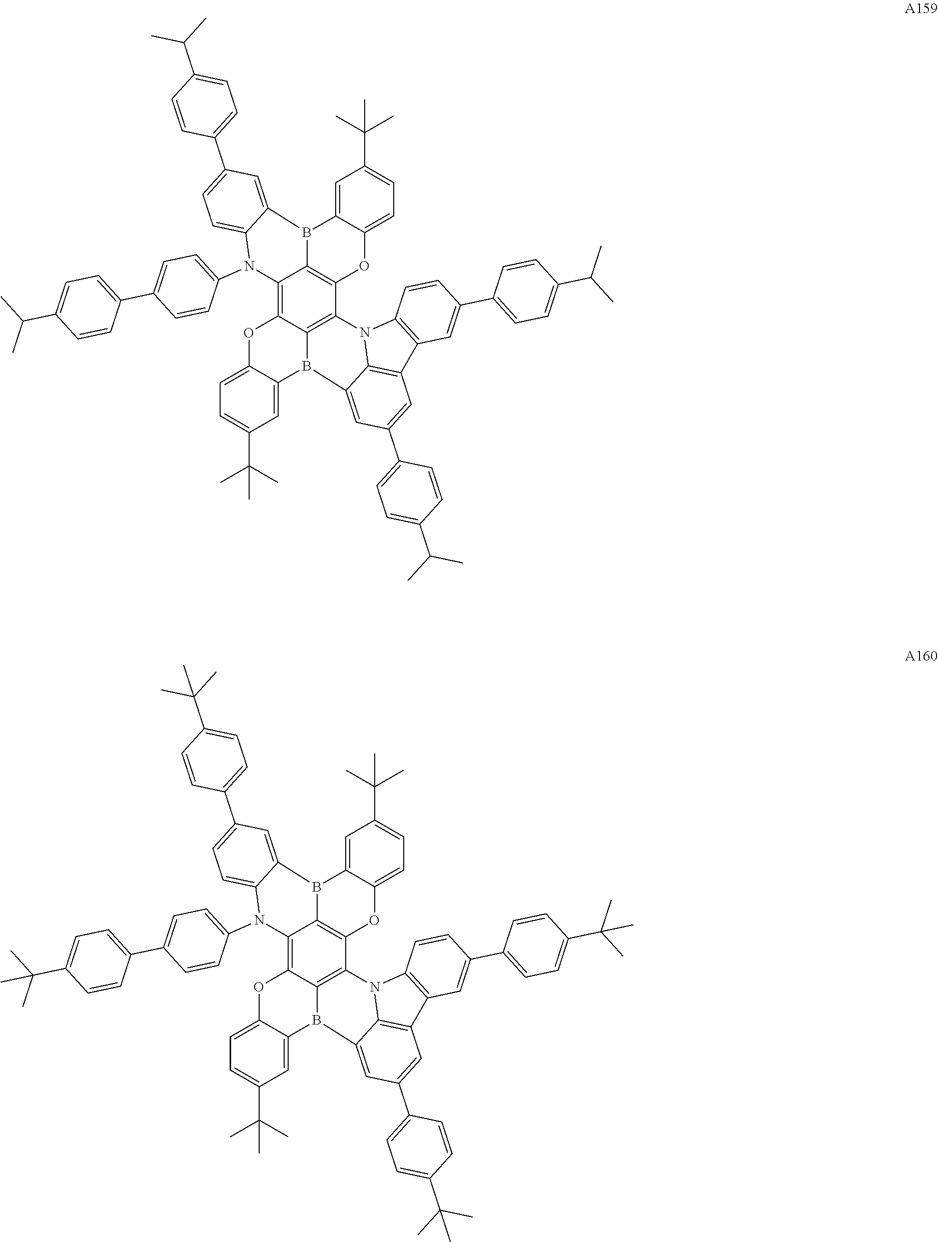

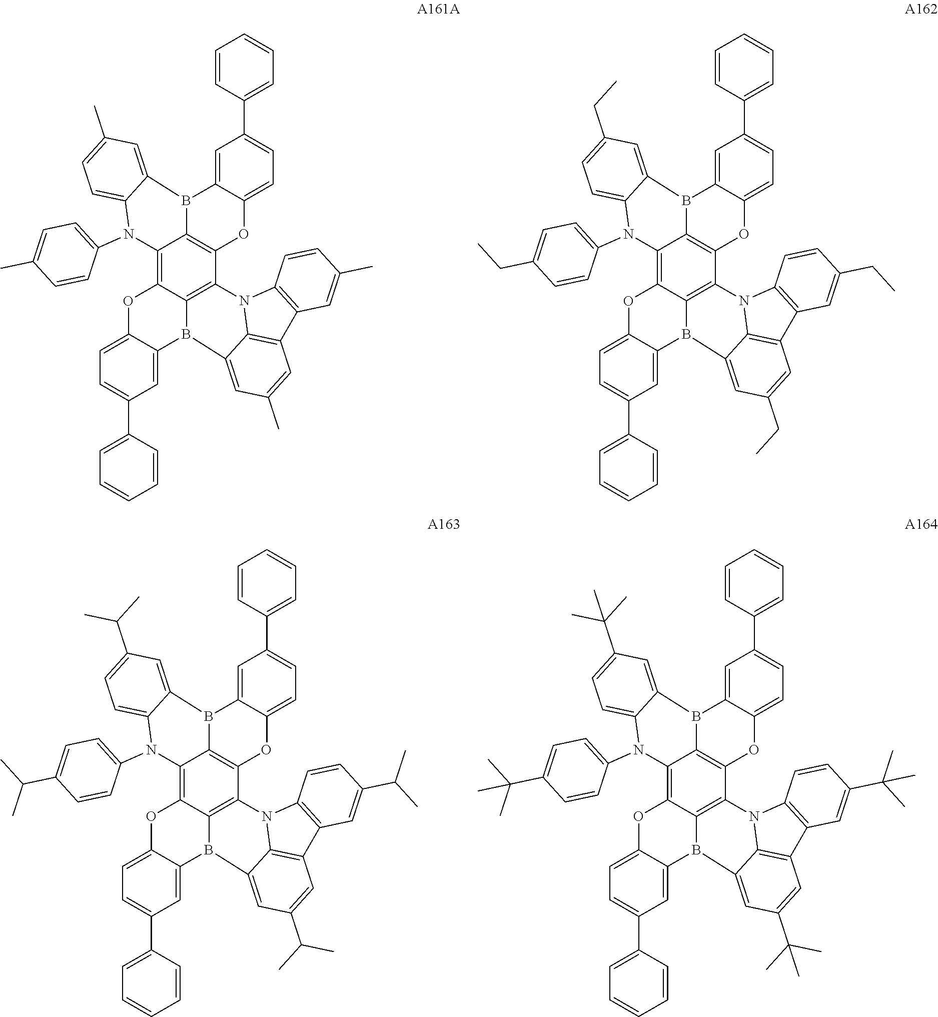

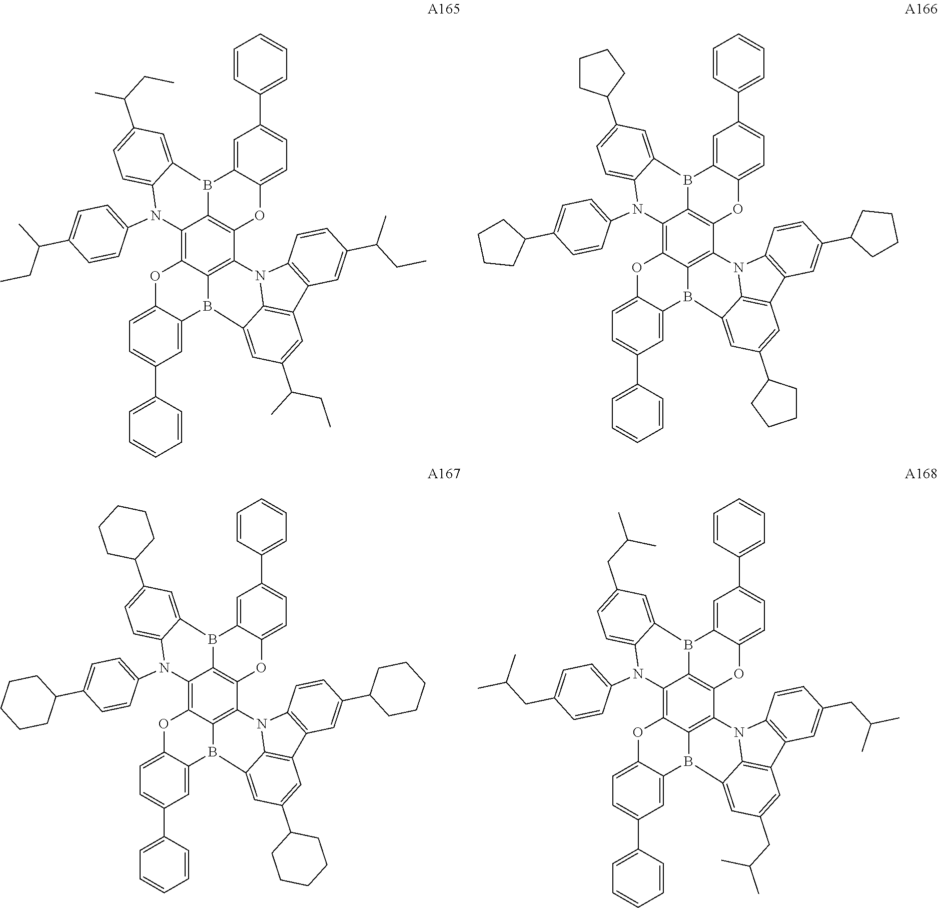

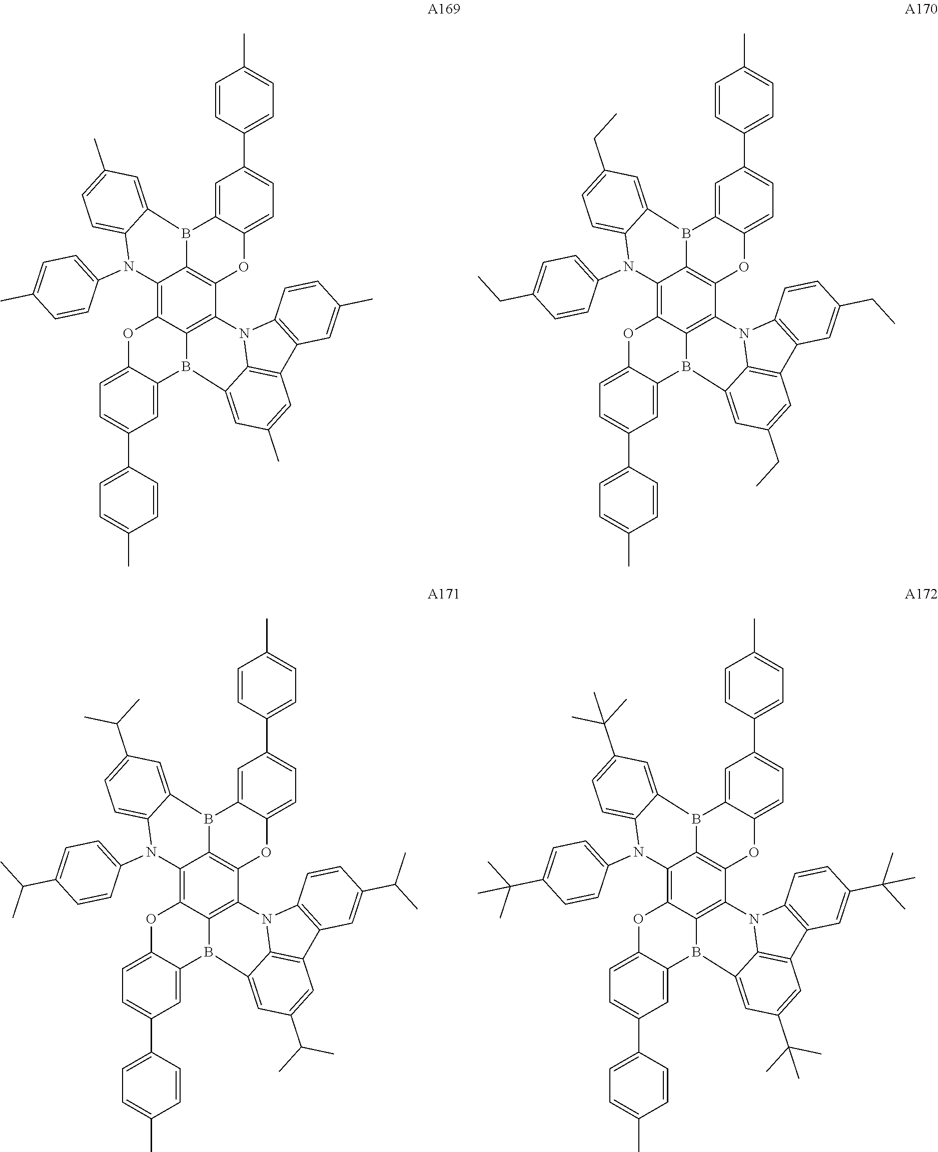

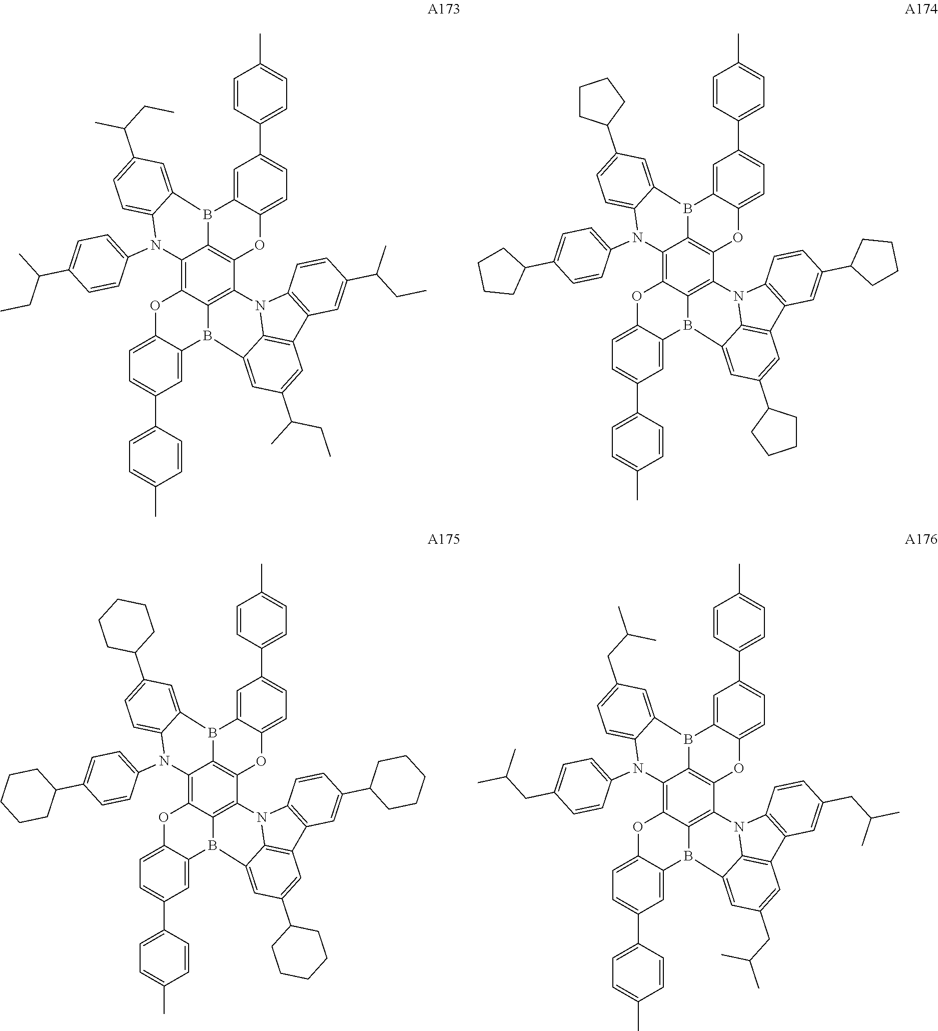

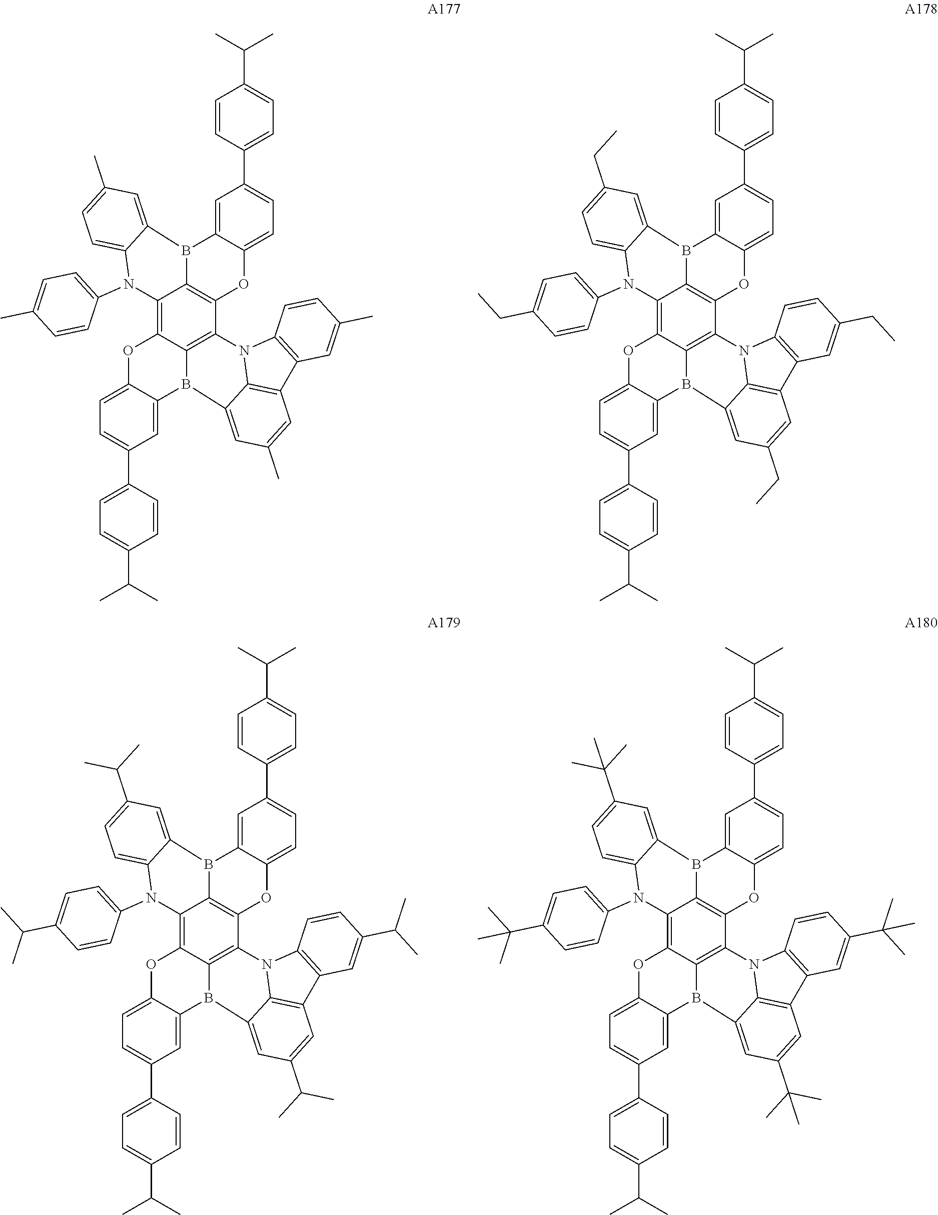

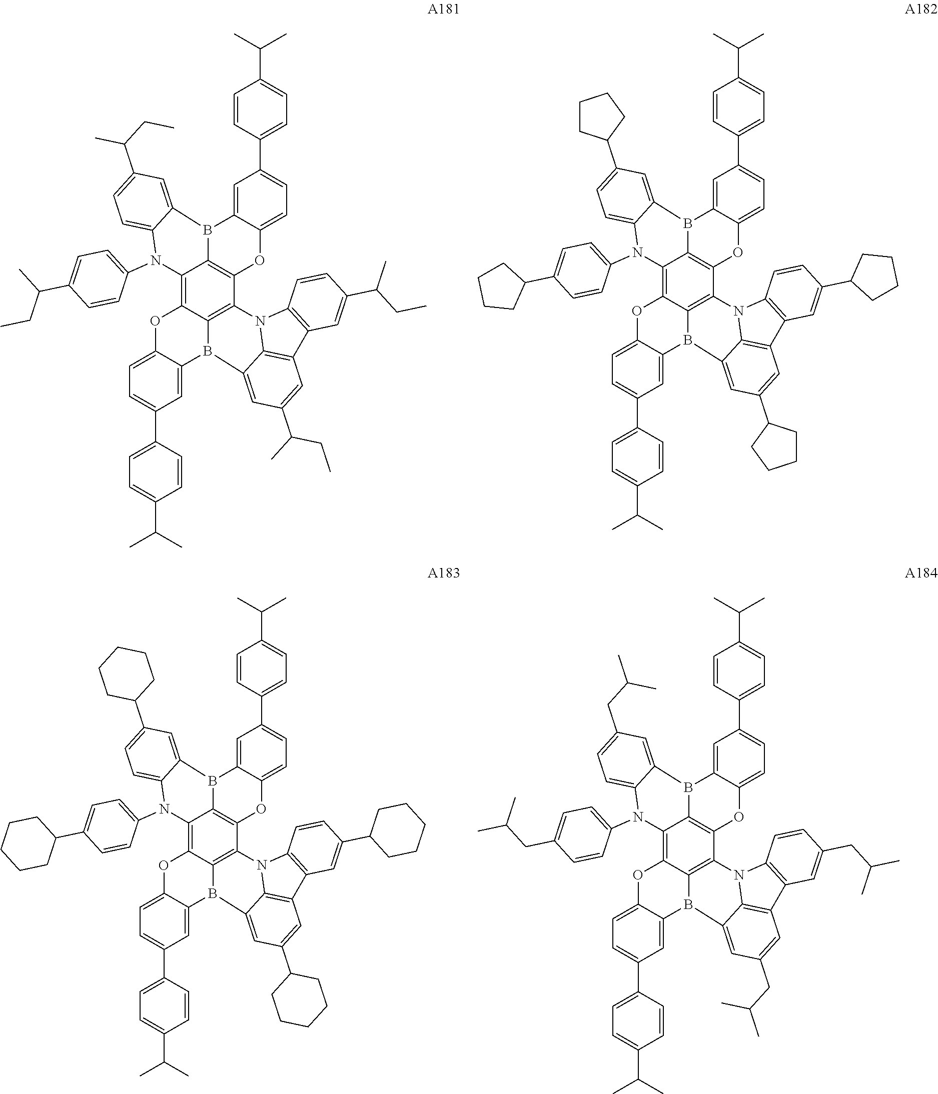

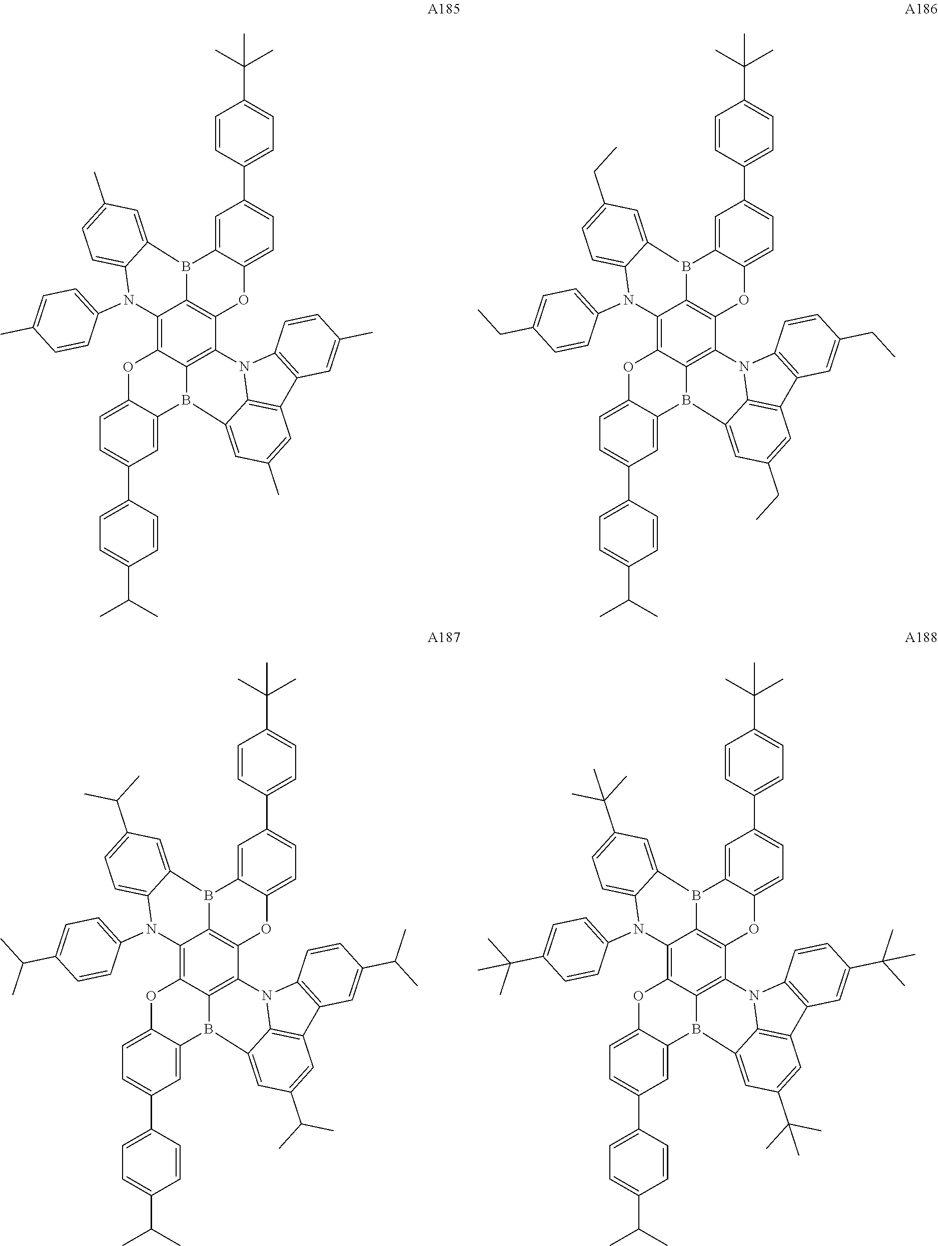

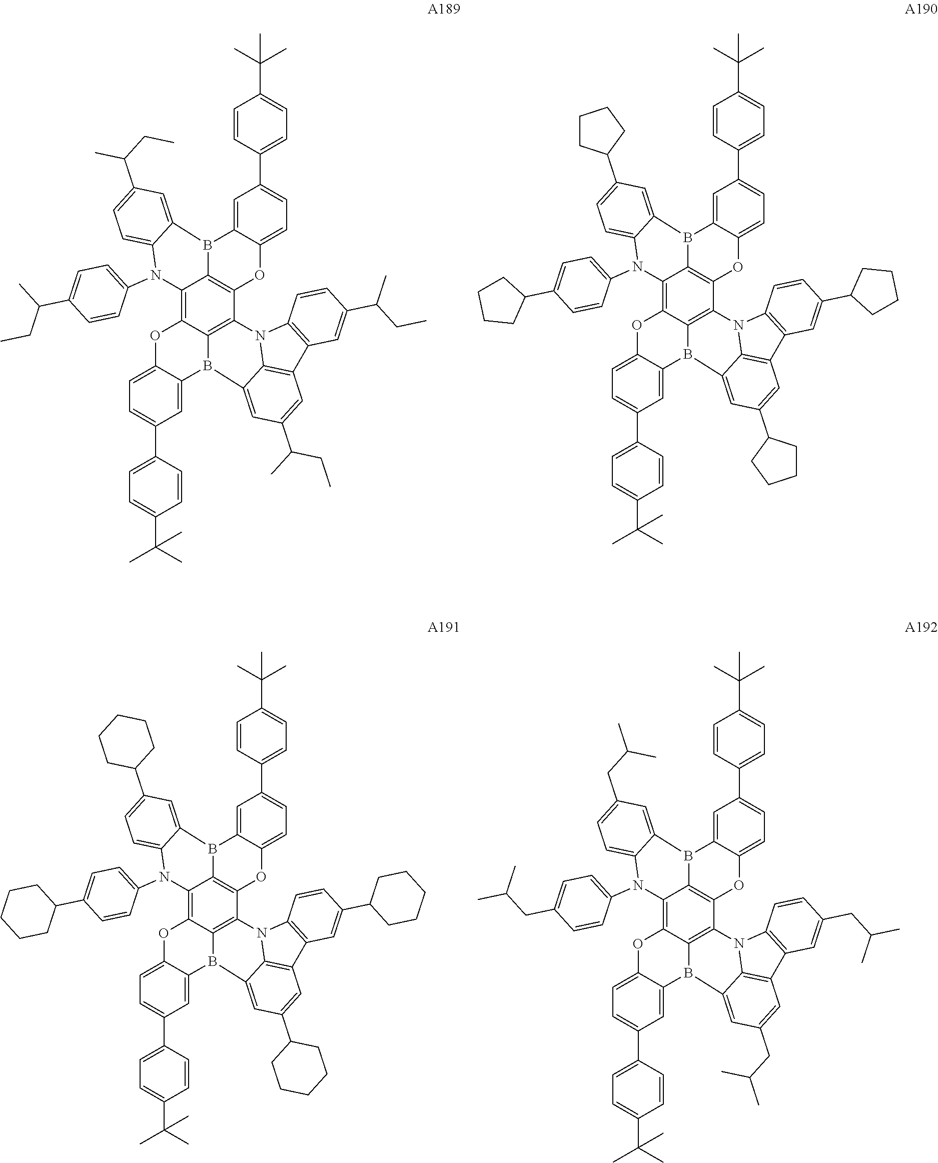

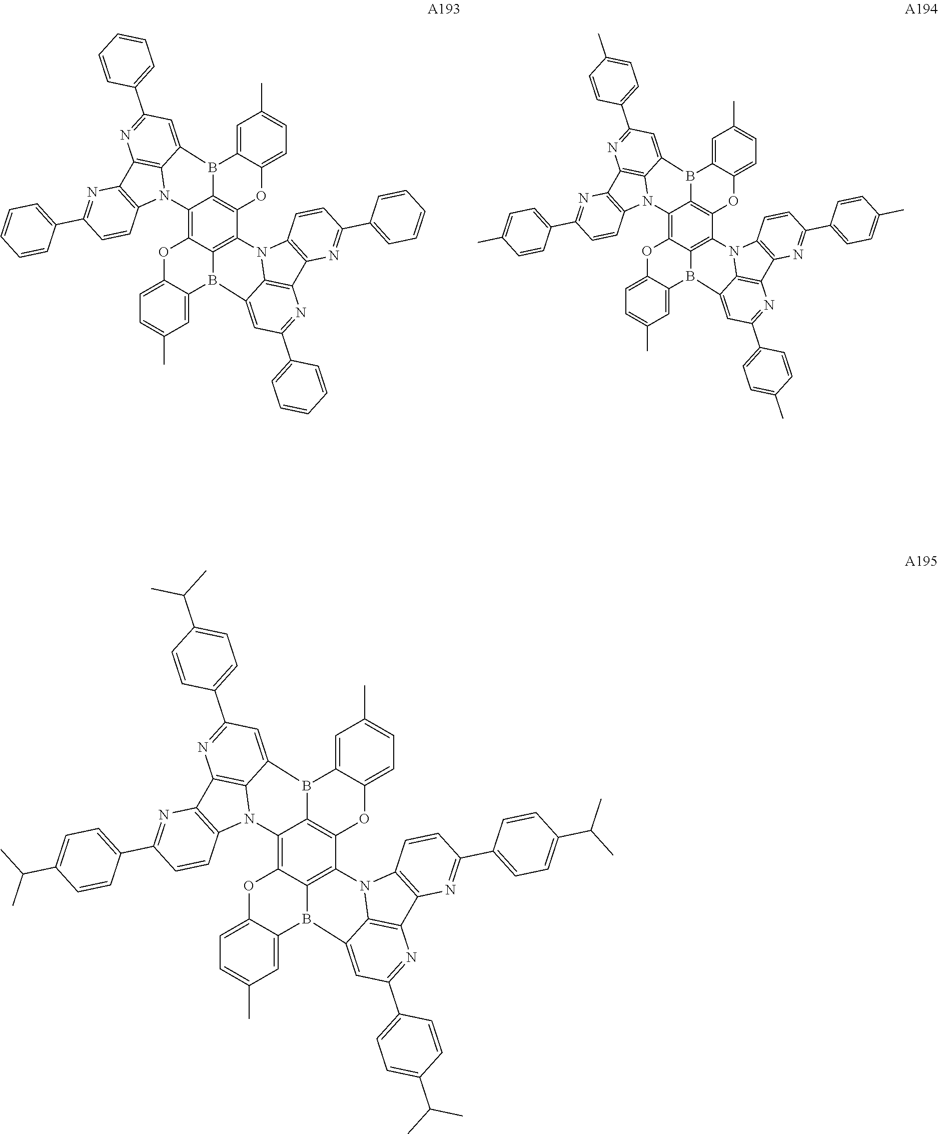

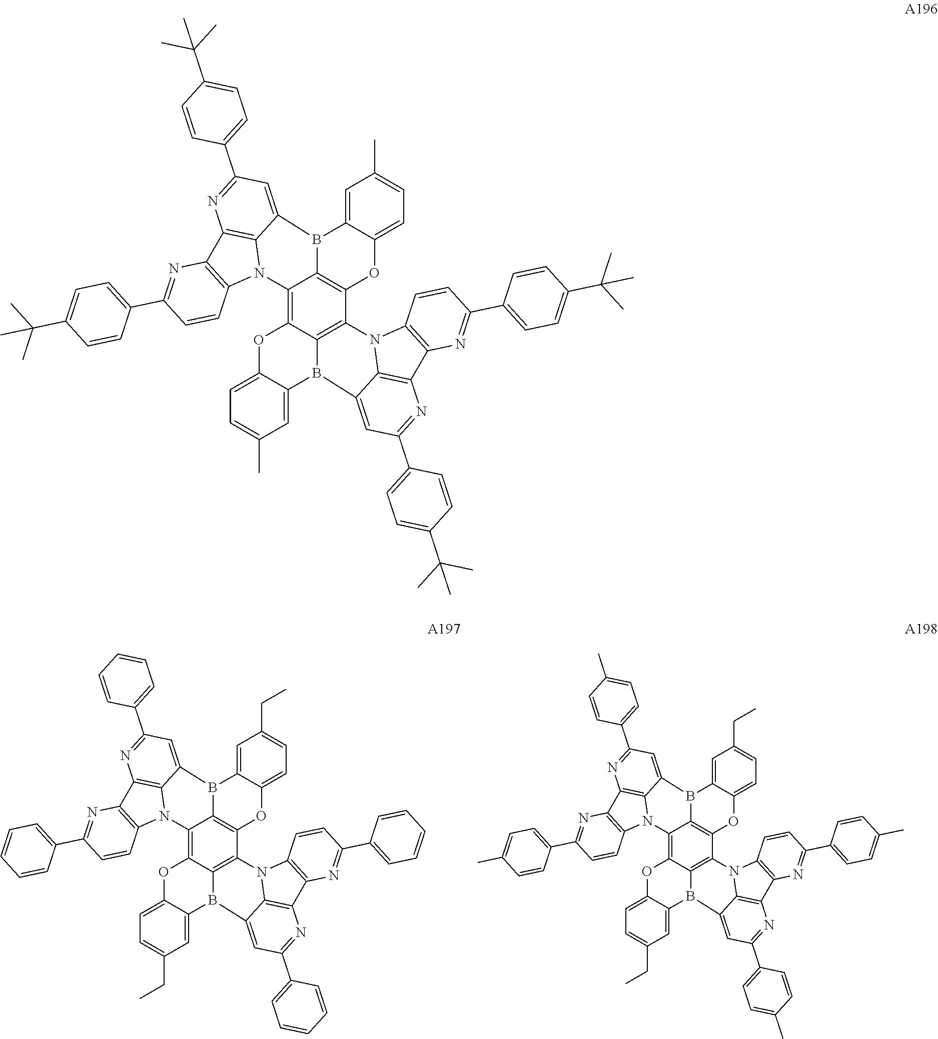

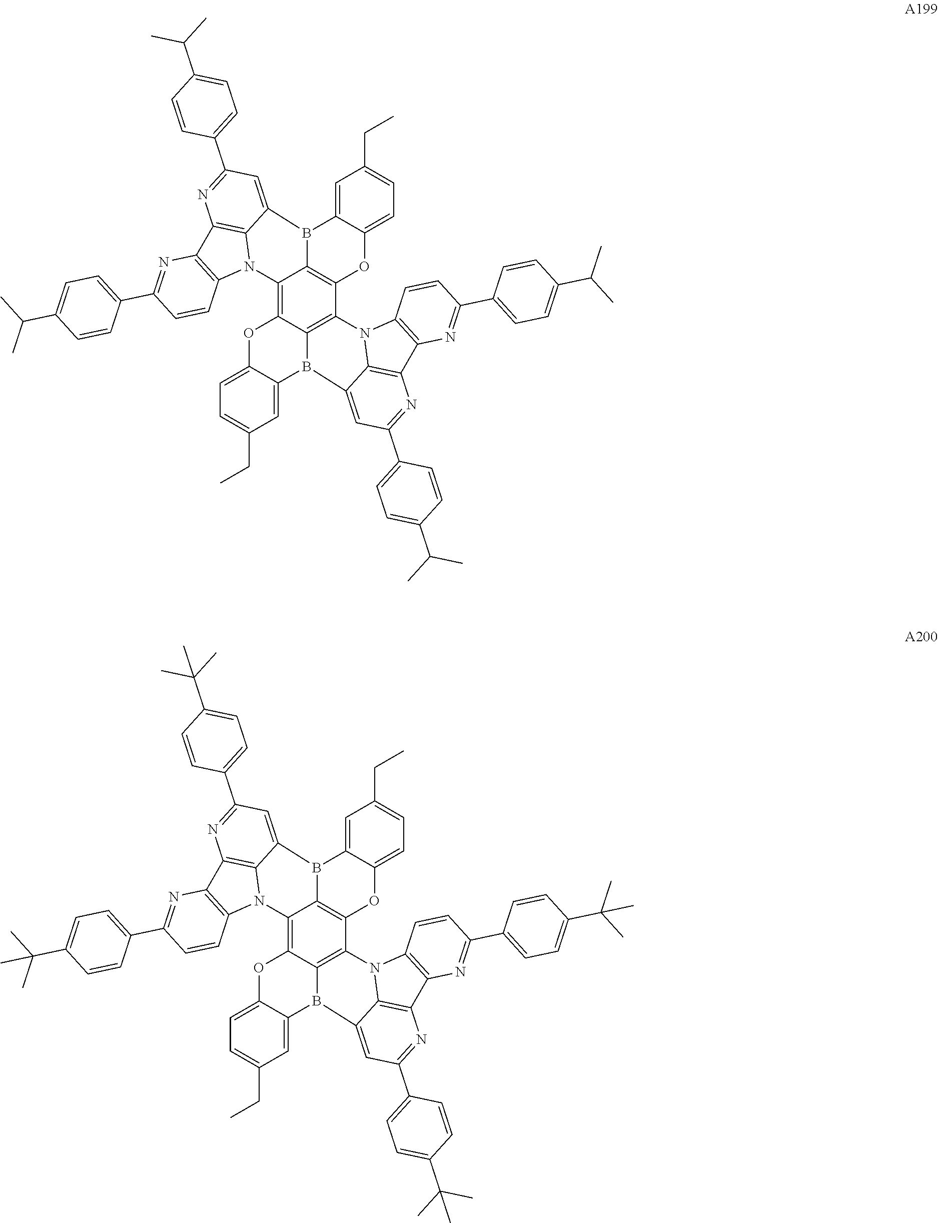

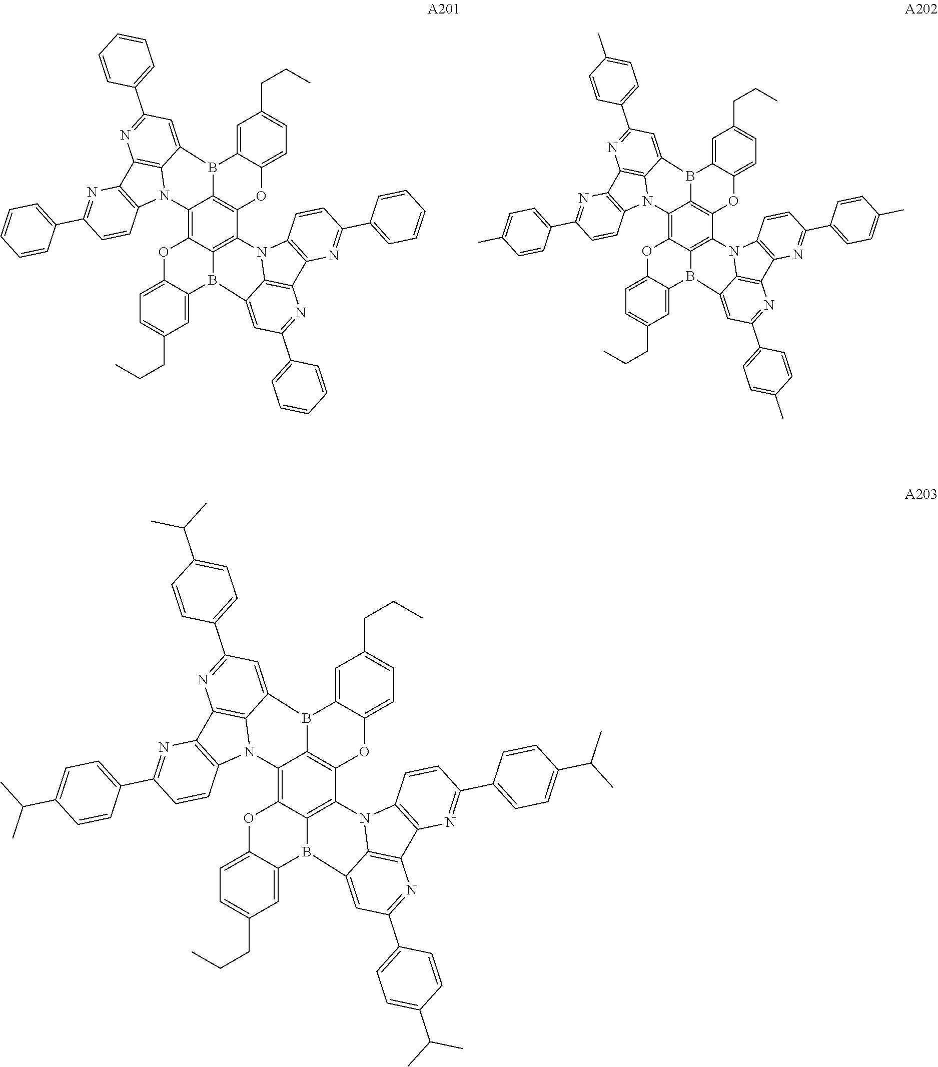

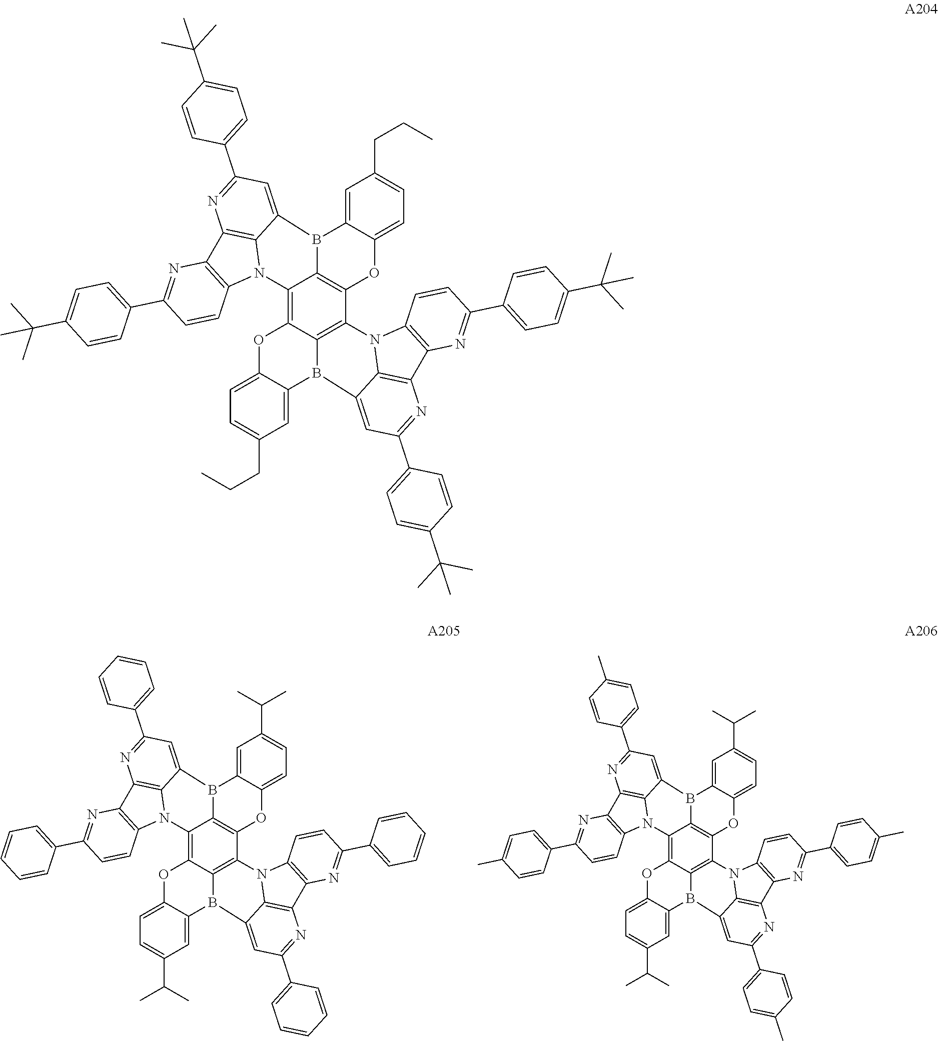

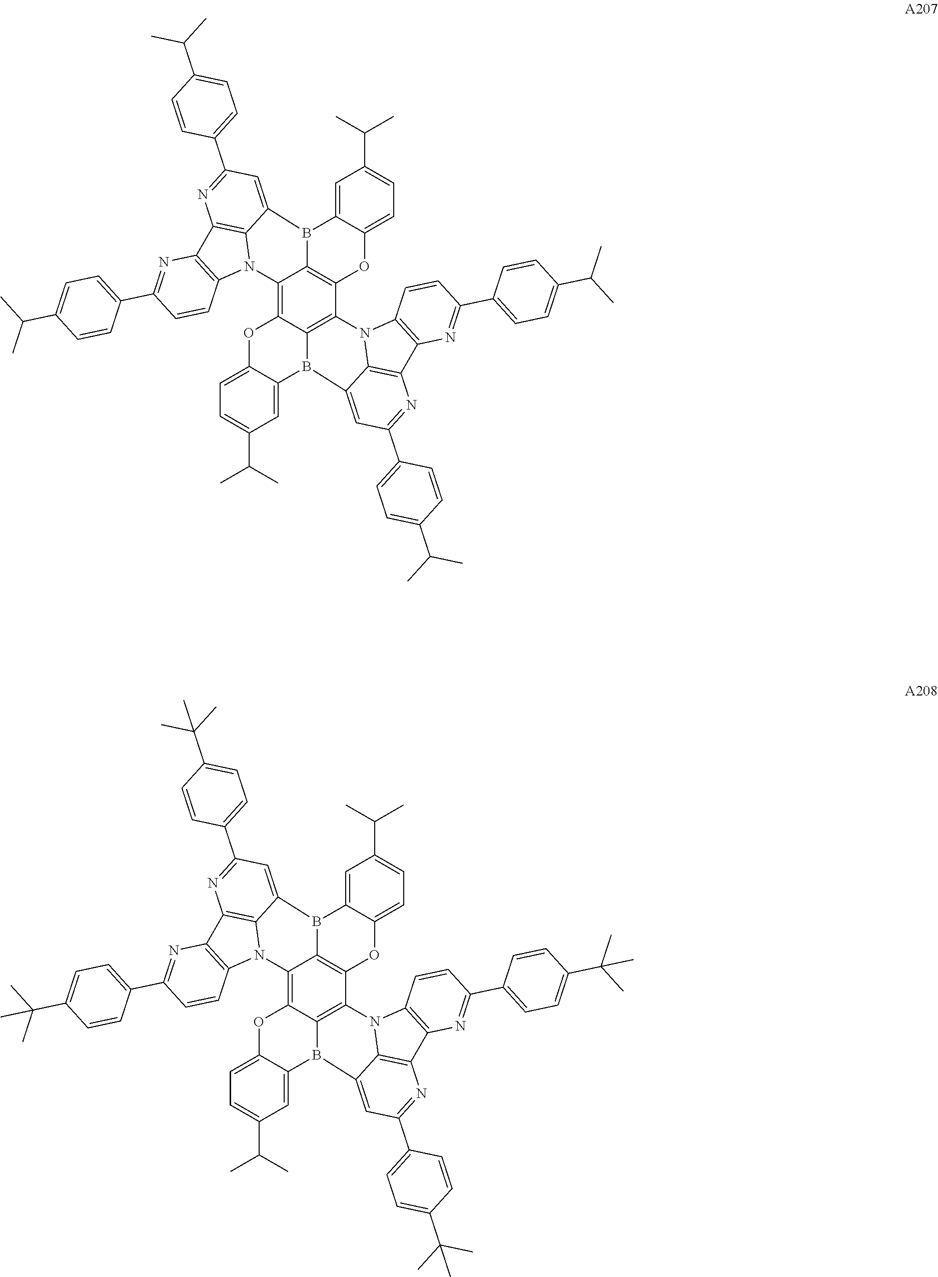

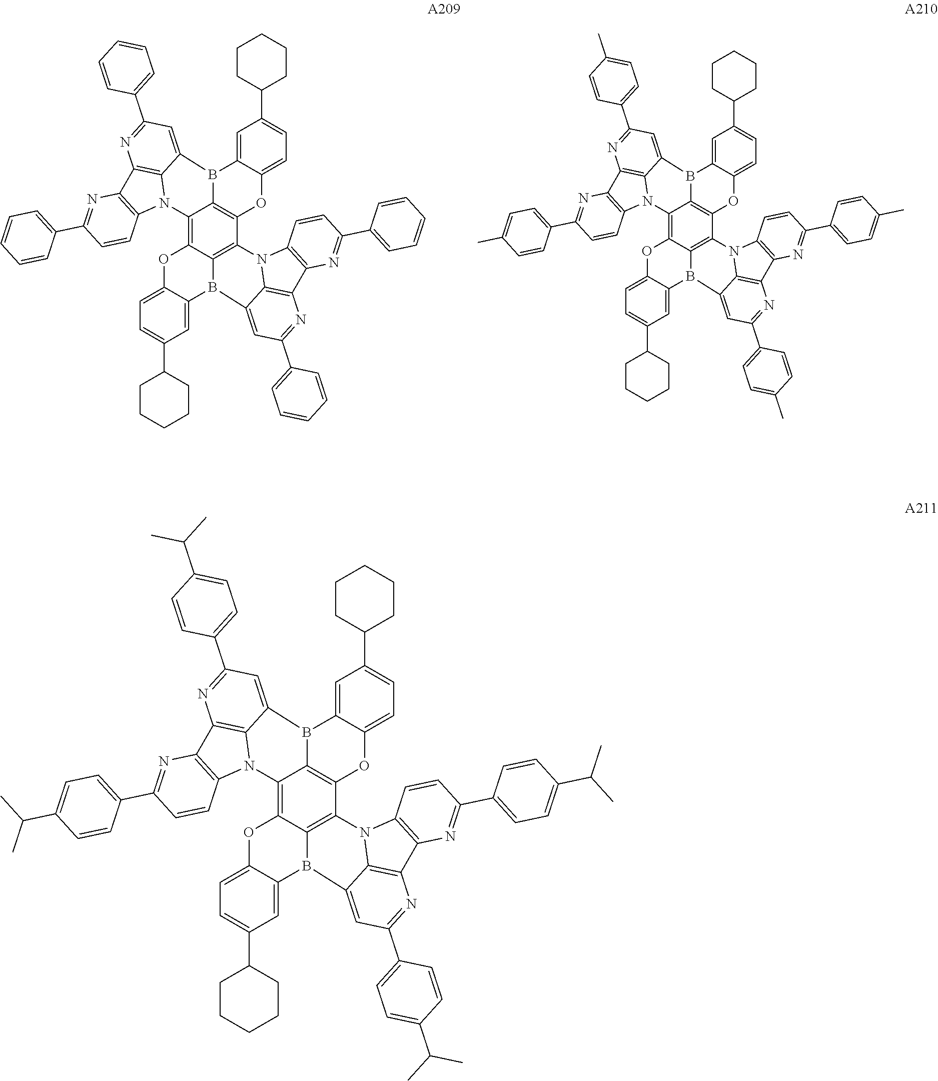

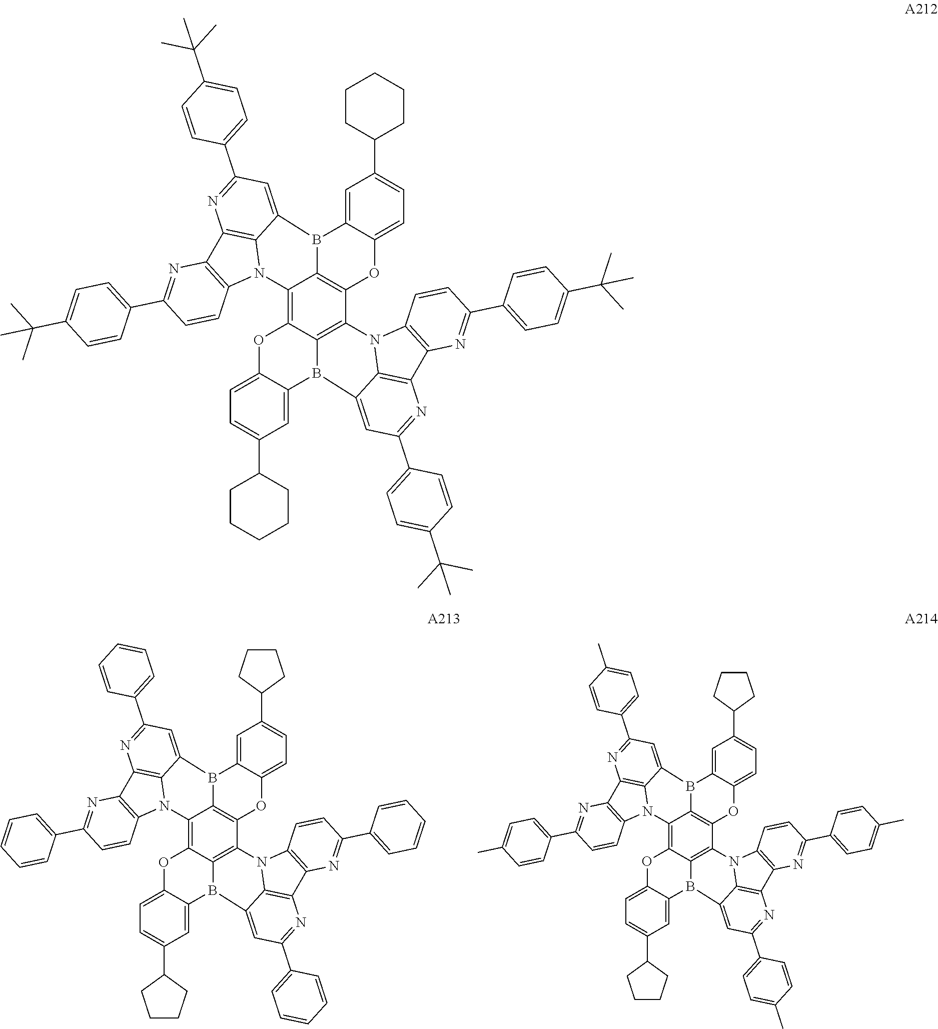

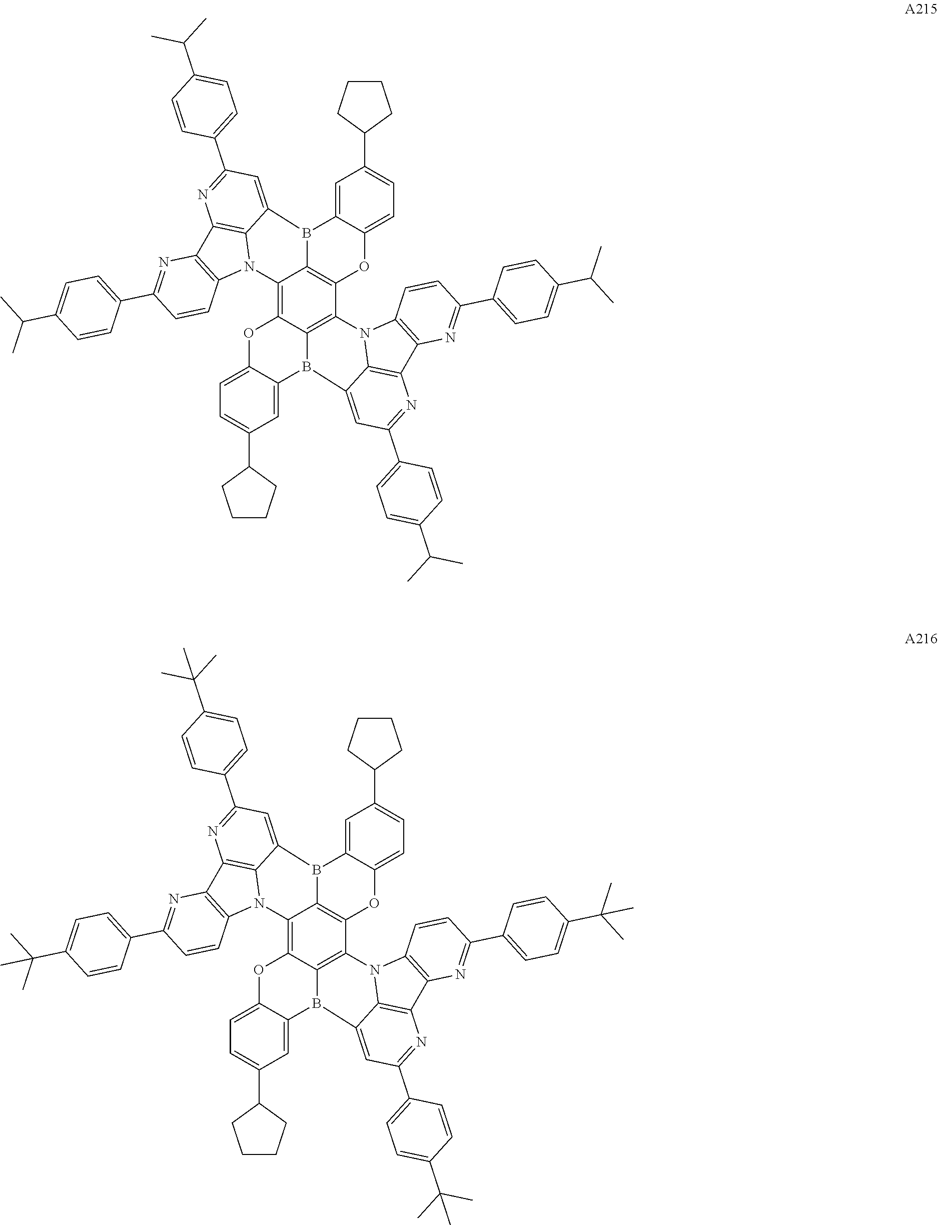

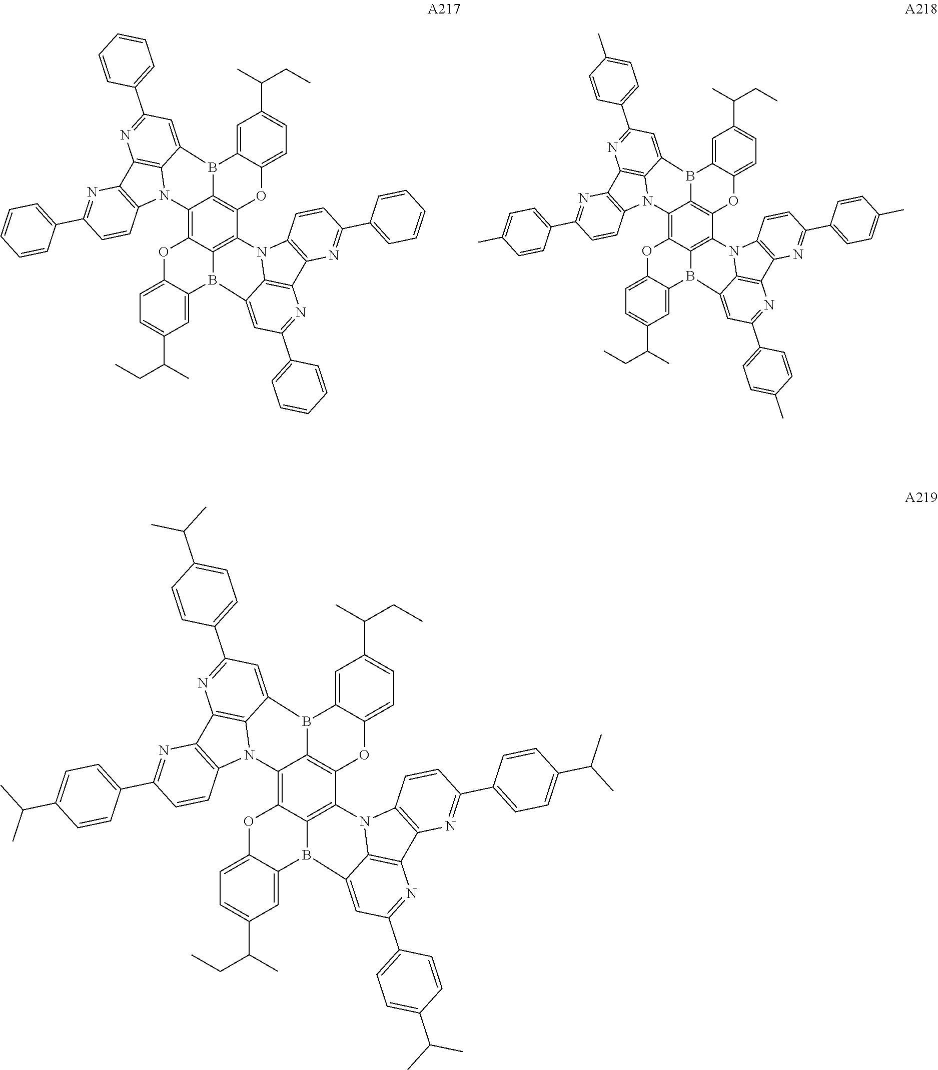

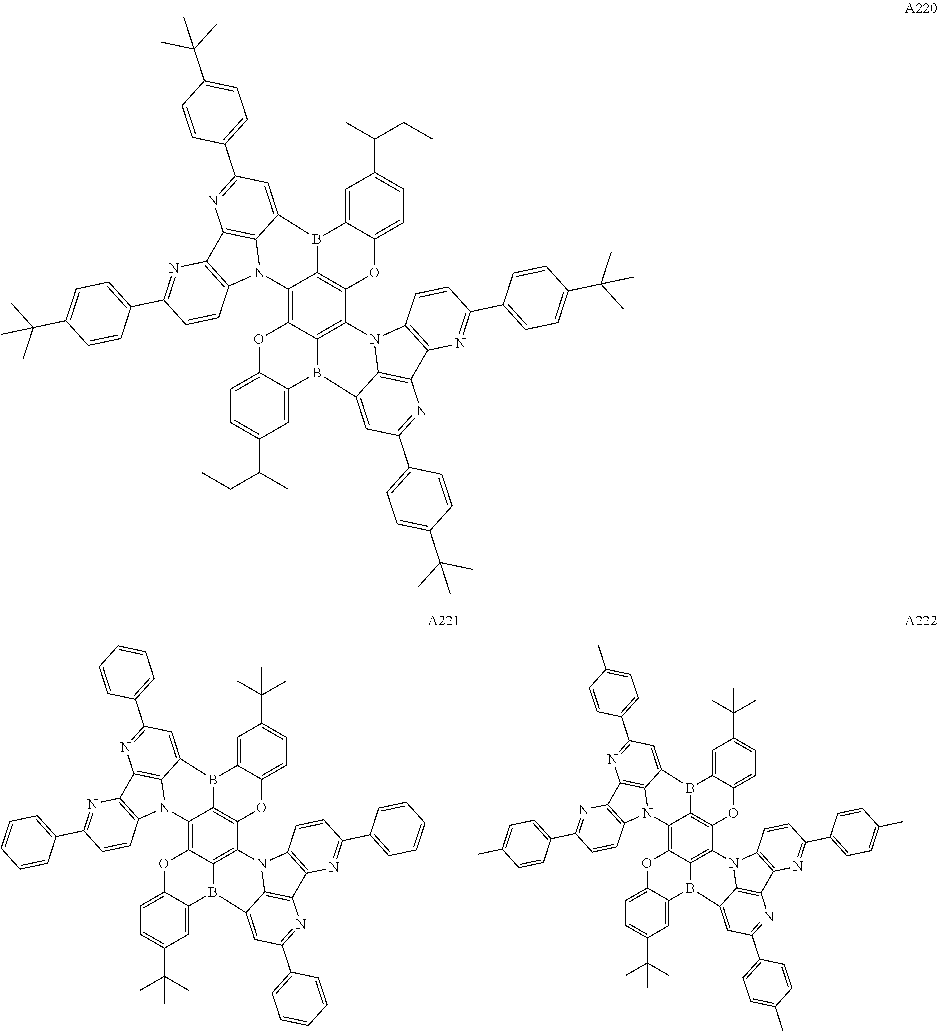

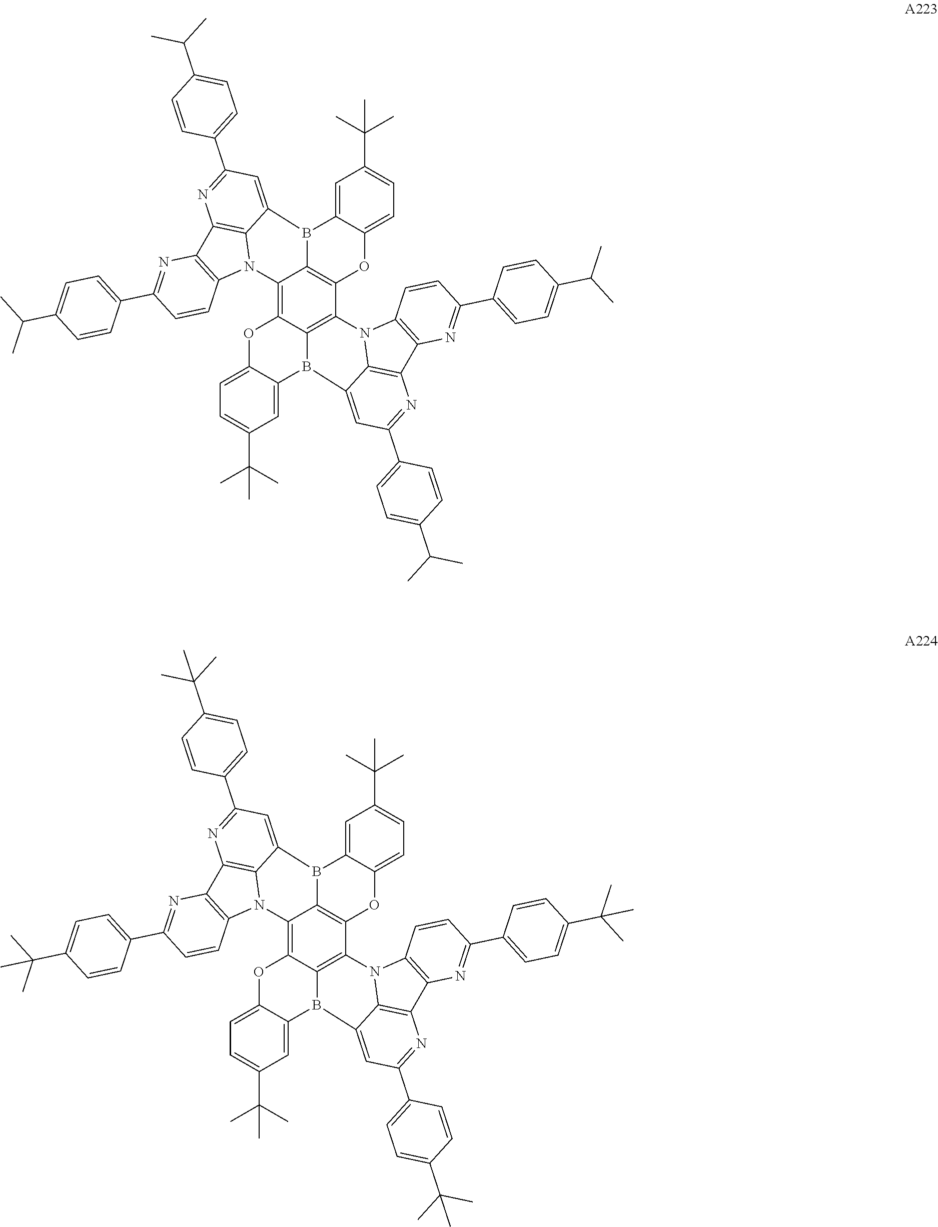

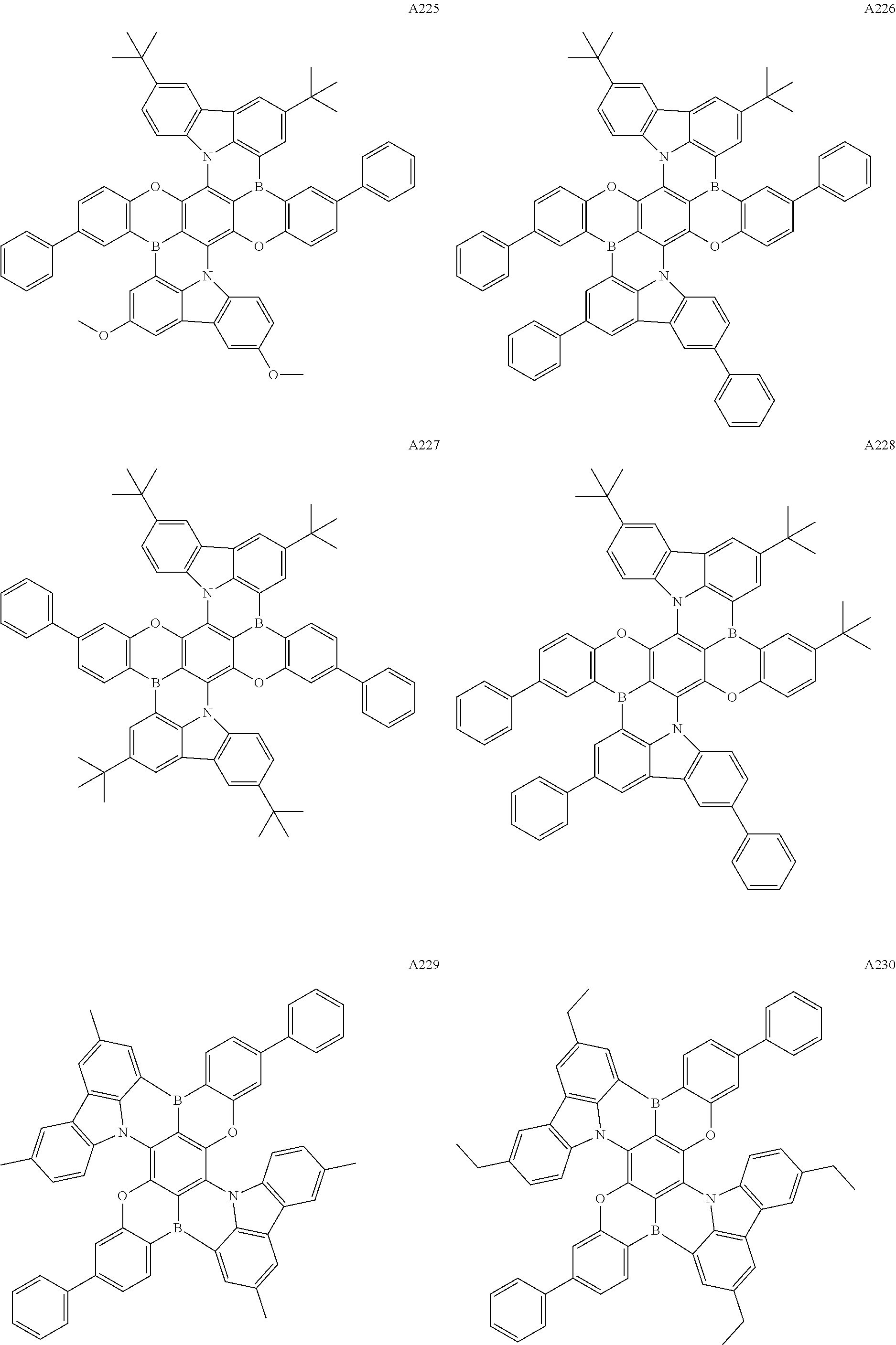

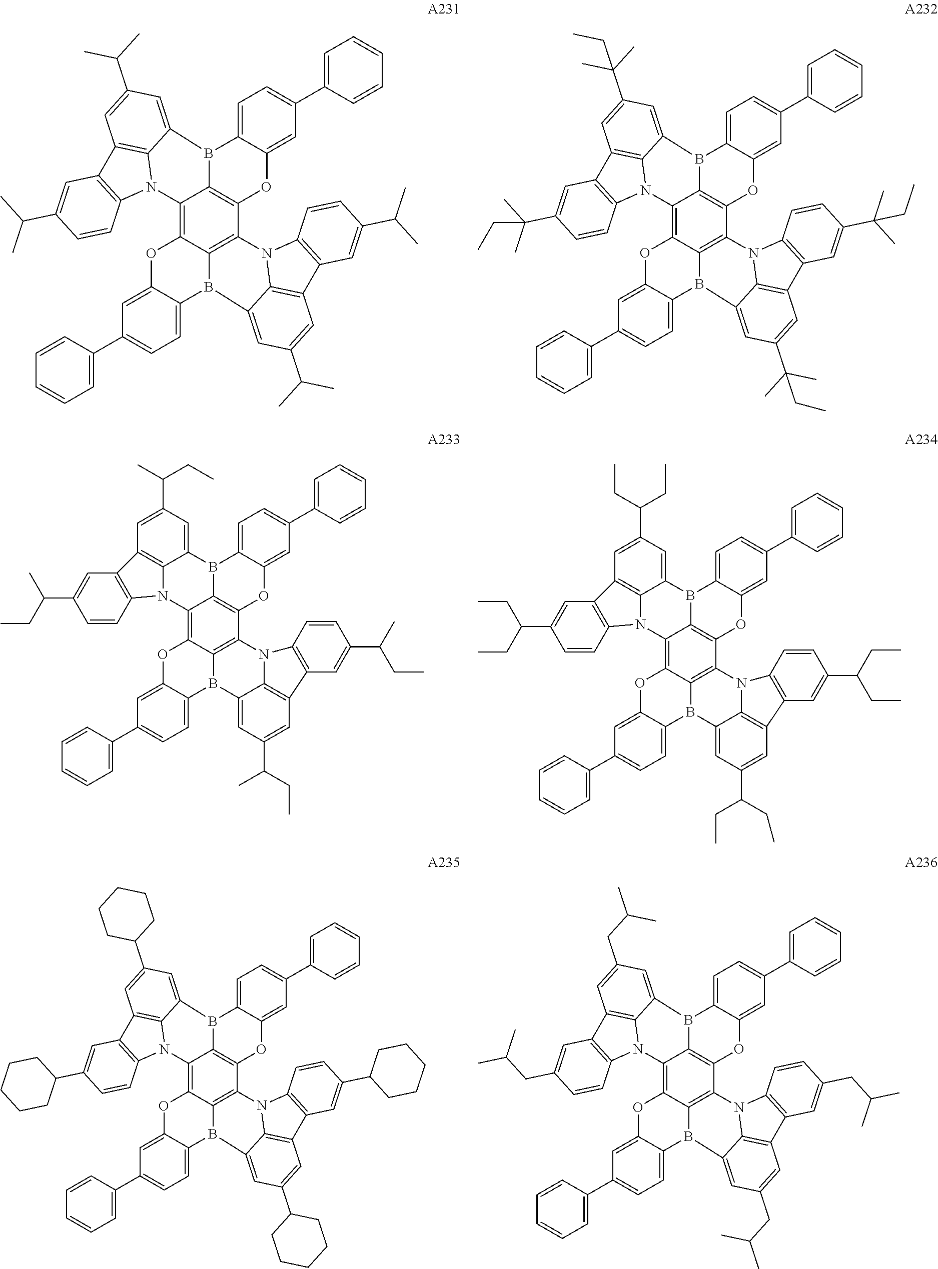

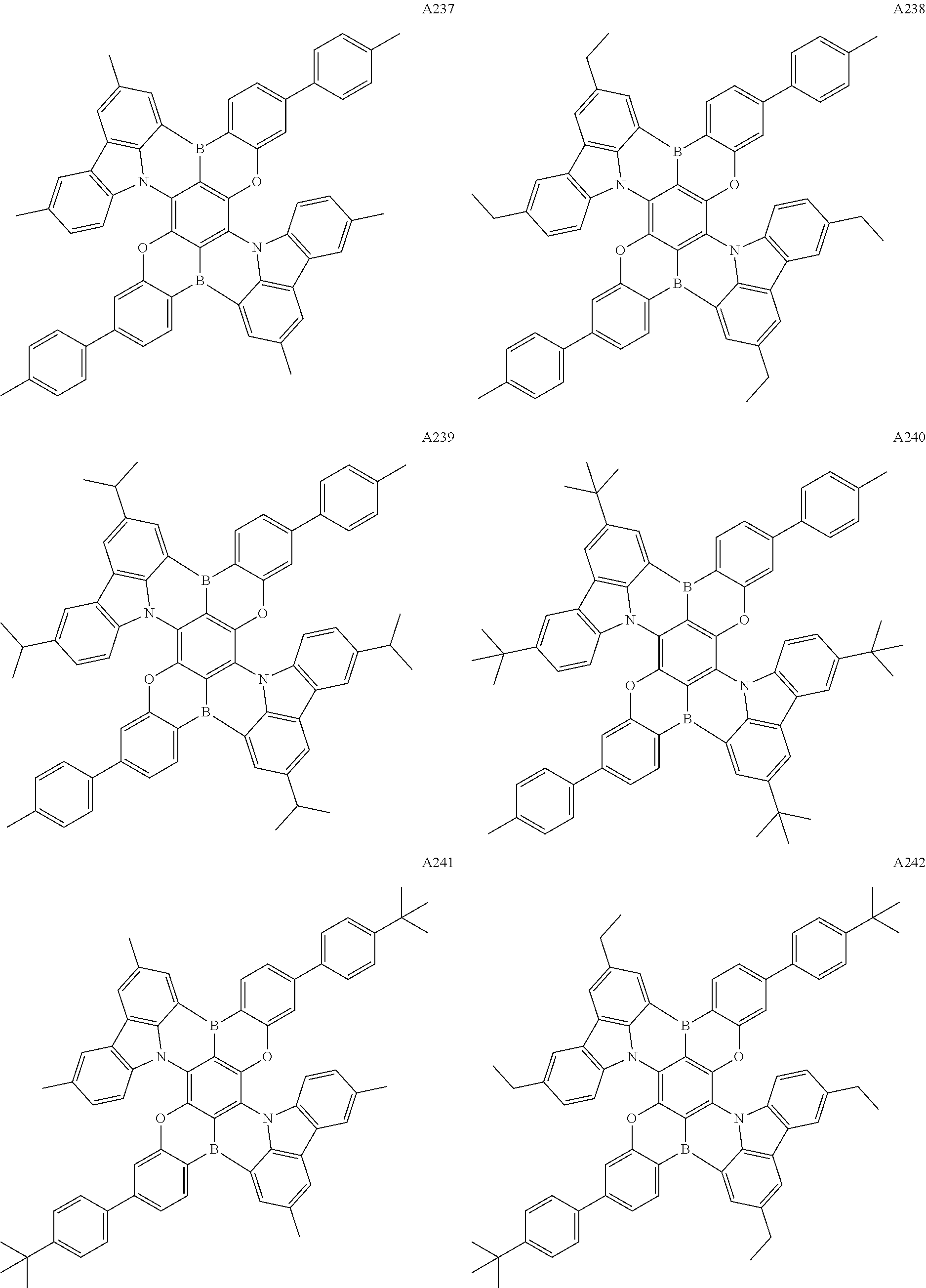

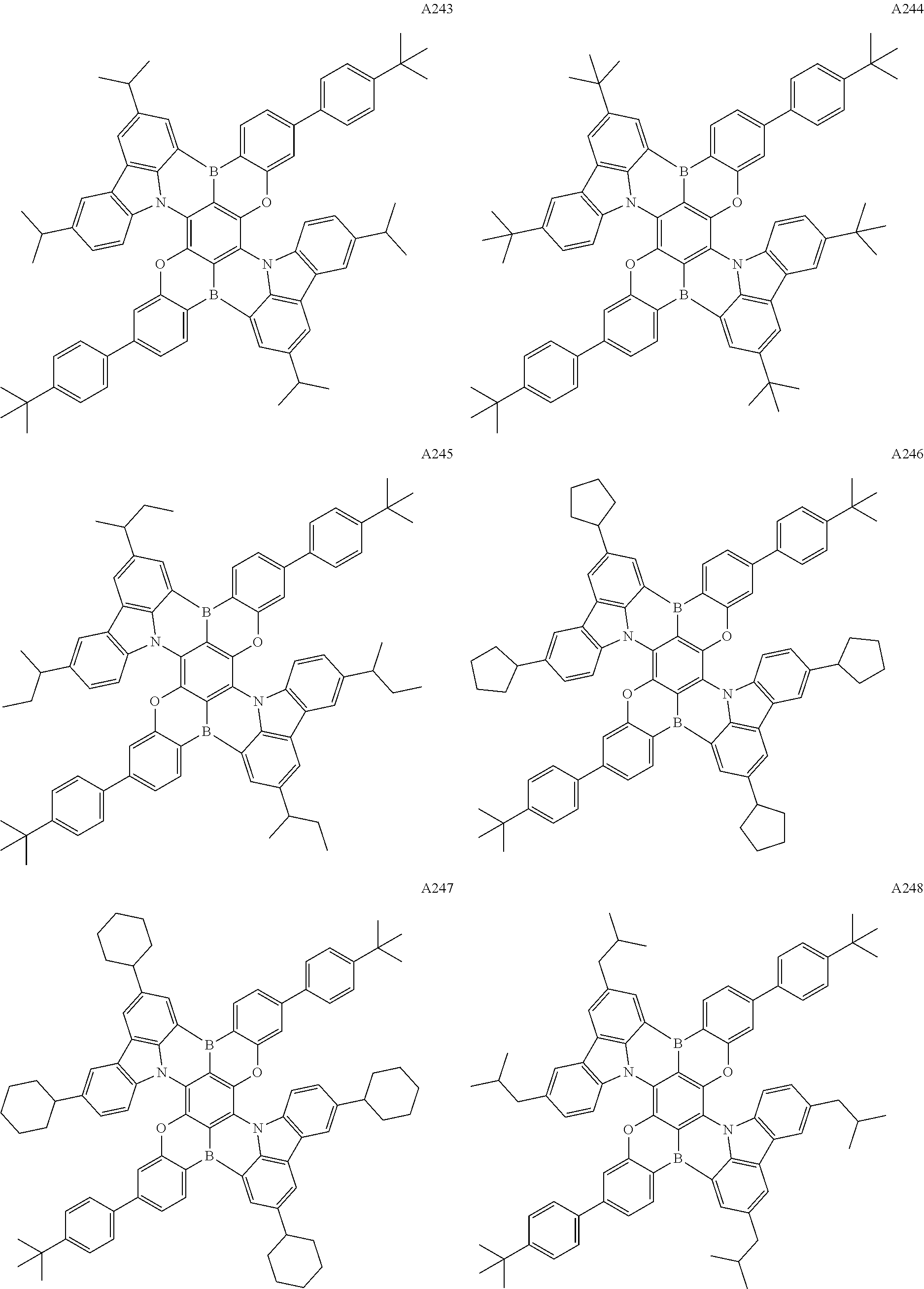

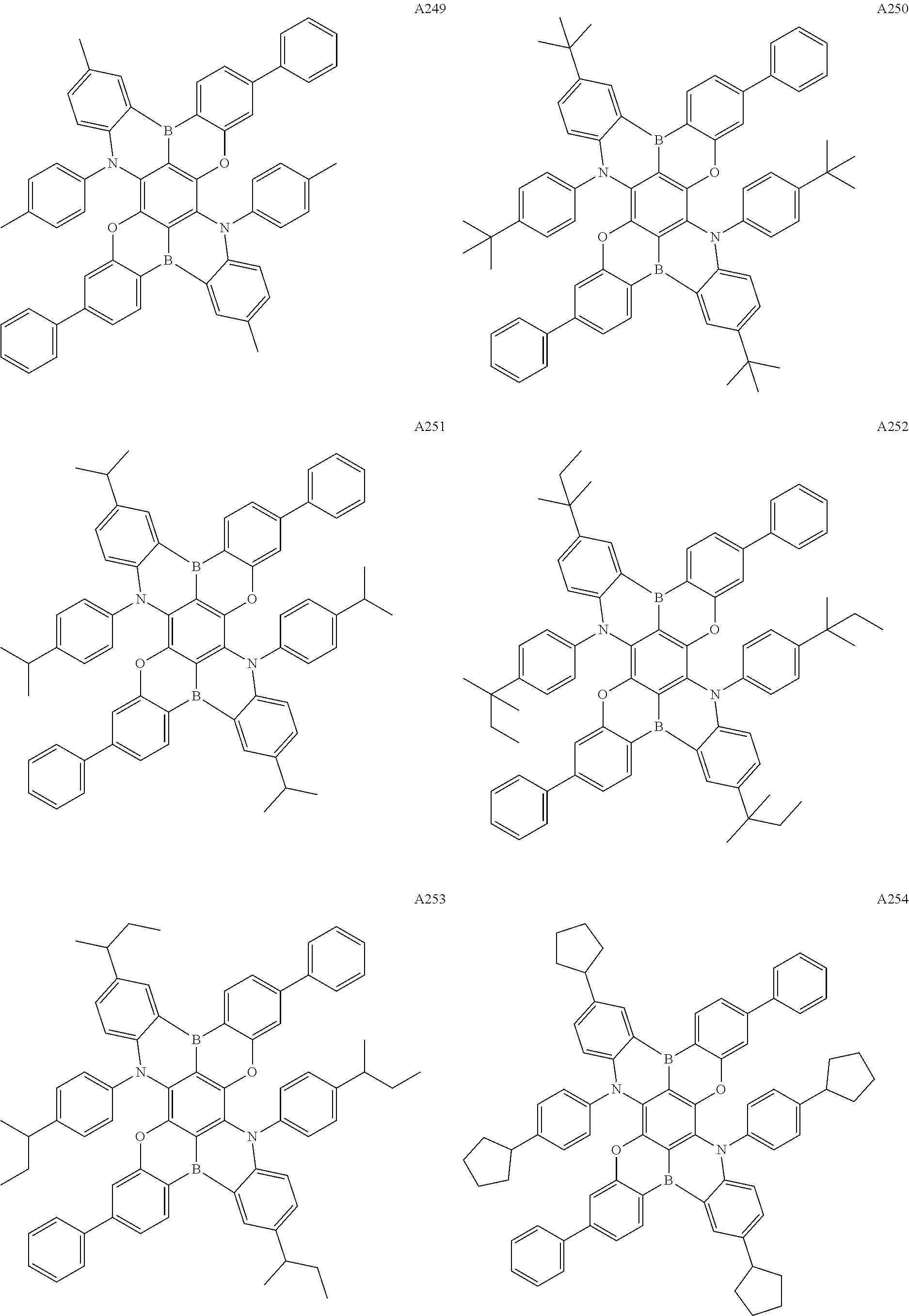

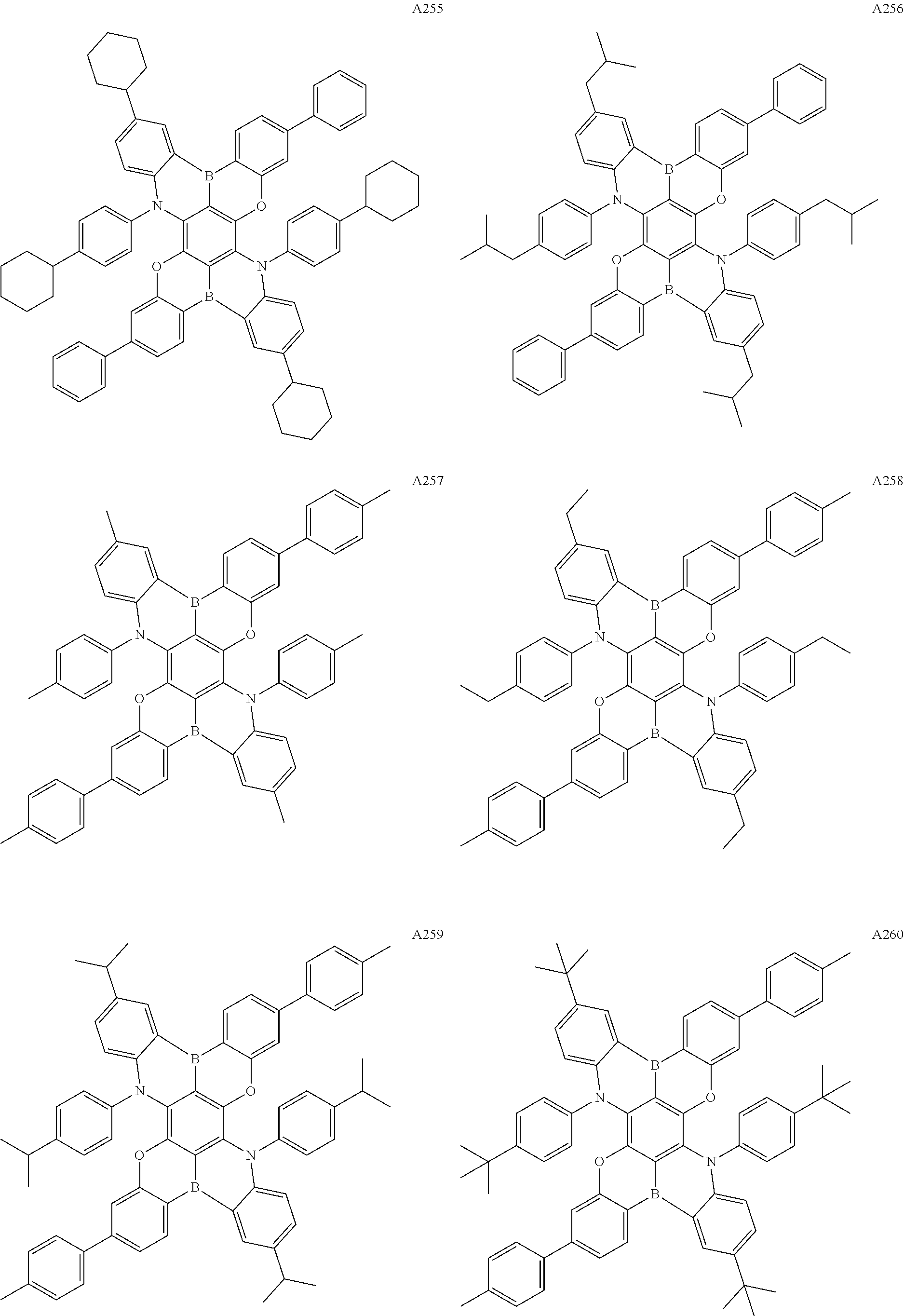

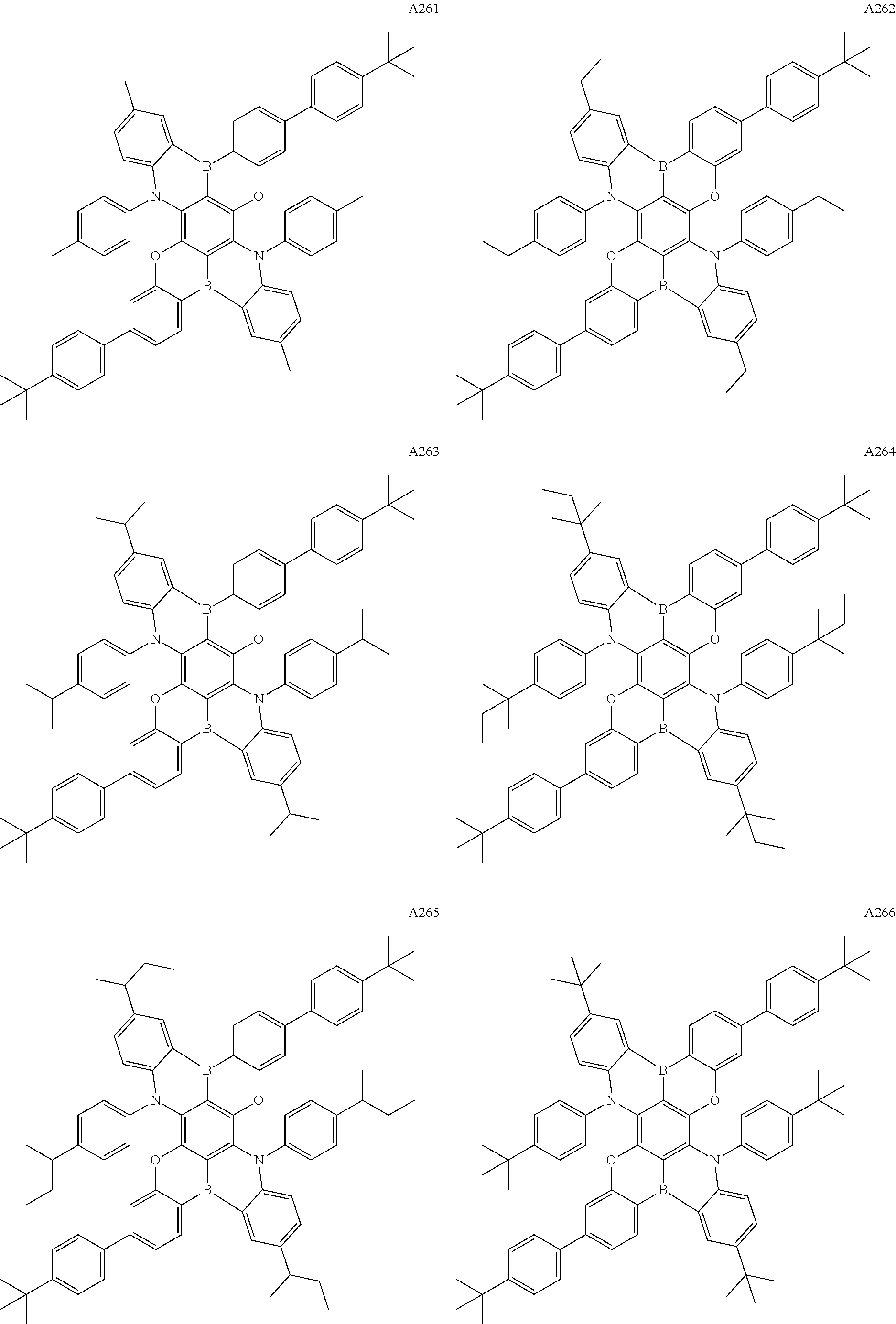

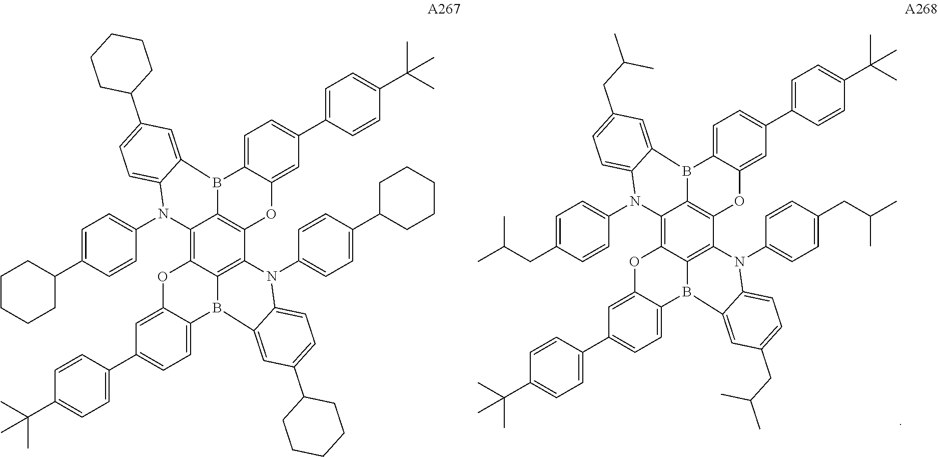 [SMILES: CC(C)(C)c1ccc(-c2ccc3c(c2)Oc2c4c(c5c6c2N(c2ccc(C7CCCCC7)cc2)c2ccc(C7CCCCC7)cc2B6c2ccc(-c6ccc(C(C)(C)C)cc6)cc2O5)N(c2ccc(C5CCCCC5)cc2)c2ccc(C5CCCCC5)cc2B34)cc1 ; CC(C)Cc1ccc(N2c3ccc(CC(C)C)cc3B3c4ccc(-c5ccc(C(C)(C)C)cc5)cc4Oc4c3c2c2c3c4N(c4ccc(CC(C)C)cc4)c4ccc(CC(C)C)cc4B3c3ccc(-c4ccc(C(C)(C)C)cc4)cc3O2)cc1]

14. The organic light-emitting diode according to claim 1, wherein the host material comprises one or more of the following compounds PH-1 to PH-85:

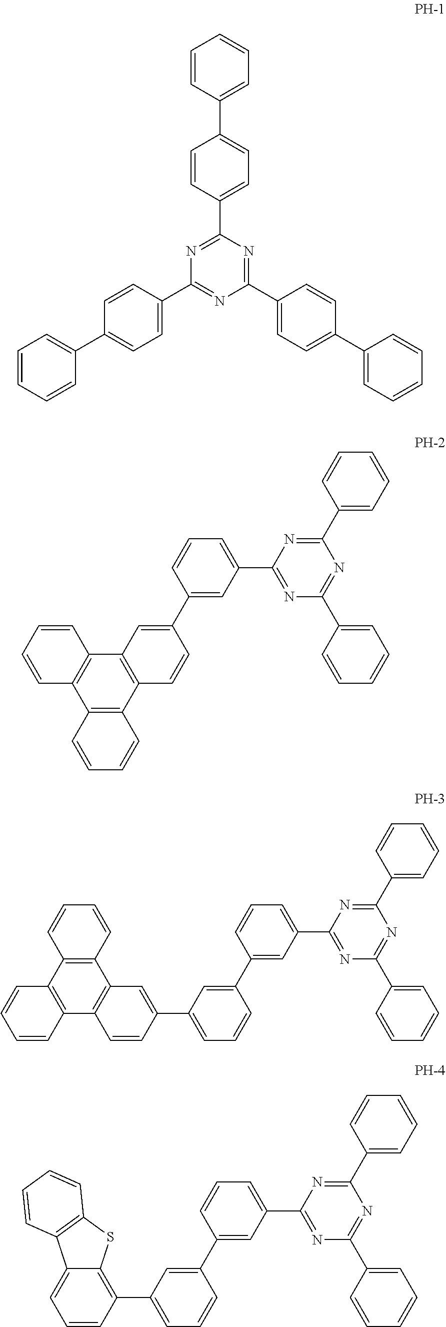 [SMILES: c1ccc(-c2ccc(-c3nc(-c4ccc(-c5ccccc5)cc4)nc(-c4ccc(-c5ccccc5)cc4)n3)cc2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4cccc(-c5cccc6c5sc5ccccc56)c4)c3)n2)cc1]

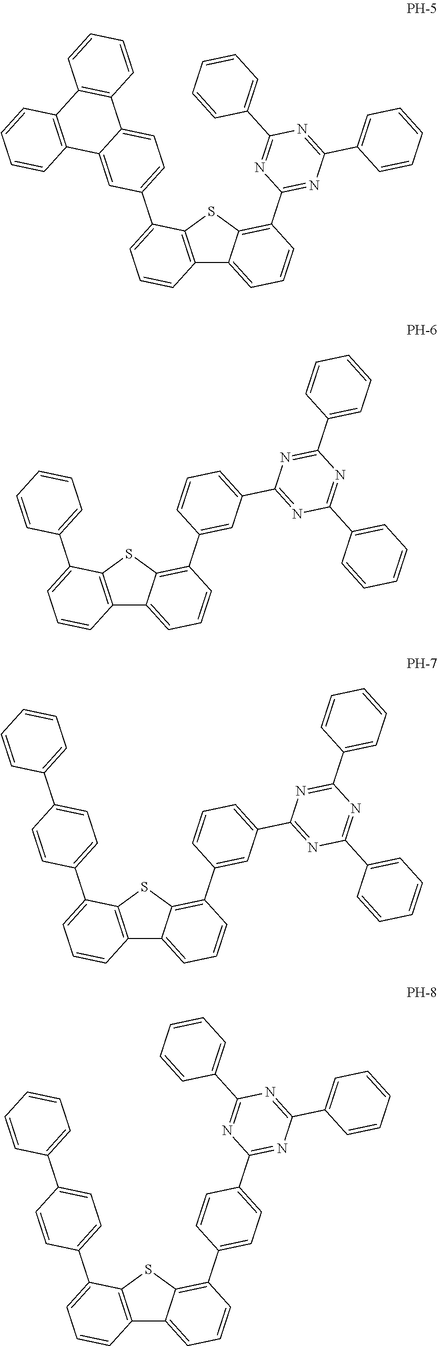 [SMILES: c1ccc(-c2nc(-c3ccccc3)nc(-c3cccc4c3sc3c(-c5ccc6c7ccccc7c7ccccc7c6c5)cccc34)n2)cc1 ; c1ccc(-c2nc(-c3ccccc3)nc(-c3cccc(-c4cccc5c4sc4c(-c6ccccc6)cccc45)c3)n2)cc1 ; c1ccc(-c2ccc(-c3cccc4c3sc3c(-c5cccc(-c6nc(-c7ccccc7)nc(-c7ccccc7)n6)c5)cccc34)cc2)cc1 ; c1ccc(-c2ccc(-c3cccc4c3sc3c(-c5ccc(-c6nc(-c7ccccc7)nc(-c7ccccc7)n6)cc5)cccc34)cc2)cc1]

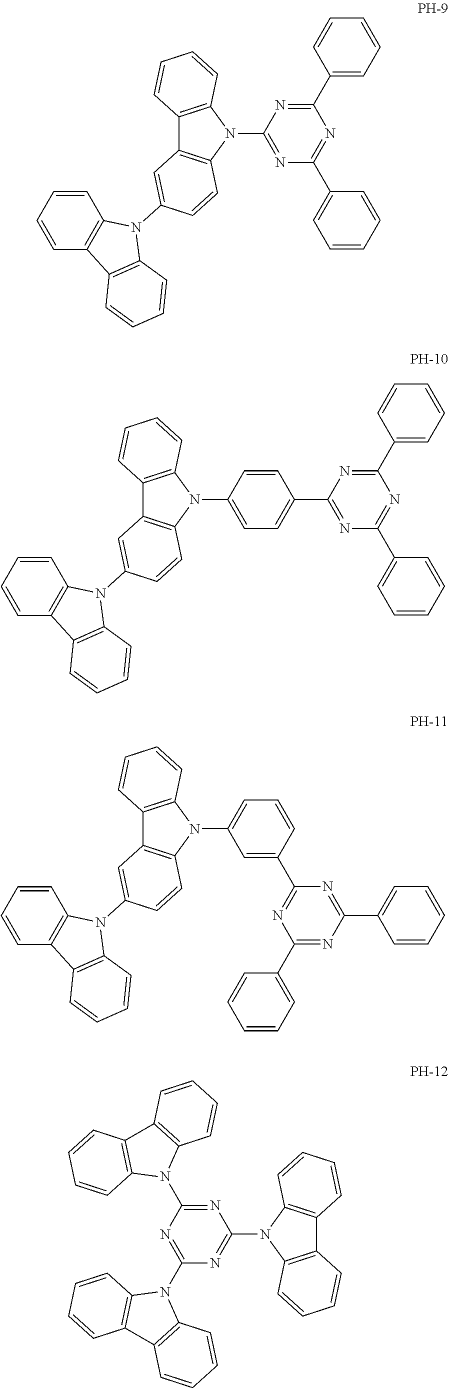 [SMILES: c1ccc(-c2nc(-c3ccccc3)nc(-n3c4ccccc4c4cc(-n5c6ccccc6c6ccccc65)ccc43)n2)cc1 ; c1ccc(-c2nc(-c3ccccc3)nc(-c3ccc(-n4c5ccccc5c5cc(-n6c7ccccc7c7ccccc76)ccc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc2c(c1)c1ccccc1n2-c1nc(-n2c3ccccc3c3ccccc32)nc(-n2c3ccccc3c3ccccc32)n1]

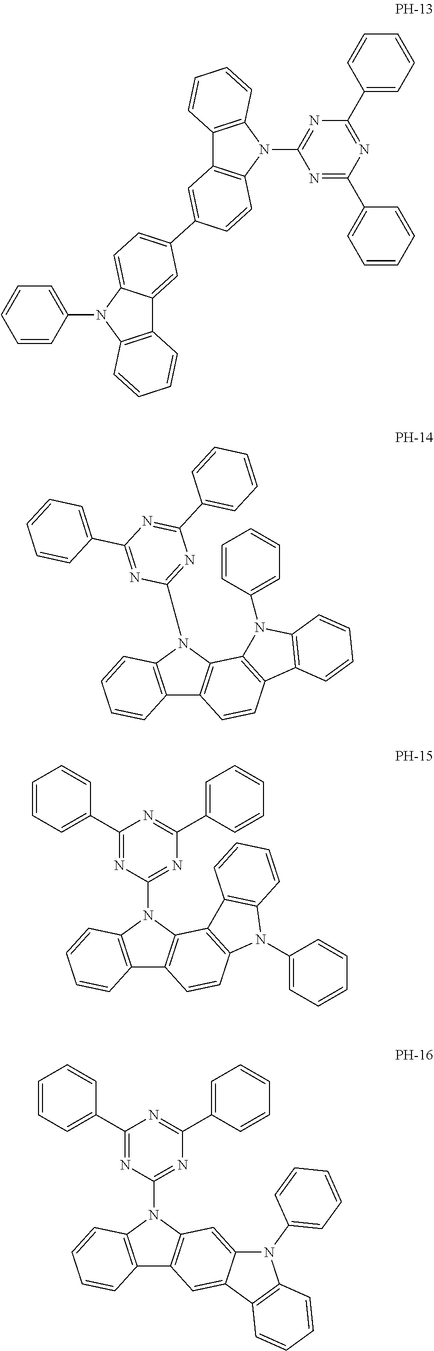 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4cc5c6ccccc6n(-c6ccccc6)c5cc43)n2)cc1]

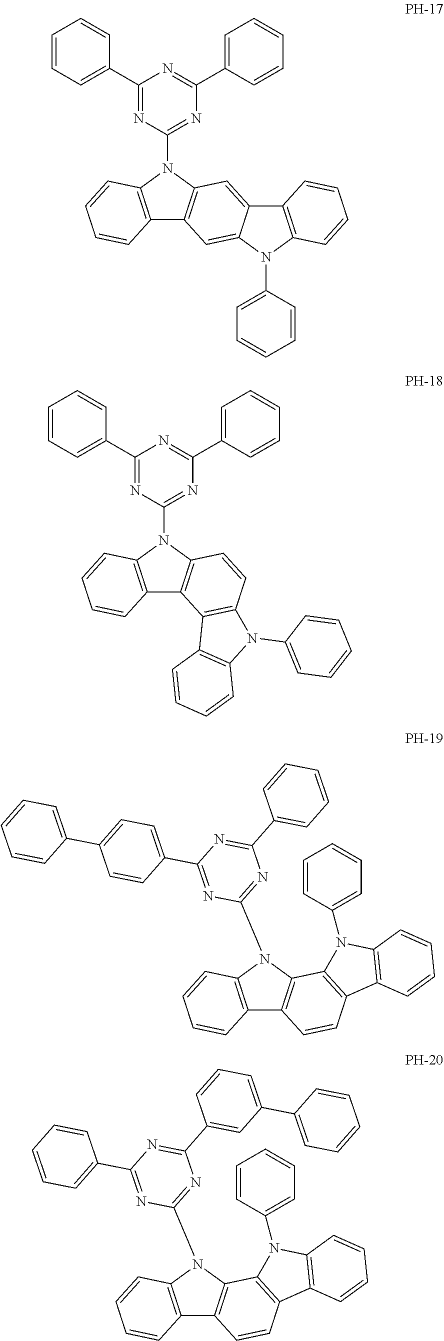

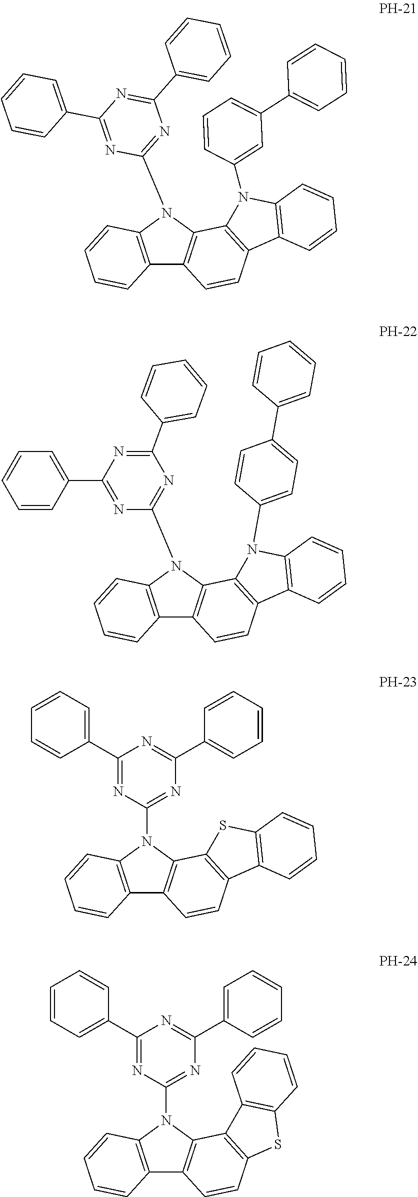 [SMILES: c1ccc(-c2cccc(-n3c4ccccc4c4ccc5c6ccccc6n(-c6nc(-c7ccccc7)nc(-c7ccccc7)n6)c5c43)c2)cc1 ; c1ccc(-c2ccc(-n3c4ccccc4c4ccc5c6ccccc6n(-c6nc(-c7ccccc7)nc(-c7ccccc7)n6)c5c43)cc2)cc1 ; c1ccc(-c2nc(-c3ccccc3)nc(-n3c4ccccc4c4ccc5c6ccccc6sc5c43)n2)cc1 ; c1ccc(-c2nc(-c3ccccc3)nc(-n3c4ccccc4c4ccc5sc6ccccc6c5c43)n2)cc1]

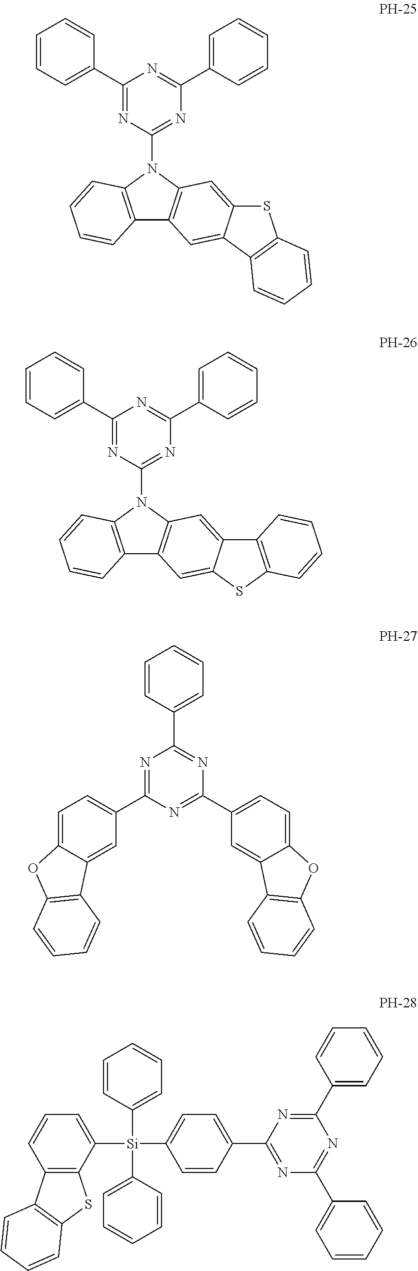 [SMILES: c1ccc(-c2nc(-c3ccccc3)nc(-n3c4ccccc4c4cc5c(cc43)sc3ccccc35)n2)cc1 ; c1ccc(-c2nc(-c3ccccc3)nc(-n3c4ccccc4c4cc5sc6ccccc6c5cc43)n2)cc1 ; c1ccc(-c2nc(-c3ccc4oc5ccccc5c4c3)nc(-c3ccc4oc5ccccc5c4c3)n2)cc1 ; c1ccc(-c2nc(-c3ccccc3)nc(-c3ccc([Si](c4ccccc4)(c4ccccc4)c4cccc5c4sc4ccccc45)cc3)n2)cc1]

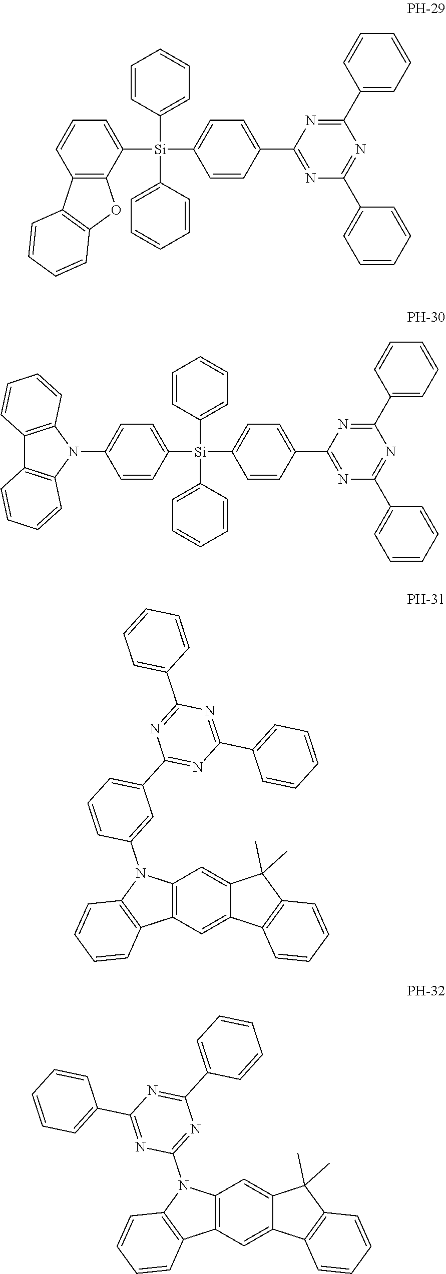 [SMILES: c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; CC1(C)c2ccccc2-c2cc3c4ccccc4n(-c4cccc(-c5nc(-c6ccccc6)nc(-c6ccccc6)n5)c4)c3cc21 ; CC1(C)c2ccccc2-c2cc3c4ccccc4n(-c4nc(-c5ccccc5)nc(-c5ccccc5)n4)c3cc21]

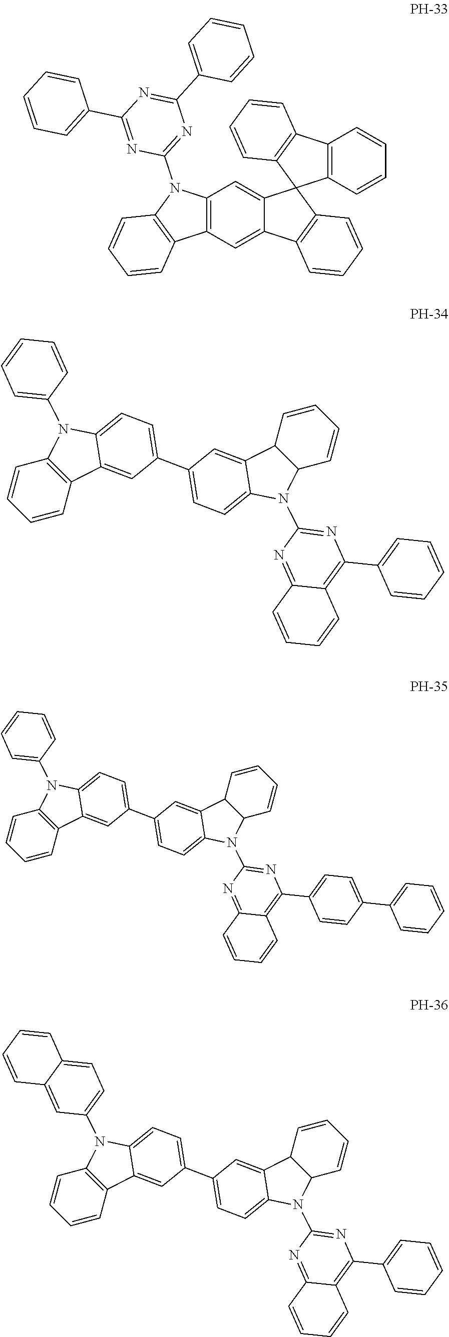 [SMILES: c1ccc(-c2nc(-c3ccccc3)nc(-n3c4ccccc4c4cc5c(cc43)C3(c4ccccc4-c4ccccc43)c3ccccc3-5)n2)cc1 ; C1=CC2c3cc(-c4ccc5c(c4)c4ccccc4n5-c4ccccc4)ccc3N(c3nc(-c4ccccc4)c4ccccc4n3)C2C=C1 ; C1=CC2c3cc(-c4ccc5c(c4)c4ccccc4n5-c4ccccc4)ccc3N(c3nc(-c4ccc(-c5ccccc5)cc4)c4ccccc4n3)C2C=C1 ; C1=CC2c3cc(-c4ccc5c(c4)c4ccccc4n5-c4ccc5ccccc5c4)ccc3N(c3nc(-c4ccccc4)c4ccccc4n3)C2C=C1]

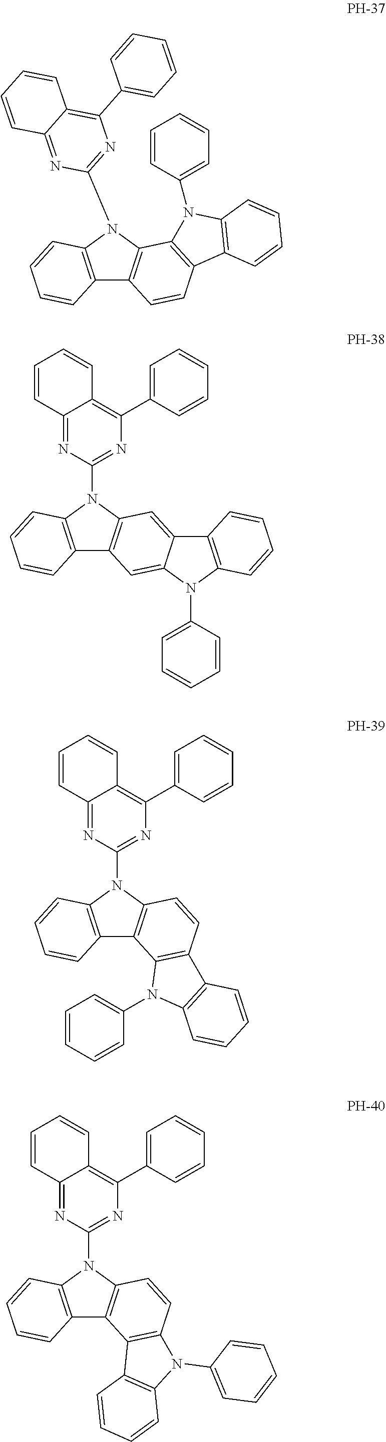

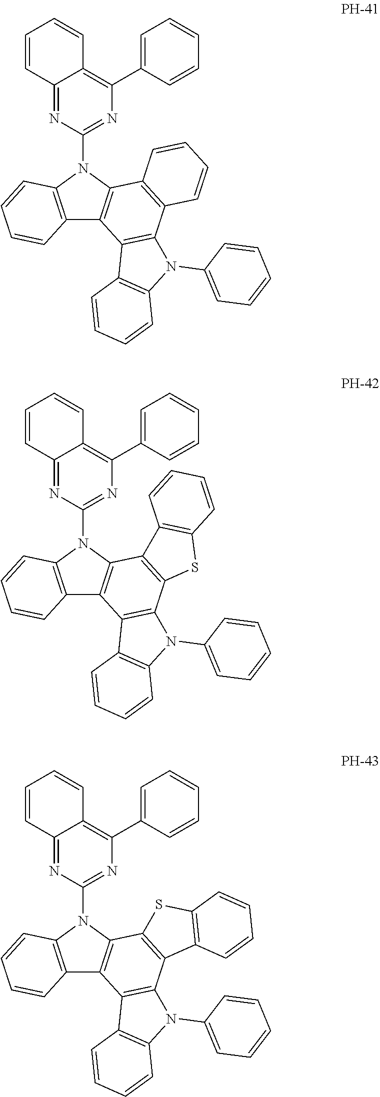 [SMILES: c1ccc(-c2nc(-n3c4ccccc4c4c5c6ccccc6n(-c6ccccc6)c5c5ccccc5c43)nc3ccccc23)cc1 ; c1ccc(-c2nc(-n3c4ccccc4c4c5c6ccccc6n(-c6ccccc6)c5c5sc6ccccc6c5c43)nc3ccccc23)cc1 ; c1ccc(-c2nc(-n3c4ccccc4c4c5c6ccccc6n(-c6ccccc6)c5c5c6ccccc6sc5c43)nc3ccccc23)cc1]

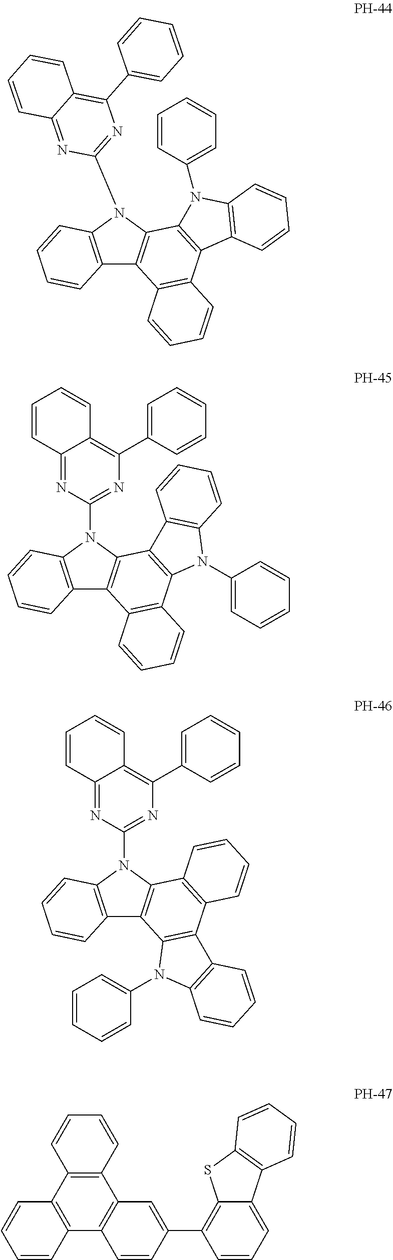

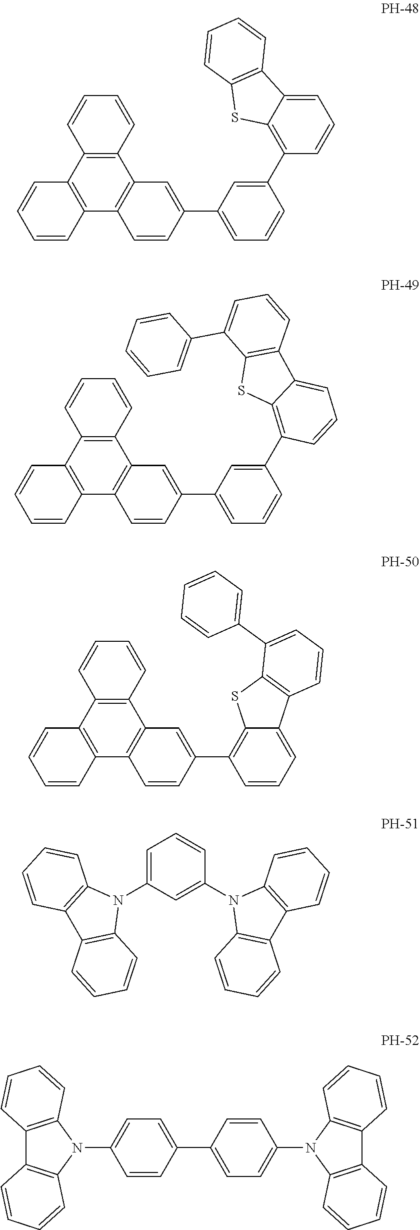 [SMILES: c1cc(-c2ccc3c4ccccc4c4ccccc4c3c2)cc(-c2cccc3c2sc2ccccc23)c1 ; c1ccc(-c2cccc3c2sc2c(-c4cccc(-c5ccc6c7ccccc7c7ccccc7c6c5)c4)cccc23)cc1 ; c1ccc(-c2cccc3c2sc2c(-c4ccc5c6ccccc6c6ccccc6c5c4)cccc23)cc1 ; c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1]

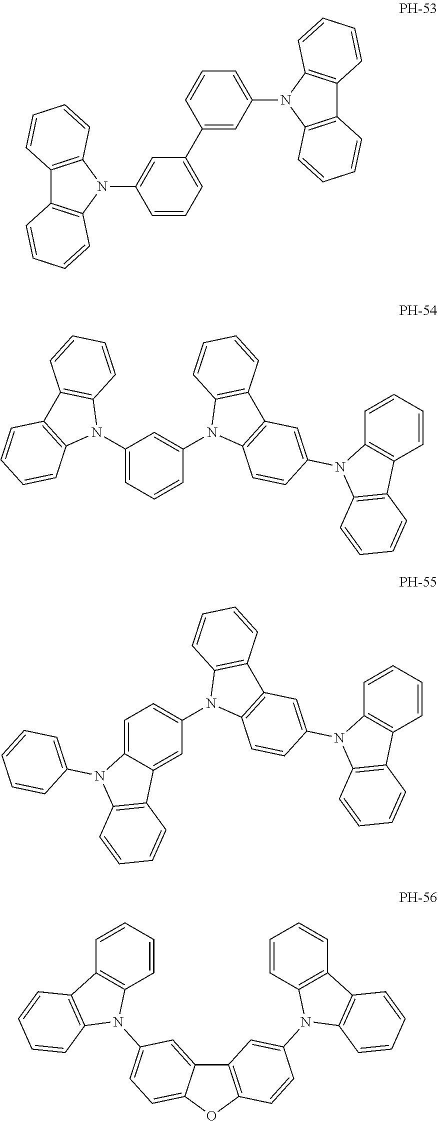 [SMILES: c1cc(-c2cccc(-n3c4ccccc4c4ccccc43)c2)cc(-n2c3ccccc3c3ccccc32)c1 ; c1cc(-n2c3ccccc3c3ccccc32)cc(-n2c3ccccc3c3cc(-n4c5ccccc5c5ccccc54)ccc32)c1 ; c1ccc(-n2c3ccccc3c3cc(-n4c5ccccc5c5cc(-n6c7ccccc7c7ccccc76)ccc54)ccc32)cc1 ; c1ccc2c(c1)c1ccccc1n2-c1ccc2oc3ccc(-n4c5ccccc5c5ccccc54)cc3c2c1]

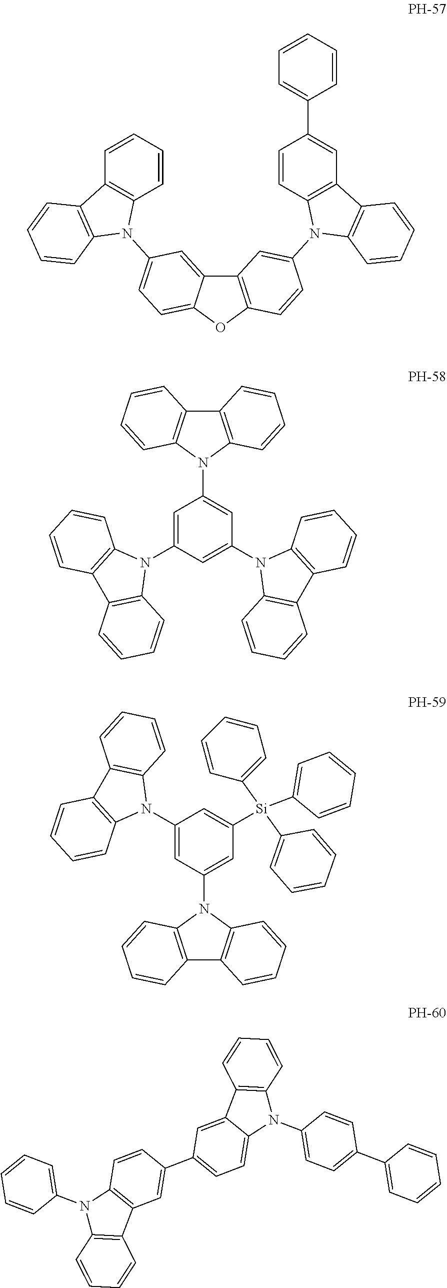 [SMILES: c1ccc(-c2ccc3c(c2)c2ccccc2n3-c2ccc3oc4ccc(-n5c6ccccc6c6ccccc65)cc4c3c2)cc1 ; c1ccc2c(c1)c1ccccc1n2-c1cc(-n2c3ccccc3c3ccccc32)cc(-n2c3ccccc3c3ccccc32)c1 ; c1ccc([Si](c2ccccc2)(c2ccccc2)c2cc(-n3c4ccccc4c4ccccc43)cc(-n3c4ccccc4c4ccccc43)c2)cc1 ; c1ccc(-c2ccc(-n3c4ccccc4c4cc(-c5ccc6c(c5)c5ccccc5n6-c5ccccc5)ccc43)cc2)cc1]

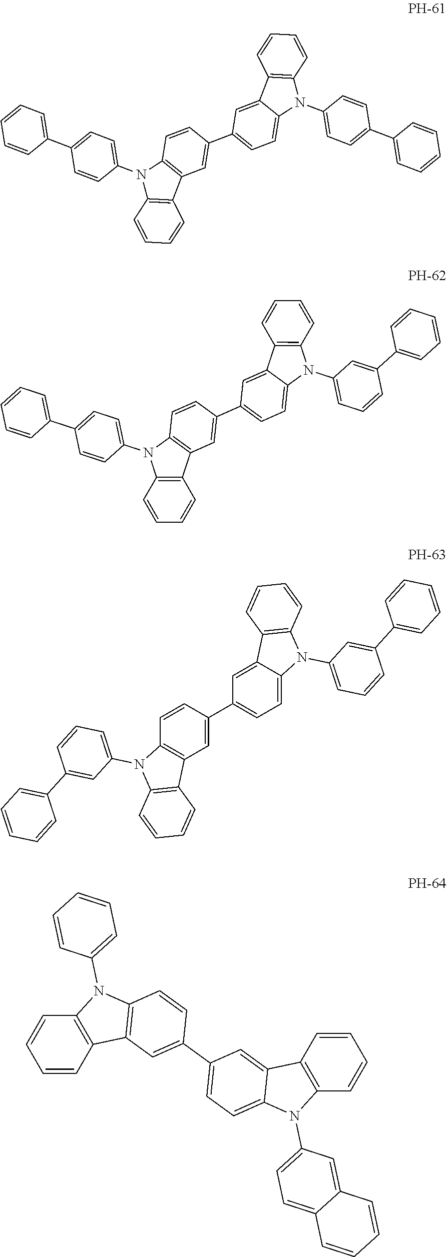 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-n2c3ccccc3c3cc(-c4ccc5c(c4)c4ccccc4n5-c4ccc5ccccc5c4)ccc32)cc1]

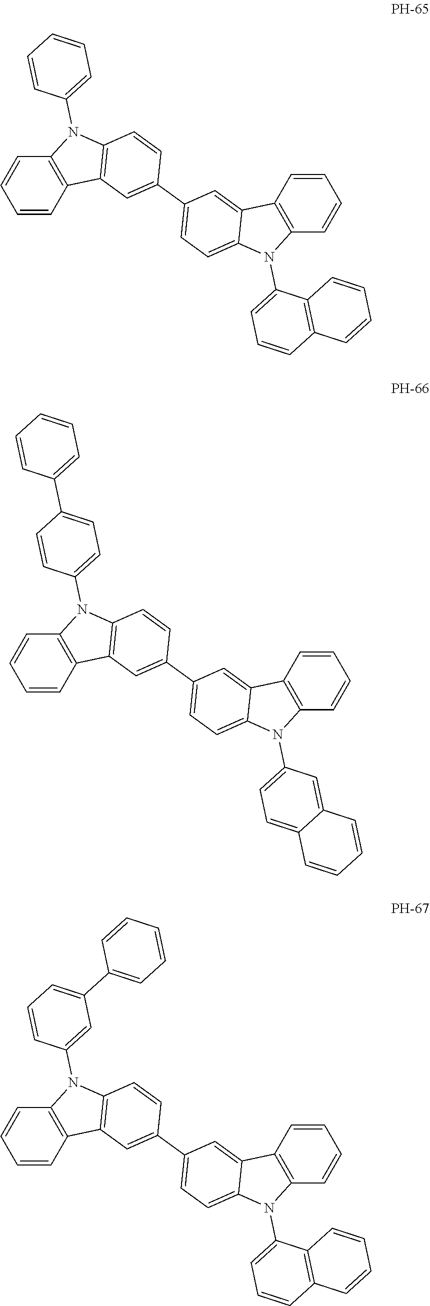 [SMILES: c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc6ccccc56)ccc43)c2)cc1]

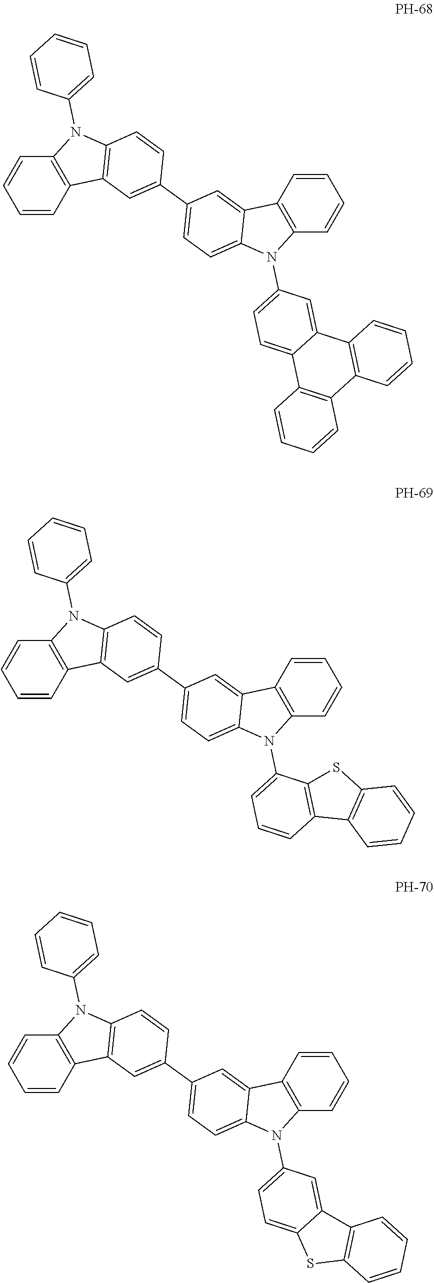 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1]

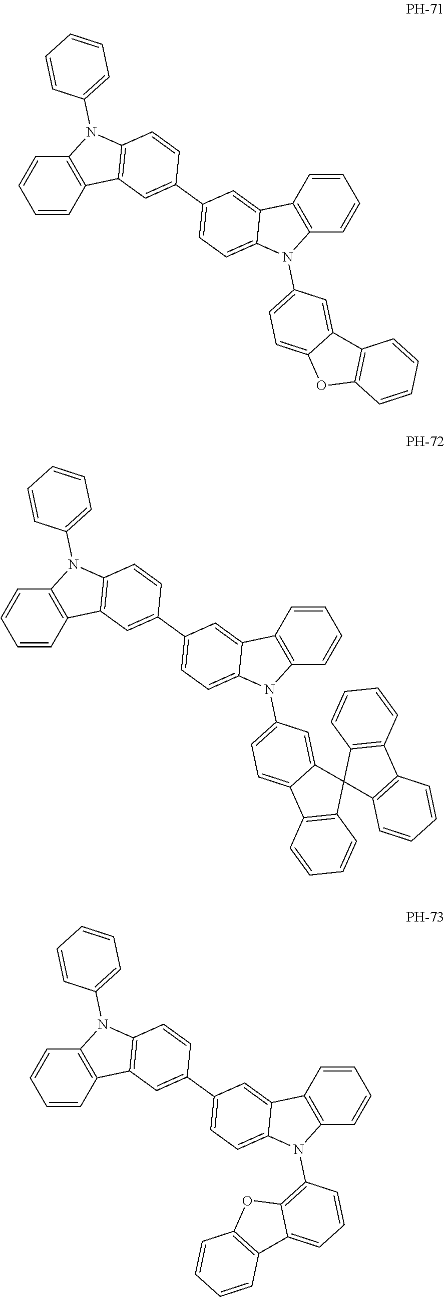 [SMILES: c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; c1ccc(-n2c3ccccc3c3cc(-c4ccc5c(c4)c4ccccc4n5-c4cccc5c4oc4ccccc45)ccc32)cc1]

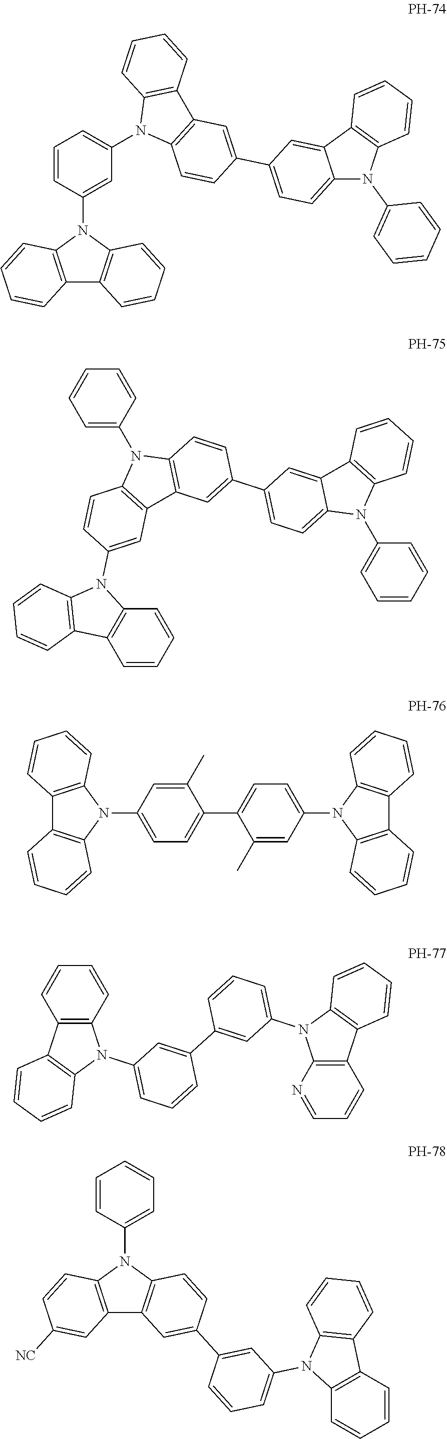 [SMILES: c1ccc(-n2c3ccccc3c3cc(-c4ccc5c(c4)c4ccccc4n5-c4cccc(-n5c6ccccc6c6ccccc65)c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1 ; Cc1cc(-n2c3ccccc3c3ccccc32)ccc1-c1ccc(-n2c3ccccc3c3ccccc32)cc1C ; c1cc(-c2cccc(-n3c4ccccc4c4cccnc43)c2)cc(-n2c3ccccc3c3ccccc32)c1 ; N#Cc1ccc2c(c1)c1cc(-c3cccc(-n4c5ccccc5c5ccccc54)c3)ccc1n2-c1ccccc1]

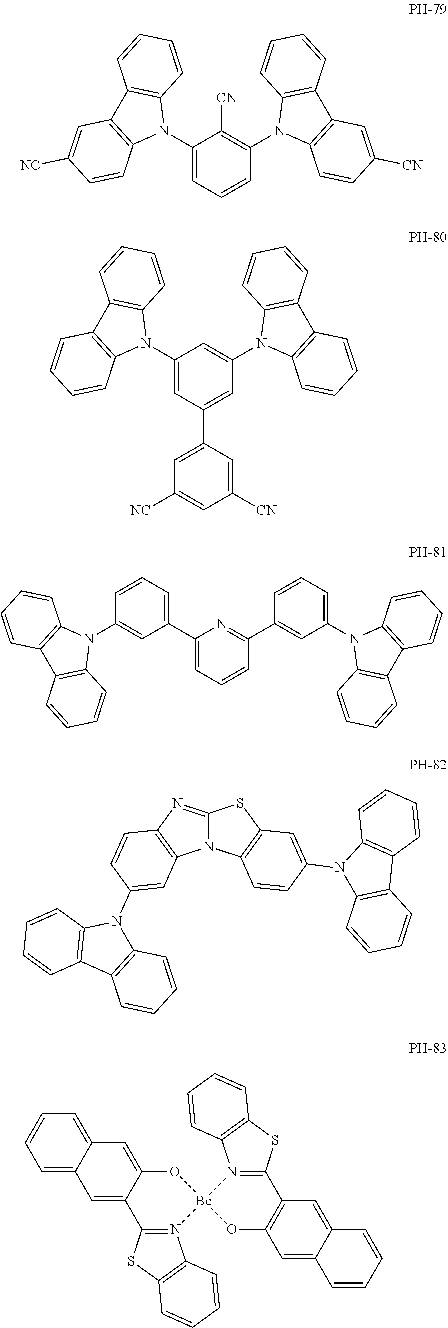

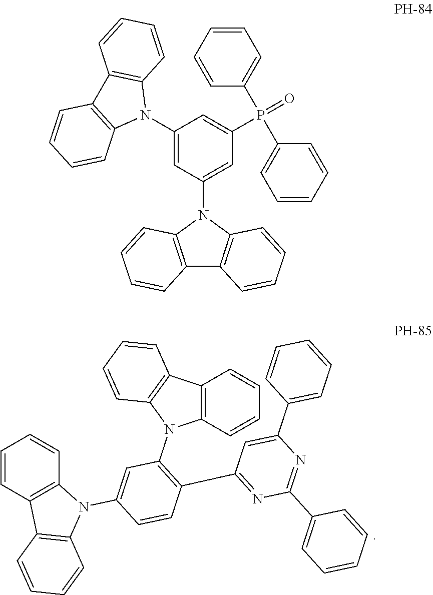 [SMILES: O=P(c1ccccc1)(c1ccccc1)c1cc(-n2c3ccccc3c3ccccc32)cc(-n2c3ccccc3c3ccccc32)c1 ; c1ccc(-c2cc(-c3ccc(-n4c5ccccc5c5ccccc54)cc3-n3c4ccccc4c4ccccc43)nc(-c3ccccc3)n2)cc1]

15. The organic light-emitting diode according to claim 1, wherein the phosphorescent sensitizer comprises one or more of the following compounds RPD-1 to RPD-29:

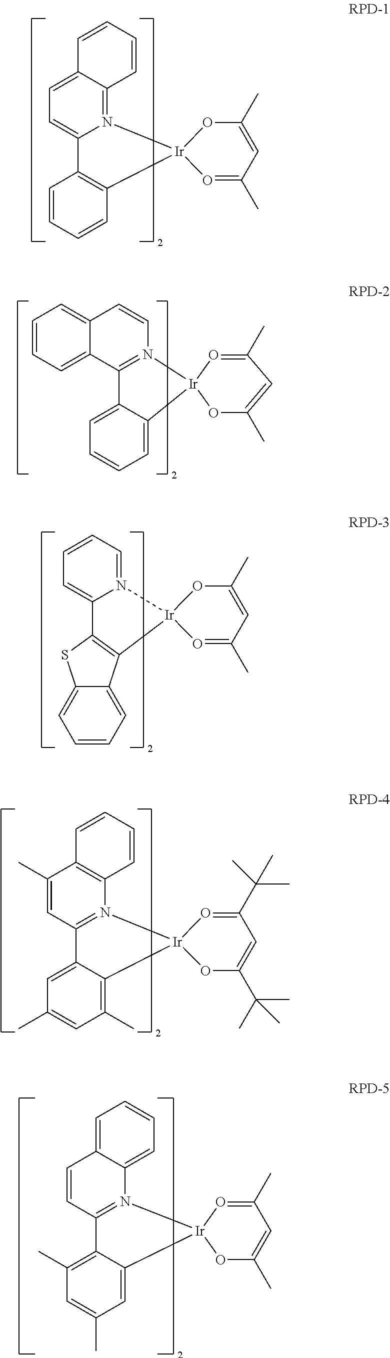

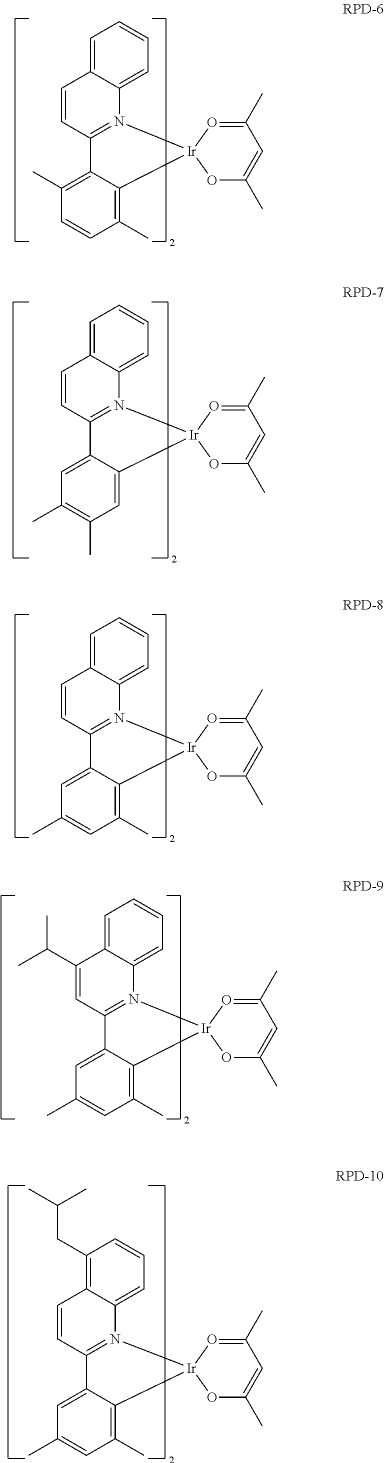

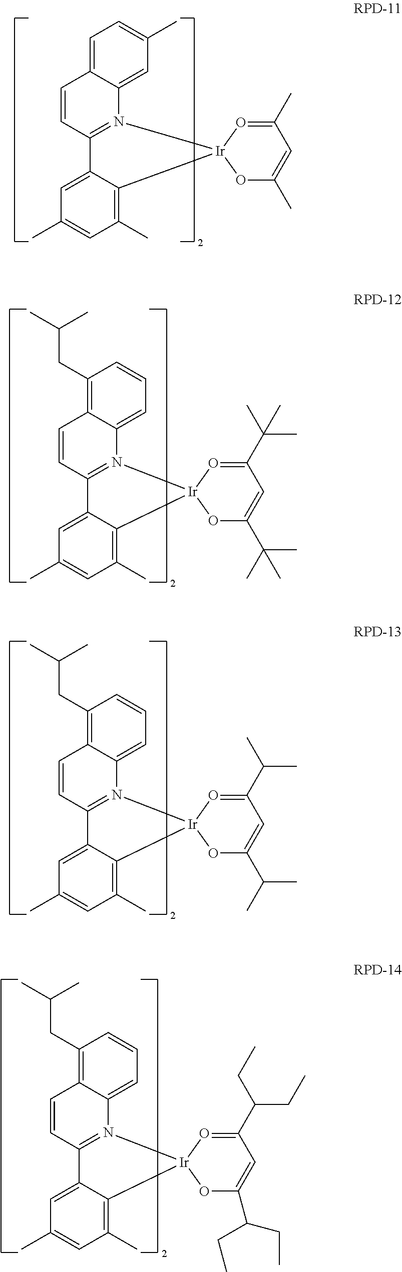

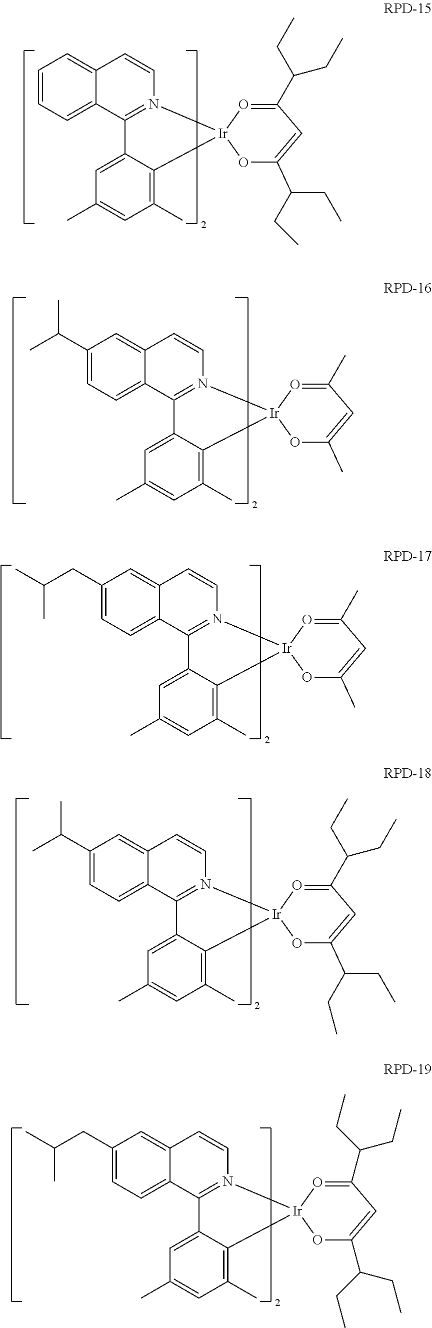

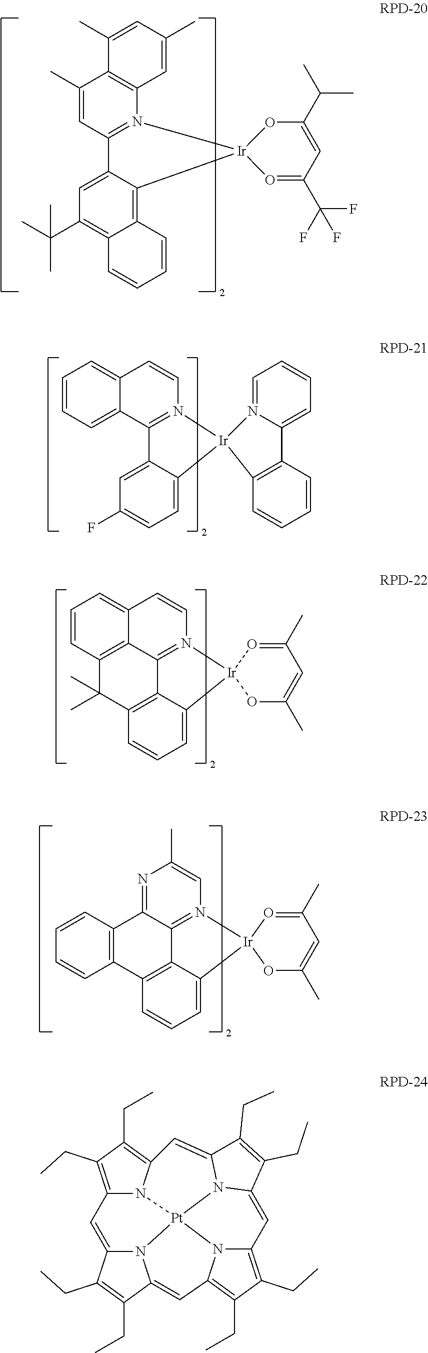

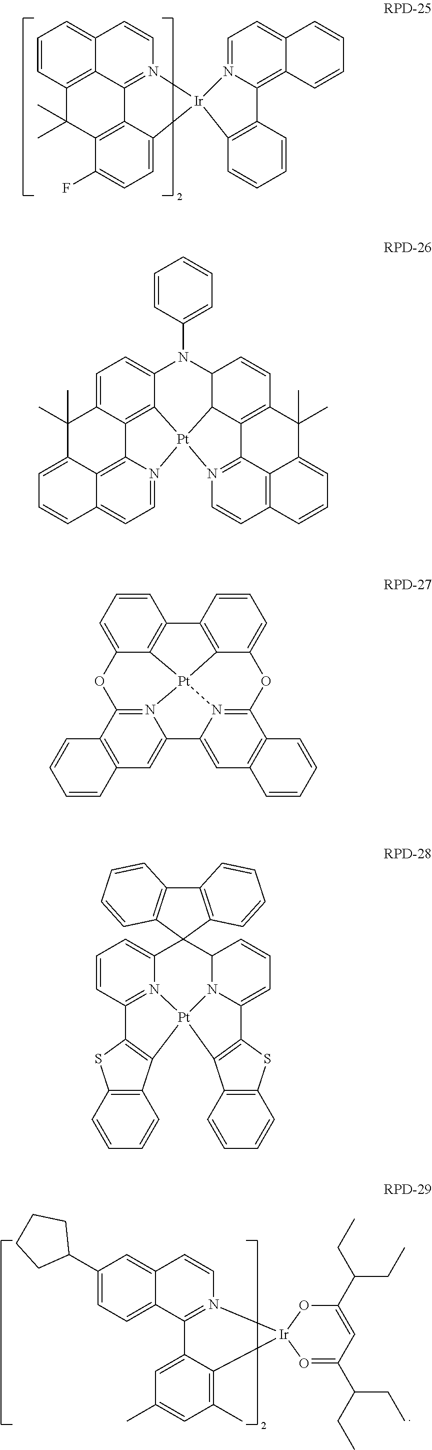

16. The organic light-emitting diode according to claim 1, wherein a mass content of the phosphorescent sensitizer in the phosphorescence sensitized layer is 0.1-50%.

17. The organic light-emitting diode according to claim 16, wherein the mass content of the phosphorescent sensitizer in the phosphorescence sensitized layer is 0.1-15%.

18. The organic light-emitting diode according to claim 1, wherein a mass content of the narrow-spectrum fluorescent material in the phosphorescence sensitized layer is 0.1-30%.

19. The organic light-emitting diode according to claim 18, wherein the mass content of the narrow-spectrum fluorescent material in the phosphorescence sensitized layer is 0.1-5%.

20. A display apparatus, comprising the organic light-emitting diode according to claim 1.
